(19) United States
(12) Patent Application Publication
(10) Pub. No.: US 2025/0194417 A1
(43) Pub. Date: Jun. 12, 2025

(54) ORGANIC ELECTROLUMINESCENT DEVICE

(71) Applicant: DuPont Specialty Materials Korea Ltd., Chungcheongnam-do (KR)

(72) Inventors: Doo-Hyeon MOON, Gyeonggi-do (KR); Yoo-Jin DOH, Gyeonggi-do (KR); Chi-Sik KIM, Gyeonggi-do (KR); Mi-Ja LEE, Gyeonggi-do (KR); So-Mi PARK, Gyeonggi-do (KR); Su-Hyun LEE, Gyeonggi-do (KR); HaeYeon KIM, Gyeonggi-do (KR)

(21) Appl. No.: 18/938,812

(22) Filed: Nov. 6, 2024

(30) Foreign Application Priority Data
Dec. 11, 2023 (KR) 10-2023-0178599
Sep. 5, 2024 (KR) 10-2024-0120902

(51) Int. Cl. H10K 85/60; C09K 11/02; C09K 11/06; H10K 50/15; H10K 50/16; H10K 85/20

(52) U.S. Cl. CPC H10K 85/633; C09K 11/02; C09K 11/06; H10K 50/156; H10K 50/166; H10K 85/20; H10K 85/622; H10K 85/625; H10K 85/653; H10K 85/654; H10K 85/656; H10K 85/6572; H10K 85/6574; H10K 85/6576

(57) ABSTRACT

The present disclosure relates to an organic electroluminescent device. The organic electroluminescent device according to the present disclosure can have overall device stability by comprising a deuterated compound in the electron transport zone.

### TECHNICAL FIELD

The present disclosure relates to an organic electroluminescent device comprising a deuterated compound(s).

### BACKGROUND ART

A small molecular green organic electroluminescent device (OLED) was first developed by Tang et al. of Eastman Kodak in 1987, utilizing a TPD/ALq3 bi-layer consisting of a light-emitting layer and a charge transport layer. Thereafter, OLED development progressed rapidly, leading to commercialization. Currently, OLEDs primarily use phosphorescent materials with excellent luminous efficiency in panel implementation. However, in various applications such as TVs and lighting, the lifetime of OLEDs is often insufficient, and there is still a need for higher OLED efficiency. Generally, the lifetime of an OLED decreases as its luminance increases. Thus, OLEDs with high luminous efficiency and/or extended lifetime are essential for long-term use and high-resolution displays.

In order to improve current efficiency and/or lifetime, various materials or concepts for an organic layer of an organic electroluminescent device have been proposed, but they have not proved satisfactory in practical use. In addition, there is a continuous demand for the development of an organic electroluminescent device with enhanced performance, such as improved current efficiency and/or lifetime properties, as compared to combinations of previously disclosed specific compounds.

Meanwhile, Korean Patent Application Laid-Open Nos. 2023-0046493, 2022-0081251, and 2022-0147537 disclose an organic electroluminescent device comprising a deuterated compound(s). Nevertheless, the aforementioned references fail to specifically disclose an organic electroluminescent device having overall device stability by comprising a deuterated compound(s) in the electron transport zone. In addition, there is a continuous demand for the development of light-emitting materials with enhanced performance, such as improved lifetime properties, compared to previously disclosed specific organic electroluminescent devices.

### DISCLOSURE OF INVENTION

### Technical Problem

The objective of the present disclosure is to provide an organic electroluminescent device with improved current efficiency and/or lifetime properties compared to conventional organic electroluminescent devices.

### Solution to Problem

As a result of intensive study to solve the technical problems, the present inventors found that the above objective can be achieved by an organic electroluminescent device comprising an anode, a hole transport zone, a light-emitting layer, an electron transport zone, and a cathode, wherein the hole transport zone, the light-emitting layer, and the electron transport zone each comprise a deuterated compound(s), and the structures of each of the compounds are the same as or different from each other.

### Advantageous Effects of Invention

An organic electroluminescent device of the present disclosure exhibits higher current efficiency and/or improved lifetime properties by comprising a deuterated compound(s) in each of the hole transport zone, the light-emitting layer, and the electron transport zone.

### MODE FOR THE INVENTION

Hereinafter, the present disclosure will be described in detail. However, the following description is intended to explain the present disclosure, and is not meant to restrict the scope of the present disclosure.

The term “organic electroluminescent compound” in the present disclosure refers to a compound that may be used in an organic electroluminescent device, and may be incorporated into any layer constituting an organic electroluminescent device, as necessary.

The term “organic electroluminescent material” in the present disclosure refers to a material that may be used in an organic electroluminescent device, and may comprise at least one compound. The organic electroluminescent material may be incorporated into any layer constituting an organic electroluminescent device, as necessary. For example, the organic electroluminescent material may be any of the following: a hole injection material, a hole transport material, a hole auxiliary material, a light-emitting auxiliary material, an electron-blocking material, a light-emitting material (including a host material and a dopant material), an electron buffer material, a hole-blocking material, an electron transport material, an electron injection material, etc.

The term “a plurality of organic electroluminescent materials” in the present disclosure refers to an organic electroluminescent material(s) comprising a combination of two or more compounds, which may be incorporated into any layer constituting an organic electroluminescent device. It may mean both a material before being comprised in an organic electroluminescent device (for example, before vapor deposition) and a material after being comprised in an organic electroluminescent device (for example, after vapor deposition). For example, a plurality of organic electroluminescent materials may be a combination of two or more compounds that may be comprised in at least one layer of a hole injection layer, a hole transport layer, a hole auxiliary layer, a light-emitting auxiliary layer, an electron-blocking layer, a light-emitting layer, an electron buffer layer, a hole-blocking layer, an electron transport layer, and an electron injection layer. The two or more compounds may be comprised in the same layer or different layers, and may be mixture-evaporated or co-evaporated, or may be individually evaporated.

The term “a plurality of host materials” in the present disclosure means a host material comprising a combination of at least two compounds, which may be comprised in any light-emitting layer constituting an organic electroluminescent device. It may mean both a material before being comprised in an organic electroluminescent device (for example, before vapor deposition) and a material after being comprised in an organic electroluminescent device (for example, after vapor deposition). For example, the plurality of host materials of the present disclosure is a combination of at least two host materials, and may selectively further comprise conventional materials comprised in an organic electroluminescent material. At least two compounds comprised in the plurality of host materials of the present disclosure may be comprised together in one light-emitting layer or may respectively be comprised in different light-emitting layers. For example, the at least two host materials may be mixture-evaporated or co-evaporated, or may be individually evaporated.

Herein, the term “(C1-C30)alkyl” is meant to be a linear or branched alkyl having 1 to 30 carbon atoms constituting the chain, in which the number of carbon atoms is preferably 1 to 10, and more preferably 1 to 6. The above alkyl may include methyl, ethyl, n-propyl, isopropyl, n-butyl, isobutyl, tert-butyl, sec-butyl, etc. The term “(C3-C30)cycloalkyl” is meant to be a mono- or polycyclic hydrocarbon having 3 to 30 ring backbone carbon atoms, in which the number of carbon atoms is preferably 3 to 20, and more preferably 3 to 7. The above cycloalkyl may include cyclopropyl, cyclobutyl, cyclopentyl, cyclohexyl, cyclopentylmethyl, cyclohexylmethyl, etc. The term “(3- to 7-membered) heterocycloalkyl” is meant to be a cycloalkyl having 3 to 7 ring backbone atoms, and including at least one heteroatom selected from the group consisting of B, N, O, S, Si, and P, and preferably from the group consisting of O, S, and N. The above heterocycloalkyl may include tetrahydrofuran, pyrrolidine, thiolan, tetrahydropyran, etc. The term “(C6-C30)aryl”, “(C6-C30)arylene”, and “(C6-C30)arentriyl” are meant to be a monocyclic or fused ring radical derived from an aromatic hydrocarbon having 6 to 30 ring backbone carbon atoms that can be partially saturated. The above aryl, arylene and arentriyl may comprise a spiro structure. The above aryl may include phenyl, biphenyl, terphenyl, quinquephenyl, naphthyl, binaphthyl, phenylnaphthyl, naphthylphenyl, fluorenyl, phenylfluorenyl, diphenylfluorenyl, benzofluorenyl, dibenzofluorenyl, phenanthrenyl, phenylphenanthrenyl, benzophenanthrenyl, anthracenyl, indenyl, triphenylenyl, pyrenyl, tetracenyl, perylenyl, chrysenyl, naphthacenyl, fluoranthenyl, spirobifluorenyl, spiro[fluorene-benzofluoren]yl, spiro[cyclopentene-fluoren]yl, spiro[dihydroindene-fluoren]yl, azulenyl, tetramethyldihydrophenanthrenyl, etc. Specifically, the above aryl may include phenyl, 1-naphthyl, 2-naphthyl, 1-anthryl, 2-anthryl, 9-anthryl, benzanthryl, 1-phenanthryl, 2-phenanthryl, 3-phenanthryl, 4-phenanthryl, 9-phenanthryl, naphthacenyl, pyrenyl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 1-fluorenyl, 2-fluorenyl, 3-fluorenyl, 4-fluorenyl, 9-fluorenyl, benzo[a]fluorenyl, benzo[b]fluorenyl, benzo[c]fluorenyl, dibenzofluorenyl, 2-biphenyl, 3-biphenyl, 4-biphenyl, o-terphenyl, m-terphenyl-4-yl, m-terphenyl-3-yl, m-terphenyl-2-yl, p-terphenyl-4-yl, p-terphenyl-3-yl, p-terphenyl-2-yl, m-quaterphenyl, 3-fluoranthenyl, 4-fluoranthenyl, 8-fluoranthenyl, 9-fluoranthenyl, benzofluoranthenyl, o-tolyl, m-tolyl, p-tolyl, 2,3-xylyl, 3,4-xylyl, 2,5-xylyl, mesityl, o-cumenyl, m-cumenyl, p-cumenyl, 4″-tert-butyl-p-terphenyl-4-yl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, 11,11-dimethyl-1-benzo[a]fluorenyl, 11,11-dimethyl-2-benzo[a]fluorenyl, 11,11-dimethyl-3-benzo[a]fluorenyl, 11,11-dimethyl-4-benzo[a]fluorenyl, 11,11-dimethyl-5-benzo[a]fluorenyl, 11,11-dimethyl-6-benzo[a]fluorenyl, 11,11-dimethyl-7-benzo[a]fluorenyl, 11,11-dimethyl-8-benzo[a]fluorenyl, 11,11-dimethyl-9-benzo[a]fluorenyl, 11,11-dimethyl-10-benzo[a]fluorenyl, 11,11-dimethyl-1-benzo[b]fluorenyl, 11,11-dimethyl-2-benzo[b]fluorenyl, 11,11-dimethyl-3-benzo[b]fluorenyl, 11,11-dimethyl-4-benzo[b]fluorenyl, 11,11-dimethyl-5-benzo[b]fluorenyl, 11,11-dimethyl-6-benzo[b]fluorenyl, 11,11-dimethyl-7-benzo[b]fluorenyl, 11,11-dimethyl-8-benzo[b]fluorenyl, 11,11-dimethyl-9-benzo[b]fluorenyl, 11,11-dimethyl-10-benzo[b]fluorenyl, 11,11-dimethyl-1-benzo[c]fluorenyl, 11,11-dimethyl-2-benzo[c]fluorenyl, 11,11-dimethyl-3-benzo[c]fluorenyl, 11,11-dimethyl-4-benzo[c]fluorenyl, 11,11-dimethyl-5-benzo[c]fluorenyl, 11,11-dimethyl-6-benzo[c]fluorenyl, 11,11-dimethyl-7-benzo[c]fluorenyl, 11,11-dimethyl-8-benzo[c]fluorenyl, 11,11-dimethyl-9-benzo[c]fluorenyl, 11,11-dimethyl-10-benzo[c]fluorenyl, 11,11-diphenyl-1-benzo[a]fluorenyl, 11,11-diphenyl-2-benzo[a]fluorenyl, 11,11-diphenyl-3-benzo[a]fluorenyl, 11,11-diphenyl-4-benzo[a]fluorenyl, 11,11-diphenyl-5-benzo[a]fluorenyl, 11,11-diphenyl-6-benzo[a]fluorenyl, 11,11-diphenyl-7-benzo[a]fluorenyl, 11,11-diphenyl-8-benzo[a]fluorenyl, 11,11-diphenyl-9-benzo[a]fluorenyl, 11,11-diphenyl-10-benzo[a]fluorenyl, 11,11-diphenyl-1-benzo[b]fluorenyl, 11,11-diphenyl-2-benzo[b]fluorenyl, 11,11-diphenyl-3-benzo[b]fluorenyl, 11,11-diphenyl-4-benzo[b]fluorenyl, 11,11-diphenyl-5-benzo[b]fluorenyl, 11,11-diphenyl-6-benzo[b]fluorenyl, 11,11-diphenyl-7-benzo[b]fluorenyl, 11,11-diphenyl-8-benzo[b]fluorenyl, 11,11-diphenyl-9-benzo[b]fluorenyl, 11,11-diphenyl-10-benzo[b]fluorenyl, 11,11-diphenyl-1-benzo[c]fluorenyl, 11,11-diphenyl-2-benzo[c]fluorenyl, 11,11-diphenyl-3-benzo[c]fluorenyl, 11,11-diphenyl-4-benzo[c]fluorenyl, 11,11-diphenyl-5-benzo[c]fluorenyl, 11,11-diphenyl-6-benzo[c]fluorenyl, 11,11-diphenyl-7-benzo[c]fluorenyl, 11,11-diphenyl-8-benzo[c]fluorenyl, 11,11-diphenyl-9-benzo[c]fluorenyl, 11,11-diphenyl-10-benzo[c]fluorenyl, 9,9,10,10-tetramethyl-9,10-dihydro-1-phenanthrenyl, 9,9,10,10-tetramethyl-9,10-dihydro-2-phenanthrenyl, 9,9,10,10-tetramethyl-9,10-dihydro-3-phenanthrenyl, 9,9,10,10-tetramethyl-9,10-dihydro-4-phenanthrenyl, etc.

The term “(3- to 30-membered)heteroaryl”, “(3- to 30-membered)heteroarylene”, and “(3- to 30-membered)heteroarentriyl” are meant to be an aryl group having 3 to 30 ring backbone atoms, and including at least one, preferably 1 to 4 heteroatoms selected from the group consisting of B, N, O, S, Si, P, Se, Te, and Ge. The above heteroaryl may be a monocyclic ring, or a fused ring condensed with at least one benzene ring; may be partially saturated; may be one formed by linking at least one heteroaryl or aryl group to a heteroaryl group via a single bond(s); and may comprise a spiro structure. The above heteroaryl may include a monocyclic ring-type heteroaryl such as furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, and pyridazinyl, and a fused ring-type heteroaryl such as benzofuranyl, benzothiophenyl, isobenzofuranyl, dibenzofuranyl, dibenzothiophenyl, dibenzoselenophenyl, naphthobenzofuranyl, naphthobenzothiophenyl, naphthooxazolyl, benzofuroquinolinyl, benzofuroquinazolinyl, benzofuronaphthyridinyl, benzofuropyrimidinyl, naphthofuropyrimidinyl, benzothienoquinolyl, benzothienoquinazolinyl, naphthyridinyl, benzothienonaphthyridinyl, benzothienopyrimidinyl, naphthothienopyrimidinyl, pyrimidoindolyl, benzopyrimidoindolyl, benzofuropyrazinyl, naphthofuropyrazinyl, benzothienopyrazinyl, naphthothienopyrazinyl, phenanthrooxazolyl, phenanthrothiazolyl, phenanthrobenzofuranyl, benzophenanthrothiophenyl, pyrazinoindolyl, benzopyrazinoindolyl, benzimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, benzoquinazolinyl, quinoxalinyl, benzoquinoxalinyl, carbazolyl, benzocarbazolyl, dibenzocarbazolyl, phenoxazinyl, phenanthridinyl, benzodioxolyl, dihydroacridinyl, benzotriazolyl, phenazinyl, imidazopyridyl, chromenoquinazolinyl, thiochromenoquinazolinyl, dimethylbenzoperimidinyl, indolocarbazolyl, indenocarbazolyl, etc. More specifically, the above heteroaryl may include 1-pyrrolyl, 2-pyrrolyl, 3-pyrrolyl, pyrazinyl, 2-pyridyl, 2-pyrimidinyl, 4-pyrimidinyl, 5-pyrimidinyl, 6-pyrimidinyl, 1,2,3-triazin-4-yl, 1,2,4-triazin-3-yl, 1,3,5-triazin-2-yl, 1-imidazolyl, 2-imidazolyl, 1-pyrazolyl, 1-indolidinyl, 2-indolidinyl, 3-indolidinyl, 5-indolidinyl, 6-indolidinyl, 7-indolidinyl, 8-indolidinyl, 2-imidazopyridyl, 3-imidazopyridyl, 5-imidazopyridyl, 6-imidazopyridyl, 7-imidazopyridyl, 8-imidazopyridyl, 3-pyridyl, 4-pyridyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, azacarbazol-1-yl, azacarbazol-2-yl, azacarbazol-3-yl, azacarbazol-4-yl, azacarbazol-5-yl, azacarbazol-6-yl, azacarbazol-7-yl, azacarbazol-8-yl, azacarbazol-9-yl, 1-phenanthridinyl, 2-phenanthridinyl, 3-phenanthridinyl, 4-phenanthridinyl, 6-phenanthridinyl, 7-phenanthridinyl, 8-phenanthridinyl, 9-phenanthridinyl, 10-phenanthridinyl, 1-acridinyl, 2-acridinyl, 3-acridinyl, 4-acridinyl, 9-acridinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrol-1-yl, 2-methylpyrrol-3-yl, 2-methylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-tert-butylpyrrol-4-yl, 3-(2-phenylpropyl)pyrrol-1-yl, 2-methyl-1-indolyl, 4-methyl-1-indolyl, 2-methyl-3-indolyl, 4-methyl-3-indolyl, 2-tert-butyl-1-indolyl, 4-tert-butyl-1-indolyl, 2-tert-butyl-3-indolyl, 4-tert-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-naphtho-[1,2-b]-benzofuranyl, 2-naphtho-[1,2-b]-benzofuranyl, 3-naphtho-[1,2-b]-benzofuranyl, 4-naphtho-[1,2-b]-benzofuranyl, 5-naphtho-[1,2-b]-benzofuranyl, 6-naphtho-[1,2-b]-benzofuranyl, 7-naphtho-[1,2-b]-benzofuranyl, 8-naphtho-[1,2-b]-benzofuranyl, 9-naphtho-[1,2-b]-benzofuranyl, 10-naphtho-[1,2-b]-benzofuranyl, 1-naphtho-[2,3-b]-benzofuranyl, 2-naphtho-[2,3-b]-benzofuranyl, 3-naphtho-[2,3-b]-benzofuranyl, 4-naphtho-[2,3-b]-benzofuranyl, 5-naphtho-[2,3-b]-benzofuranyl, 6-naphtho-[2,3-b]-benzofuranyl, 7-naphtho-[2,3-b]-benzofuranyl, 8-naphtho-[2,3-b]-benzofuranyl, 9-naphtho-[2,3-b]-benzofuranyl, 10-naphtho-[2,3-b]-benzofuranyl, 1-naphtho-[2,1-b]-benzofuranyl, 2-naphtho-[2,1-b]-benzofuranyl, 3-naphtho-[2,1-b]-benzofuranyl, 4-naphtho-[2,1-b]-benzofuranyl, 5-naphtho-[2,1-b]-benzofuranyl, 6-naphtho-[2,1-b]-benzofuranyl, 7-naphtho-[2,1-b]-benzofuranyl, 8-naphtho-[2,1-b]-benzofuranyl, 9-naphtho-[2,1-b]-benzofuranyl, 10-naphtho-[2,1-b]-benzofuranyl, 1-naphtho-[1,2-b]-benzothiophenyl, 2-naphtho-[1,2-b]-benzothiophenyl, 3-naphtho-[1,2-b]-benzothiophenyl, 4-naphtho-[1,2-b]-benzothiophenyl, 5-naphtho-[1,2-b]-benzothiophenyl, 6-naphtho-[1,2-b]-benzothiophenyl, 7-naphtho-[1,2-b]-benzothiophenyl, 8-naphtho-[1,2-b]-benzothiophenyl, 9-naphtho-[1,2-b]-benzothiophenyl, 10-naphtho-[1,2-b]-benzothiophenyl, 1-naphtho-[2,3-b]-benzothiophenyl, 2-naphtho-[2,3-b]-benzothiophenyl, 3-naphtho-[2,3-b]-benzothiophenyl, 4-naphtho-[2,3-b]-benzothiophenyl, 5-naphtho-[2,3-b]-benzothiophenyl, 1-naphtho-[2,1-b]-benzothiophenyl, 2-naphtho-[2,1-b]-benzothiophenyl, 3-naphtho-[2,1-b]-benzothiophenyl, 4-naphtho-[2,1-b]-benzothiophenyl, 5-naphtho-[2,1-b]-benzothiophenyl, 6-naphtho-[2,1-b]-benzothiophenyl, 7-naphtho-[2,1-b]-benzothiophenyl, 8-naphtho-[2,1-b]-benzothiophenyl, 9-naphtho-[2,1-b]-benzothiophenyl, 10-naphtho-[2,1-b]-benzothiophenyl, 2-benzofuro[3,2-d]pyrimidinyl, 6-benzofuro[3,2-d]pyrimidinyl, 7-benzofuro[3,2-d]pyrimidinyl, 8-benzofuro[3,2-d]pyrimidinyl, 9-benzofuro[3,2-d]pyrimidinyl, 2-benzothio[3,2-d]pyrimidinyl, 6-benzothio[3,2-d]pyrimidinyl, 7-benzothio[3,2-d]pyrimidinyl, 8-benzothio[3,2-d]pyrimidinyl, 9-benzothio[3,2-d]pyrimidinyl, 2-benzofuro[3,2-d]pyrazinyl, 6-benzofuro[3,2-d]pyrazinyl, 7-benzofuro[3,2-d]pyrazinyl, 8-benzofuro[3,2-d]pyrazinyl, 9-benzofuro[3,2-d]pyrazinyl, 2-benzothio[3,2-d]pyrazinyl, 6-benzothio[3,2-d]pyrazinyl, 7-benzothio[3,2-d]pyrazinyl, 8-benzothio[3,2-d]pyrazinyl, 9-benzothio[3,2-d]pyrazinyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl, 1-dibenzoselenophenyl, 2-dibenzoselenophenyl, 3-dibenzoselenophenyl, 4-dibenzoselenophenyl, etc. “Heteroaryl(ene)” may be classified into heteroaryl(ene) with electronic properties and heteroaryl(ene) with hole properties. Heteroaryl(ene) with electronic properties is a substituent that is relatively rich in electrons in the parent nucleus, for example, a substituted or unsubstituted pyridinyl, a substituted or unsubstituted pyrimidinyl, a substituted or unsubstituted triazinyl, a substituted or unsubstituted quinazolinyl, a substituted or unsubstituted quinoxalinyl, a substituted or unsubstituted quinolyl, etc.

Heteroaryl(ene) with hole properties is a substituent that is relatively electron-deficient in the parent nucleus, for example, a substituted or unsubstituted carbazolyl, a substituted or unsubstituted dibenzofuranyl, a substituted or unsubstituted dibenzothiophenyl, etc. Herein, the term “halogen” includes F, Cl, Br, and I.

In addition, “ortho-” (“o-”), “meta-” (“ ”), and “para-” (“p-”) are prefixes which each represent the relative positions of substituents. The prefix “ortho-” indicates that two substituents are adjacent to each other, and for example, when two substituents in a benzene derivative occupy positions 1 and 2, or positions 2 and 3, this is called an “ortho-” configuration. The prefix “meta-” indicates that two substituents are at positions 1 and 3, and for example, when two substituents in a benzene derivative occupy positions 1 and 3, this is called a “meta-” configuration. The prefix “para-” indicates that two substituents are at positions 1 and 4, and for example, when two substituents in a benzene derivative occupy positions 1 and 4, this is called a “para-” configuration. Unless otherwise specified, the substituent may replace hydrogen at a position where the substituent can be substituted without limitation, and when two or more hydrogen atoms in a certain functional group are each replaced with a substituent, each substituent may be the same as or different from each other. The maximum number of substituents that can be substituted for a certain functional group may be the total number of valences that can be substituted for each atom forming the functional group.

Herein, the substituted alkyl, the substituted alkenyl, the substituted cycloalkyl, the substituted cycloalkenyl, the substituted heterocycloalkyl, the substituted silyl, the substituted aryl(ene), the substituted heteroaryl(ene), the substituted alkoxy, the substituted trialkylsilyl, the substituted dialkylarylsilyl, the substituted alkyldiarylsilyl, the substituted triarylsilyl, the substituted fused ring group of an aliphatic ring(s) and an aromatic ring(s), the substituted mono- or di-alkylamino, the substituted mono- or di-alkenylamino, the substituted mono- or di-arylamino, the substituted mono- or di-heteroarylamino, the substituted alkylalkenylamino, the substituted alkylarylamino, the substituted alkylheteroarylamino, the substituted alkenylarylamino, the substituted alkenylheteroarylamino, the substituted arylheteroarylamino, the substituted dibenzofuranyl, the substituted dibenzothiophenyl, or the substituted carbazolyl each independently, may be substituted by at least one selected from the group consisting of deuterium; a halogen; a cyano; a carboxyl; a nitro; a hydroxyl; a phosphine oxide; a (C1-C30)alkyl; a halo(C1-C30)alkyl; a (C2-C30)alkenyl; a (C2-C30)alkynyl; a (C1-C30)alkoxy; a (C1-C30)alkylthio; a (C3-C30)cycloalkyl; a (C3-C30)cycloalkenyl; a (3- to 7-membered)heterocycloalkyl; a (C6-C30)aryloxy; a (C6-C30)arylthio; a (C6-C30)aryl unsubstituted or substituted with at least one of a (C1-C30)alkyl(s) a (C6-C30)aryl(s), and a (3- to 30-membered)heteroaryl(s); a (3- to 30-membered)heteroaryl unsubstituted or substituted with a (C6-C30)aryl(s); a tri(C1-C30)alkylsilyl; a tri(C6-C30)arylsilyl(s); a di(C1-C30)alkyl(C6-C30)arylsilyl; a (C1-C30)alkyldi(C6-C30)arylsilyl; a fused ring group of an (C3-C30)aliphatic ring(s) and an (C6-C30)aromatic ring(s); amino; a mono- or di-(C1-C30)alkylamino; a mono- or di-(C2-C30)alkenylamino; a mono- or di-(C6-C30)arylamino unsubstituted or substituted with a (C1-C30)alkyl(s); a mono- or di-((3- to 30-membered)heteroarylamino; a (C1-C30)alkyl(C2-C30)alkenylamino; a (C1-C30)alkyl(C6-C30)arylamino; a (C1-C30)alkyl(3- to 30-membered)heteroarylamino; a (C2-C30)alkenyl(C6-C30)arylamino; a (C2-C30)alkenyl(3- to 30-membered)heteroarylamino; a (C6-C30)aryl(3- to 30-membered)heteroarylamino; a (C1-C30)alkylcarbonyl; a (C1-C30)alkoxycarbonyl; a (C6-C30)arylcarbonyl; a di(C6-C30)arylboronyl; a di(C1-C30)alkylboronyl; a (C1-C30)alkyl(C6-C30)arylboronyl; a (C6-C30)aryl(C1-C30)alkyl; and a (C1-C30)alkyl(C6-C30)aryl. According to one embodiment of the present disclosure, the substituted alkyl, etc. each independently are substituted by at least one selected from the group consisting of a (C1-C25)alkyl; a (C3-C25)cycloalkyl; a (C6-C25)aryl unsubstituted or substituted with at least one of a (C1-C30)alkyl(s) a (C6-C30)aryl(s), and a (3- to 30-membered)heteroaryl(s); a (3- to 25-membered)heteroaryl unsubstituted or substituted with a (C6-C30)aryl(s); and a mono- or di-(C6-C25)arylamino unsubstituted or substituted with a (C6-C30)aryl(s). For example, the substituted alkyl, etc. may be substituted by at least one selected from the group consisting of a methyl, a phenyl, a biphenyl, a terphenyl, a naphthyl, a naphthyl substituted with a phenyl(s), a naphthyl substituted with a naphthyl(s), a naphthyl substituted with a dibenzofuranyl(s), a phenanthrenyl, a triphenylene, a benzofluorenyl, a benzofluorenyl substituted with a methyl(s), a benzofluorenyl substituted with a phenyl(s), a carbazolyl, carbazolyl substituted with a phenyl(s), a dibenzofuranyl, a dibenzothiophenyl, a diphenylamino, a phenylbiphenylamino, etc.

In the present disclosure, if a substituent is not indicated in the formula or compound structure, it may mean that all possible positions for the substituent are hydrogen or deuterium. That is, in the case of deuterium, it is an isotope of hydrogen, and some hydrogen atoms may be the isotope deuterium, and in this case, the content of deuterium may be 0% to 100%. In the present disclosure, in cases where a substituent is not indicated in the formula or compound structure, if the substituent is not explicitly excluded, such as 0% deuterium, 100% hydrogen, and all substituents are hydrogen, hydrogen and deuterium may be used intermixed in a compound. The deuterium is one of the isotopes of hydrogen and an element with a deuteron consisting of one proton and one neutron as its nucleus. It can be represented as hydrogen-2, whose element symbol can also be written as D or ²H. The isotopes are atoms with the same atomic number (Z) but different mass numbers (A), and can also be interpreted as elements with the same number of protons but different numbers of neutrons.

In the present disclosure, “a combination thereof” refers to a combination of one or more elements from the corresponding list to form a known or chemically stable arrangement that can be envisioned by a person skilled in the art from the corresponding list. For example, alkyl and deuterium can be combined to form a partially or fully deuterated alkyl group; halogen and alkyl can be combined to form a halogenated alkyl substituent; and halogen, alkyl, and aryl can be combined to form a halogenated arylalkyl. For example, a preferred combination of substituents includes up to 50 atoms that are not hydrogen or deuterium, up to 40 atoms that are not hydrogen or deuterium, or up to 30 atoms that are not hydrogen or deuterium, but in many cases, a preferred combination of substituents may comprise up to 20 atoms that are not hydrogen or deuterium.

In the formula of the present disclosure, when there are multiple substituents represented by the same symbol, each substituent represented by the same symbol may be the same as or different from each other.

In the formulas of the present disclosure, when forming a ring by linking to adjacent substituents, the ring may be linked to an adjacent two or more substituent(s) to form a substituted or unsubstituted, mono- or polycyclic, (3- to 30-membered) alicyclic or aromatic ring, or a combination thereof. In addition, the formed ring may contain at least one heteroatom selected from B, N, O, S, Si, and P, preferably at least one heteroatom selected from N, O, and S. According to one embodiment of the present disclosure, the number of ring backbone atoms is (5- to 20-membered), and according to another embodiment of the present disclosure, the number of ring backbone atoms is (5- to 15-membered).

The present disclosure relates to an organic electroluminescent device comprising an anode, a hole transport zone, a light-emitting layer, an electron transport zone, and a cathode, wherein the hole transport zone, the light-emitting layer, and the electron transport zone each comprise a deuterated compound(s), and the structures of each of the compounds are the same as or different from each other.

According to one embodiment of the present disclosure, the organic electroluminescent device is provided wherein the hole transport zone is configured by sequentially stacking a hole injection layer, a hole transport layer composed of one or more layers, and a hole auxiliary layer or an electron-blocking layer composed of one or more layers on the anode, and wherein at least one of the layers comprises a deuterated compound(s).

According to one embodiment of the present disclosure, the organic electroluminescent device is provided wherein the electron transport zone is configured by sequentially stacking an electron buffer layer or a hole-blocking layer composed of one or more layers, an electron transport layer composed of one or more layers, and an electron injection layer on the light-emitting layer, and at least one of the layers comprises a deuterated compound(s).

According to one embodiment of the present disclosure, the organic electroluminescent device is provided wherein the light-emitting layer is composed of one or more layers, and at least one of the light-emitting layers comprises one or more deuterated compounds as a host.

According to one embodiment of the present disclosure, the organic electroluminescent device is provided wherein the light-emitting layer comprises a phosphorescent or fluorescent luminescent compound, and the compound comprises iridium (Ir), platinum (Pt), or boron (B) atoms.

According to one embodiment of the present disclosure, the organic electroluminescent device according to the present disclosure may comprise at least one layer of the hole transport zone comprising a compound represented by the following formula 1.

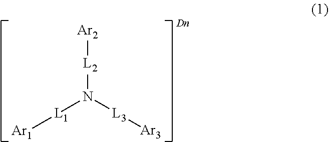

In formula 1,
Ar₁ to Ar₃ each independently represent hydrogen, deuterium, a halogen, a cyano, a substituted or unsubstituted (C1-C30)alkyl, a substituted or unsubstituted (C3-C30)cycloalkyl, a substituted or unsubstituted silyl, a substituted or unsubstituted (C6-C30)aryl, a substituted or unsubstituted (3- to 30-membered)heteroaryl, a substituted or unsubstituted mono- or di-(C6-C30)arylamino, a mono- or di-(C1-C30)alkylamino, a mono- or di-(C2-C30)alkenylamino, a (C1-C30)alkyl(C6-C30)arylamino, a mono- or di-(3- to 30-membered)heteroarylamino, or a (C6-C30)aryl(3- to 30-membered)heteroarylamino, with a proviso that each of Ar₁ to each of Ar₃ comprise at least one of a substituted or unsubstituted (C6-C30)aryl(s) or a substituted or unsubstituted (3- to 30-membered)heteroaryl(s);
L₁ to L₃ each independently represent a single bond, a substituted or unsubstituted (C6-C30)arylene, or a substituted or unsubstituted (3- to 30-membered)heteroarylene; and
Dₙ represents that n number of hydrogens are replaced with deuterium, and n represents an integer of 1 or more, and has an upper limit of the number of hydrogen atoms in the non-deuterated compound.

According to one embodiment of the present disclosure, Ar₁ to Ar₃ each independently represent hydrogen, deuterium, a substituted or unsubstituted (C6-C30)aryl, a substituted or unsubstituted (3- to 30-membered)heteroaryl, or a substituted or unsubstituted mono- or di-(C6-C30)arylamino; preferably hydrogen, deuterium, a substituted or unsubstituted (C6-C26)aryl, a substituted or unsubstituted (3- to 13-membered)heteroaryl, or a substituted or unsubstituted mono- or di-(C6-C12)arylamino, with a proviso that each of Ar₁ to each of Ar₃ may comprise at least one of a substituted or unsubstituted (C6-C30)aryl(s) or a substituted or unsubstituted (3- to 30-membered)heteroaryl(s). More preferably, at least one of Ar₁ to Ar₃ represents a substituted or unsubstituted phenanthrenyl, a substituted or unsubstituted carbazolyl, a substituted or unsubstituted fluorenyl, a substituted or unsubstituted benzofluorenyl, a substituted or unsubstituted triphenylenyl, a substituted or unsubstituted dibenzofuranyl, or a substituted or unsubstituted dibenzothiophenyl. For example, Ar₁ to Ar₃ each independently represent a substituted or unsubstituted fluorenyl, a substituted or unsubstituted benzofluorenyl, a substituted or unsubstituted spirobifluorenyl, a substituted or unsubstituted phenyl, a substituted or unsubstituted biphenyl, a substituted or unsubstituted terphenyl, a substituted or unsubstituted phenanthrenyl, a substituted or unsubstituted carbazolyl, a substituted or unsubstituted dibenzothiophenyl, a substituted or unsubstituted dibenzofuranyl, a substituted or unsubstituted diphenylamino, or a substituted or unsubstituted phenylbiphenylamino, etc., with a proviso that each of Ar₁ to each of Ar₃ may comprise at least one of a substituted or unsubstituted (C6-C30)aryl(s) or a substituted or unsubstituted (3- to 30-membered)heteroaryl(s). In the above, the substituents of the substituted ones may be at least one selected from deuterium, a methyl(s), a phenyl(s), a biphenyl(s), a phenanthrenyl(s), a benzofluorenyl(s) substituted with a methyl(s), a benzofluorenyl(s) substituted with a phenyl(s), a carbazolyl(s), a carbazolyl(s) substituted with a phenyl(s), a dibenzofuranyl(s), a diphenylamino(s), and a phenylbiphenylamino(s).

According to one embodiment of the present disclosure, L₁ to L₃ each independently may represent a single bond, a substituted or unsubstituted (C6-C25)arylene, or a substituted or unsubstituted (3- to 25-membered)heteroarylene. Preferably, L₁ to L₃ each independently may represent a single bond, a substituted or unsubstituted (6-C12)arylene, or a substituted or unsubstituted (3- to 13-membered)heteroarylene. For example, L₁ to L₃ each independently may be a single bond, a substituted or unsubstituted phenylene, a biphenylene, a substituted or unsubstituted carbazolylene, a dibenzothiophenylene, or a dibenzofuranylene, etc. In the above, the substituents of the substituted ones may be at least one selected from deuterium, a phenyl(s), a carbazolyl(s), a carbazolyl(s) substituted with a phenyl(s), a dibenzofuranyl(s), and a dibenzothiophenyl(s).

According to one embodiment of the present disclosure, the deuterium substitution rate is preferably 20% to 100% of the total number of hydrogens, more preferably 20% to 95%, even more preferably 30% to 95%, and even more preferably 40% to 95%.

According to one embodiment of the present disclosure, the deuterated compound may be more specifically exemplified as the following compounds, but is not limited thereto.

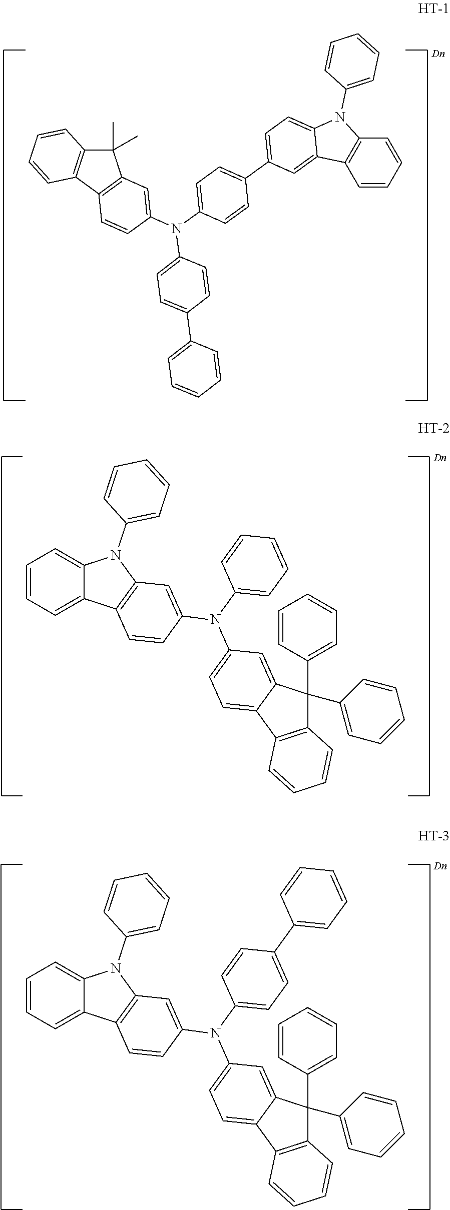

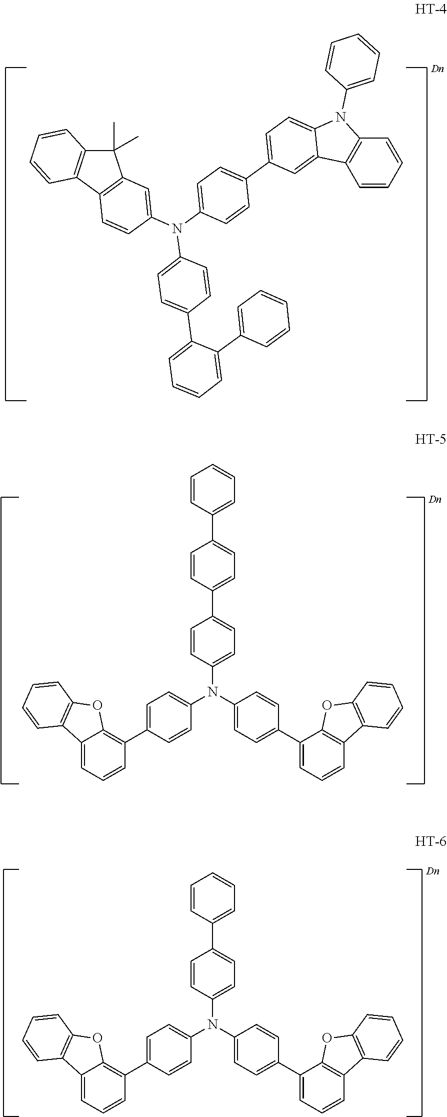

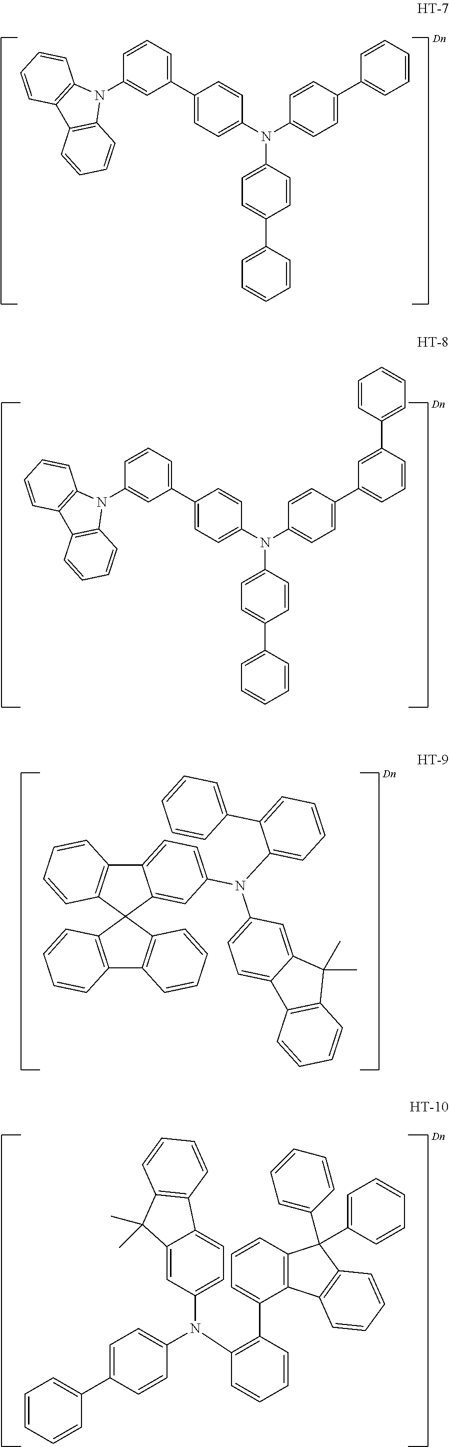

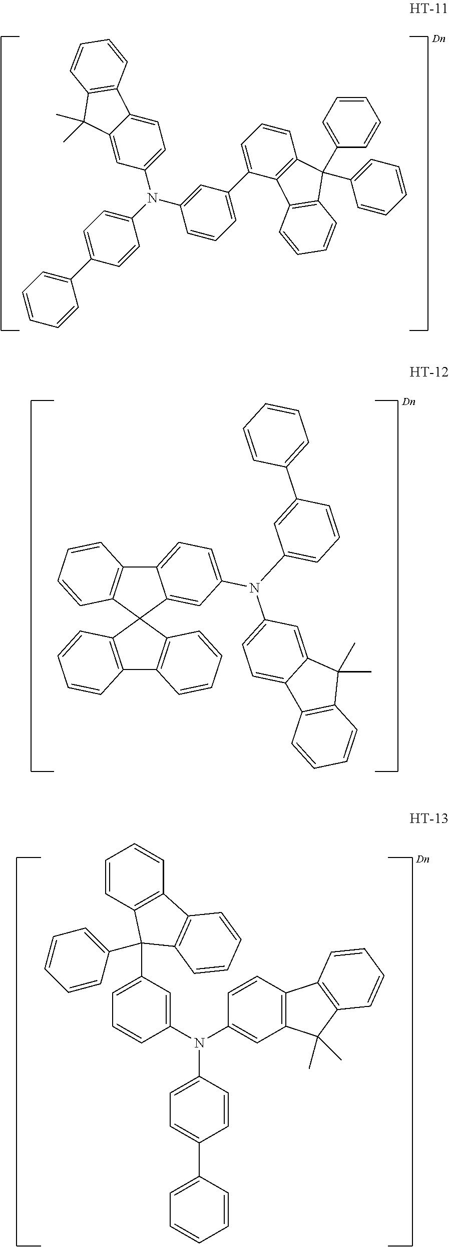

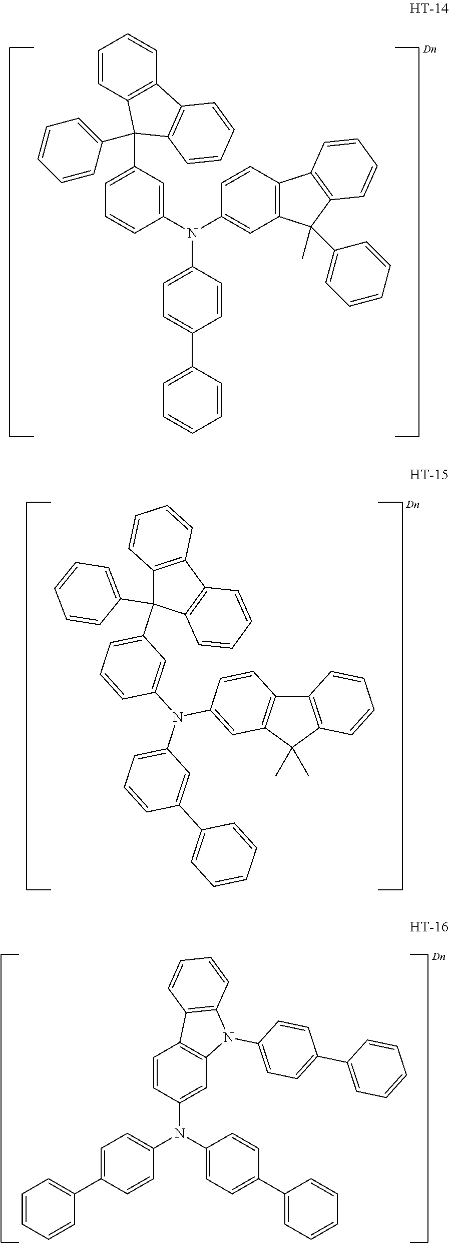

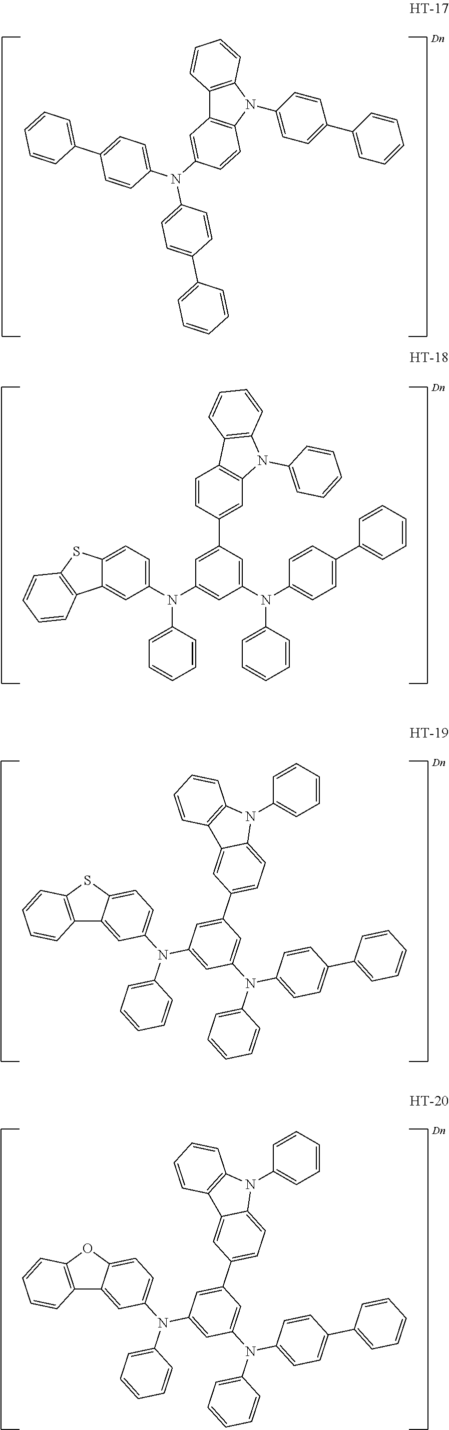

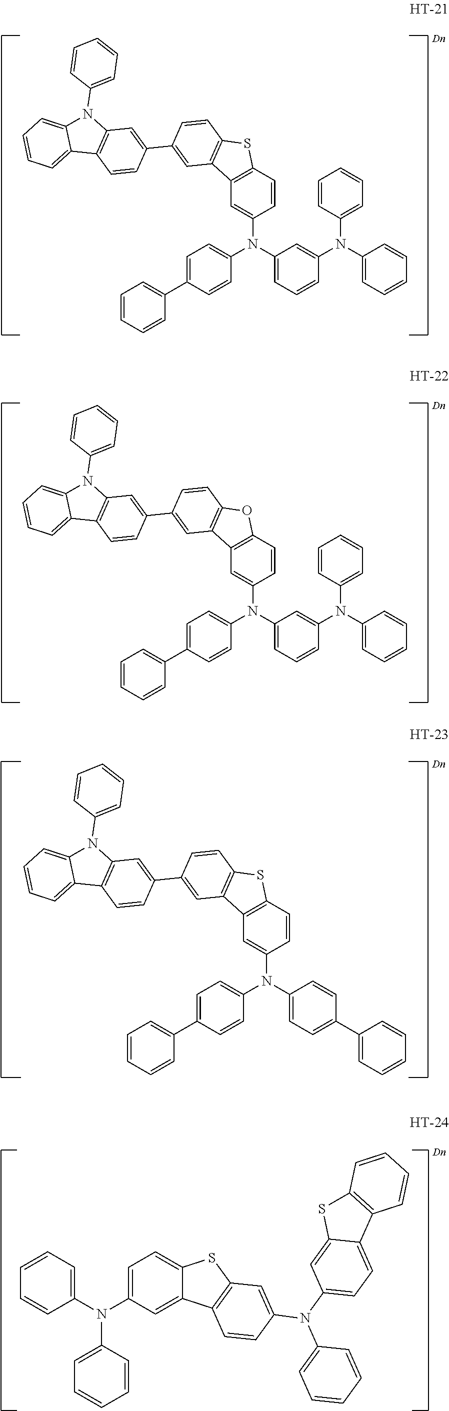

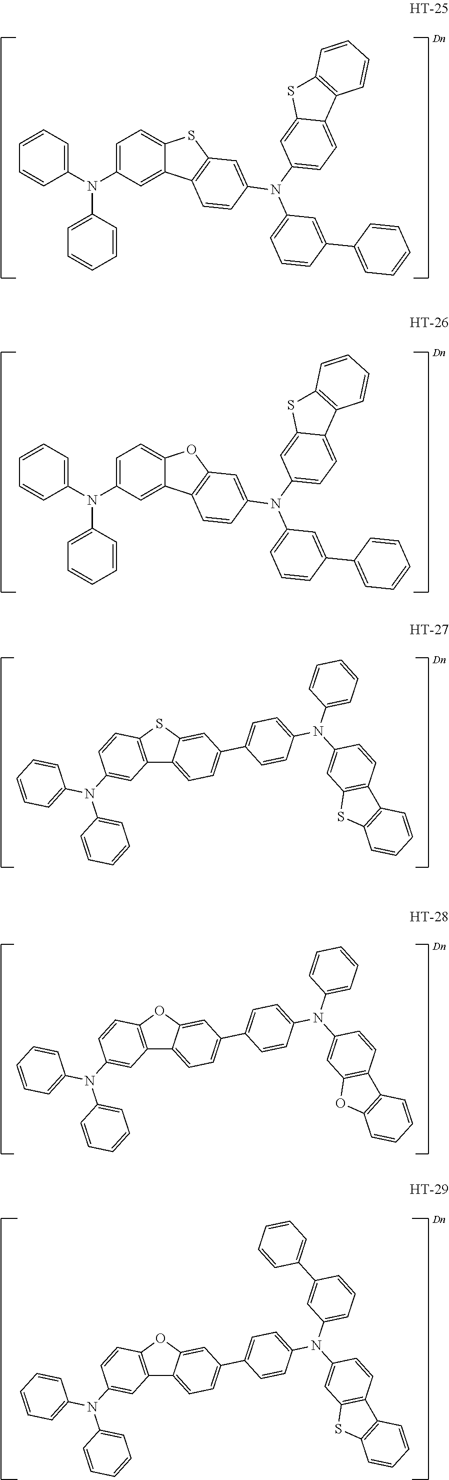

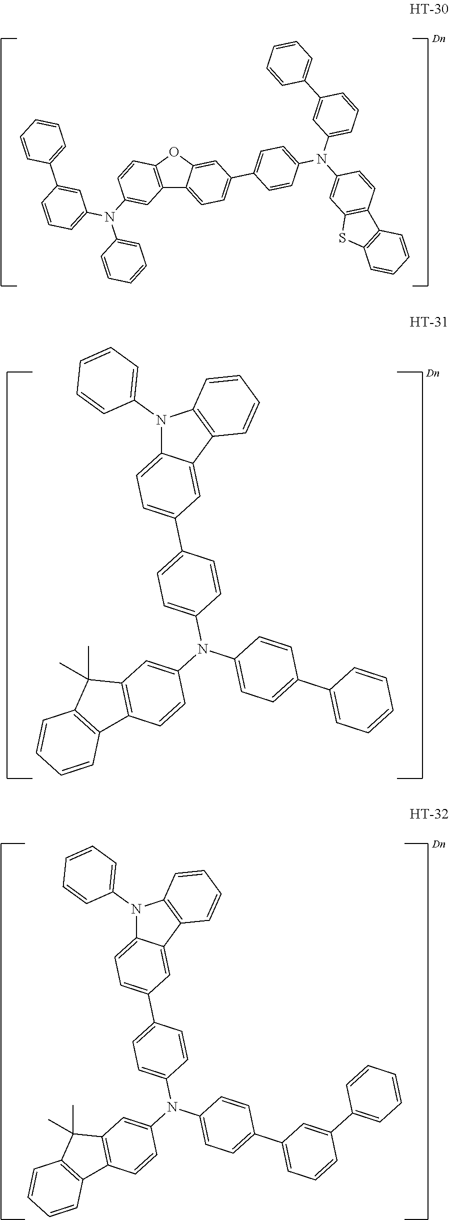

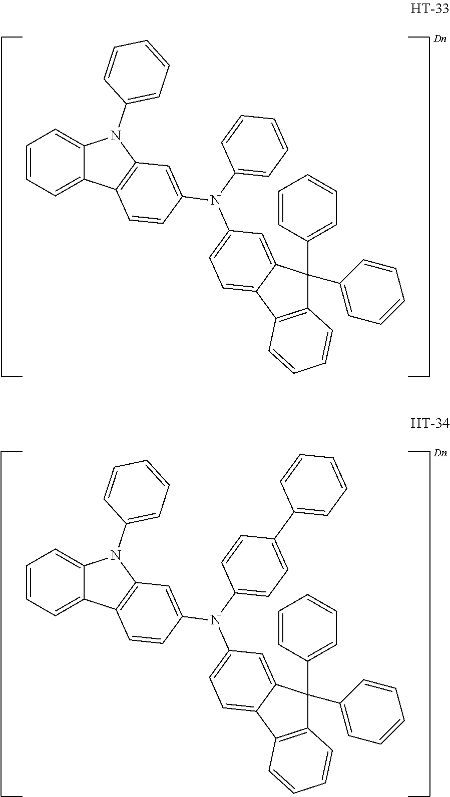

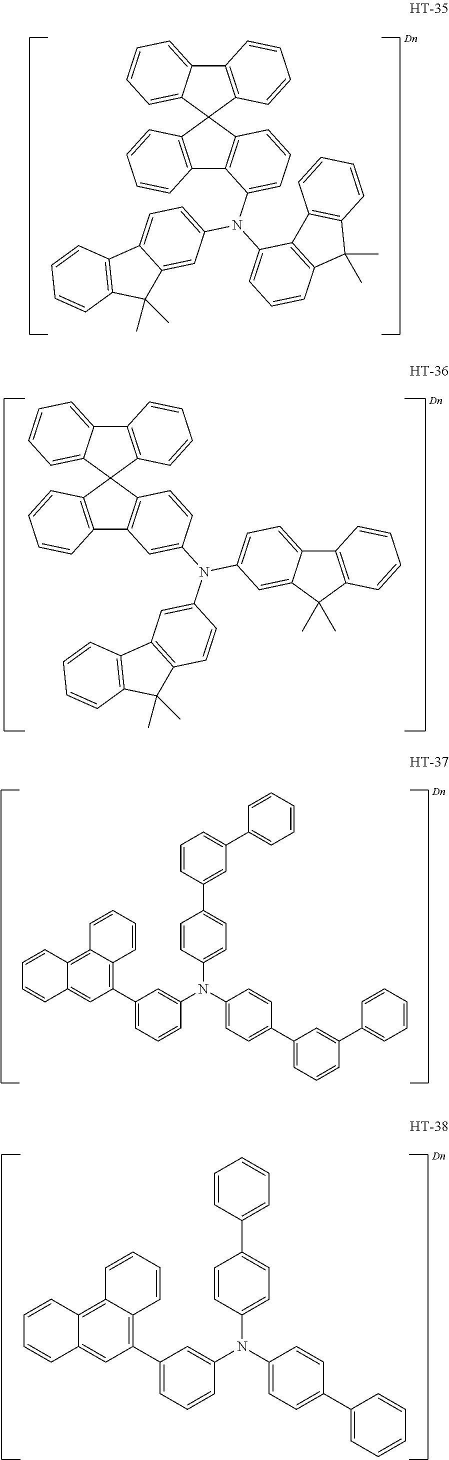

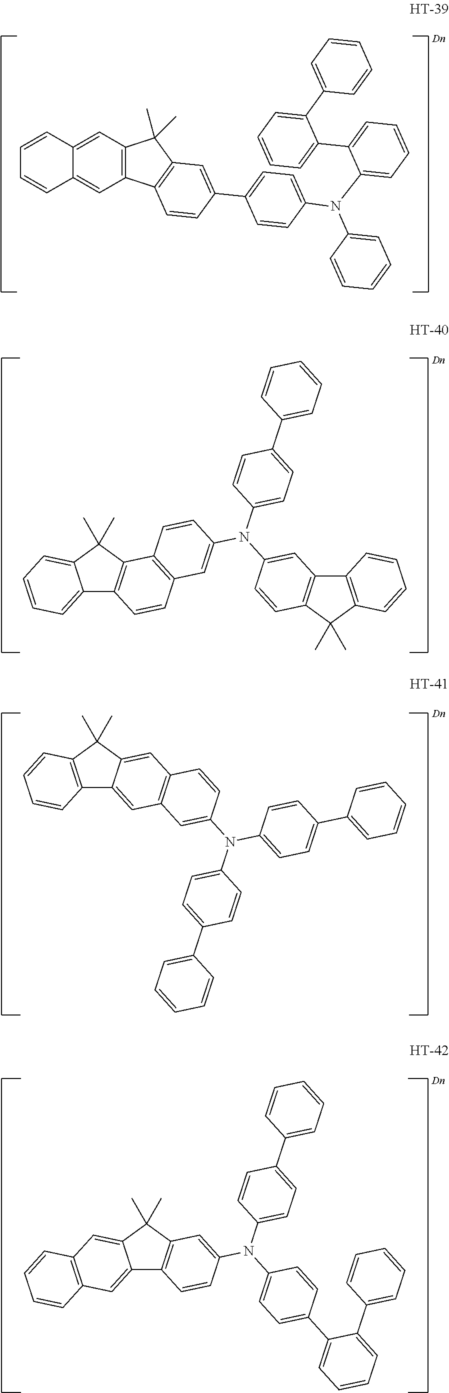

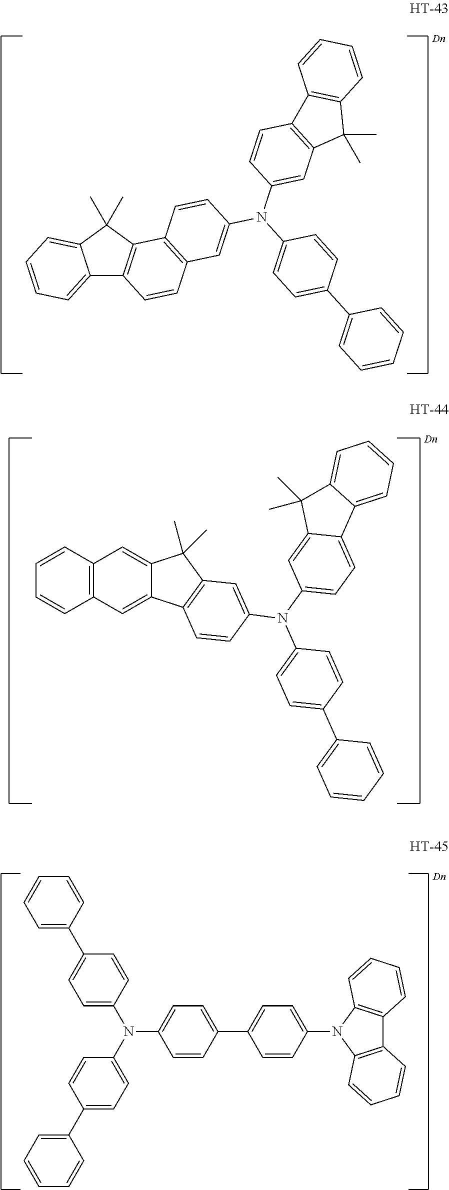

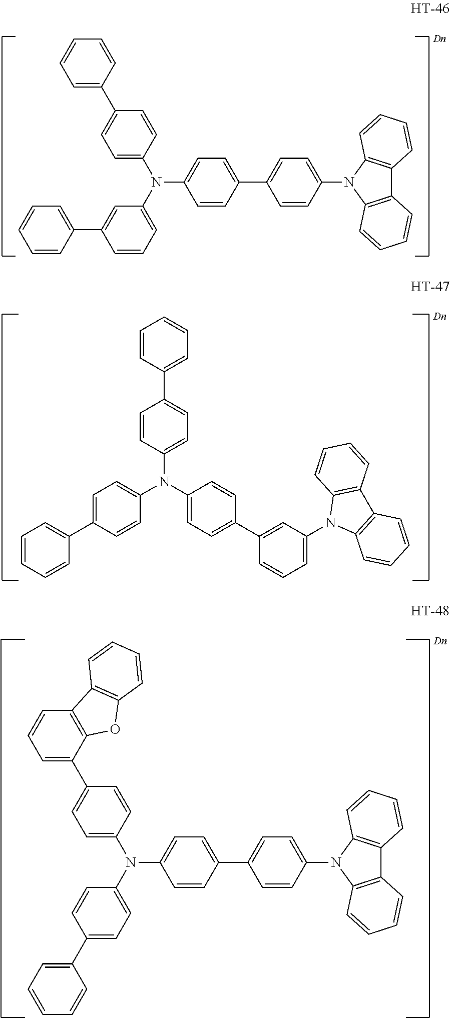

According to one embodiment of the present disclosure, the organic electroluminescent device of the present disclosure may comprise a compound represented by the following formula 2 or formula 3 in at least one layer of the electron transport zone.

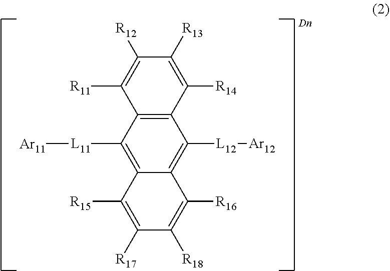

In formula 2,
L₁₁ and L₁₂ each independently represent a single bond, a substituted or unsubstituted (C6-C30)arylene, or a substituted or unsubstituted (3- to 30-membered)heteroarylene;
Ar₁₁ and Ar₁₂ each independently represent a substituted or unsubstituted (C6-C30)aryl or a substituted or unsubstituted (3- to 30-membered)heteroaryl;
R₁₁ to R₁₈ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C2-C30)alkenylamino, a substituted or unsubstituted mono- or di-(C6-C30)arylamino, a substituted or unsubstituted mono- or di-(3- to 30-membered)heteroarylamino, a substituted or unsubstituted (C1-C30)alkyl(C2-C30)alkenylamino, a substituted or unsubstituted (C1-C30)alkyl(C6-C30)arylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C₃₀)aryl(3- to 30-membered)heteroarylamino;
at least one of R₁₁ and R₁₄ to R₁₆ represents deuterium; and
Dₙ represents that n number of hydrogens are replaced with deuterium, and n represents an integer of 1 or more, and has an upper limit of the number of hydrogen atoms in the non-deuterated compound.

According to one embodiment of the present disclosure, L₁₁ and L₁₂ each independently may represent a single bond or a substituted or unsubstituted (C6-C30)arylene; preferably a single bond or a substituted or unsubstituted (C6-C25)arylene; more preferably a single bond or a substituted or unsubstituted (C6-C18)arylene. For example, L₁₁ and L₁₂ each independently may be a single bond or a phenylene.

According to one embodiment of the present disclosure, Ar₁₁ and Ar₁₂ each independently may represent a substituted or unsubstituted (C6-C30)aryl or a substituted or unsubstituted (5- to 30-membered)heteroaryl; preferably, a substituted or unsubstituted (C6-C25)aryl or a substituted or unsubstituted (5- to 25-membered)heteroaryl; more preferably, a substituted or unsubstituted (C6-C25)aryl or a substituted or unsubstituted (5- to 20-membered)heteroaryl. For example, Ar₁₁ and Ar₁₂ each independently may be a substituted or unsubstituted phenyl, a substituted or unsubstituted naphthyl, a substituted or unsubstituted m-biphenyl, a substituted or unsubstituted p-biphenyl, or a substituted or unsubstituted benzimidazolyl represented by the following formula 2-1 or 2-2.

According to one embodiment of the present disclosure, the deuterium substitution rate is preferably 20% to 100% of the total number of hydrogens, more preferably 20% to 95%, even more preferably 30% to 95%, and even more preferably 40% to 95%.

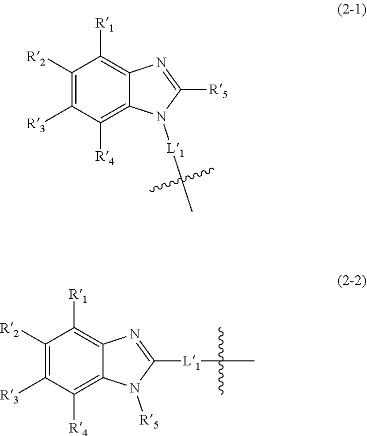

In formula 2-1 and 2-2,
L′₁ represents a single bond, a substituted or unsubstituted (C6-C30)arylene, or a substituted or unsubstituted (3- to 30-membered)heteroarylene; and
R′₁ to R′₅ each independently represent hydrogen, deuterium, a substituted or unsubstituted (C1-C30)alkyl, a substituted or unsubstituted (C6-C30)aryl, or a substituted or unsubstituted (3- to 30-membered)heteroaryl.

According to one embodiment of the present disclosure, L′₁ may represent a single bond or a substituted or unsubstituted (C6-C30)arylene; preferably, a single bond or a substituted or unsubstituted (C6-C25)arylene; more preferably a single bond or a substituted or unsubstituted (C6-C18)arylene. For example, L′₁ may be a single bond or a phenylene.

According to one embodiment of the present disclosure, R′₁ to R′₄ each independently may represent hydrogen or deuterium.

According to one embodiment of the present disclosure, R′₅ may represent a substituted or unsubstituted (C1-C30)alkyl or a substituted or unsubstituted (C6-C30)aryl; preferably, a substituted or unsubstituted (C1-C10)alkyl or a substituted or unsubstituted (C6-C25)aryl; more preferably a substituted or unsubstituted (C1-C4)alkyl or a substituted or unsubstituted (C6-C18)aryl. For example, R′₅ may be an ethyl, a phenyl, a naphthyl, or a biphenyl.

According to one embodiment of the present disclosure, R₁₁ to R₁₈ each independently may represent hydrogen, deuterium, or a substituted or unsubstituted benzimidazolyl represented by the following formula 2-1 or 2-2.

According to one embodiment of the present disclosure, at least one of R₁₁ to R₁₈, Ar₁₁, and Ar₁₂ may be a substituted or unsubstituted benzimidazolyl represented by the above formula 2-1 or 2-2.

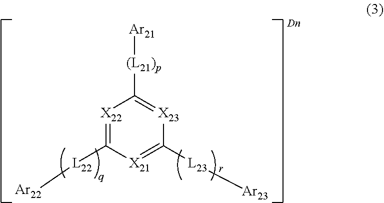

In formula 3,
X₂₁ to X₂₃ each independently represent CR′ or N, with a proviso that at least two of X₂₁ to X₂₃ represent N;
R′ represents hydrogen or deuterium;
L₂₁ to L₂₃ each independently represent a single bond, a substituted or unsubstituted (C6-C₃₀)arylene, or a substituted or unsubstituted (3- to 30-membered)heteroarylene;
Ar₂₁ to Ar₂₃ each independently represent a substituted or unsubstituted (C6-C30)aryl or a substituted or unsubstituted (3- to 30-membered)heteroaryl, with a proviso that at least one of Ar₂₁ to Ar₂₃ comprises deuterium;
p, q, and reach independently represent an integer of 1 to 3, in which if p, q, and r represent an integer of 2 or more, each of L₂₁ to each of L₂₃ may be the same or different; and
Dₙ represents that n number of hydrogens are replaced with deuterium, and n represents an integer of 1 or more, and has an upper limit of the number of hydrogen atoms in the non-deuterated compound.

According to one embodiment of the present disclosure, at least two of X₂₁ to X₂₃ represent N, and preferably, all of X₂₁ to X₂₃ may represent N.

According to one embodiment of the present disclosure, L₂₁ to L₂₃ each independently may represent a single bond or a substituted or unsubstituted (C6-C30)arylene. Preferably, L₂₁ to L₂₃ each independently represent a single bond or a substituted or unsubstituted (C6-C25)arylene. More preferably, L₂₁ to L₂₃ each independently may represent a single bond or a substituted or unsubstituted (C6-C18)arylene. For example, L₂₁ to L₂₃ each independently may be a single bond, a substituted or unsubstituted phenylene, a substituted or unsubstituted naphthylene, a substituted or unsubstituted p-biphenylene, a substituted or unsubstituted m-biphenylene, or a substituted or unsubstituted o-terphenylene. In the above, the substituents of the substituted ones may be at least one selected from deuterium, a phenanthrenyl(s), a pyridyl(s) unsubstituted or substituted with at least one of a methyl(s) or a phenyl(s), and quinolinyl(s).

According to one embodiment of the present disclosure, Ar₂₁ to Ar₂₃ each independently may represent a substituted or unsubstituted (C6-C30)aryl or a substituted or unsubstituted (5- to 30-membered)heteroaryl; preferably, a substituted or unsubstituted (C6-C25)aryl or a substituted or unsubstituted (5- to 26-membered)heteroaryl; and more preferably, a substituted or unsubstituted (C6-C18)aryl or a substituted or unsubstituted (5- to 26-membered)heteroaryl. Preferably, at least one of Ar₂₁ to Ar₂₃ may comprise a substituted or unsubstituted phenanthrenyl, a substituted or unsubstituted carbazolyl, a substituted or unsubstituted fluorenyl, a substituted or unsubstituted benzofluorenyl, a substituted or unsubstituted triphenylenyl, a substituted or unsubstituted dibenzofuranyl, or a substituted or unsubstituted dibenzothiophenyl, with a proviso that at least one of Ar₂₁ to Ar₂₃ comprises deuterium. For example, Ar₂₁ to Ar₂₃ each independently represent a substituted or unsubstituted phenyl, a substituted or unsubstituted naphthyl, a substituted or unsubstituted p-biphenyl, a substituted or unsubstituted m-biphenyl, a substituted or unsubstituted phenanthrenyl, a substituted or unsubstituted fluorenyl, a substituted or unsubstituted pyridyl, a substituted or unsubstituted triazinyl, a substituted or unsubstituted quinolinyl, a substituted or unsubstituted spiro[fluorene-9,9′-xanthene]yl, or a 22-membered heteroaryl, and the substituents of the substituted ones may be at least one selected from deuterium, a cyano(s), a methyl(s), a phenyl(s), a biphenyl(s), and a naphthyl(s).

According to one embodiment of the present disclosure, the deuterium substitution rate is preferably 20% to 100% of the total number of hydrogens, more preferably 20% to 95%, even more preferably 30% to 95%, and even more preferably 40% to 95%.

According to one embodiment of the present disclosure, the deuterated compound may be more specifically exemplified as the following compounds, but is not limited thereto.

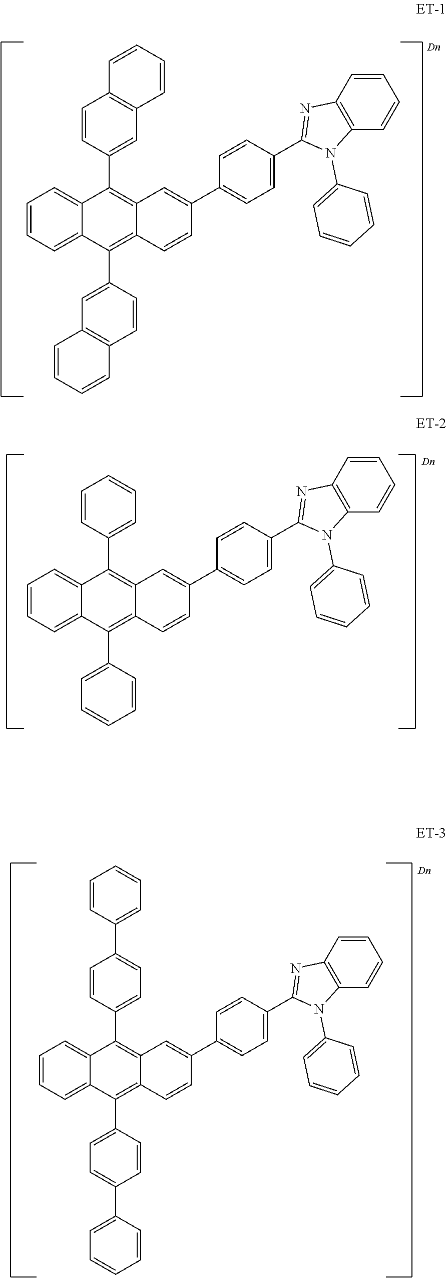

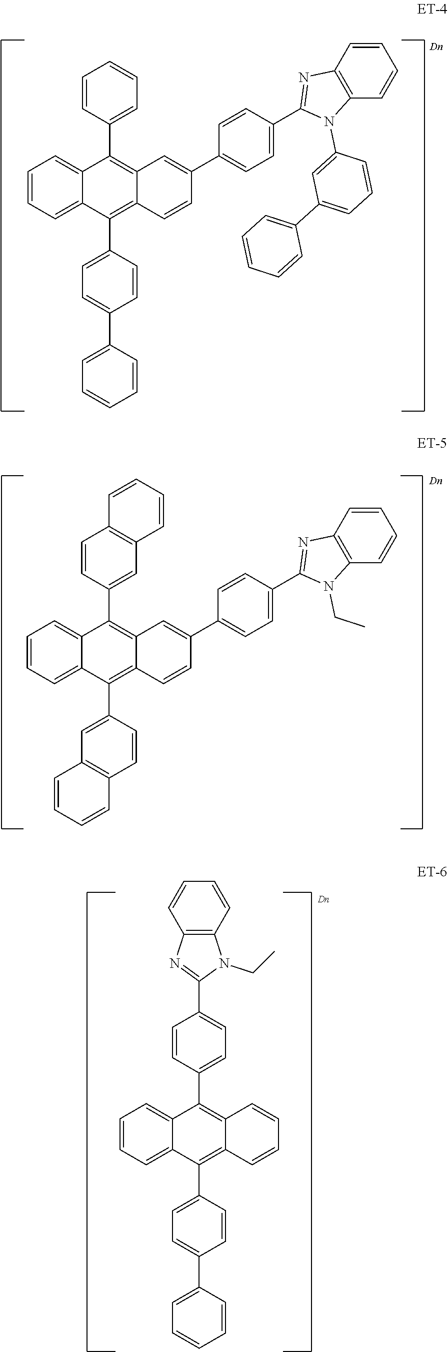

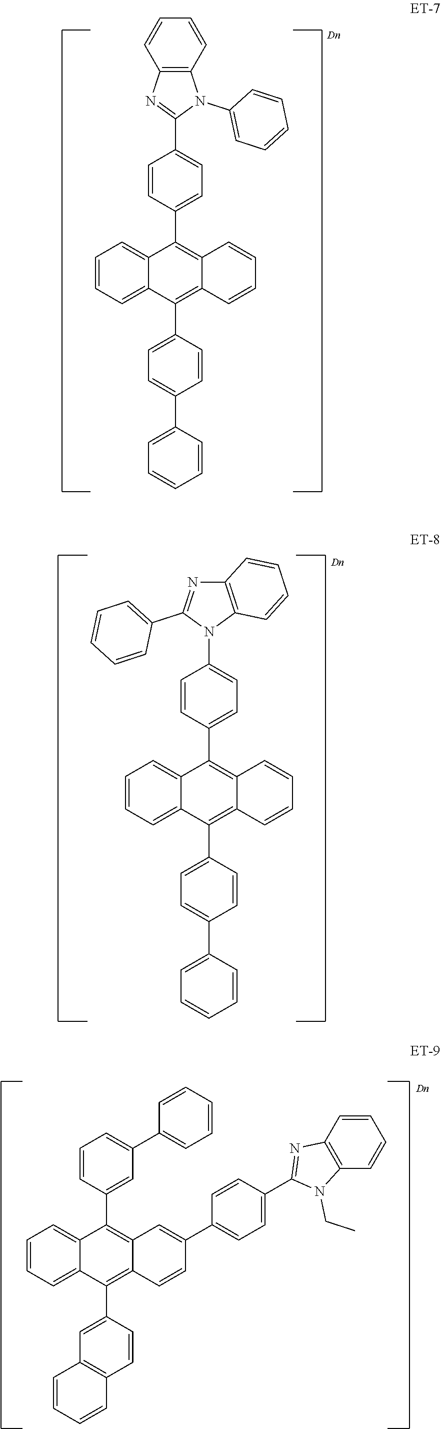

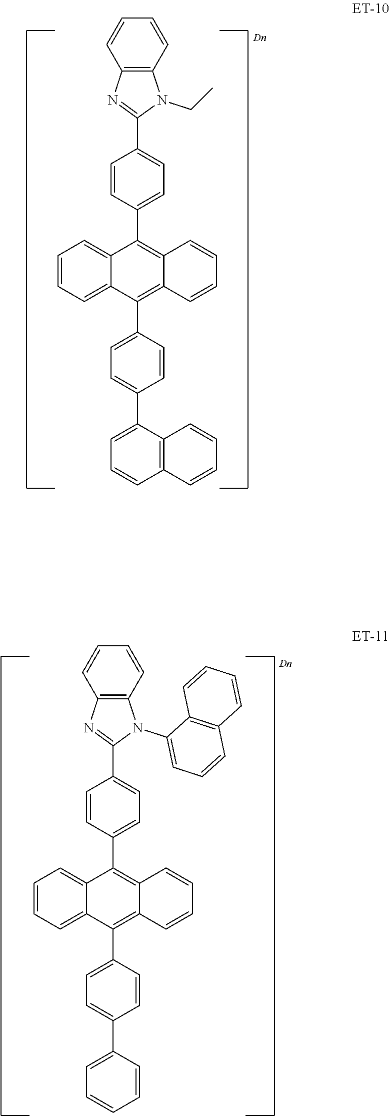

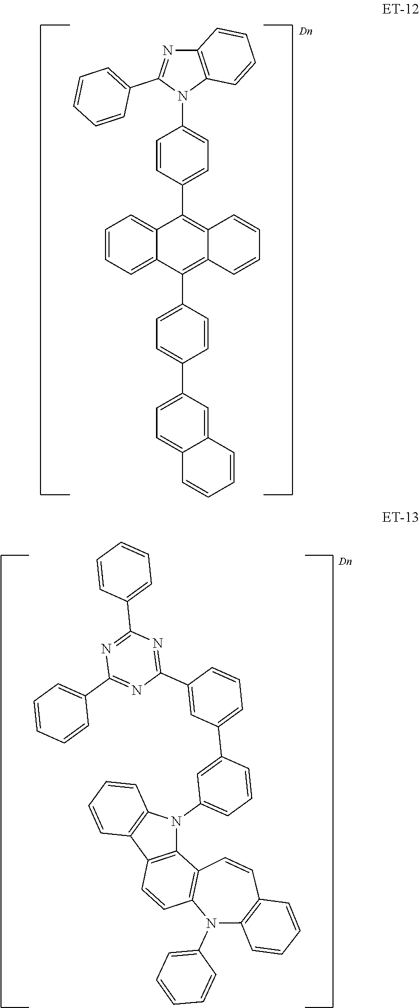

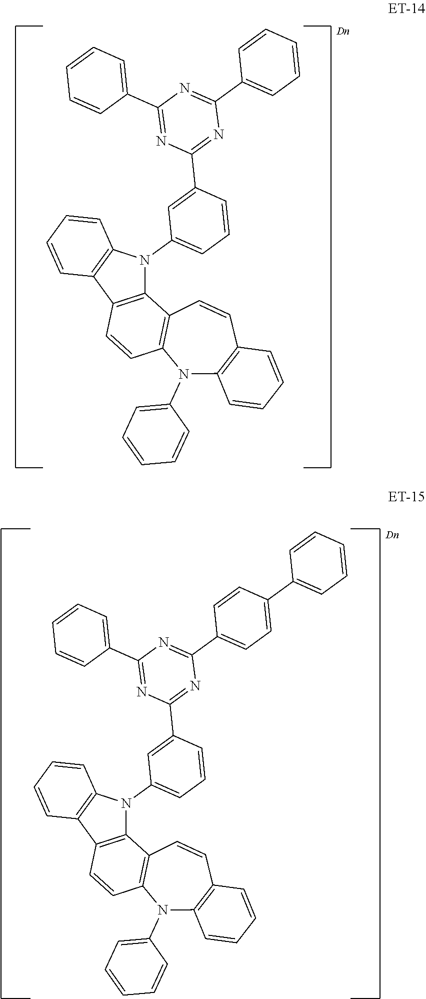

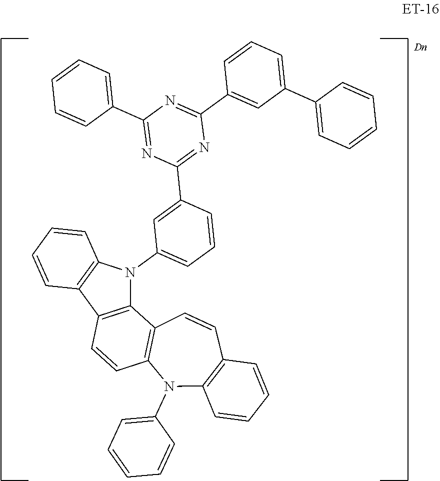

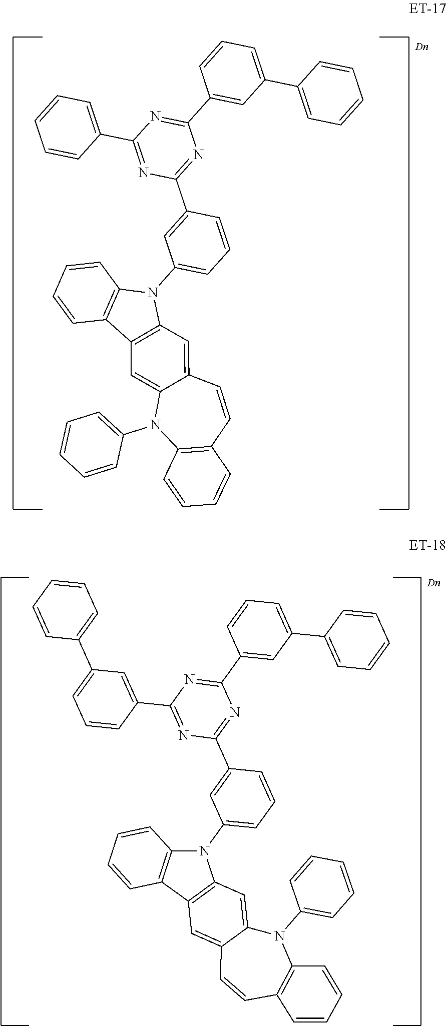

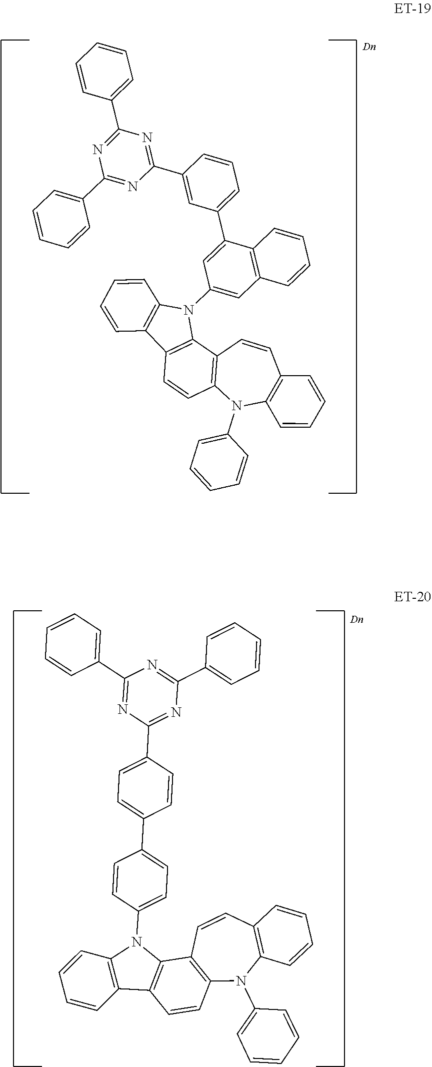

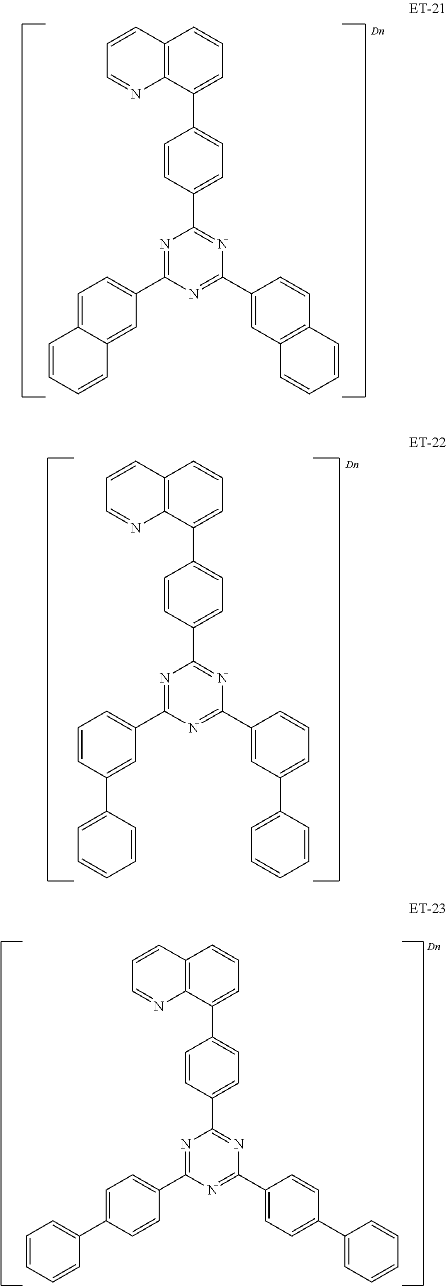

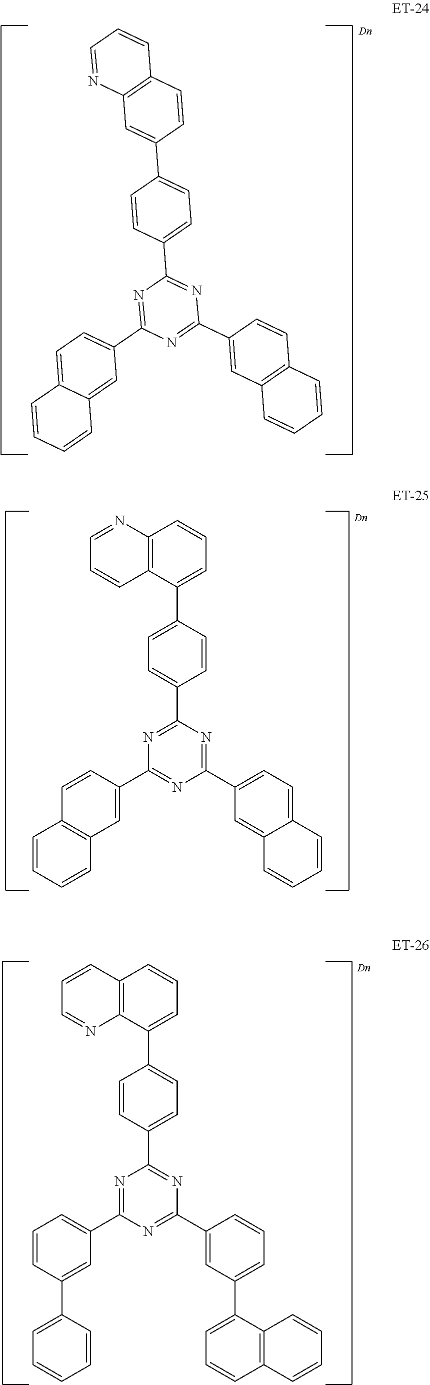

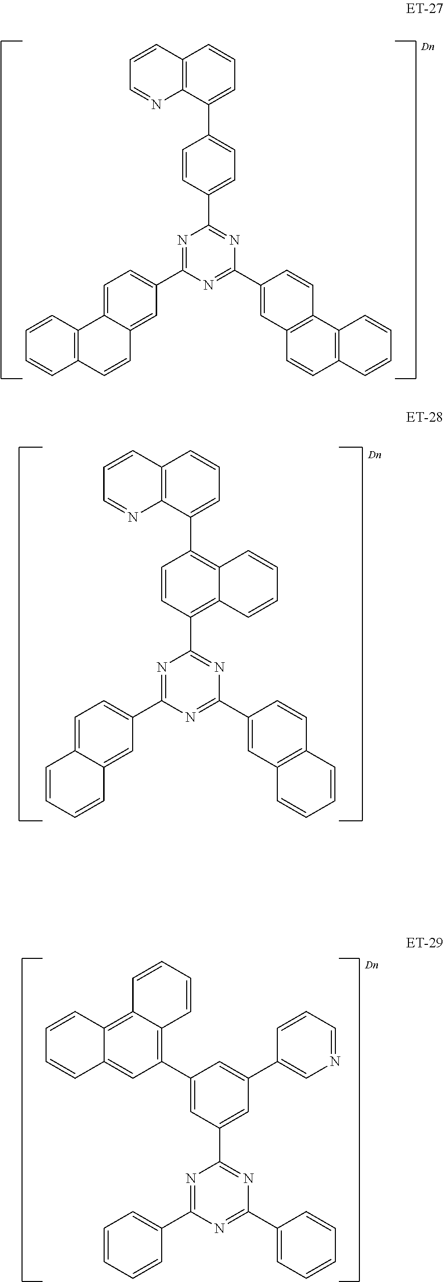

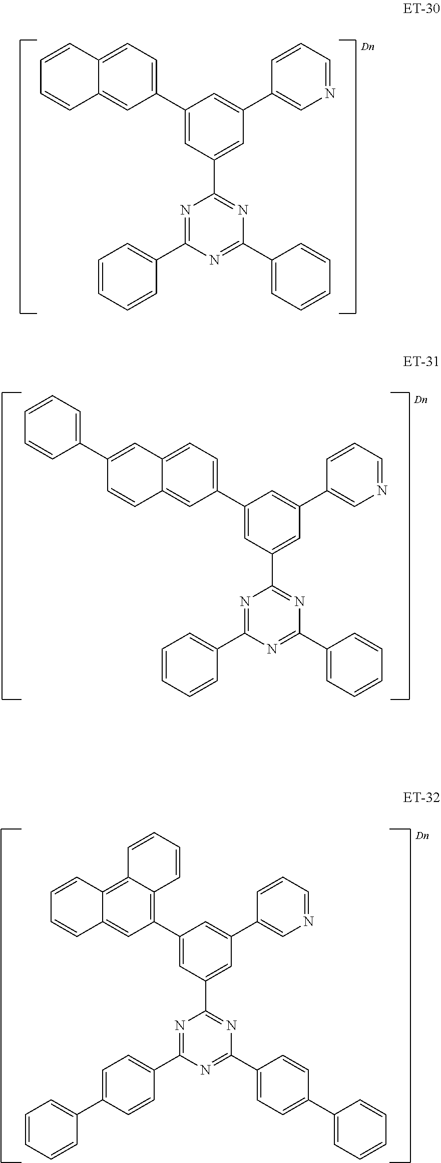

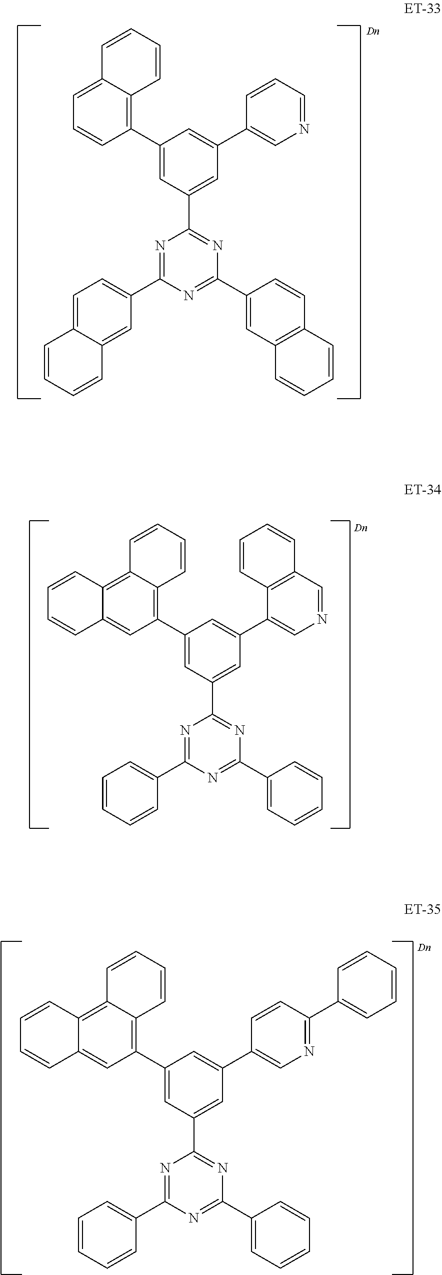

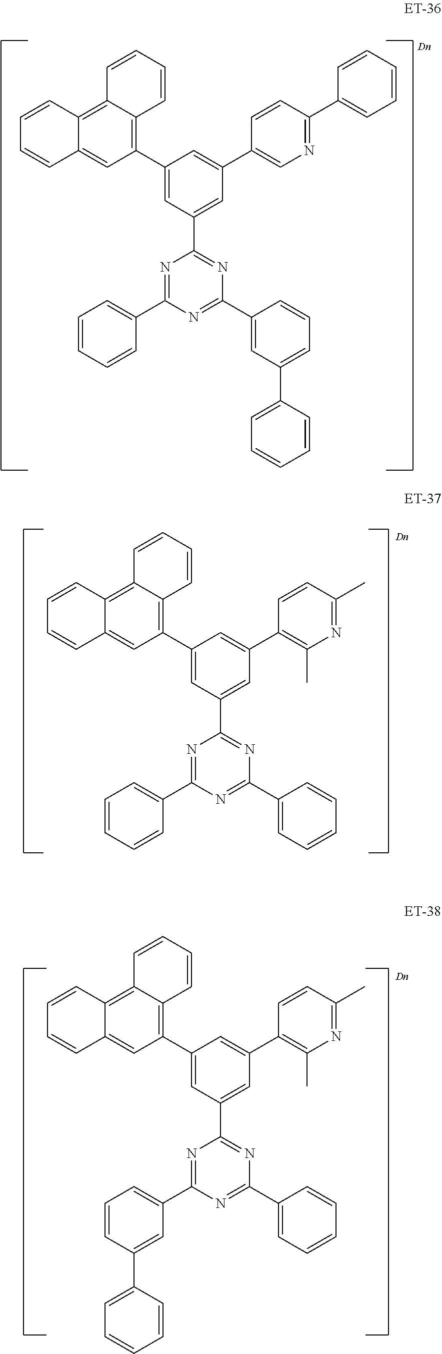

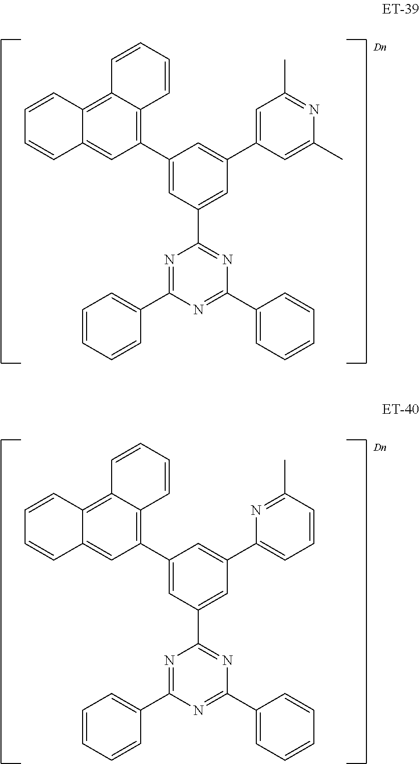

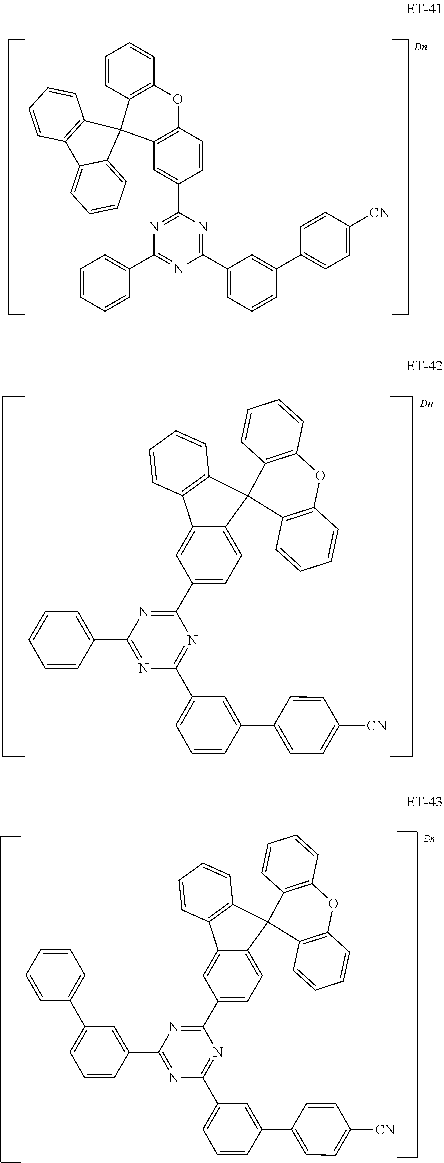

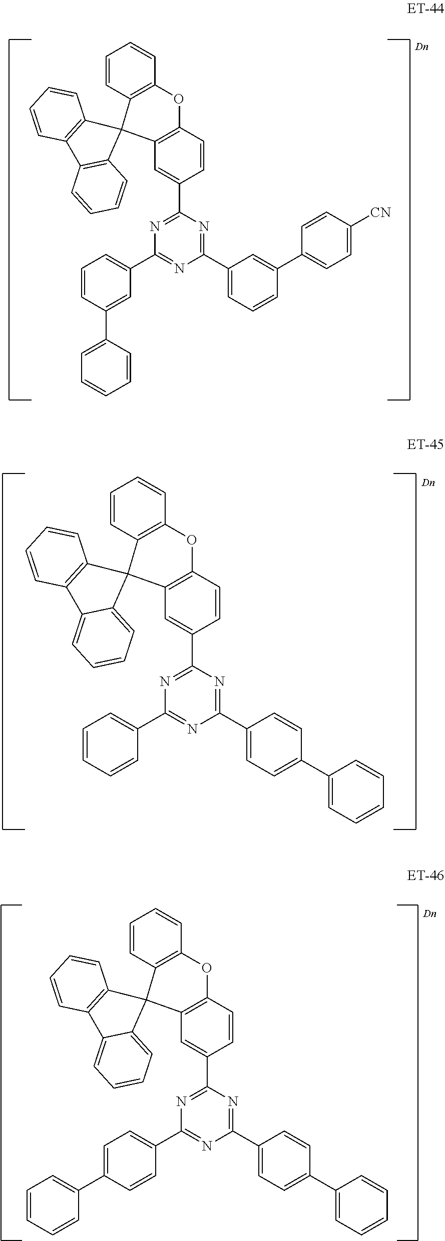

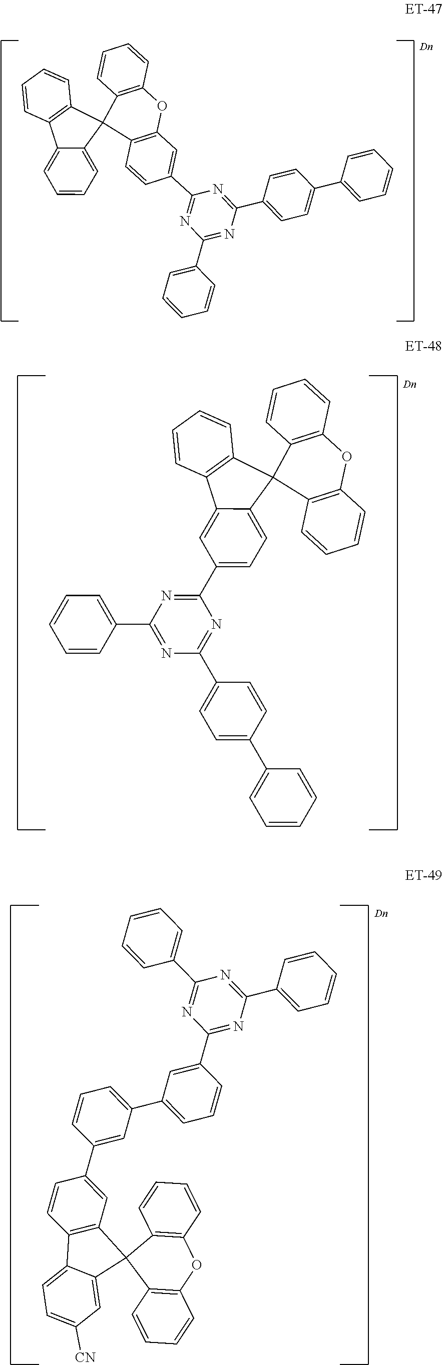

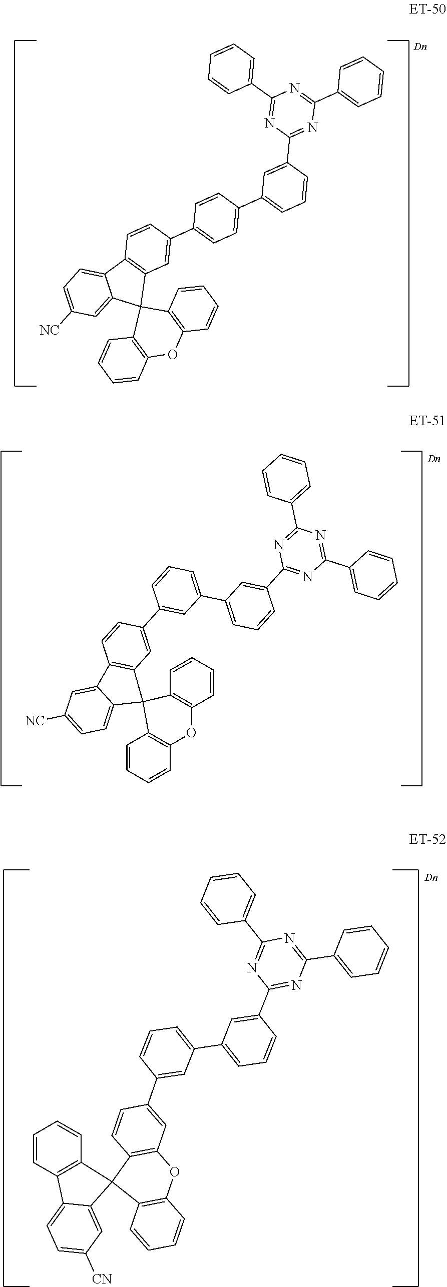

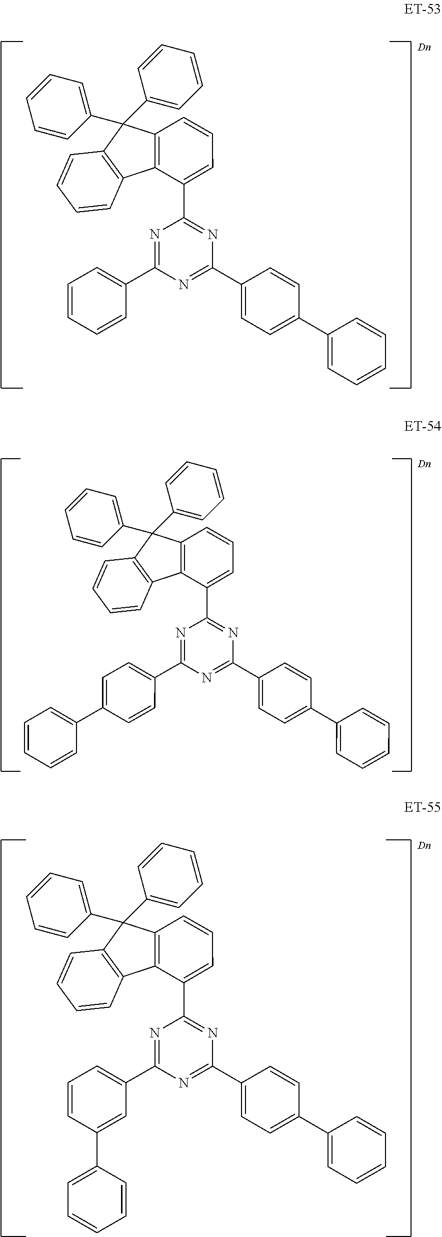

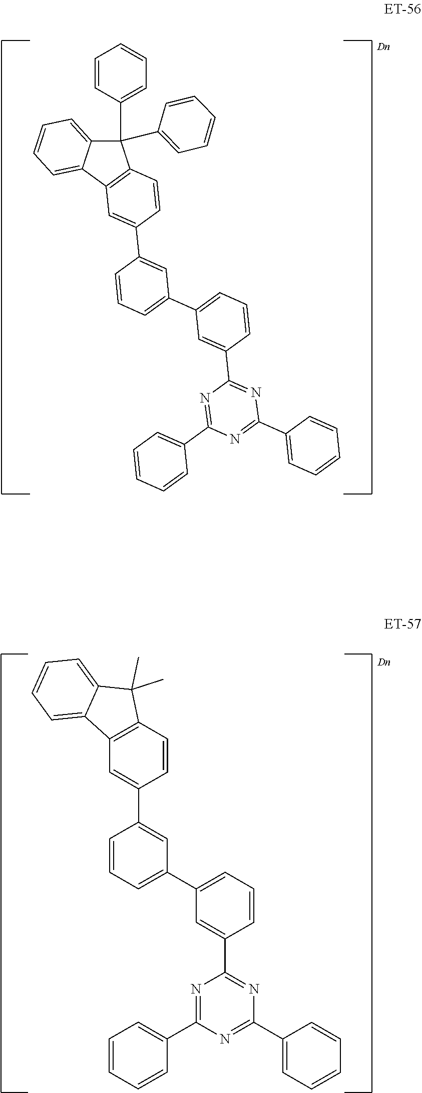

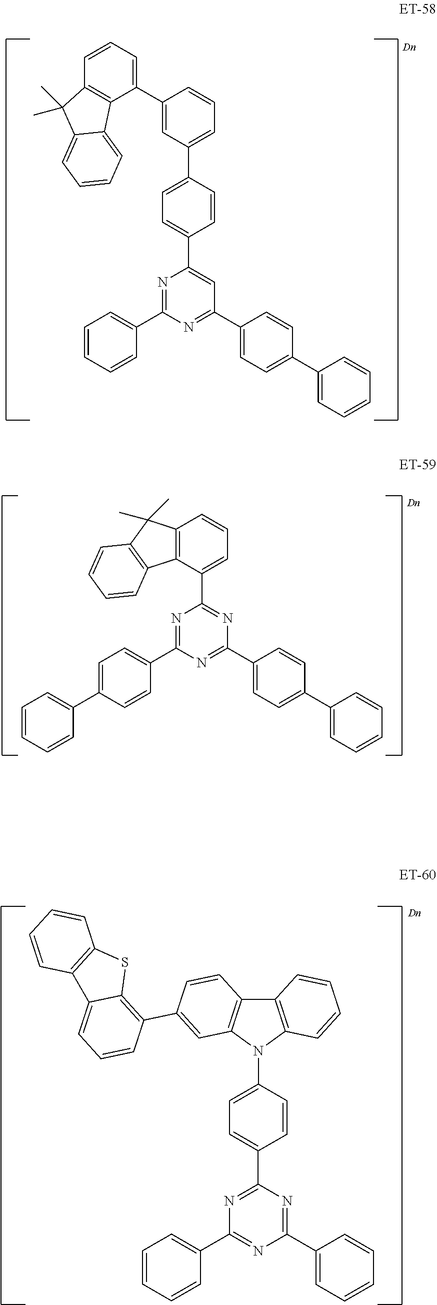

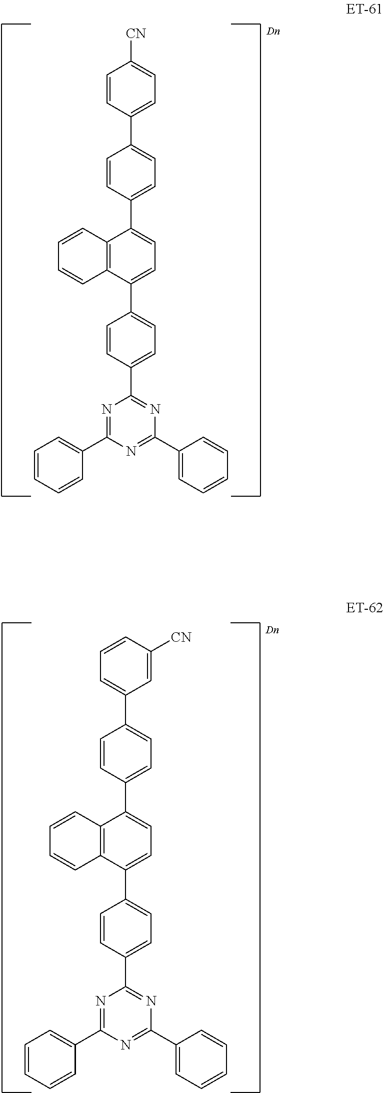

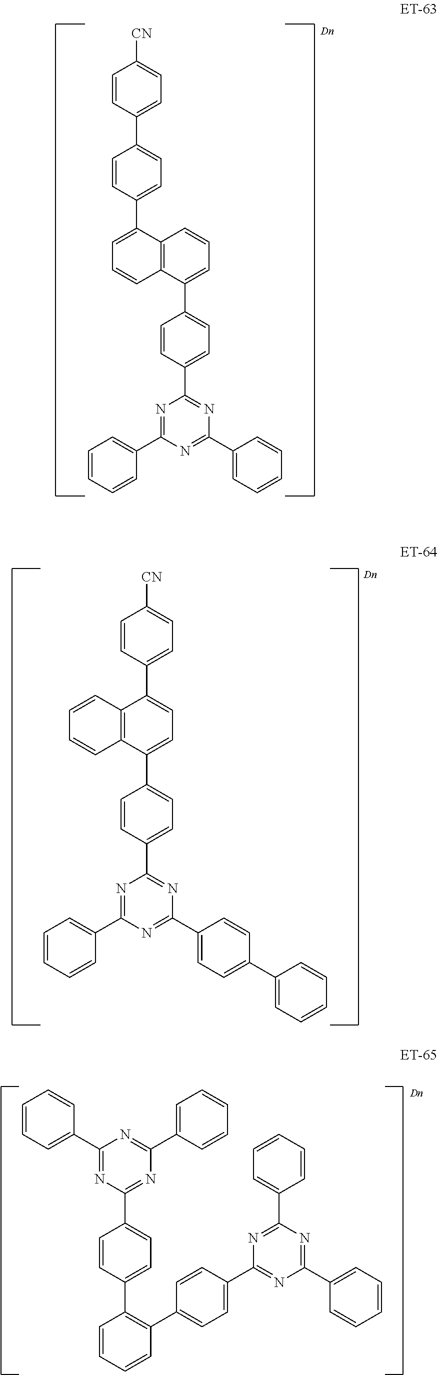

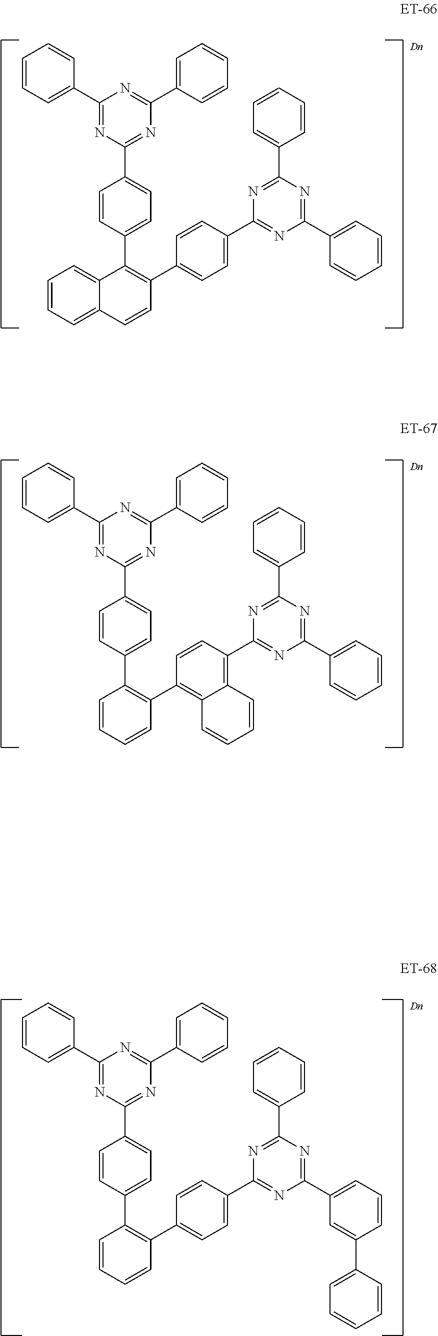

According to one embodiment of the present disclosure, the organic electroluminescent device according to the present disclosure may comprise at least one layer in the light-emitting layer comprising a compound represented by the following formula 4 or formula 5.

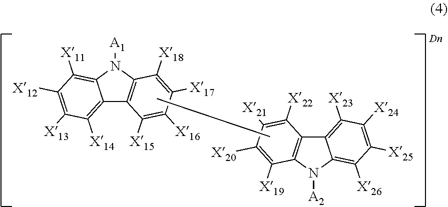

In formula 4,
A₁ and A₂ each independently represent a substituted or unsubstituted (C6-C30)aryl, a substituted or unsubstituted dibenzofuranyl, a substituted or unsubstituted dibenzothiophenyl, or a substituted or unsubstituted carbazolyl; any one of X′₁₅ to X′₁₈ and any one of X′₁₉ to X′₂₂ are linked to each other to form a single bond; X′₁₁ to X′₁₄, X′₂₃ to X′₂₆, and X′₁₅ to X′₂₂ which do not form a single bond each independently represent hydrogen, deuterium, a substituted or unsubstituted (C6-C30)aryl, or a substituted or unsubstituted (3- to 30-membered)heteroaryl, or may be linked to an adjacent substituent(s) to form a ring(s);
at least one of X′₁₁, X′₁₈, X′₁₉, or X′₂₆ represents deuterium; and
Dₙ represents that n number of hydrogens are replaced with deuterium, and n represents an integer of 1 or more, and has an upper limit of the number of hydrogen atoms in the non-deuterated compound.

According to one embodiment of the present disclosure, A₁ and A₂ each independently may represent a substituted or unsubstituted (C6-C30)aryl or a substituted or unsubstituted dibenzofuranyl. Preferably A₁ and A₂ each independently may represent a substituted or unsubstituted (C6-C18)aryl or a substituted or unsubstituted dibenzofuranyl. For example, A₁ and A₂ each independently may be a substituted or unsubstituted phenyl, a biphenyl, a substituted or unsubstituted naphthyl, a terphenyl, a triphenylenyl, or a substituted or unsubstituted dibenzofuranyl. The substituents of the above substituted ones may be at least one selected from deuterium, a phenyl(s), a naphthyl(s), a triphenylenyl(s), and a dibenzofuranyl(s).

According to one embodiment of the present disclosure, the deuterium substitution rate is preferably 20% to 100% of the total number of hydrogens, more preferably 20% to 95%, even more preferably 30% to 95%, and even more preferably 40% to 95%.

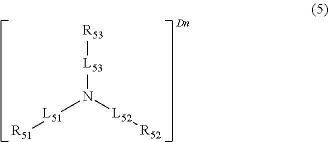

In formula 5,
at least one of R₅₁ to R₅₃ comprises the following formula 5-1 or formula 5-2:

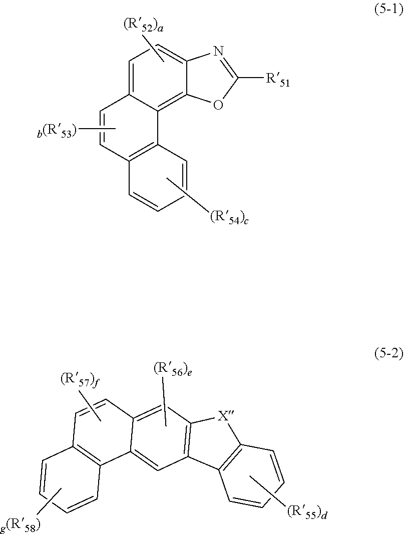

or, L₅₁ and L₅₂ may be single bonds, and R₅₁ and R₅₂ may be linked to each other to be represented by any one of the following formulas 5-3 to 5-5:

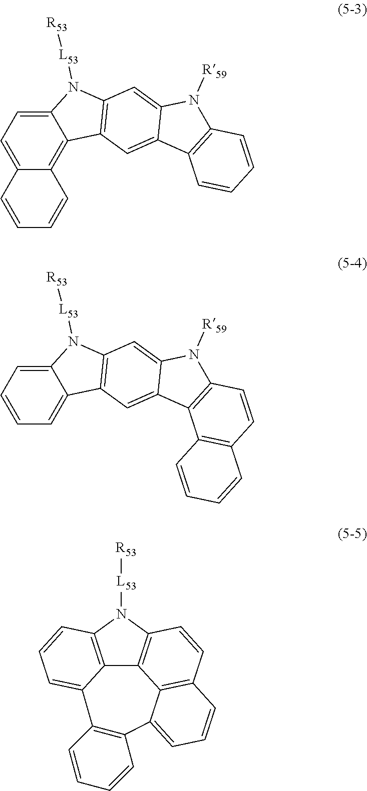

R₅₁ to R₅₃ and R′₅₁ to R′₅₉ each independently represent hydrogen, deuterium, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), a substituted or unsubstituted mono- or di-(C1-C30)alkylamino, a substituted or unsubstituted mono- or di-(C2-C30)alkenylamino, a substituted or unsubstituted (C1-C30)alkyl(C2-C30)alkenylamino, a substituted or unsubstituted mono- or di-(C6-C30)arylamino, a substituted or unsubstituted (C1-C30)alkyl(C6-C30)arylamino, a substituted or unsubstituted mono- or di-(3- to 30-membered)heteroarylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino, or may be linked to adjacent substituent(s) to form a ring(s);
L₅₁ to L₅₃ each independently represent a single bond, a substituted or unsubstituted (C6-C30)arylene, or a substituted or unsubstituted (3- to 30-membered)heteroarylene;
X″ represents O or S;
a, b, e, and f each independently represent an integer of 1 or 2, c, d, and g represent an integer of 1 to 4, in which if a to g represent an integer of 2 or more,
each of R′₅₁ to each of R′₅₉ may be the same or different; and
Dₙ represents that n number of hydrogens are replaced with deuterium, and n represents an integer of 1 or more, and has an upper limit of the number of hydrogen atoms in the non-deuterated compound.

According to one embodiment of the present disclosure, R₅₁ to R₅₃ and R′₅₁ to R′₅₉ each independently may represent hydrogen, deuterium, a substituted or unsubstituted (C6-C30)aryl, a substituted or unsubstituted (3- to 30-membered)heteroaryl, a substituted or unsubstituted fused ring group of a (C3-C30) aliphatic ring(s) and a (C6-C30) aromatic ring(s), a substituted or unsubstituted mono- or di-(C6-C30)arylamino, or a substituted or unsubstituted (C1-C30)alkyl(C6-C30)arylamino, or may be linked to adjacent substituent(s) to form a ring(s). Preferably, R₅₁ to R₅₃ and R′₅₁ to R′₅₉ each independently may represent a substituted or unsubstituted (C6-C25)aryl, a substituted or unsubstituted (5- to 25-membered)heteroaryl, a substituted or unsubstituted fused ring group of a (C3-C30) aliphatic ring(s) and a (C6-C30) aromatic ring(s), a substituted or unsubstituted mono- or di-(C6-C18)arylamino, or may be linked to adjacent substituent(s) to form a ring(s). For example, R₅₁ to R₅₃ and R′₅₁ to R′₅₉ each independently may be a phenyl unsubstituted or substituted with a phenyl, a naphthyl, a biphenyl, a terphenyl, a phenanthrenyl, a 23-membered heteroaryl, a dibenzofuranyl, a dibenzothiophenyl, a diphenylamino, a phenylbiphenylamino, a phenylnaphthylamino, a dibiphenylamino, formula 5-1, or formula 5-2, etc., or may be linked to adjacent substituent(s) to form a benzoindolocarbazole ring such as formula 5-3 or formula 5-4, which may be further substituted with one or more deuterium atoms.

According to one embodiment of the present disclosure, X″ may represent O.

According to one embodiment of the present disclosure, L₅₁ to L₅₅ each independently may represent a single bond or a substituted or unsubstituted (C6-C30)arylene. Preferably, L₅₁ to L₅₅ each independently may represent a single bond or a substituted or unsubstituted (C6-C12)arylene. For example, L₅₁ to L₅₃ each independently may be a single bond, a phenyl, or a biphenyl, etc., which may be further substituted with one or more deuterium atoms.

According to one embodiment of the present disclosure, the deuterium substitution rate is preferably 20% to 100% of the total number of hydrogens, more preferably 20% to 95%, even more preferably 30% to 95%, and even more preferably 40% to 95%.

According to one embodiment of the present disclosure, the deuterated compound may be more specifically exemplified as the following compounds, but is not limited thereto.

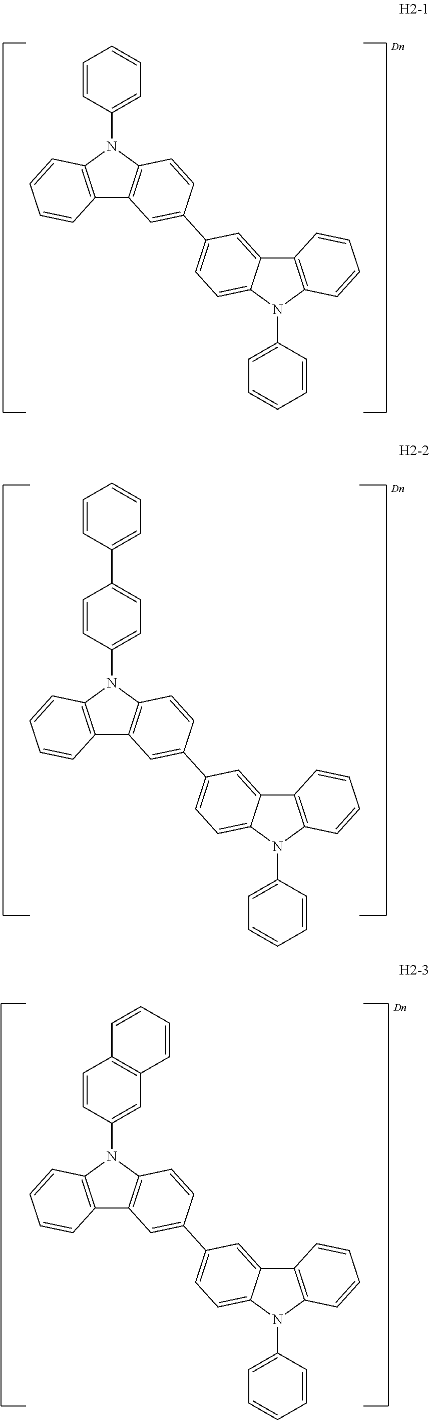

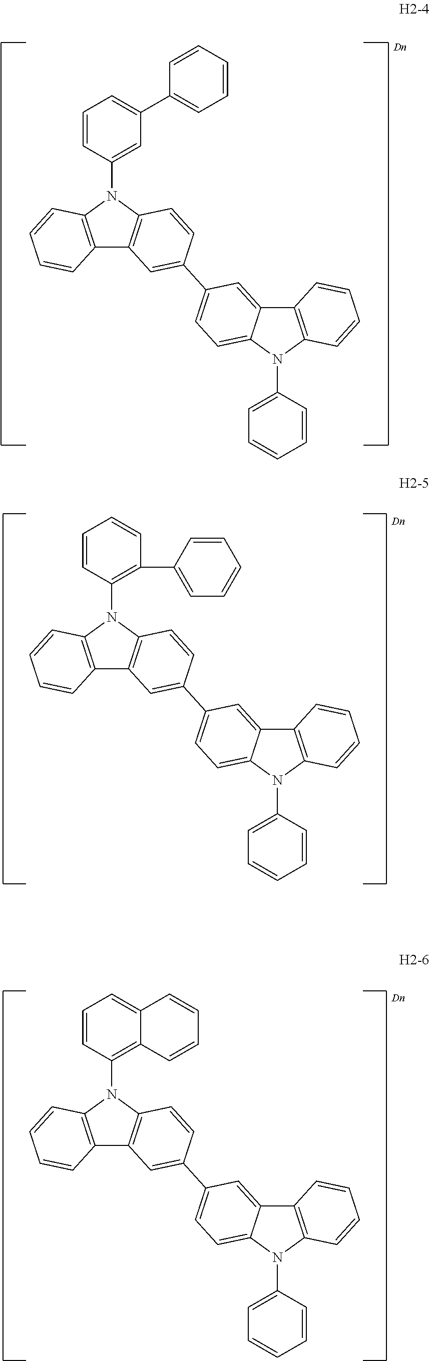

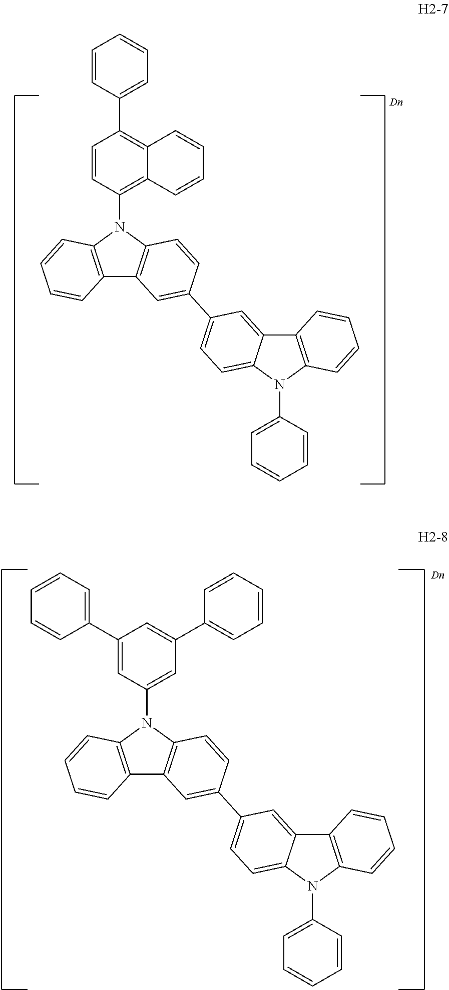

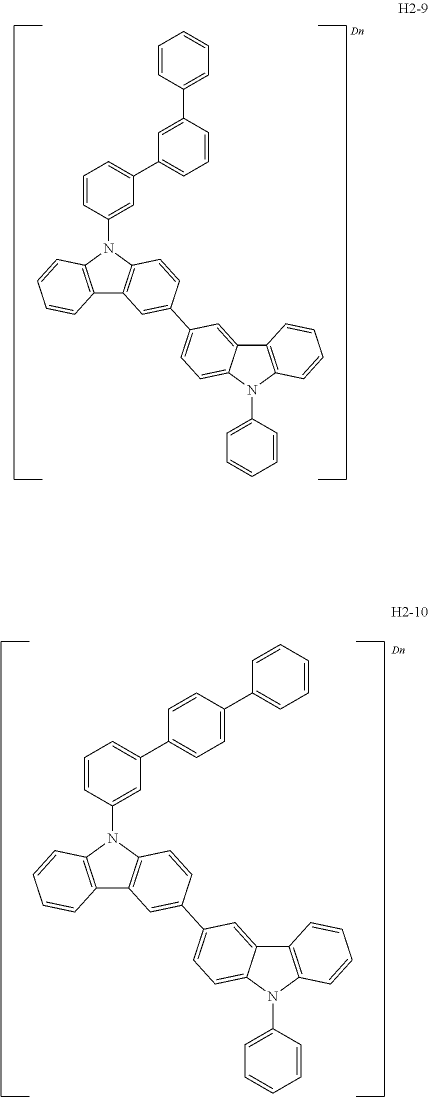

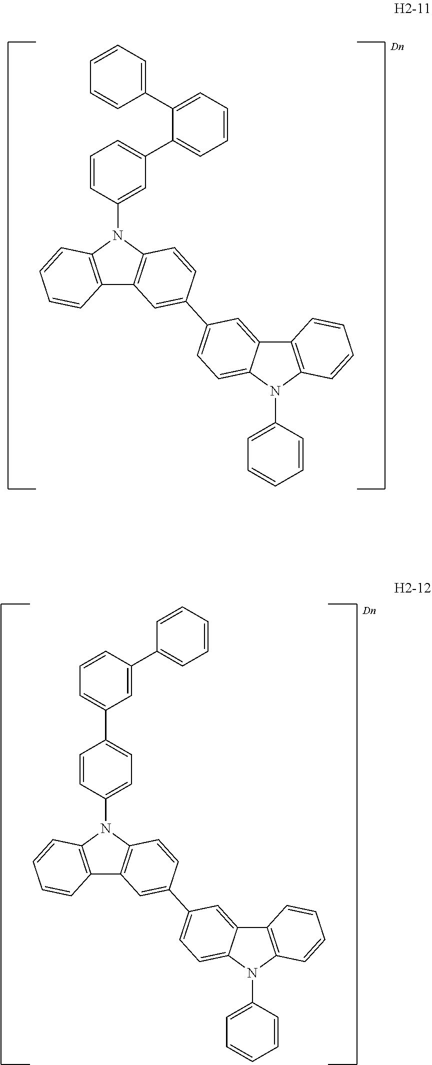

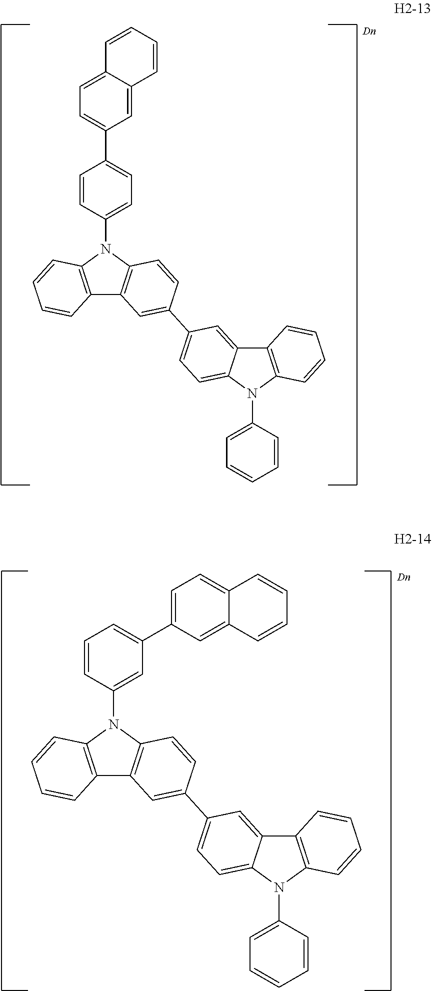

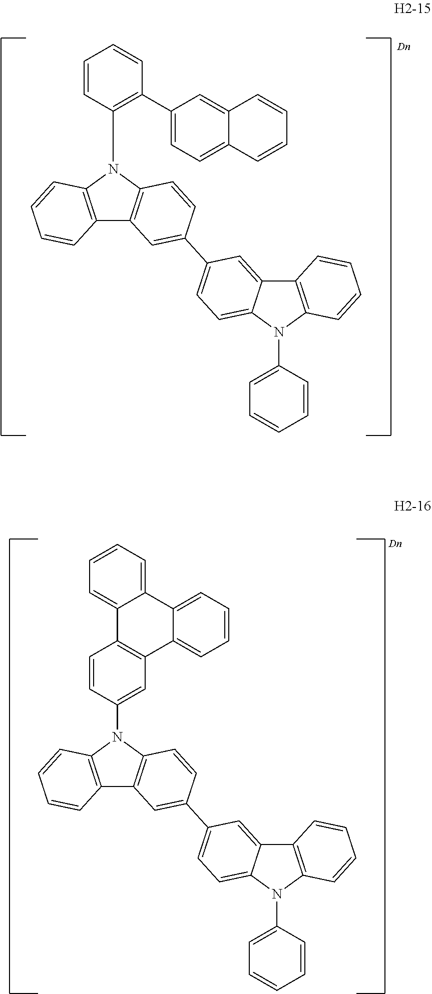

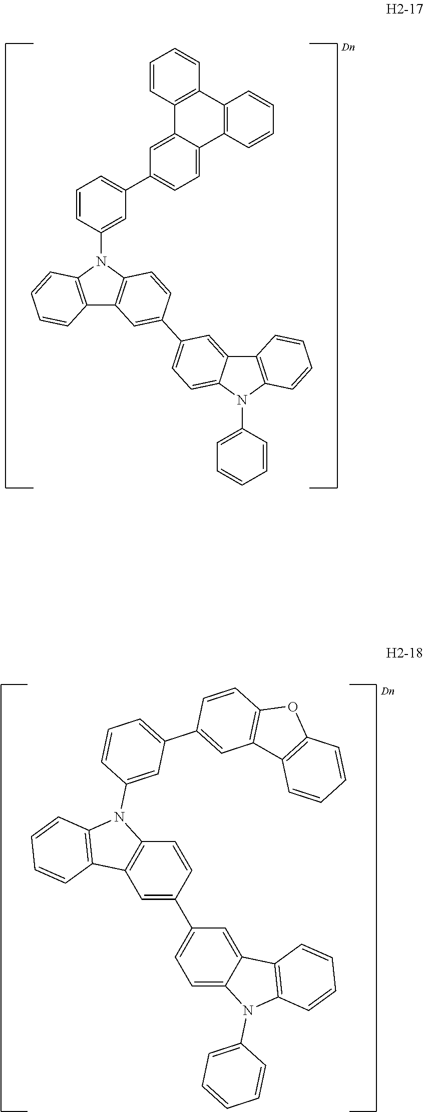

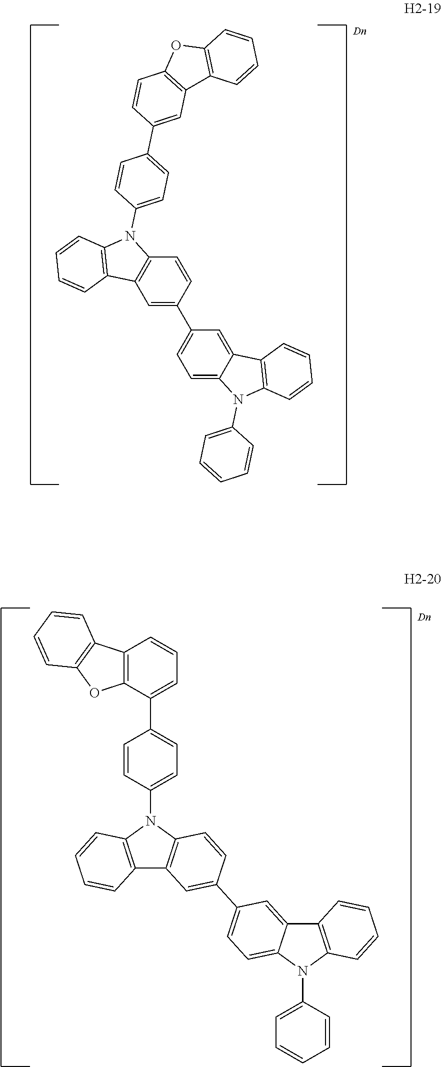

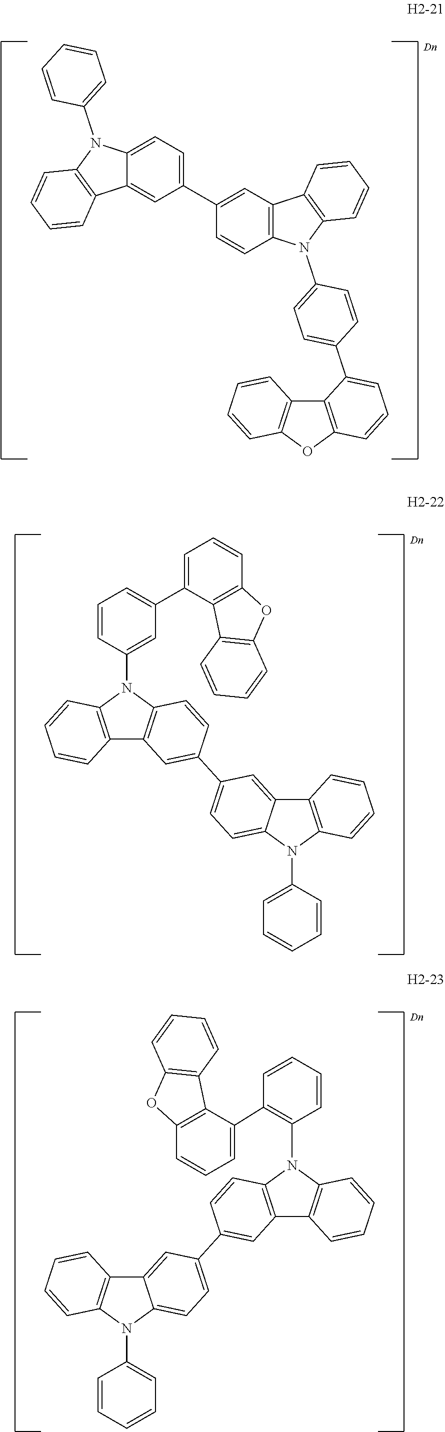

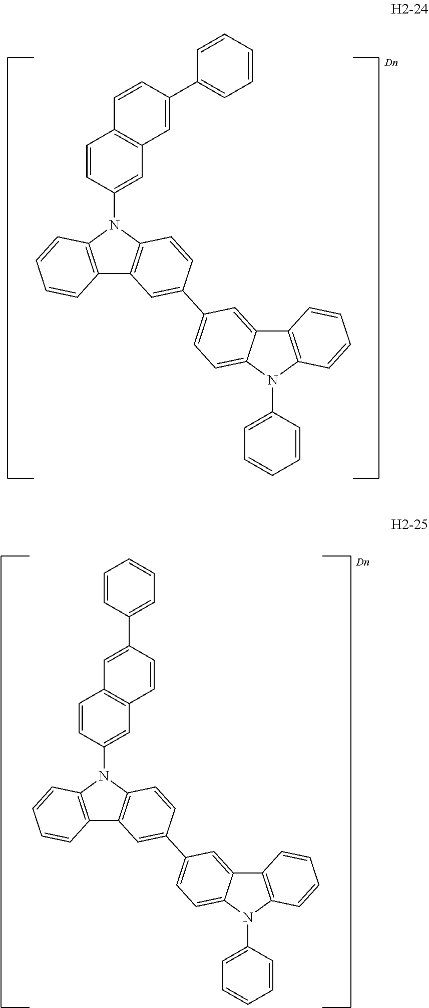

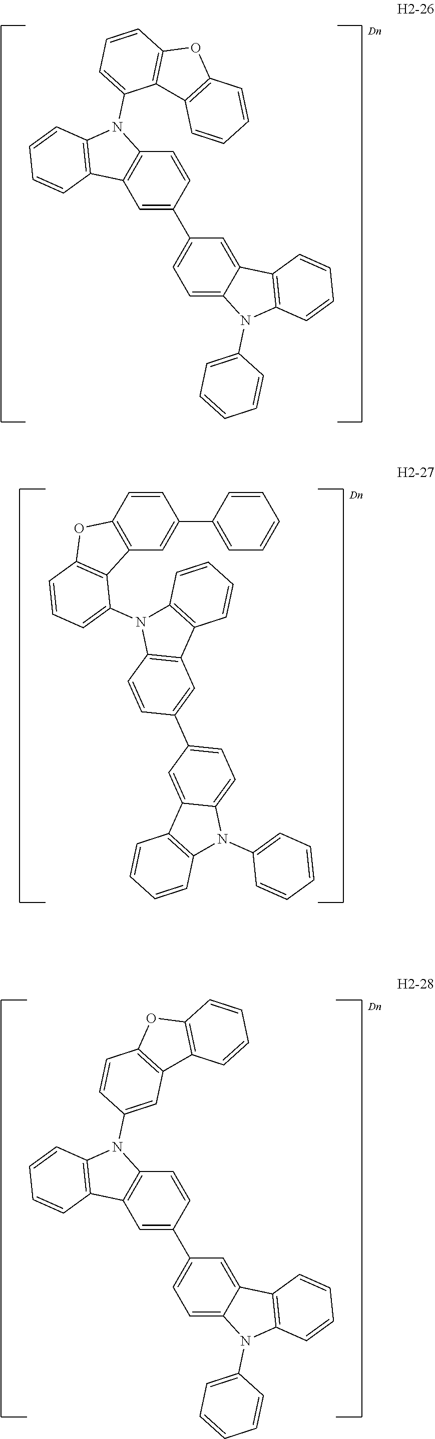

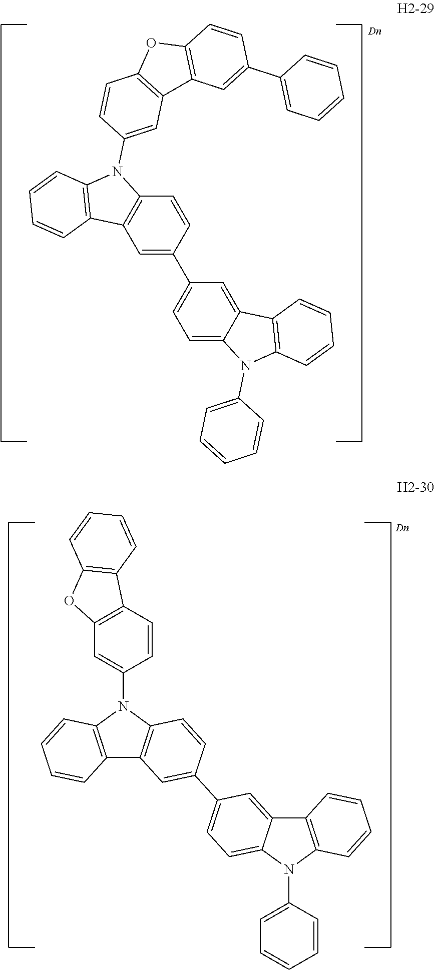

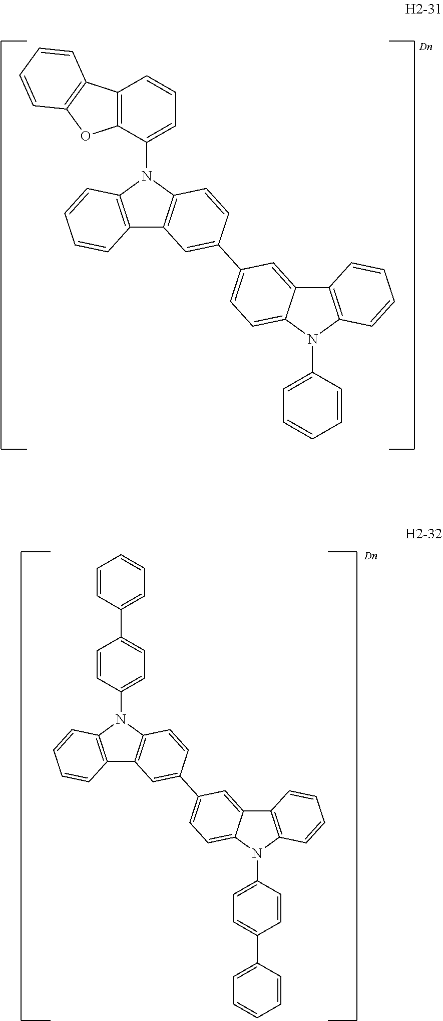

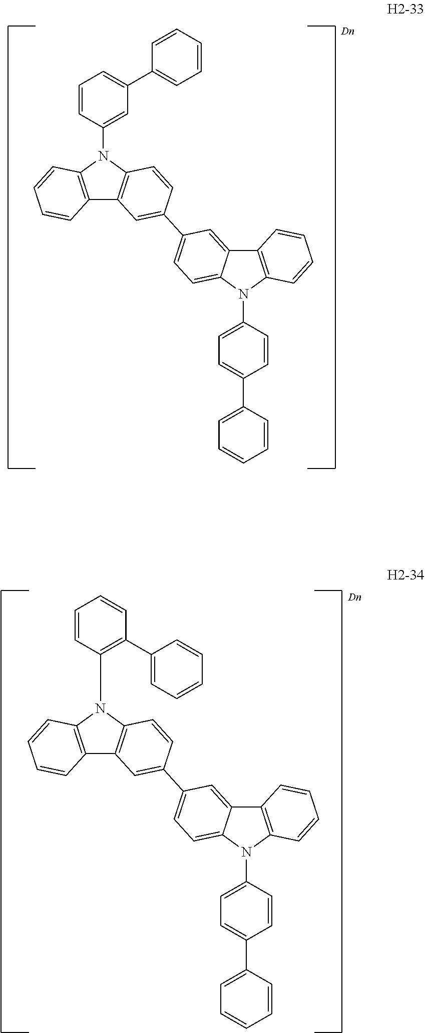

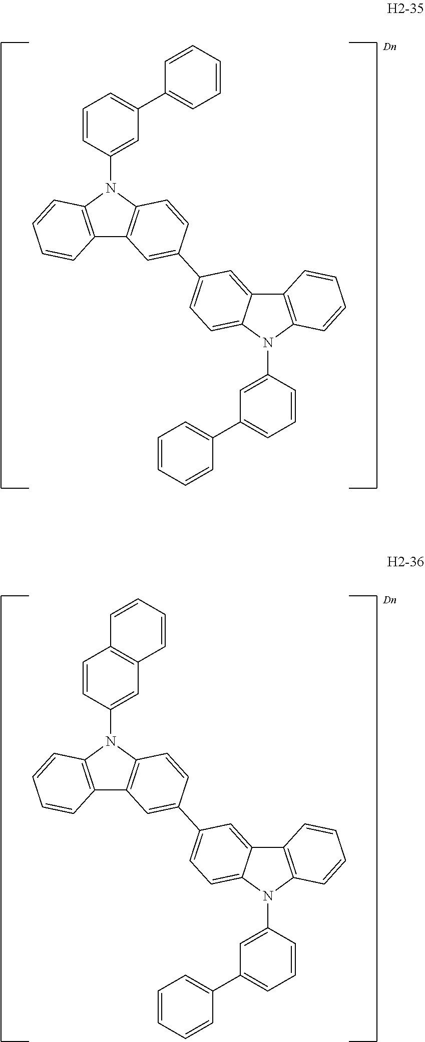

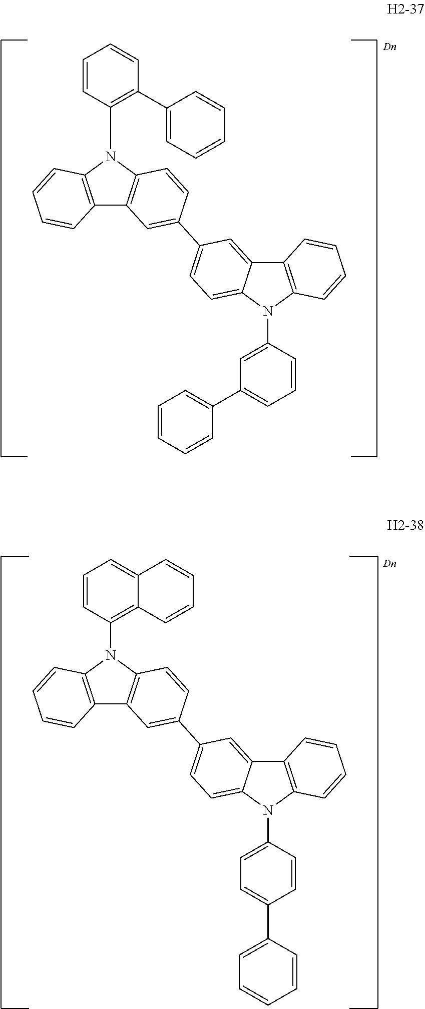

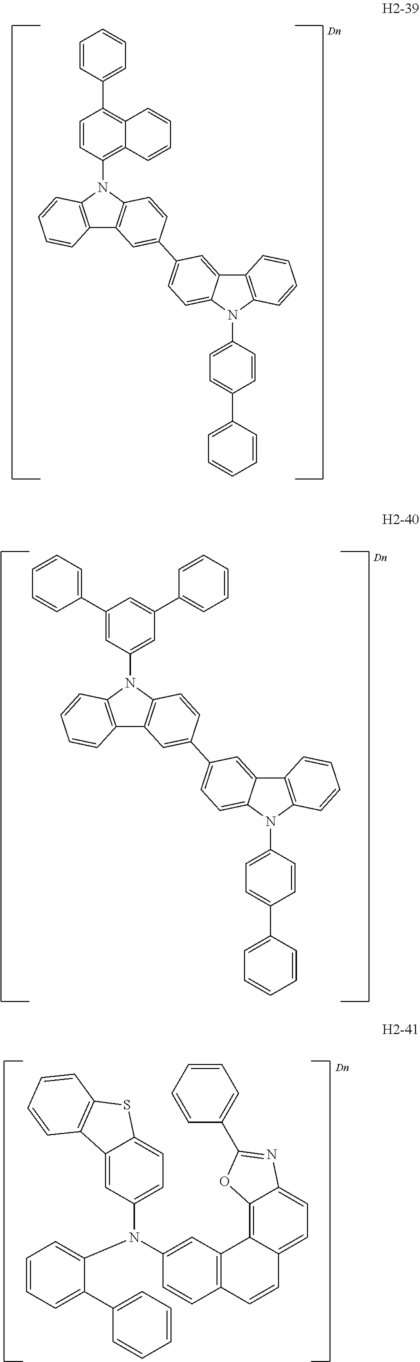

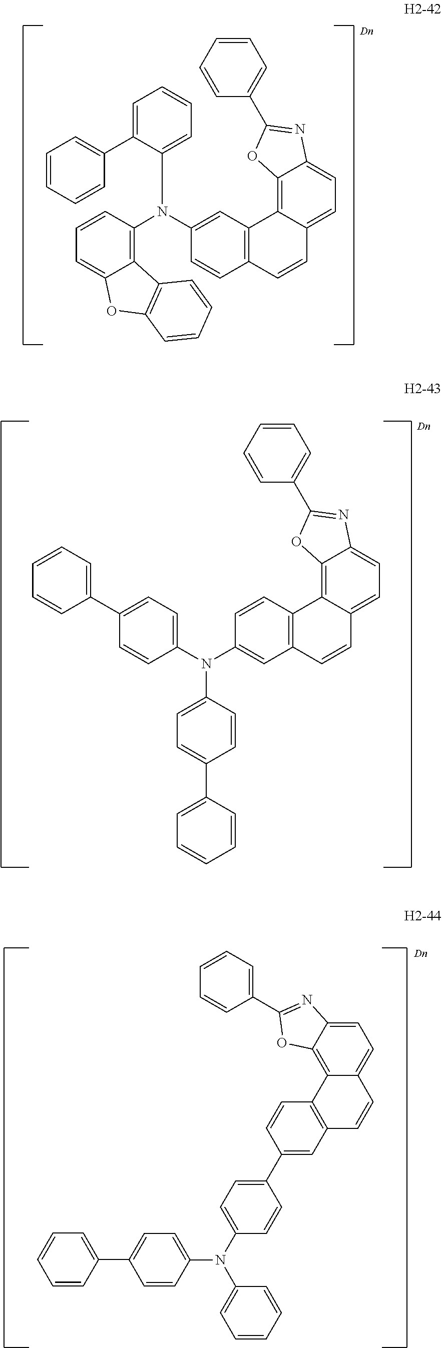

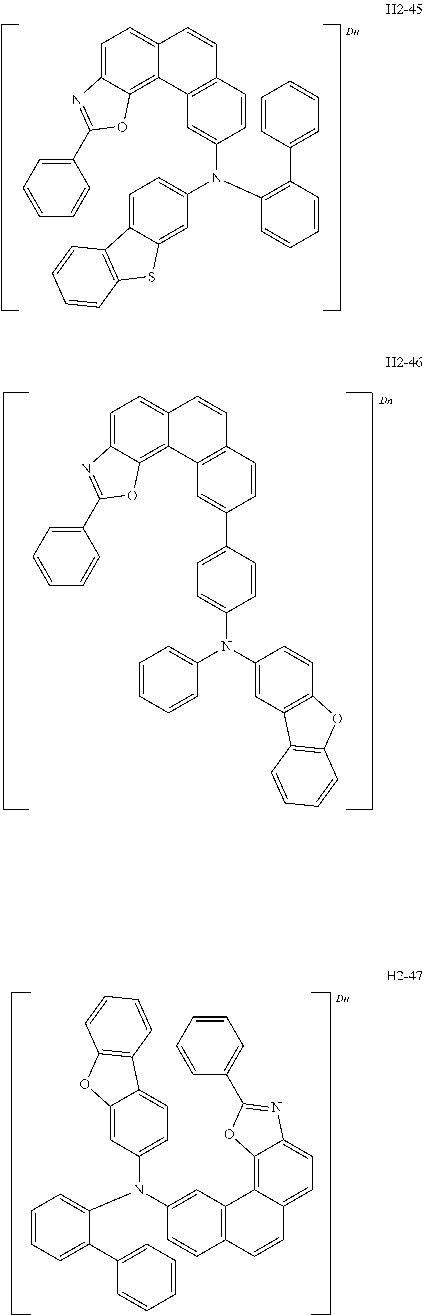

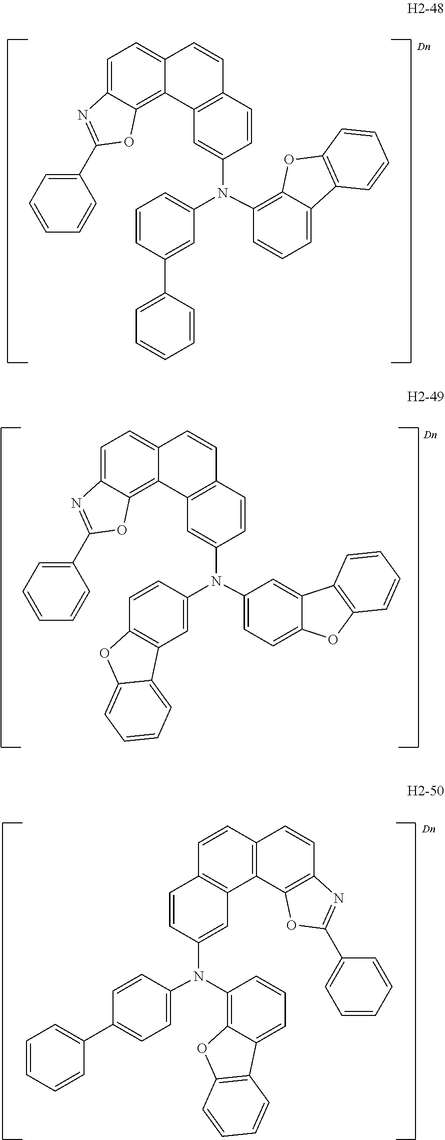

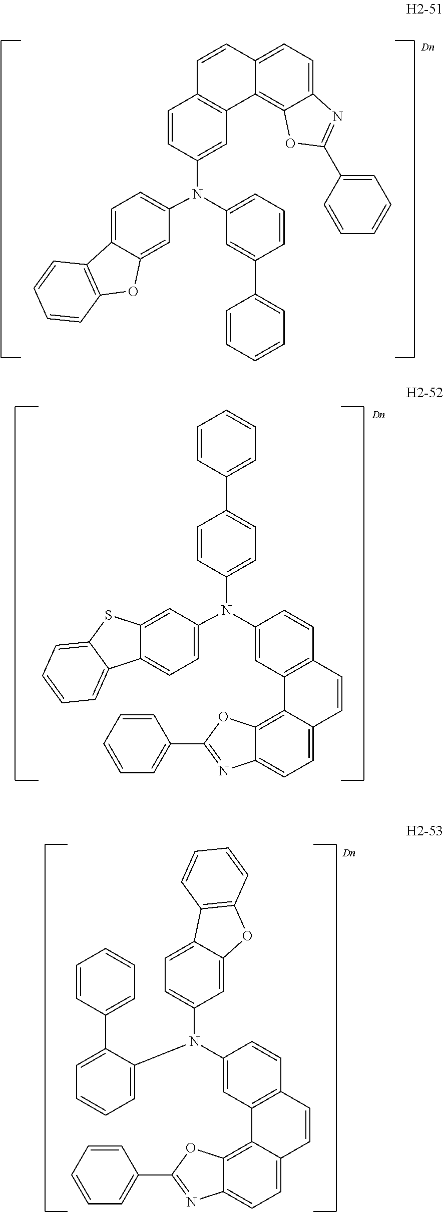

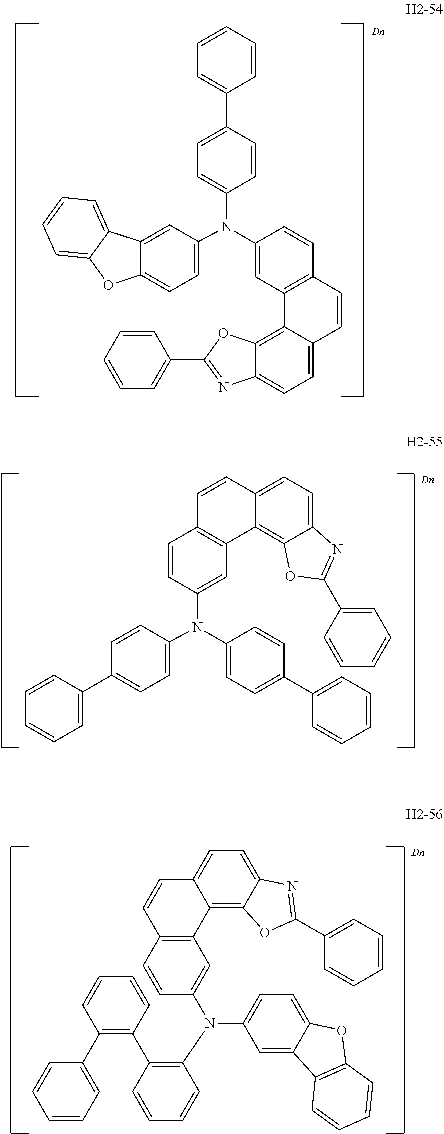

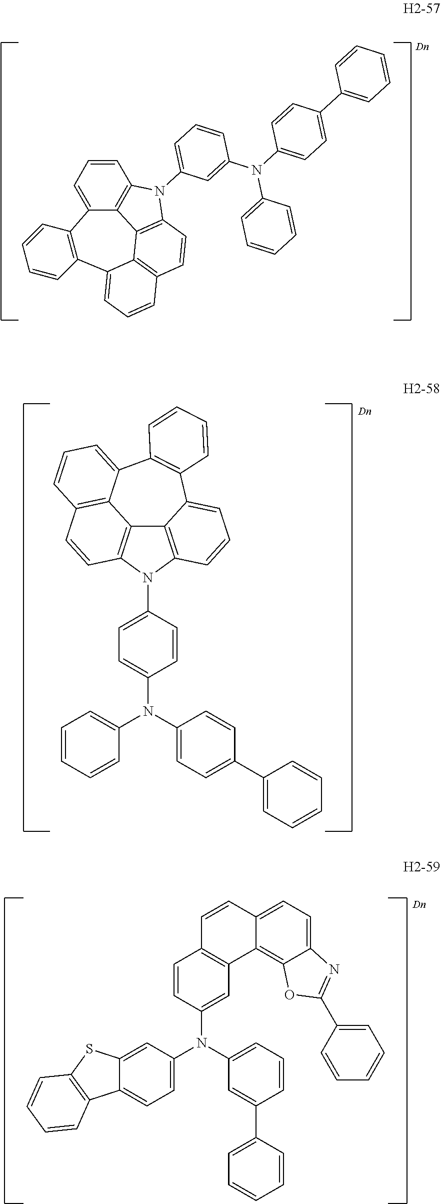

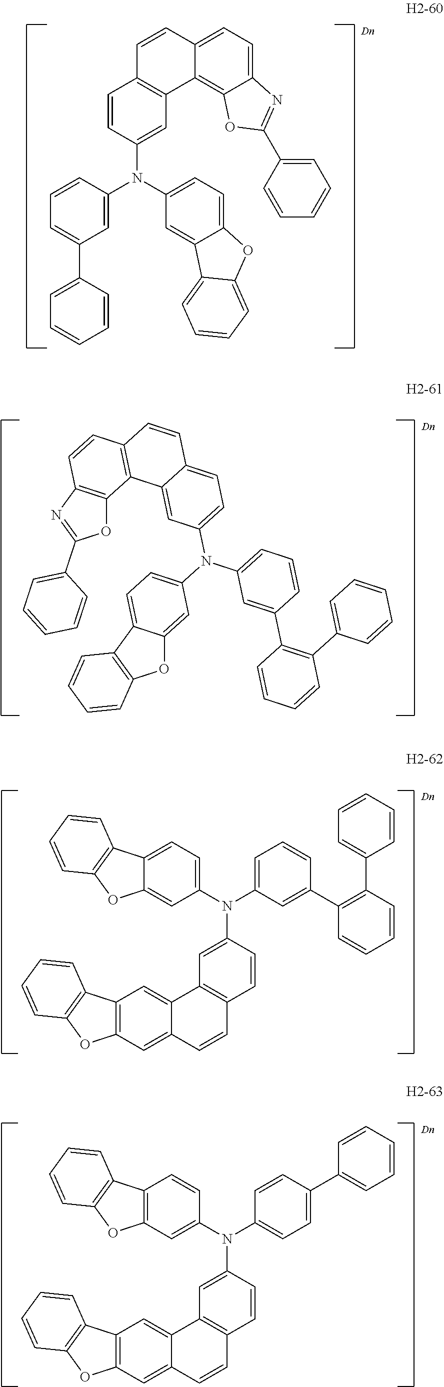

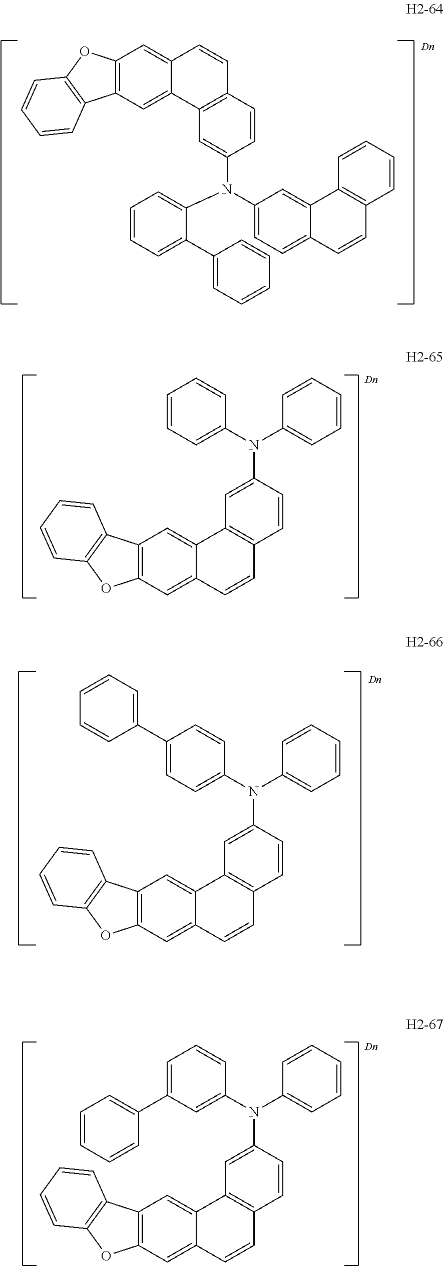

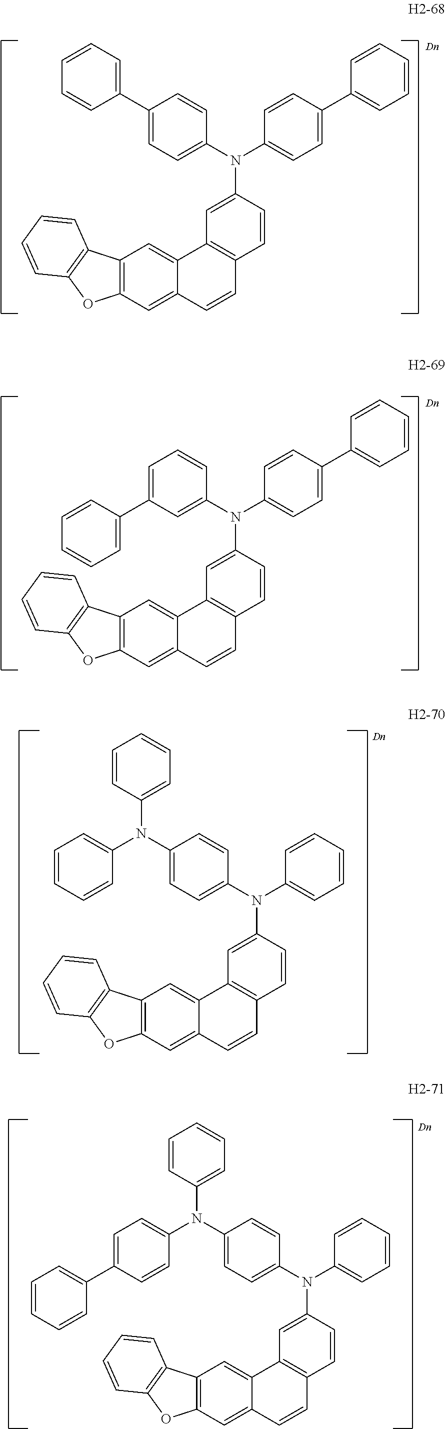

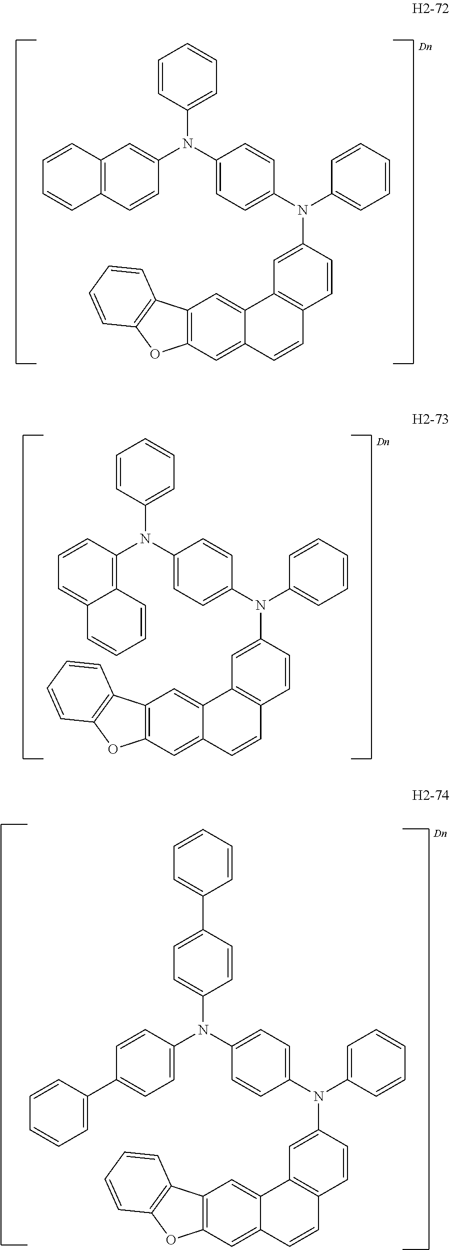

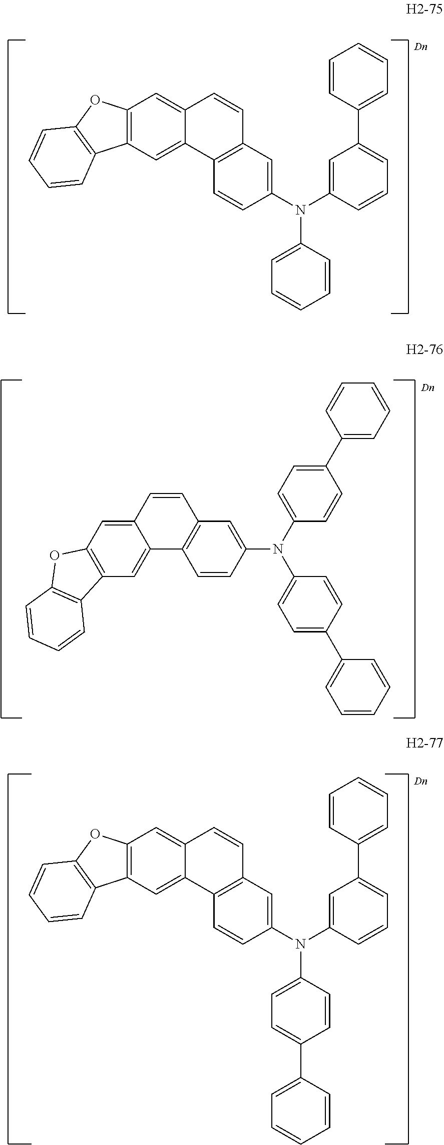

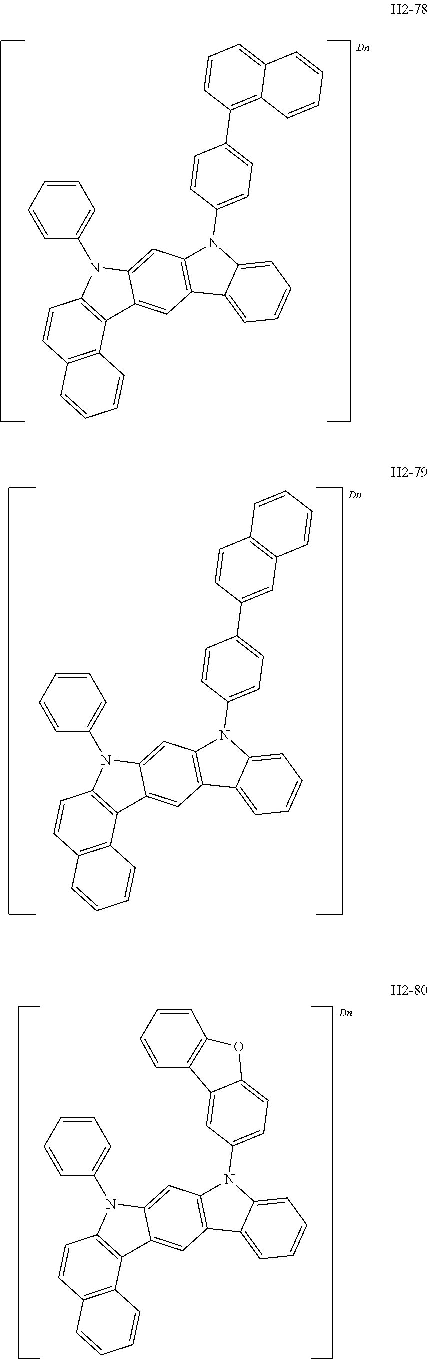

According to one embodiment of the present disclosure, the organic electroluminescent device according to the present disclosure may comprise at least one layer in the light-emitting layer comprising two or more compounds, wherein the two or more compounds comprise a compound represented by the following formula 6 or formula 7.

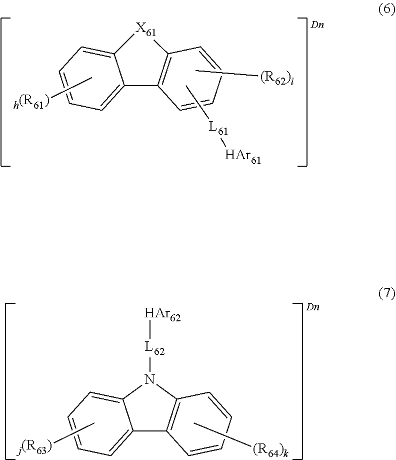

In formula 6 and formula 7,
X₆₁ represents O or S;
HAr₆₁ and HAr₆₂ each independently represent a substituted or unsubstituted (3- to 30-membered)heteroaryl containing one or more nitrogen atoms;
L₆₁ and L₆₂ each independently represent a single bond, a substituted or unsubstituted (C6-C30)arylene, or a substituted or unsubstituted (3- to 30-membered)heteroarylene;
R₆₁ to R₆₄ each independently represent hydrogen, deuterium, a substituted or unsubstituted (C6-C30)aryl, or a substituted or unsubstituted (3- to 30-membered)heteroaryl; or may be linked to an adjacent substituent(s) to form a ring(s);
h to k each independently represent an integer of 1 to 4, in which if h to k represent an integer of 2 or more, each of R₆₁ to each of R₆₄ may be the same or different; and
Dₙ represents that n number of hydrogens are replaced with deuterium, and n represents an integer of 1 or more, and has an upper limit of the number of hydrogen atoms in the non-deuterated compound.

According to one embodiment of the present disclosure, HAr₆₁ and HAr₆₂ each independently may represent a substituted or unsubstituted (3- to 15-membered)heteroaryl containing one or more nitrogen atoms. For example, HAr₆₁ and HAr₆₂ each independently may be a substituted triazinyl, wherein the substituent(s) of the substituted triazinyl may be at least one, preferably two, selected from a naphthyl(s), a biphenyl(s), a terphenyl(s), a naphthyl(s) substituted with a phenyl(s), a naphthyl(s) substituted with a naphthyl(s), a naphthyl substituted with dibenzofuranyl, and a dibenzofuranyl(s), which may be further substituted with one or more deuterium atoms.

According to one embodiment of the present disclosure, L₆₁ and L₆₂ each independently may represent a single bond or a substituted or unsubstituted (C6-C15)arylene. Preferably, L₆₁ and L₆₂ each independently may represent a single bond or a substituted or unsubstituted (C6-C10)arylene. For example, L₆₁ and L₆₂ each independently may be a single bond, a phenylene, a naphthylene, etc., which may be further substituted with one or more deuterium atoms.

According to one embodiment of the present disclosure, R₆₁ to R₆₄ each independently may represent hydrogen, deuterium, a substituted or unsubstituted (C6-C20)aryl, or a substituted or unsubstituted (3- to 20-membered)heteroaryl; or may be linked to an adjacent substituent(s) to form a ring(s). Preferably, R₆₁ to R₆₄ each independently may represent hydrogen, deuterium, a substituted or unsubstituted (C6-C18)aryl, or a substituted or unsubstituted (3- to 20-membered)heteroaryl; or may be linked to an adjacent substituent(s) to form a ring(s). For example, R₆₁ to R₆₄ each independently may be hydrogen, deuterium, a naphthyl, a carbazolyl, a dibenzothiophenyl, a dibenzofuranyl, etc., or may be linked to an adjacent substituent(s) to form an indole ring substituted with a phenyl(s) or a biphenyl(s), a benzothiophene ring, or a benzene ring, etc., which may be further substituted with one or more deuterium atoms.

According to one embodiment of the present disclosure, the deuterium substitution rate is preferably 20% to 100% of the total number of hydrogens, more preferably 20% to 95%, even more preferably 30% to 95%, and even more preferably 40% to 95%.

According to one embodiment of the present disclosure, the deuterated compound may be more specifically exemplified as the following compounds, but is not limited thereto.

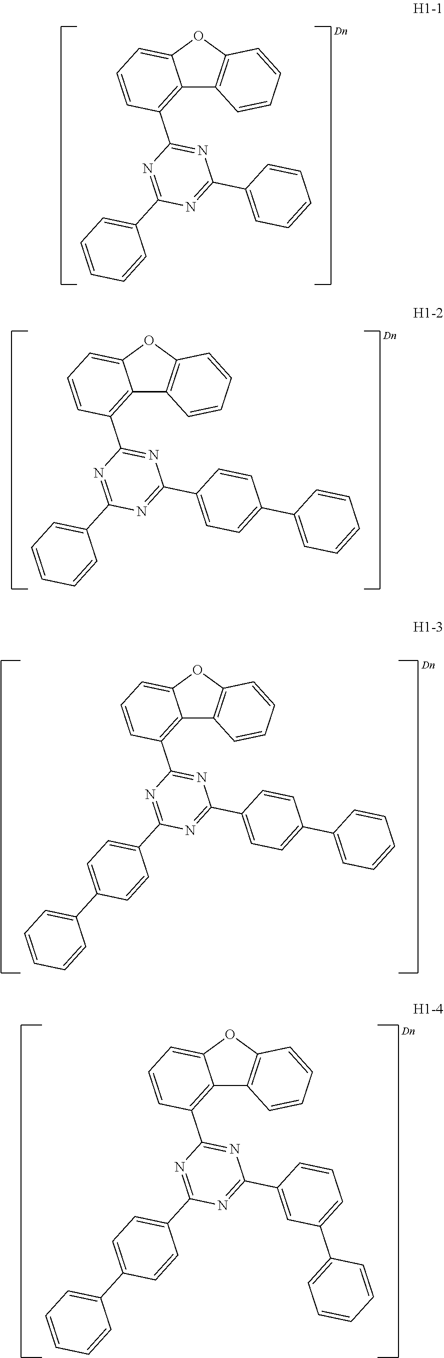

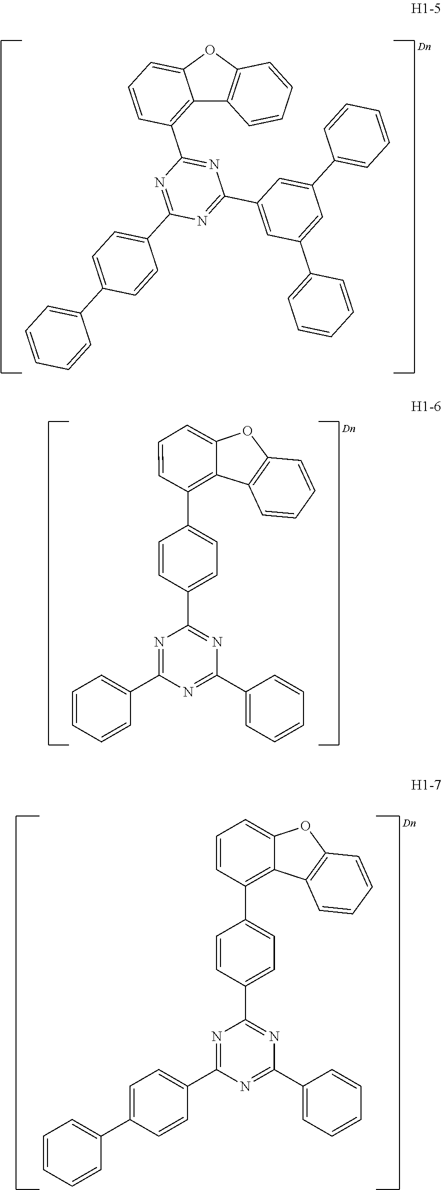

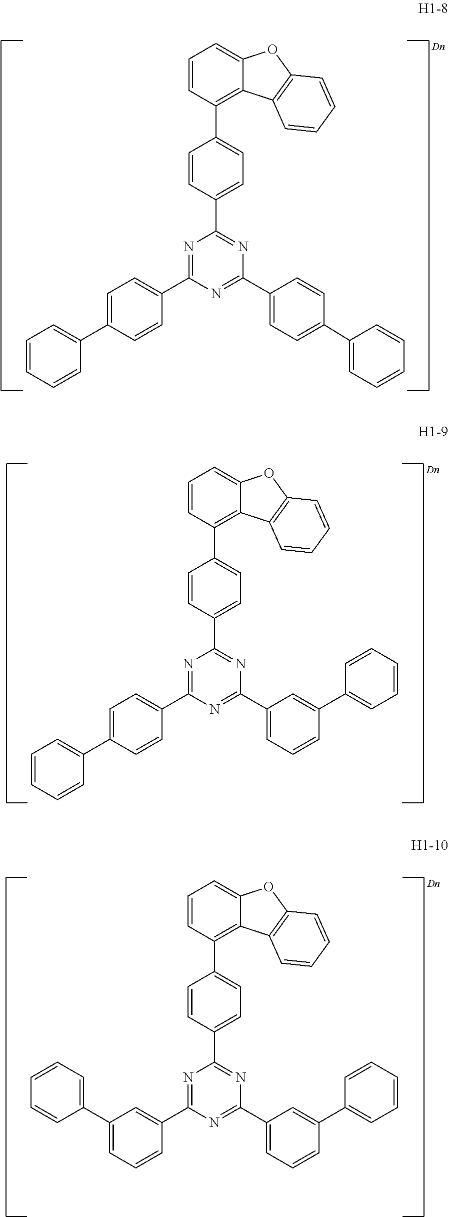

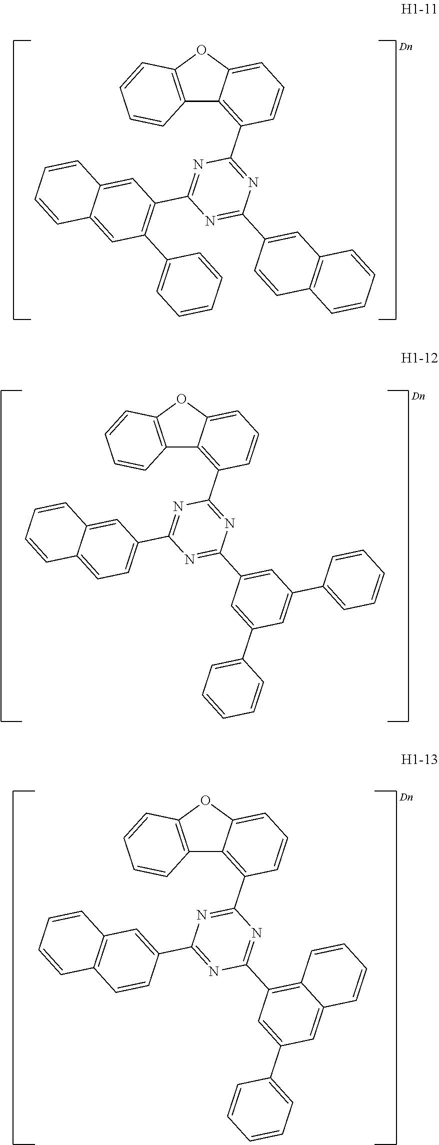

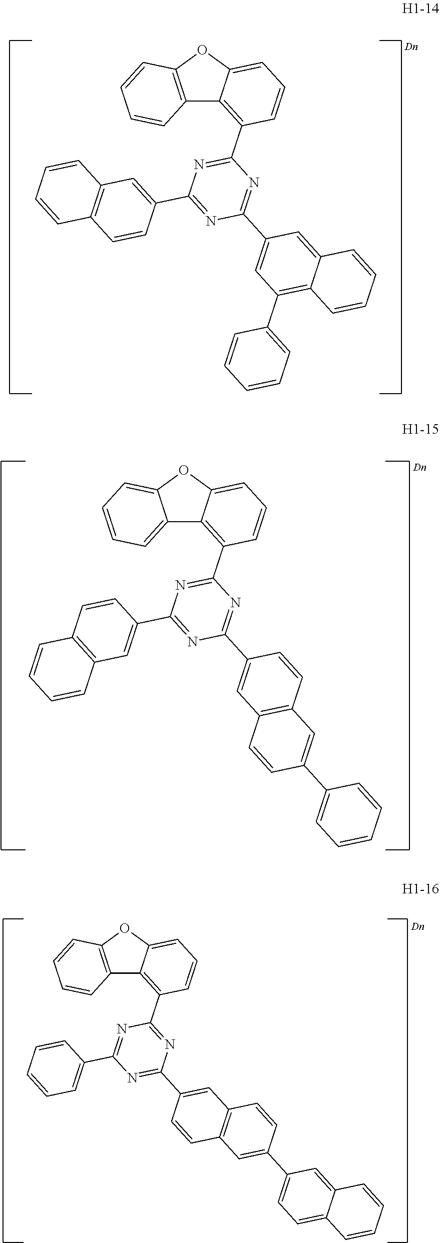

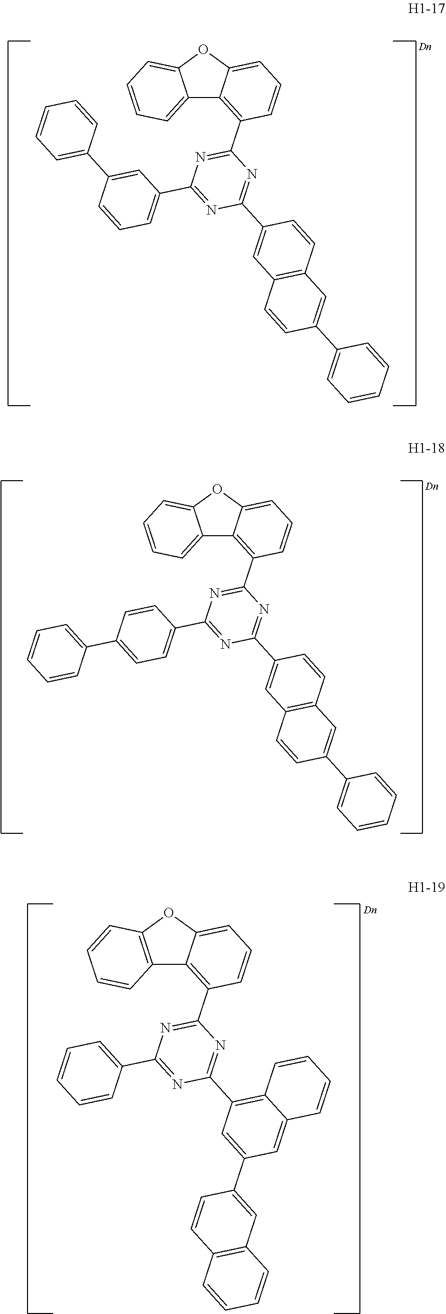

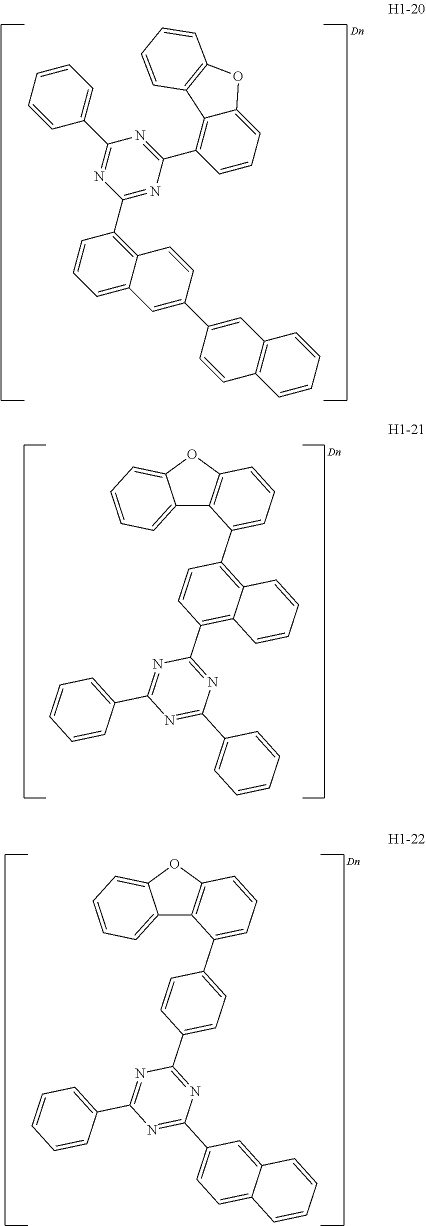

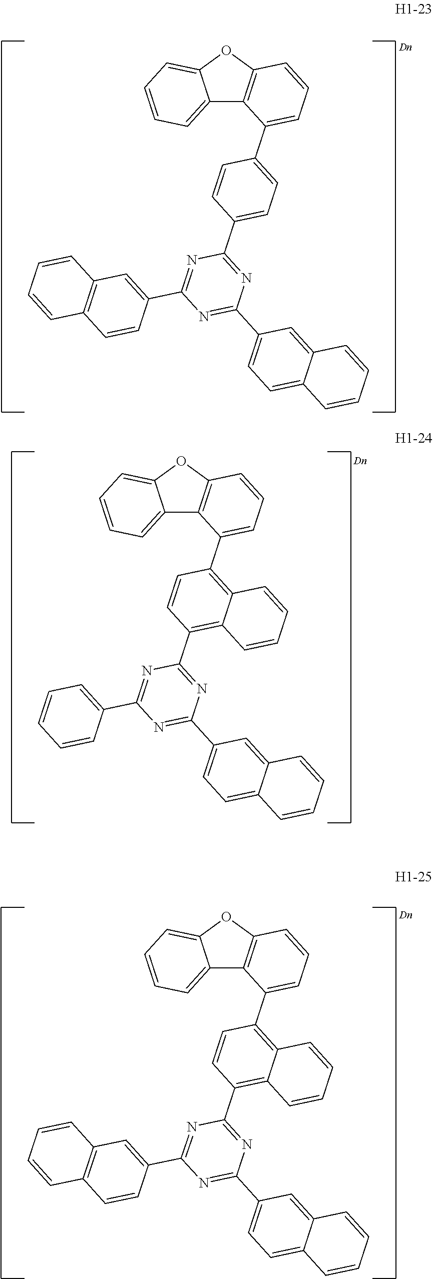

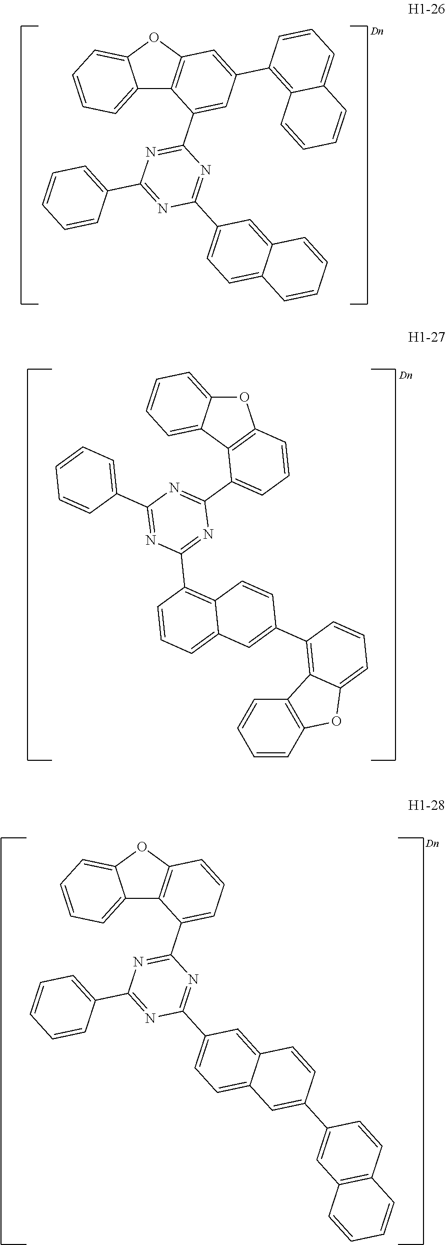

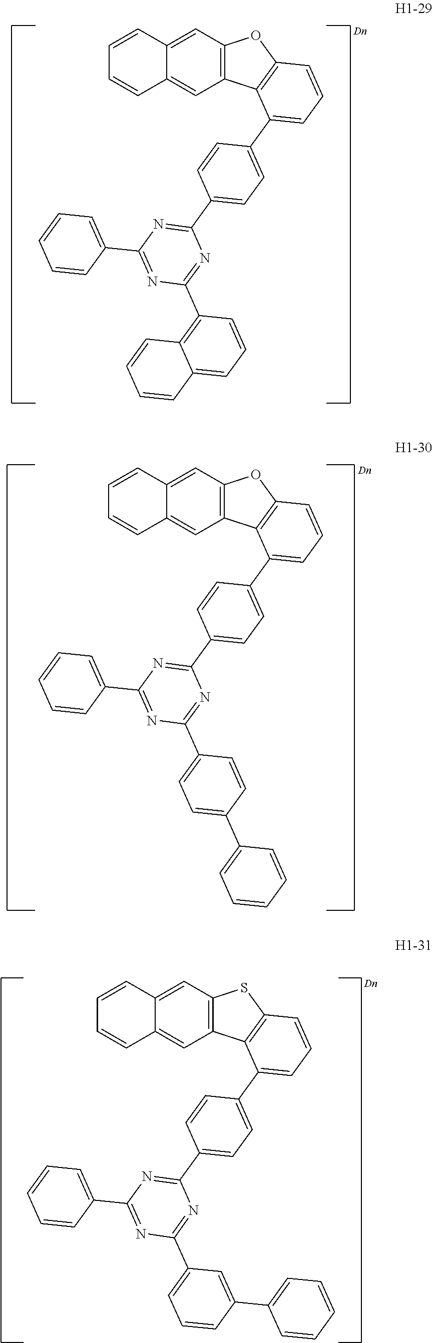

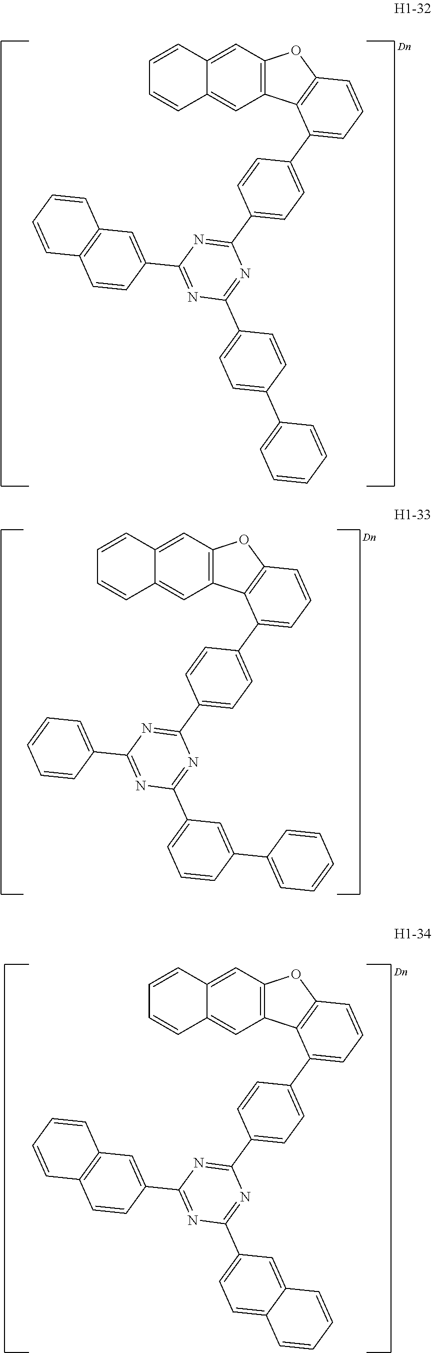

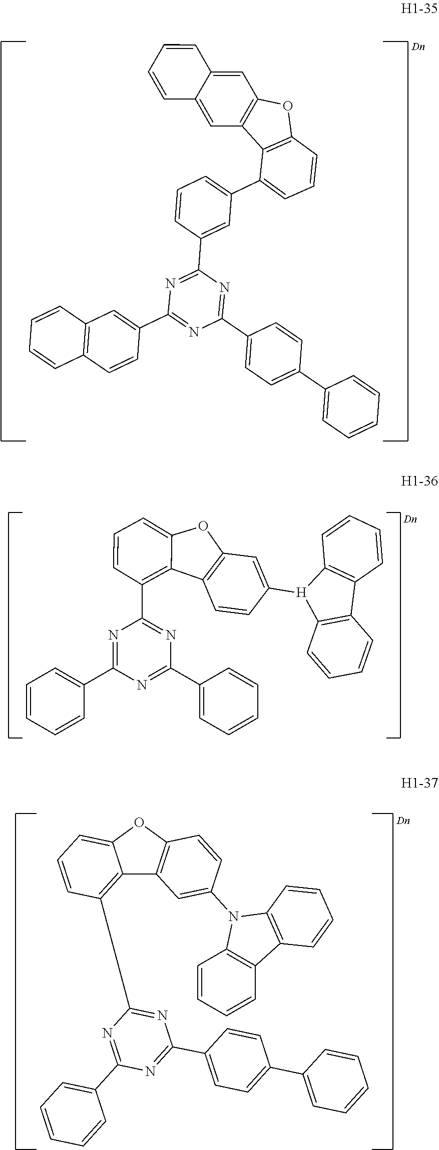

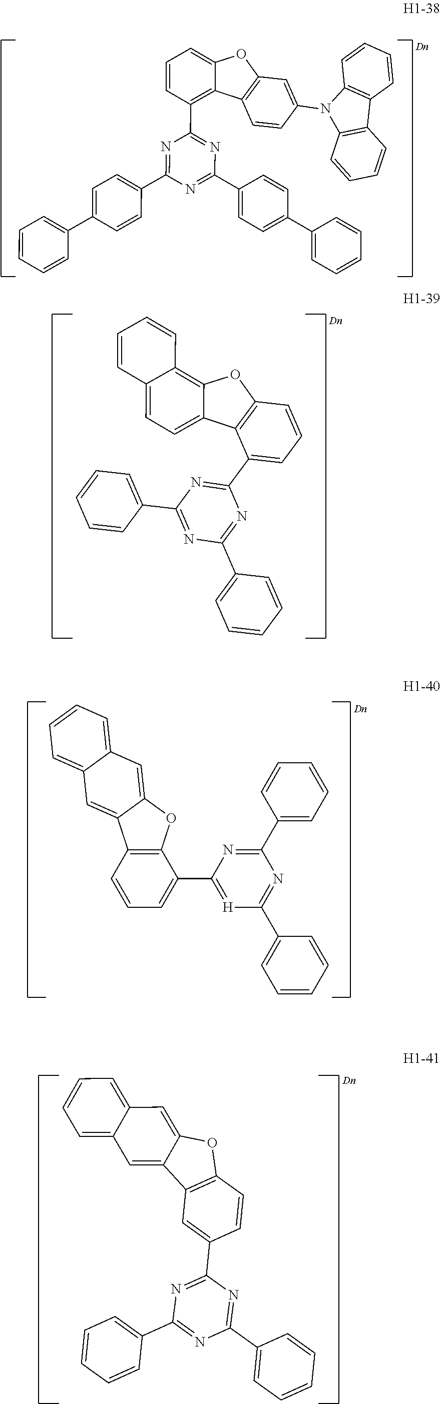

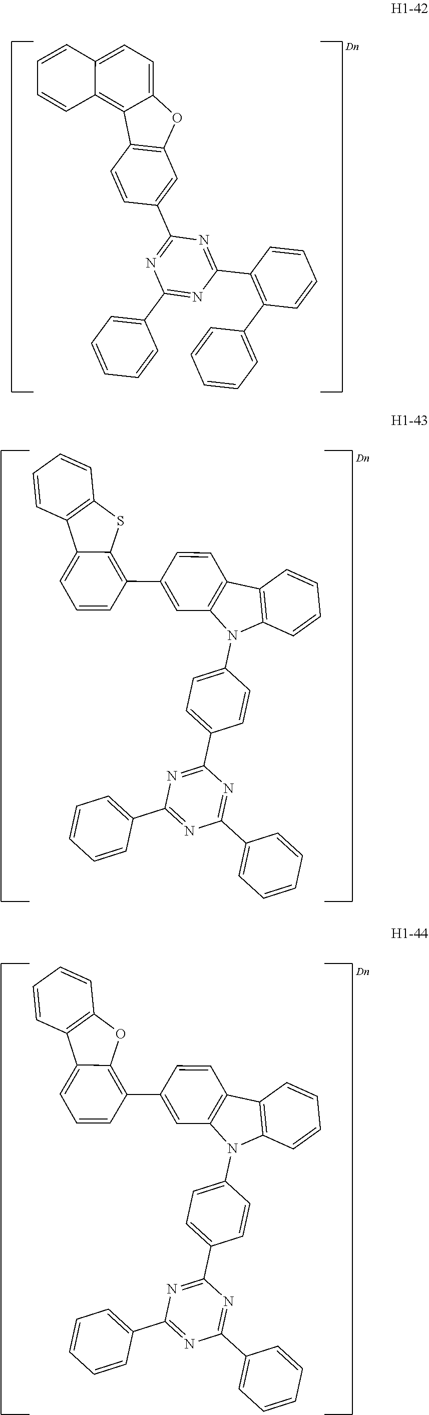

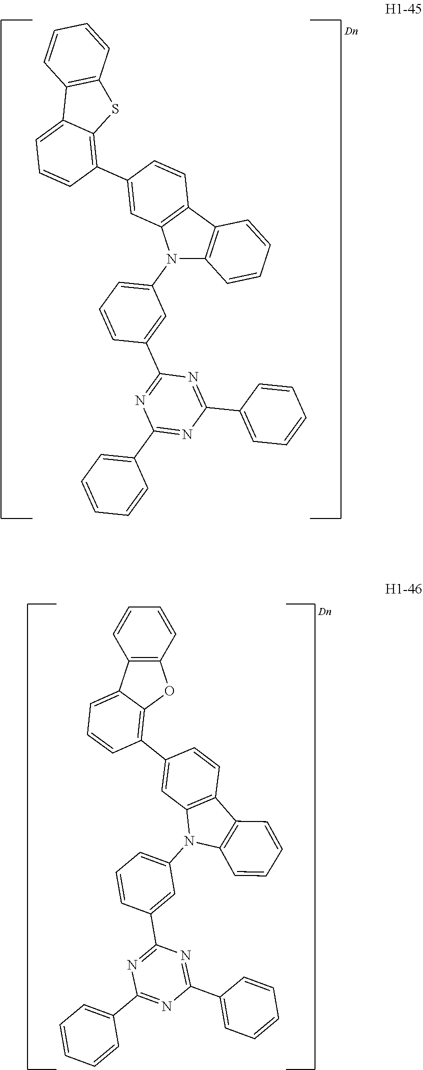

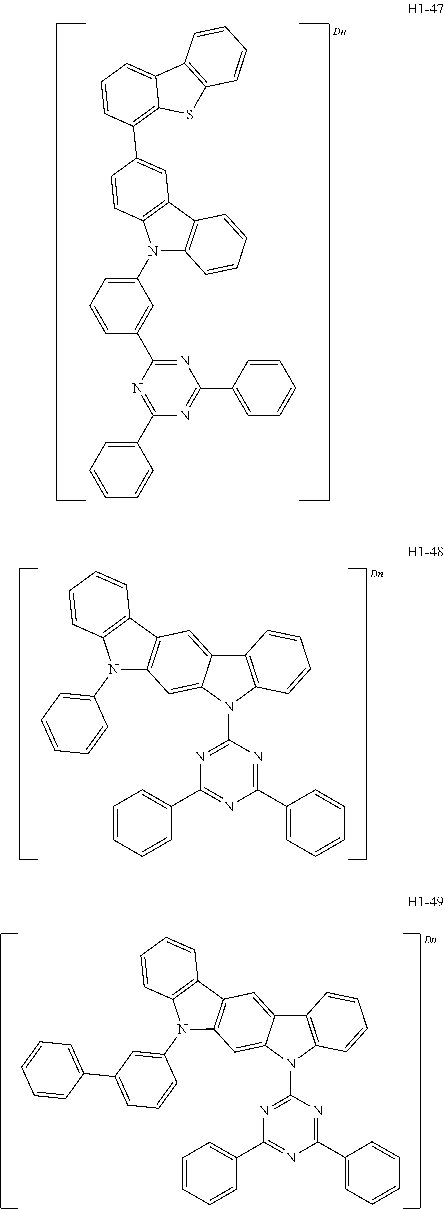

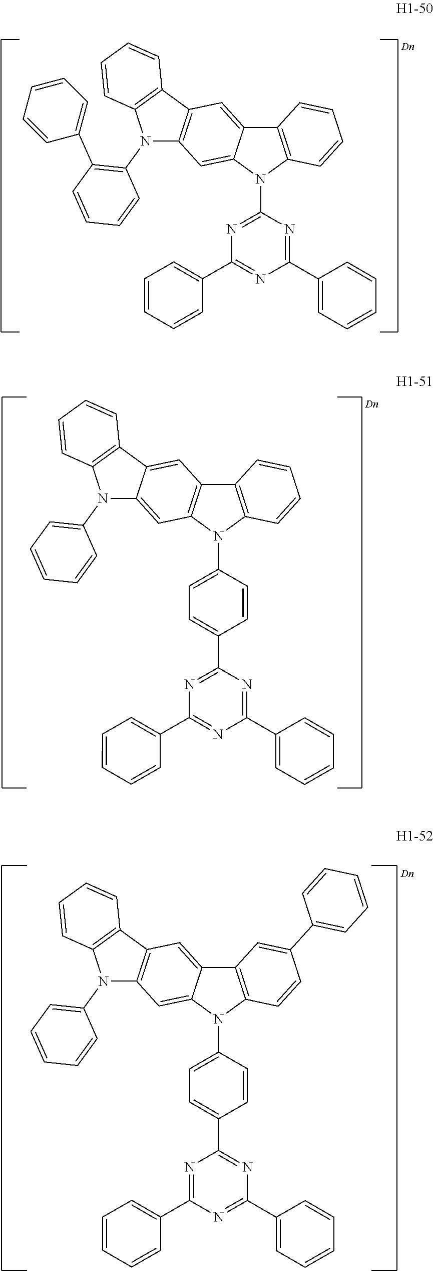

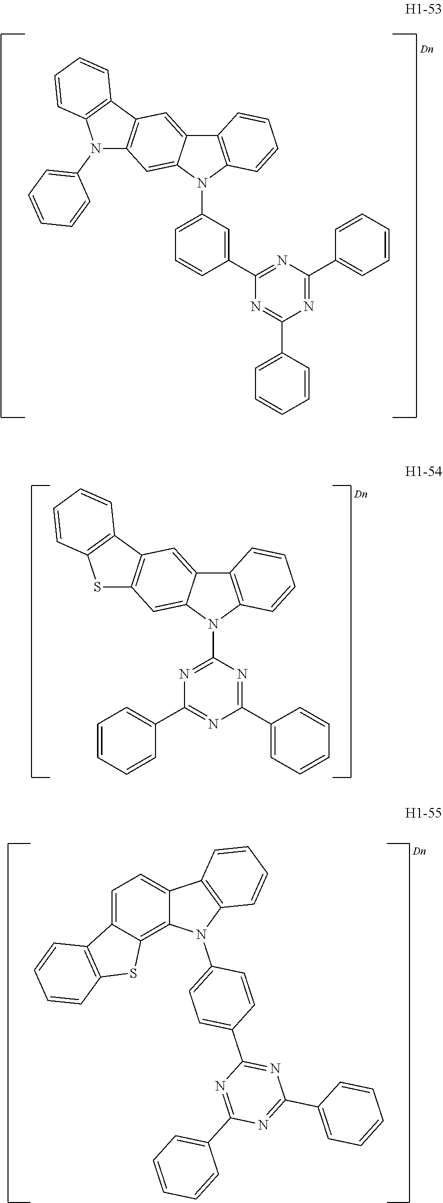

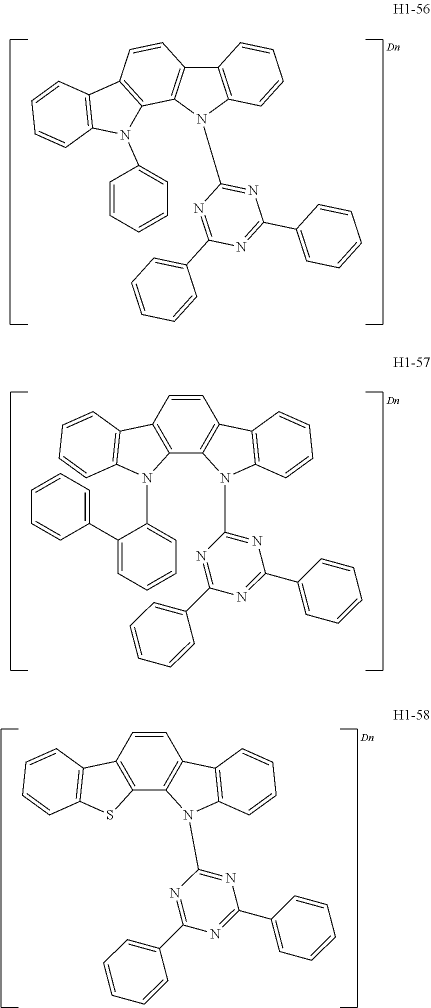

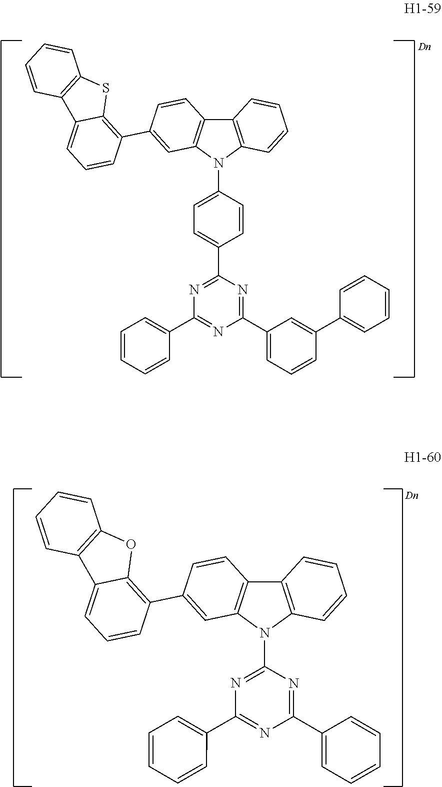

According to one embodiment of the present disclosure, the organic electroluminescent device of the present disclosure may comprise at least one layer in the light-emitting layer comprising a compound represented by the following formula 8.

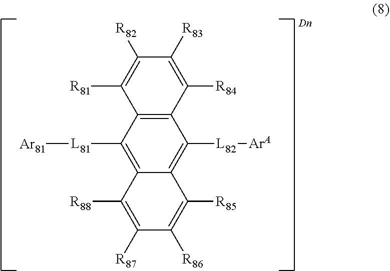

In formula 8,
Ar₈₁ represents a substituted or unsubstituted (C6-C30)aryl, or a substituted or unsubstituted (3- to 30-membered)heteroaryl;
R₈₁ to R₈₈ each independently represent hydrogen, deuterium, a halogen, a cyano, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C3-C30)cycloalkenyl, a substituted or unsubstituted (3- to 7-membered)heterocycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, or a substituted or unsubstituted fused ring group of a (C3-C30) aliphatic ring(s) and a (C6-C30) aromatic ring(s);
Ar^{A} represents a substituted or unsubstituted (C6-C30)aryl, or a substituted or unsubstituted (3- to 30-membered)heteroaryl, or is represented by the following formula A-1;
Dₙ represents that n number of hydrogens are replaced with deuterium, and n represents an integer of 1 or more, and has an upper limit of the number of hydrogen atoms in the non-deuterated compound;

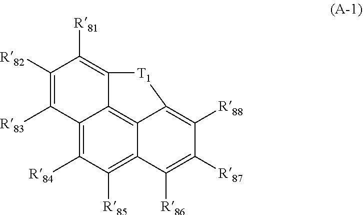

T₁ represents O, S, or CR_{f}Rₘ;
R′81 to R′₈₈ each independently are a site linked to L₈₂, or represent hydrogen, deuterium, a halogen, a cyano, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C3-C30)cycloalkenyl, a substituted or unsubstituted (3- to 7-membered)heterocycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), or -L₈₃-N(Ar₈₃)(Ar₈₄);
Rₗ and Rₘ each independently represent a substituted or unsubstituted (C1-C30)alkyl, or a substituted or unsubstituted (C6-C30)aryl, or may be linked to each other to form a ring(s);
L₈₁ to L₈₃ each independently represent a single bond, a substituted or unsubstituted (C6-C30)arylene, or a substituted or unsubstituted (3- to 30-membered)heteroarylene; and
Ar₈₃ and Ar₈₄ each independently represent hydrogen, deuterium, a halogen, a cyano, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C3-C30)cycloalkenyl, a substituted or unsubstituted (3- to 7-membered)heterocycloalkyl, a substituted or unsubstituted (C1-C30)alkoxy, a substituted or unsubstituted fused ring group of a (C3-C30) aliphatic ring(s) and a (C6-C30) aromatic ring(s), a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, or a substituted or unsubstituted tri(C6-C30)arylsilyl.

According to one embodiment of the present disclosure, Ar₈₁ may represent a substituted or unsubstituted (C6-C30)aryl. Preferably, Ar₈₁ may represent a substituted or unsubstituted (C6-C18)aryl. For example, Ar₈₁ may be a phenyl unsubstituted or substituted with a naphthyl(s), a naphthyl, or a biphenyl, etc., which may be further substituted with one or more deuterium atoms.

According to one embodiment of the present disclosure, R₈₁ to R₈₈ each independently may represent hydrogen, deuterium, a halogen, a cyano, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, a substituted or unsubstituted (C3-C30)cycloalkyl, or a substituted or unsubstituted (C3-C30)cycloalkenyl. Preferably, R₈₁ to R₈₈ each independently may represent hydrogen, deuterium, a halogen, a cyano, a substituted or unsubstituted (C1-C30)alkyl, a substituted or unsubstituted (C2-C30)alkenyl, a substituted or unsubstituted (C6-C30)aryl, or a substituted or unsubstituted (3- to 30-membered)heteroaryl. For example, R₈₁ to R₈₈ each independently may be hydrogen or deuterium.

According to one embodiment of the present disclosure, Ar^{A} may represent a substituted or unsubstituted (C6-C25)aryl, or a substituted or unsubstituted (5- to 20-membered)heteroaryl, or may be represented by the above formula A-1. Preferably, Ar^{A} may represent a substituted or unsubstituted (C6-C13)aryl, or a substituted or unsubstituted (13- to 17-membered)heteroaryl, or may be represented by the above formula A-1. For example, Ar^{A} may be a substituted or unsubstituted phenyl, a substituted or unsubstituted naphthyl, a substituted or unsubstituted benzofluorenyl, a dibenzofuranyl, or a benzonaphthofuranyl, or may be the above formula A-1, wherein the substituents of the above substituted ones may be at least one selected from deuterium, a methyl, a phenyl, a naphthyl, and a dibenzofuranyl.

According to one embodiment of the present disclosure, T₁ may represent O or S. For example, T₁ may be O.

According to one embodiment of the present disclosure, R′₈₁ to R′₈₈ each independently may be a site linked to L₈₂, or may represent hydrogen, deuterium, a halogen, a cyano, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, or a substituted or unsubstituted (C3-C30)cycloalkyl. Preferably, R′₈₁ to R′₈₈ each independently may be a site linked to L₈₂, or may represent hydrogen, deuterium, or an unsubstituted (C6-C18)aryl. For example, R′₈₁ to R′₈₈ each independently may be a site linked to L₈₂, or hydrogen, deuterium, or a phenyl, etc., which may be further substituted with one or more deuterium atoms.

According to one embodiment of the present disclosure, L₈₁ to L₈₃ each independently may represent a single bond, or a substituted or unsubstituted (C6-C30)arylene. Preferably, L₈₁ to L₈₃ each independently may represent a single bond, or a substituted or unsubstituted (C6-C15)arylene. For example, L₈₁ to L₈₃ each independently may represent a single bond, a phenylene, a naphthylene, or a phenanthrenylene, etc., which may be further substituted with one or more deuterium atoms.

According to one embodiment of the present disclosure, the deuterium substitution rate is preferably 20% to 100% of the total number of hydrogens, more preferably 20% to 95%, even more preferably 30% to 95%, and even more preferably 40% to 95%.

According to one embodiment of the present disclosure, the deuterated compound may be more specifically exemplified as the following compounds, but is not limited thereto.

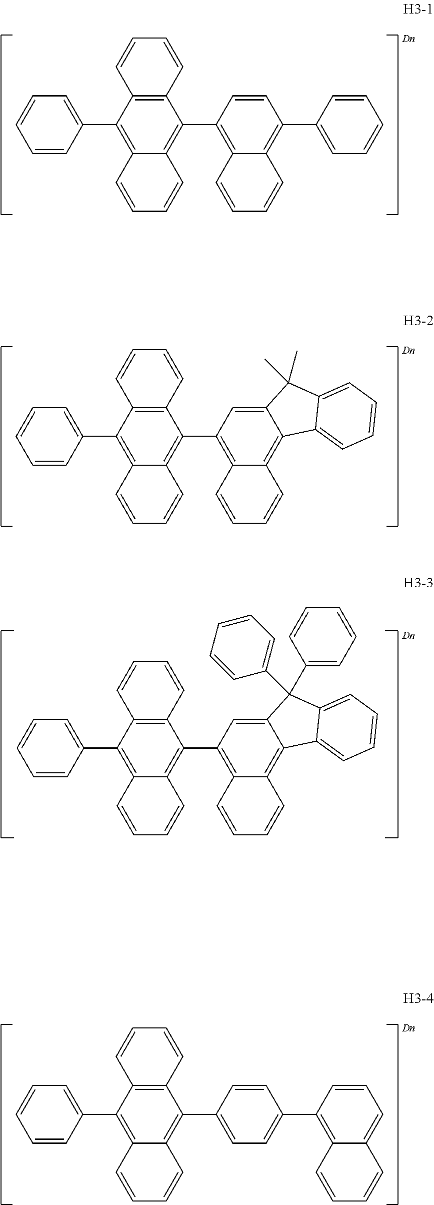

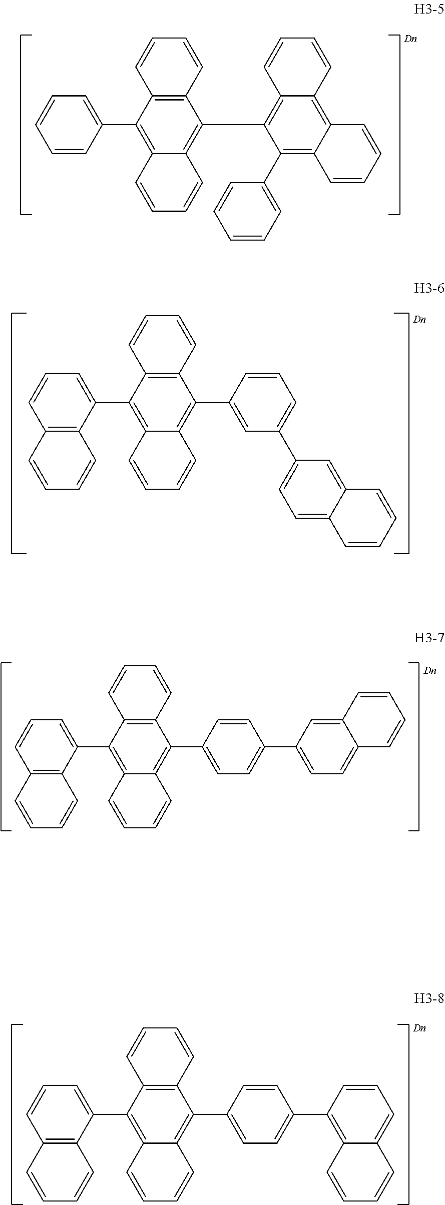

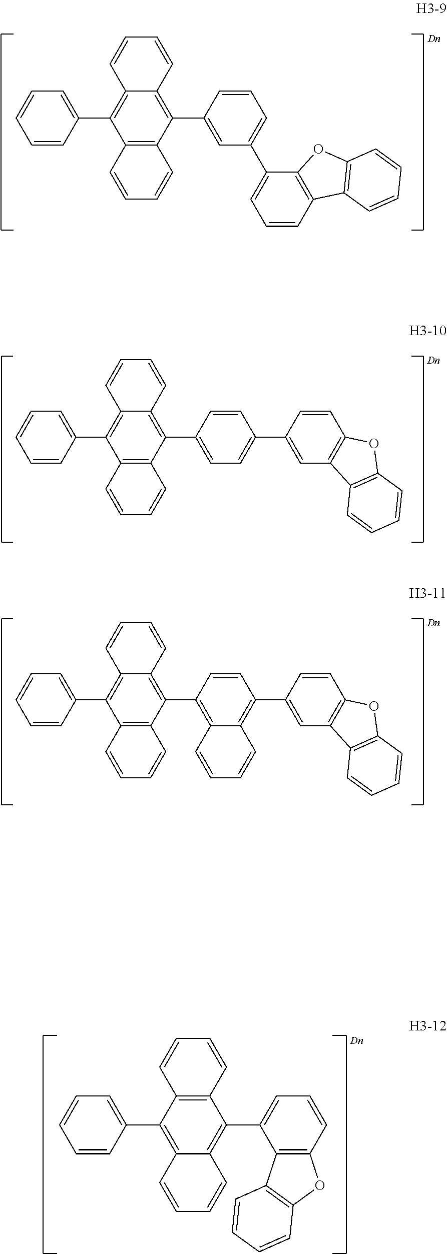

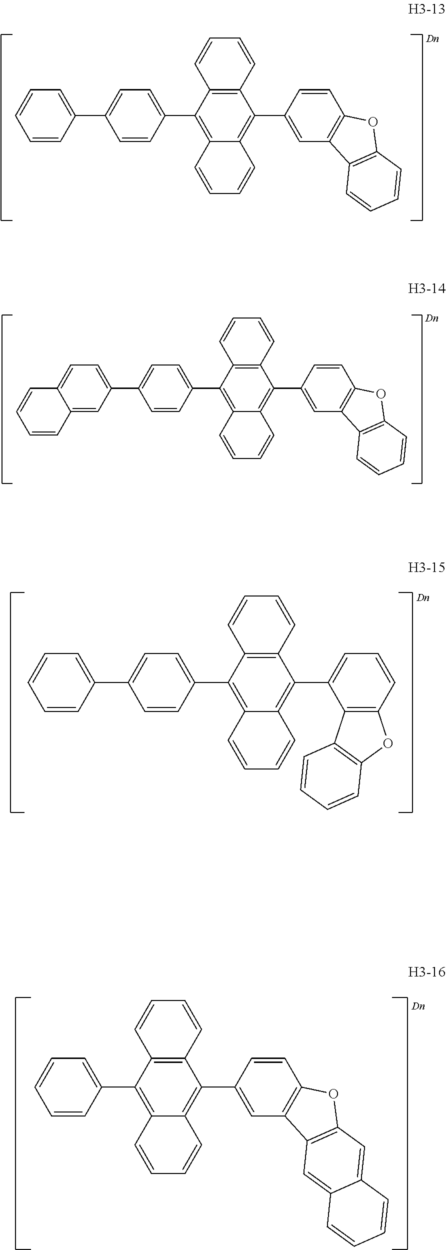

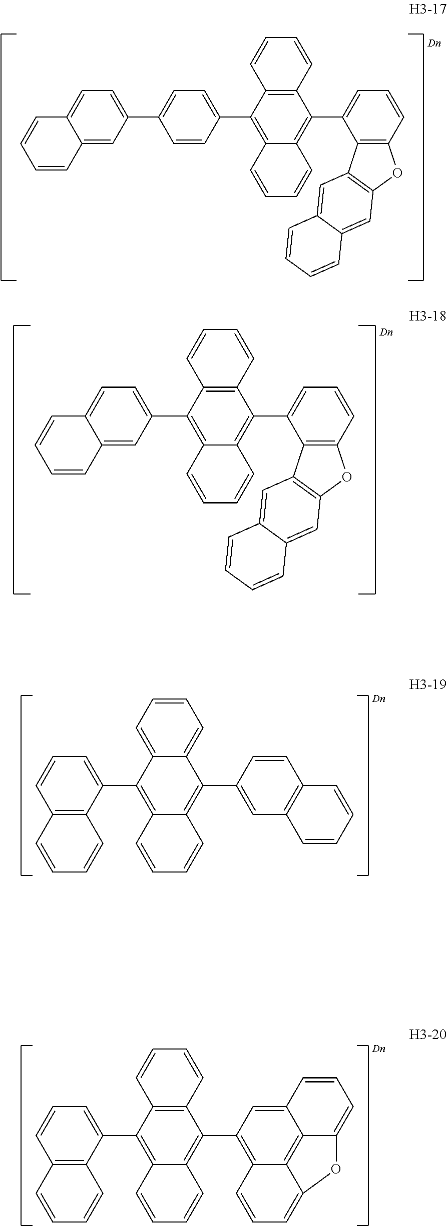

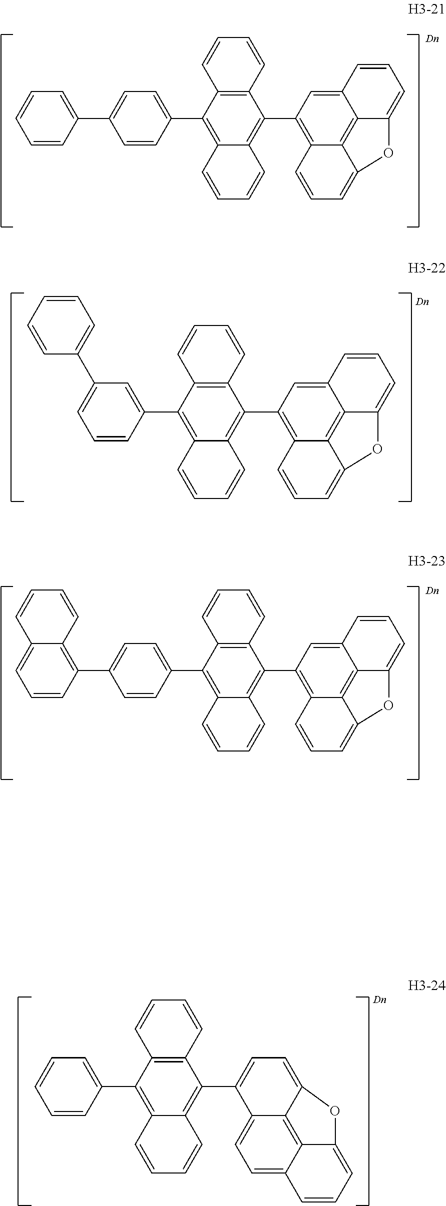

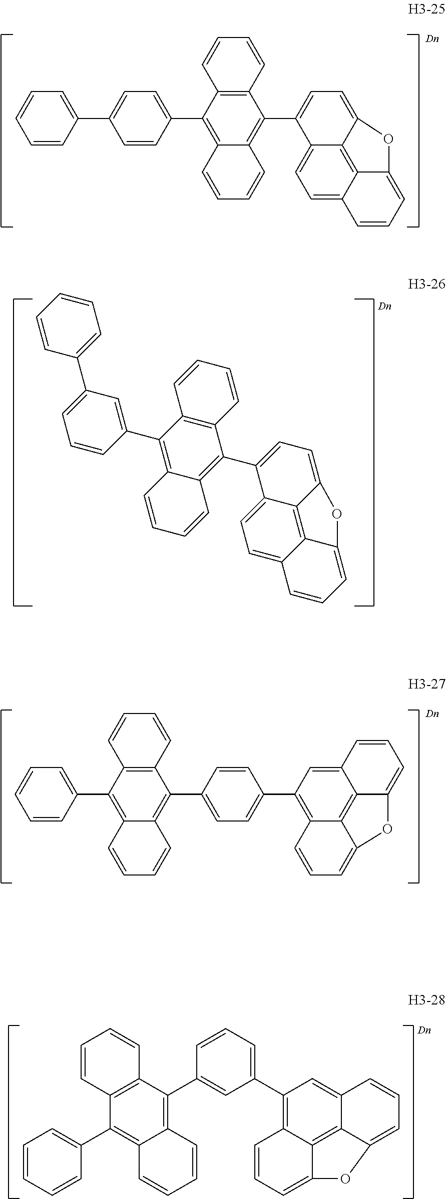

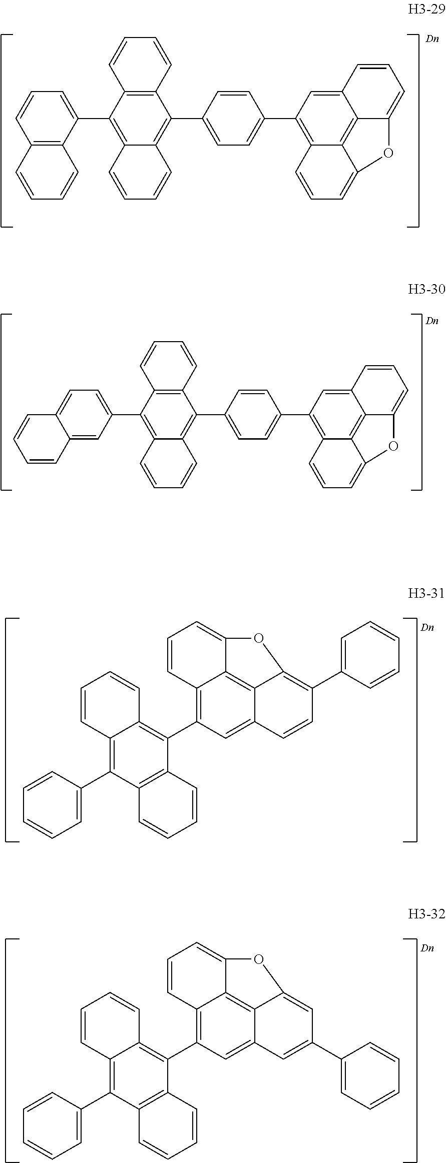

According to one embodiment of the present disclosure, the organic electroluminescent device of the present disclosure may include at least one layer in the light-emitting layer comprising a compound represented by the following formula 9.

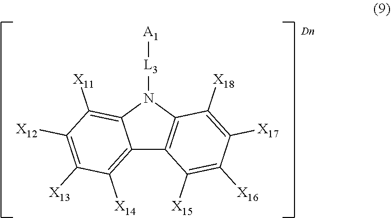

In formula 9,
any adjacent pair of X₁₅ to X₁₈ is linked to the following formula 9-A to form a ring(s), and X₁₅ to X₁₈, which do not form a ring, X₁₁ to X₁₄, and X₃₁ to X₃₄ each independently represent hydrogen, deuterium, a substituted or unsubstituted (C6-C30)aryl, or a substituted or unsubstituted (3- to 30-membered)heteroaryl;

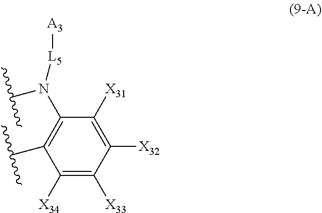

in formulas 9 and 9-A,
A₁ and A₃ each independently represent a substituted or unsubstituted (C6-C30)aryl, a substituted or unsubstituted dibenzofuranyl, a substituted or unsubstituted dibenzothiophenyl, or a substituted or unsubstituted carbazolyl;
L₃ and L₅ each independently represent a single bond, or a substituted or unsubstituted (C6-C30)arylene; and
Dₙ represents that n number of hydrogens are replaced with deuterium, and n represents an integer of 1 or more, and has an upper limit of the number of hydrogen atoms in the non-deuterated compound.

According to one embodiment of the present disclosure, A₁ and A₃ each independently may represent a substituted or unsubstituted (C6-C18)aryl, a substituted or unsubstituted dibenzofuranyl, or a substituted or unsubstituted carbazolyl. For example, A₁ and A₃ each independently may be a substituted or unsubstituted naphthyl, a substituted or unsubstituted phenyl, a substituted or unsubstituted p-biphenyl, a substituted or unsubstituted m-biphenyl, a substituted or unsubstituted p-terphenyl, a substituted or unsubstituted m-terphenyl, a substituted or unsubstituted o-terphenyl, a substituted or unsubstituted naphthyl, a substituted or unsubstituted dibenzofuranyl, or a substituted or unsubstituted carbazolyl, etc, wherein the substituents of the above substituted ones may be at least one selected from deuterium, a phenyl, a carbazolyl unsubstituted or substituted with a phenyl(s), and a naphthyl.

According to one embodiment of the present disclosure, L₃ and L₅ each independently may represent a single bond, or a substituted or unsubstituted (C6-C12)arylene. For example, L₃ and L₅ each independently may represent a single bond, a substituted or unsubstituted phenylene, a substituted or unsubstituted p-biphenylene, a substituted or unsubstituted m-biphenylene, a substituted or unsubstituted o-biphenylene, or a substituted or unsubstituted naphthylene, etc., wherein the substituents of the above substituted ones may be at least one selected from deuterium and carbazolyl.

According to one embodiment of the present disclosure, X₁₅ to X₁₈, which do not form a ring, X₁₁ to X₁₄, and X₃₁ to X₃₄ each independently may represent hydrogen or deuterium.

According to one embodiment of the present disclosure, the deuterium substitution rate is preferably 20% to 100% of the total number of hydrogens, more preferably 20% to 95%, even more preferably 30% to 95%, and even more preferably 40% to 95%.

According to one embodiment of the present disclosure, in the organic electroluminescent device of the present disclosure X₁₁ or X₃₁ may represent deuterium.

According to one embodiment of the present disclosure, the compound represented by formula 9 may be represented by any one of the following formulas 9-1 to 9-6.

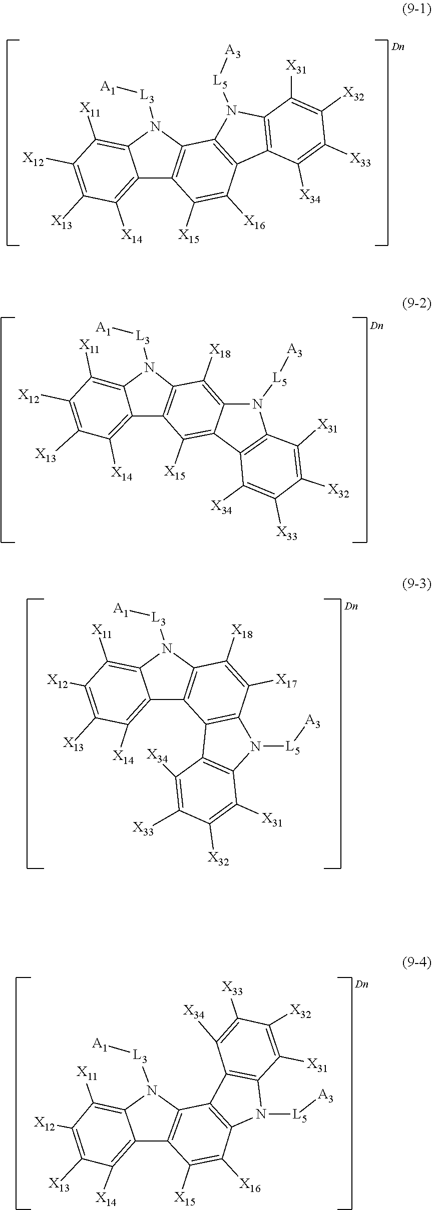

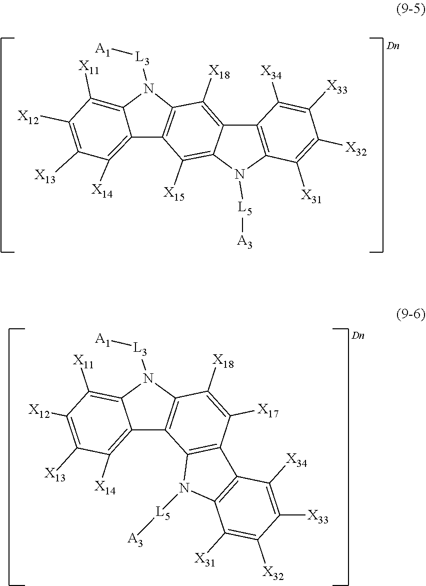

In formulas 9-1 to 9-6, A₁, A₃, L₃, L₅, X₁₁ to X₁₈, X₃₁ to X₃₄, and Dₙ are as defined in formula 9 and formula 9-A.

According to one embodiment of the present disclosure, the deuterated compound may be more specifically exemplified as the following compounds, but is not limited thereto.

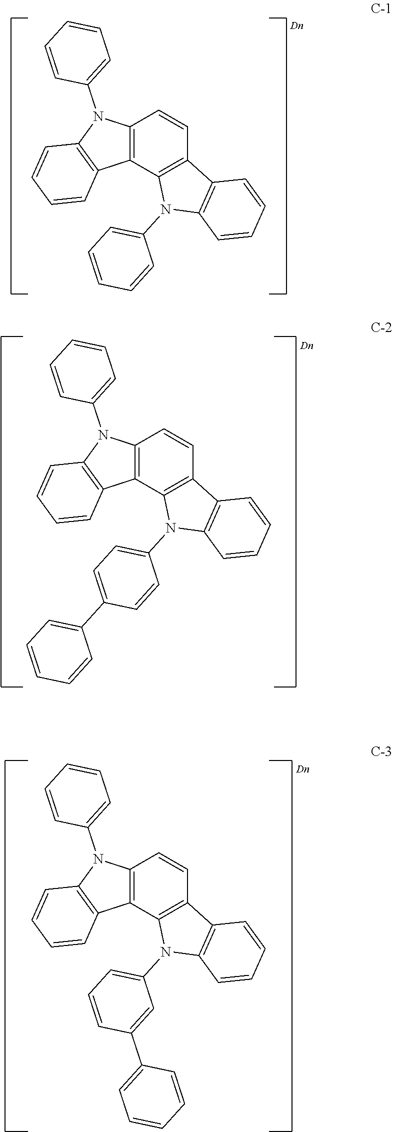

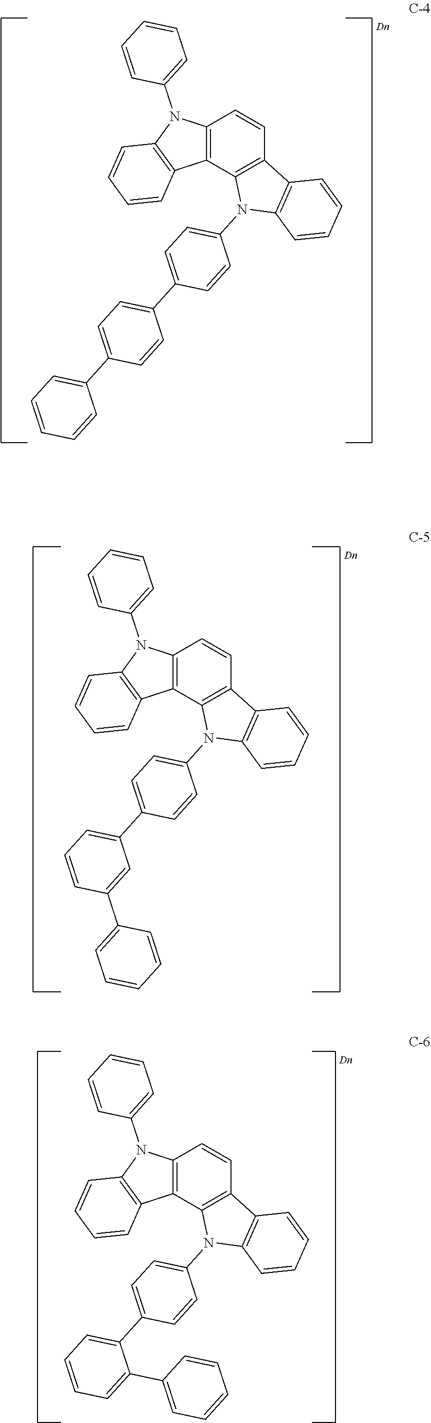

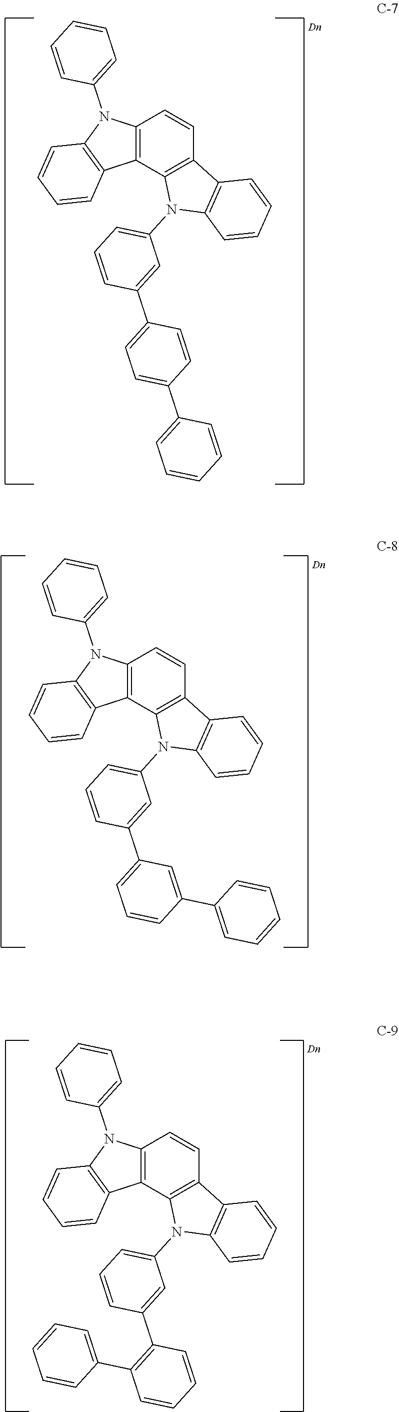

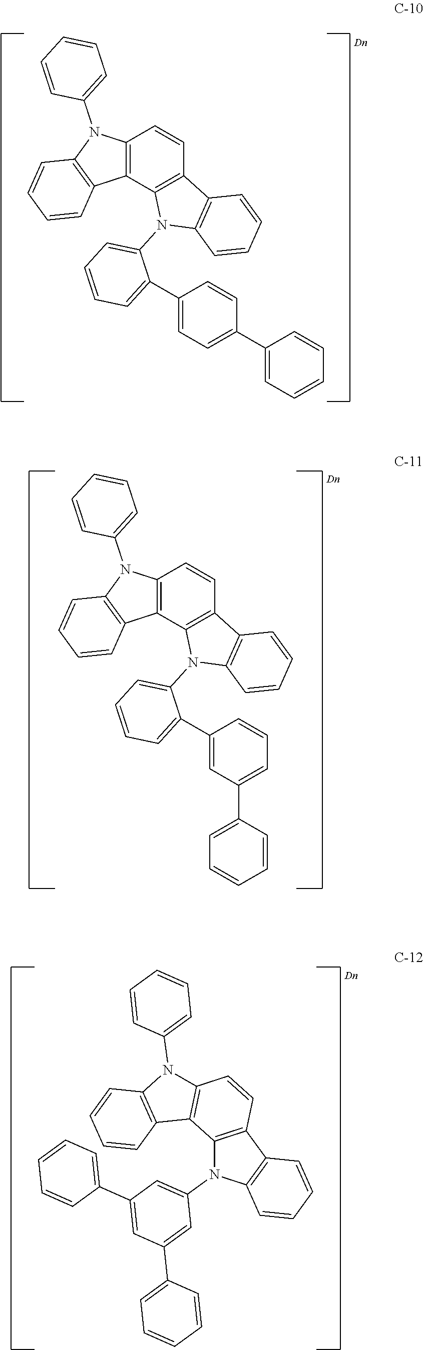

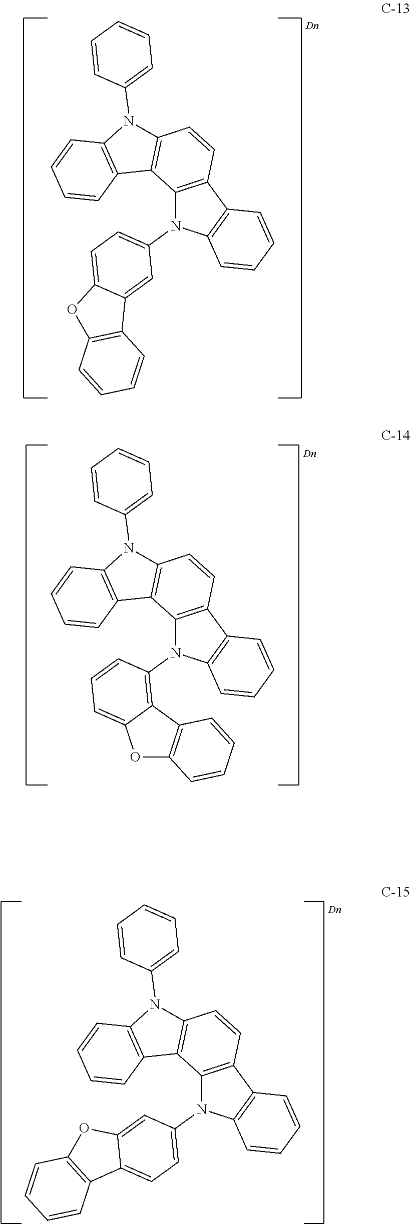

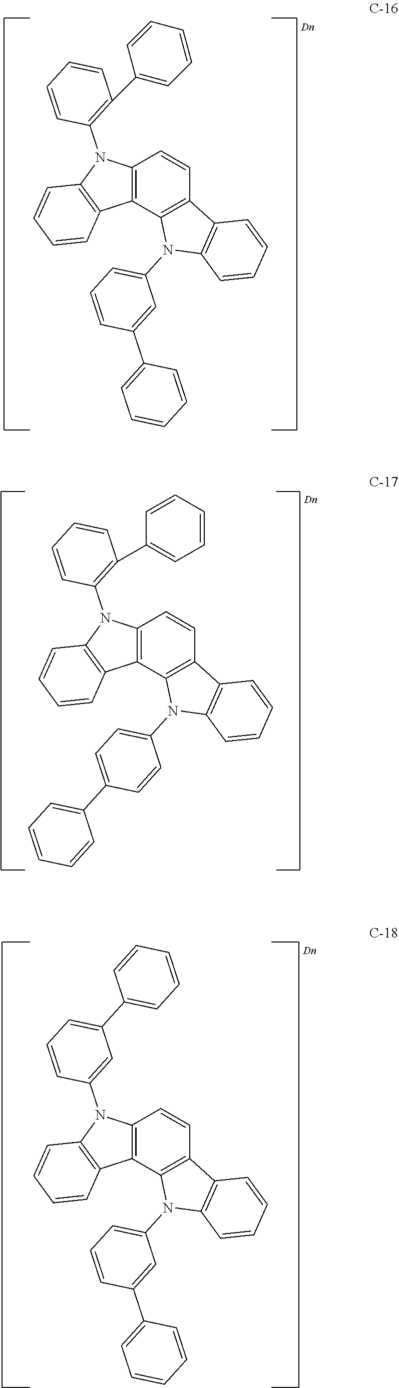

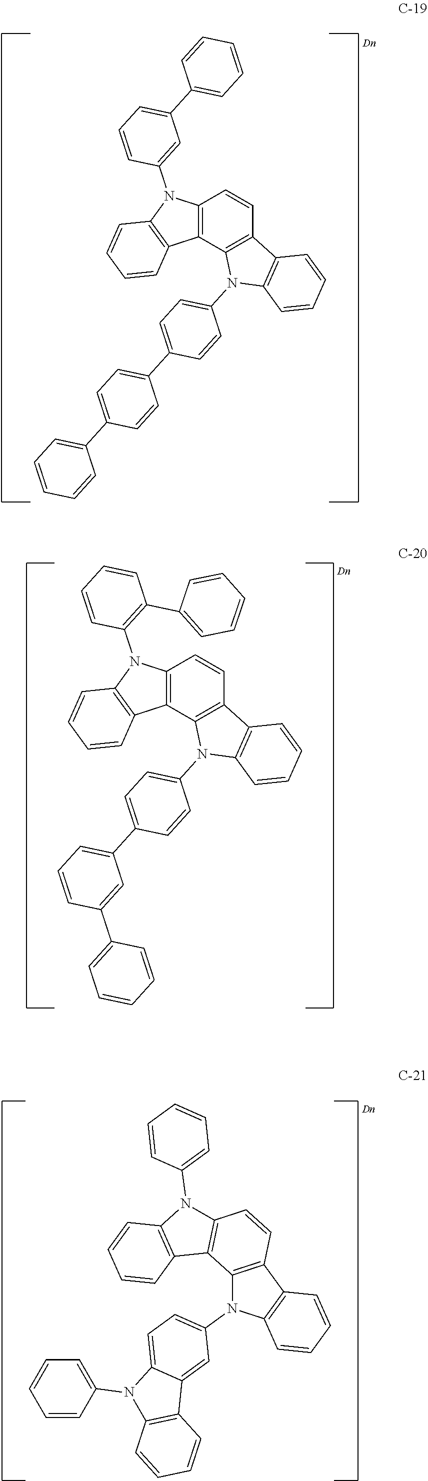

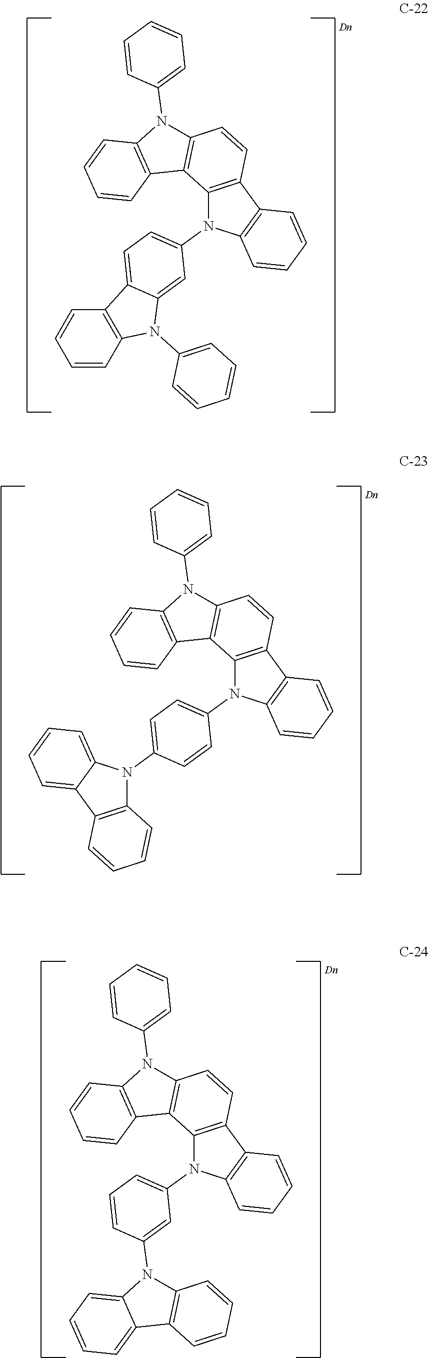

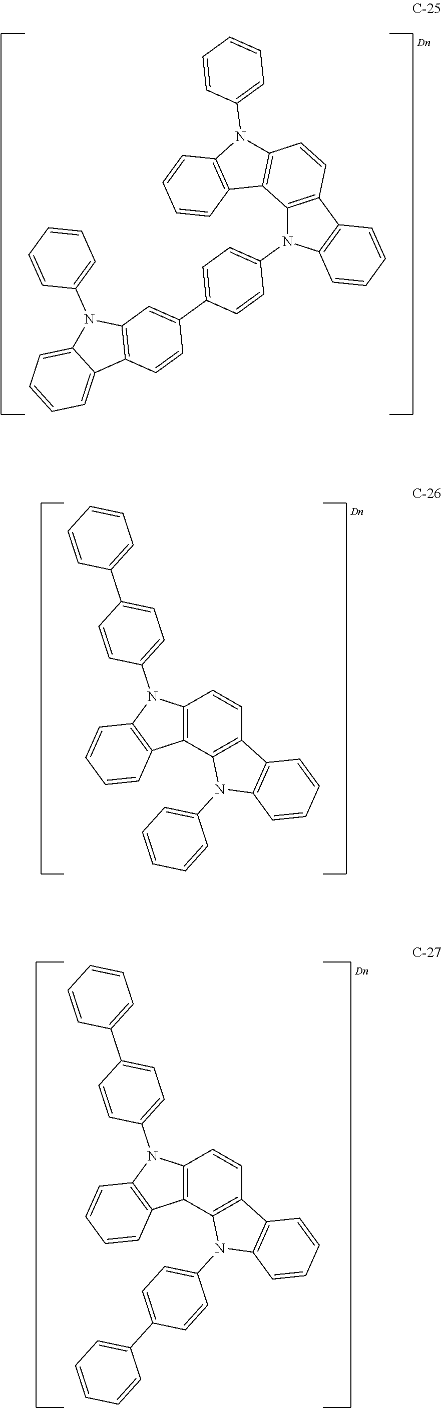

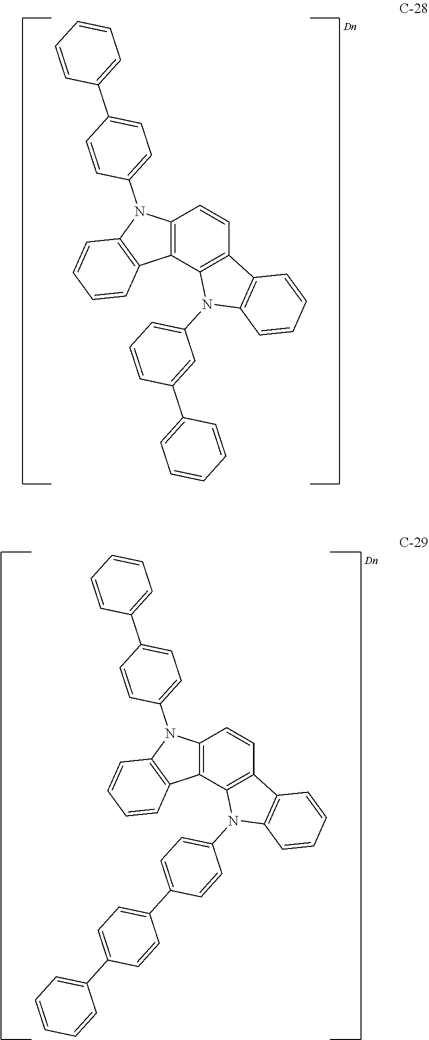

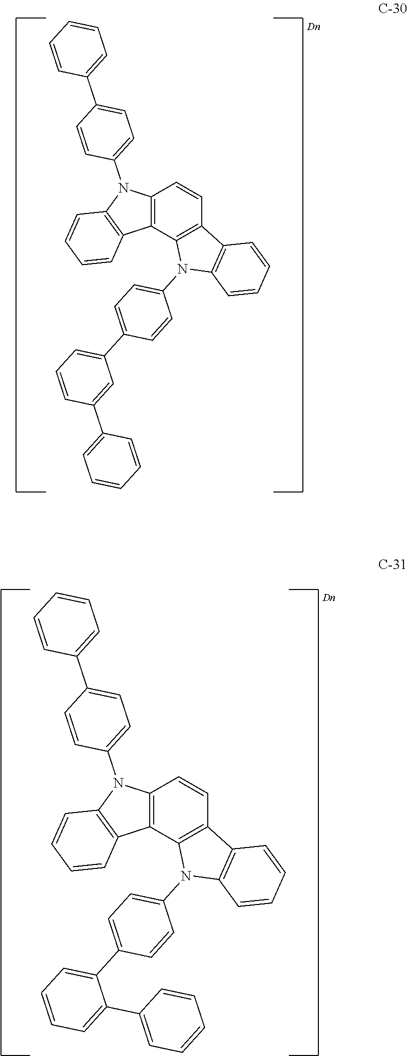

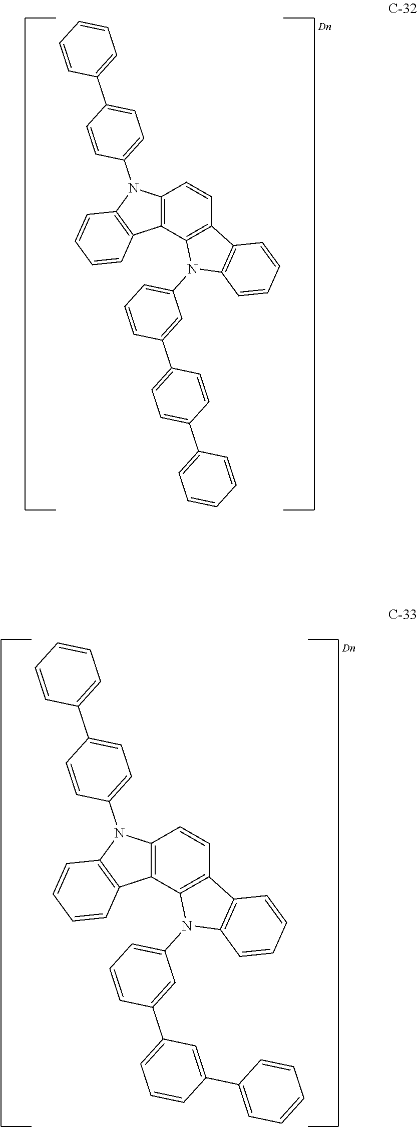

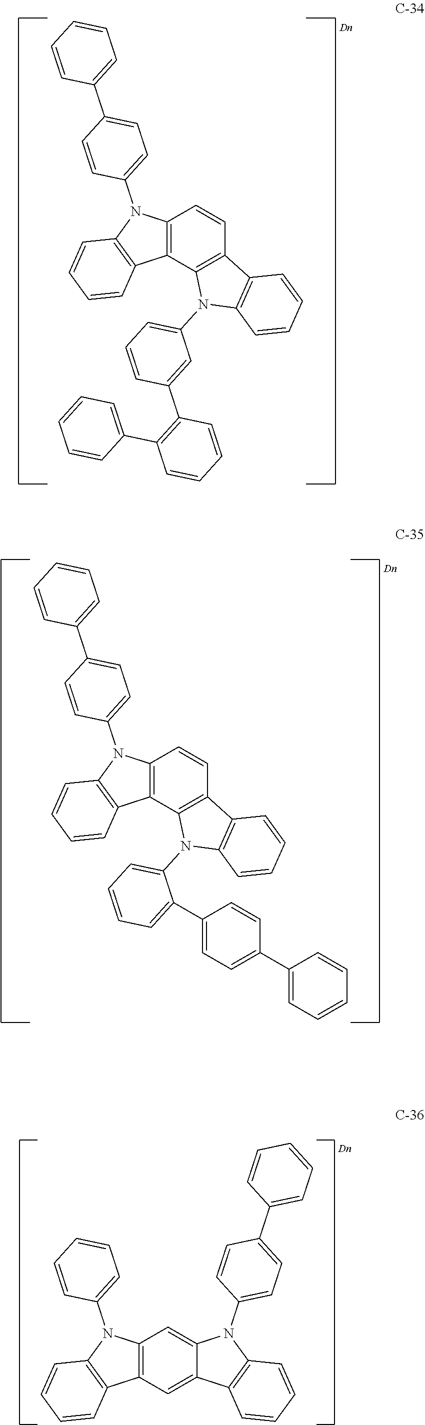

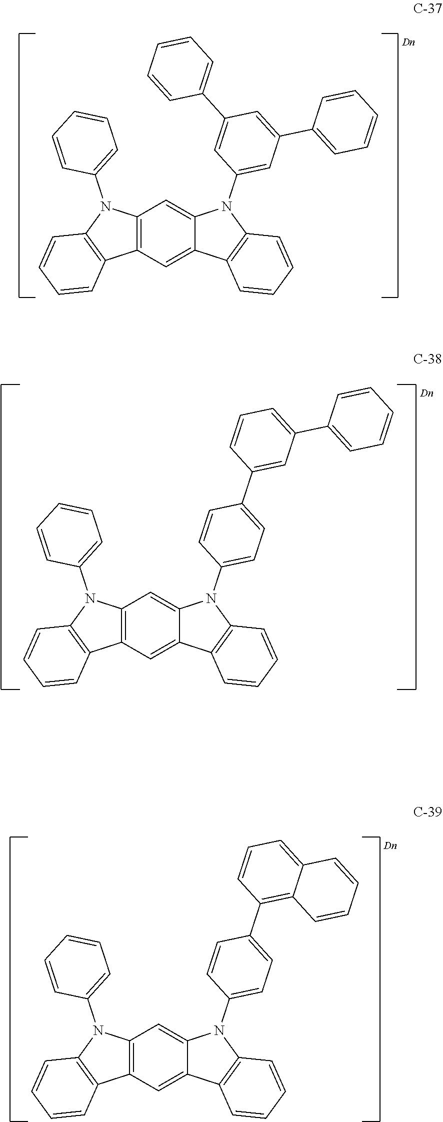

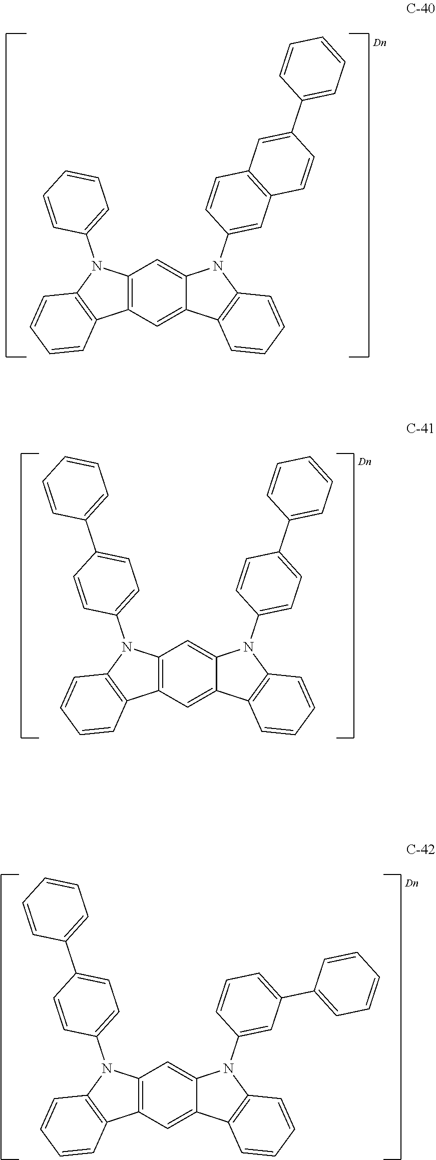

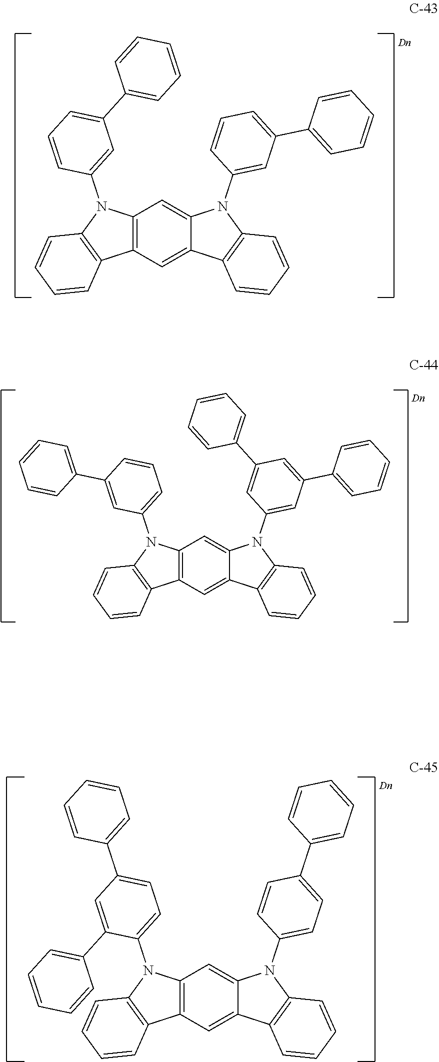

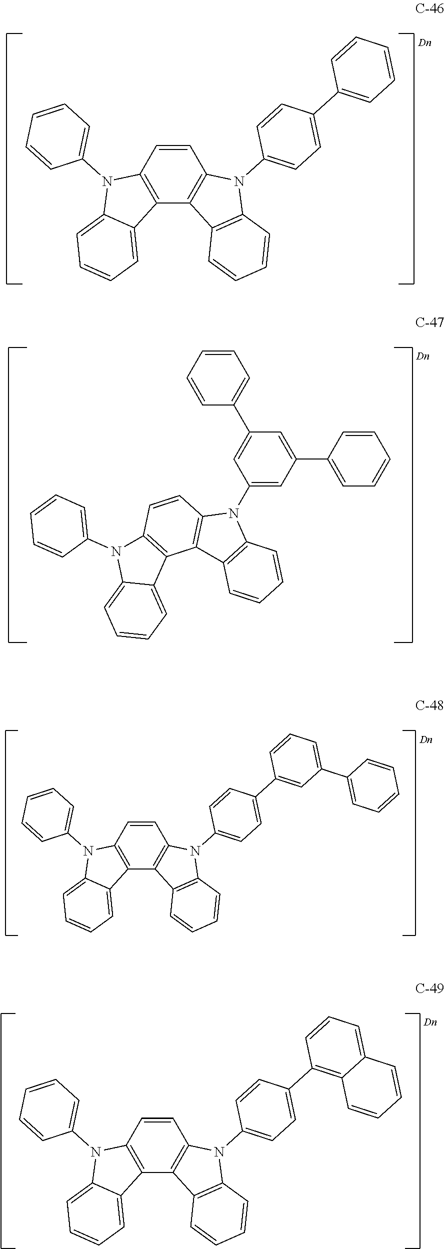

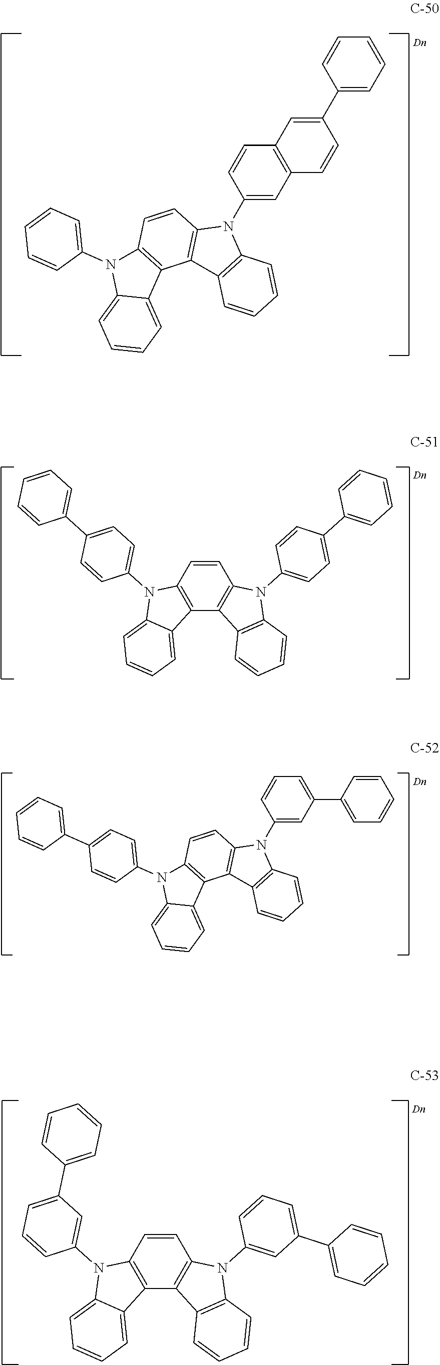

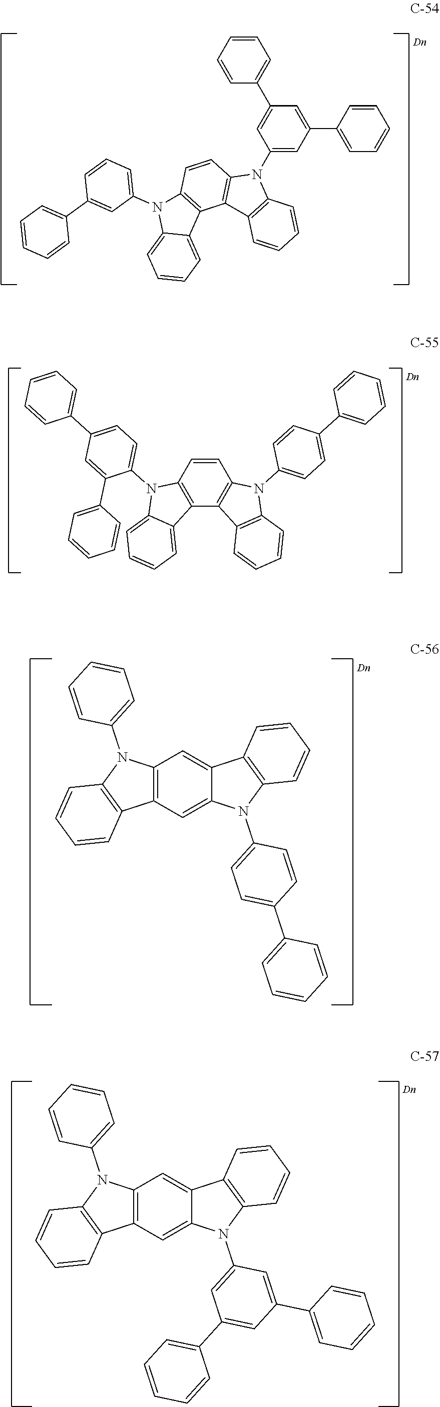

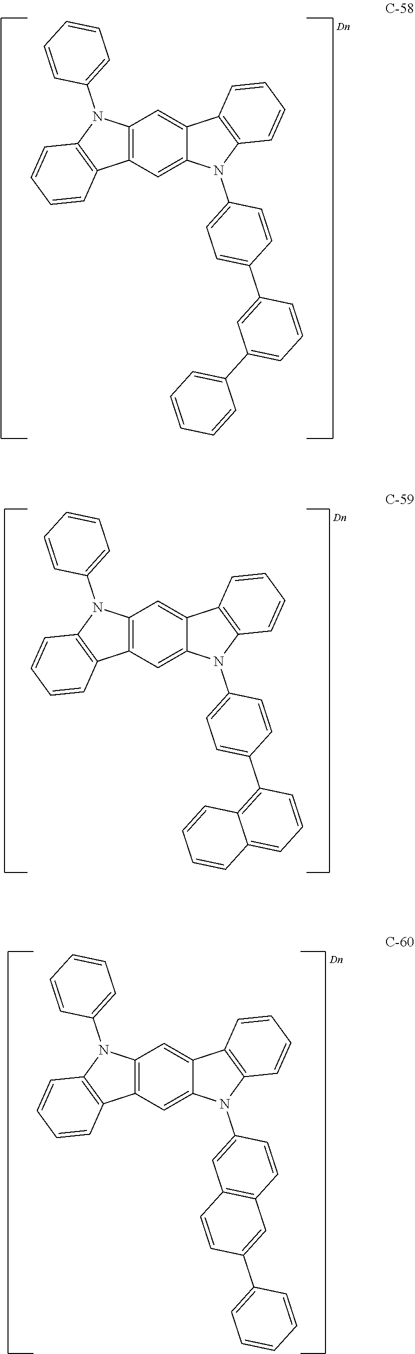

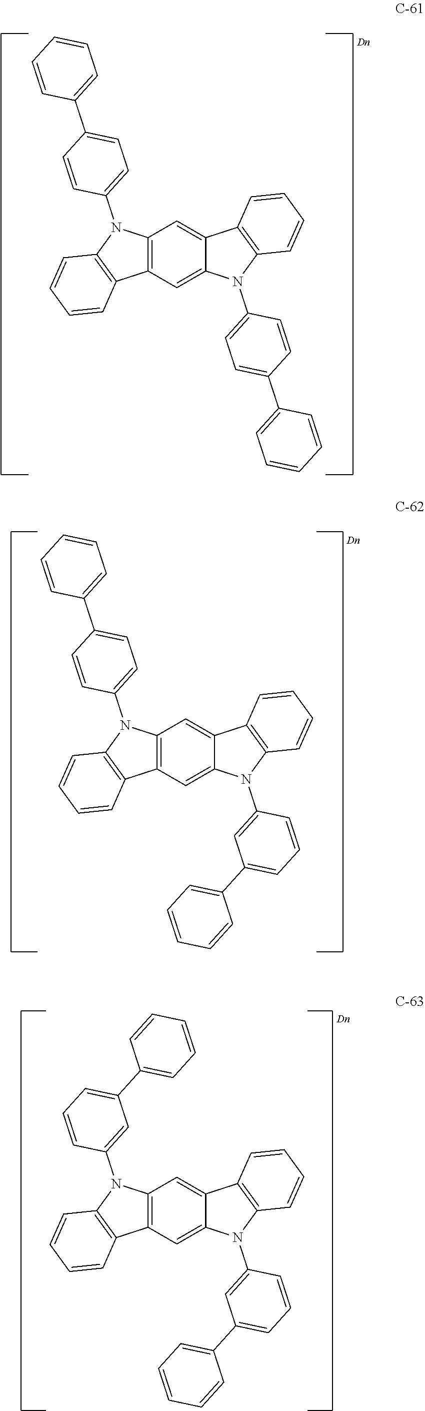

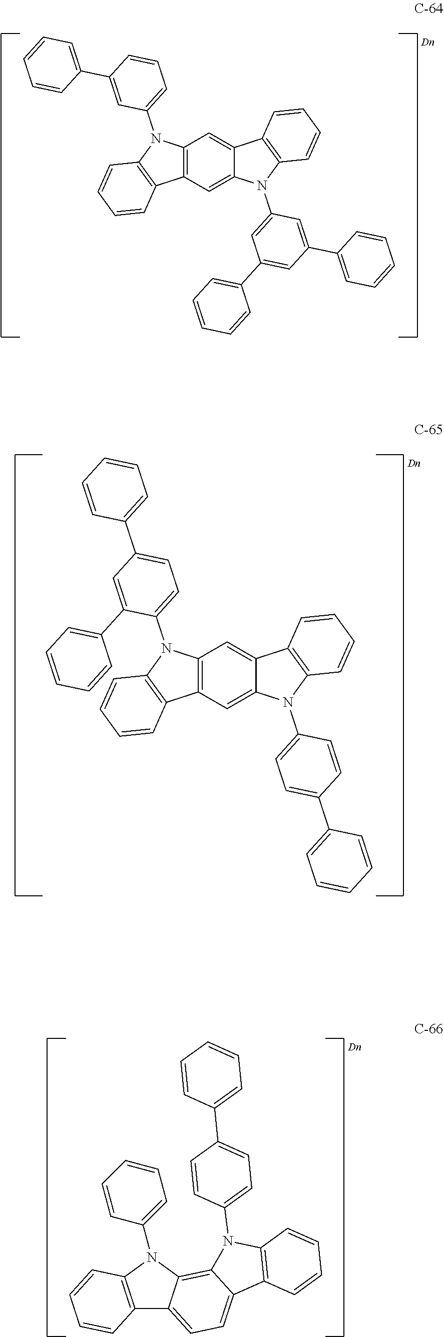

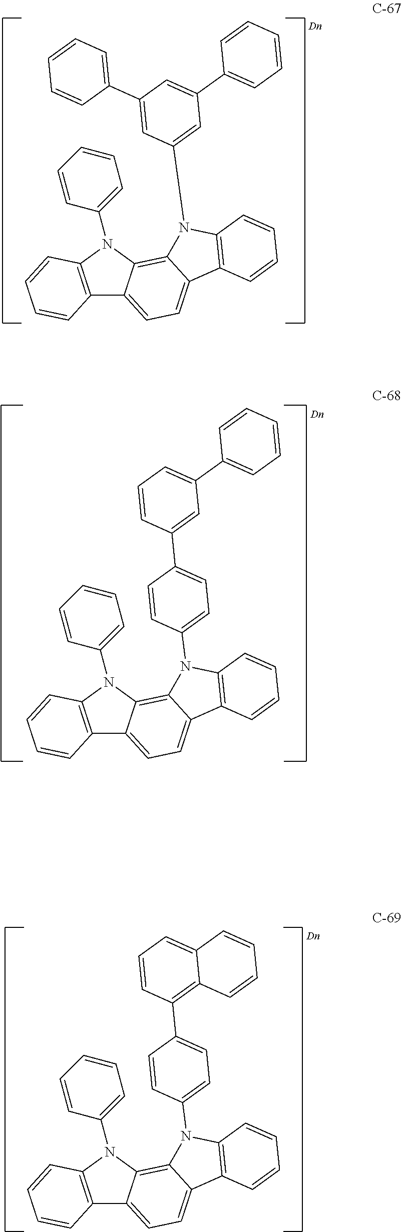

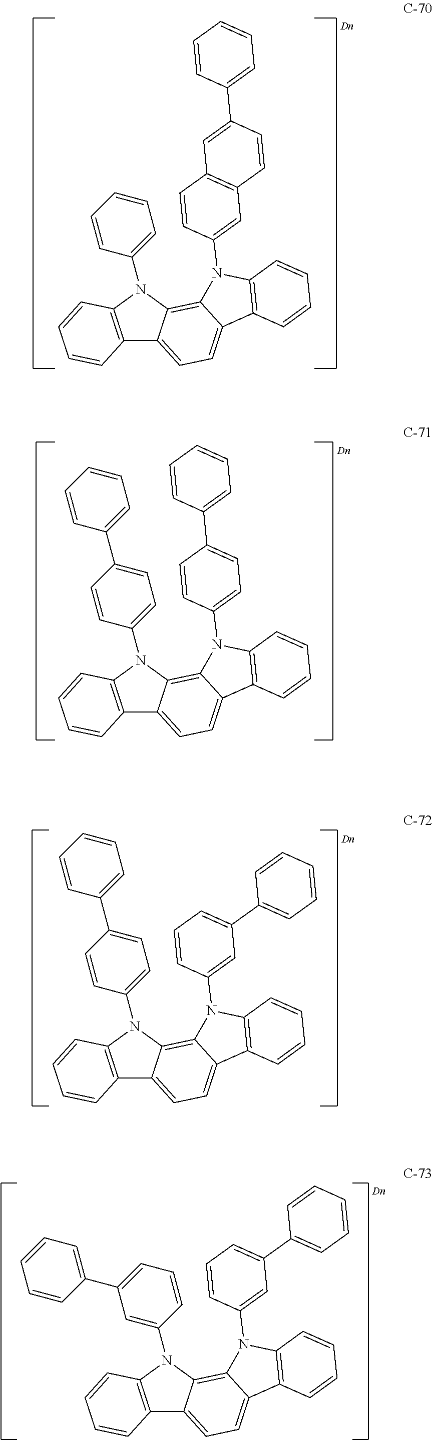

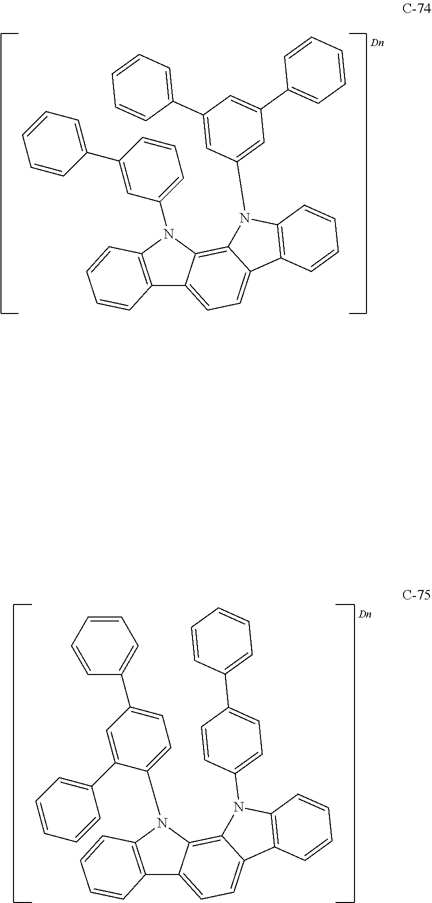

In the above compounds, Dₙ represents that n number of hydrogens are replaced with deuterium, and n represents an integer of 1 or more, and has an upper limit of the number of hydrogen atoms in the non-deuterated compound.

In the synthesis of the compounds represented by formulas 1 to 9 above, one skilled in the art will be able to readily understand that all of these are based on a Buchwald-Hartwig cross coupling reaction, an N-arylation reaction, an H-mont-mediated etherification reaction, a Miyaura borylation reaction, a Suzuki cross-coupling reaction, an intramolecular acid-induced cyclization reaction, a Pd(II)-catalyzed oxidative cyclization reaction, a Grignard reaction, a Heck reaction, a cyclic dehydration reaction, an S_{N}1 substitution reaction, an S_{N}2 substitution reaction, a phosphine-mediated reductive cyclization reaction, and Wittig reaction, etc., and the above reactions proceed even when substituents defined in formulas 1 to 9 other than those substituents specified in the specific synthesis examples are bonded.

Hereinafter, the above-mentioned compounds and an organic electroluminescent device comprising the same will be described.

The organic layer of the present disclosure may include at least one layers selected from a hole transport layer, a light-emitting layer, a hole injection layer, a hole auxiliary layer, a light-emitting auxiliary layer, an electron transport layer, an electron injection layer, an interlayer, a hole-blocking layer, an electron-blocking layer, and an electron buffer layer. The organic layer may further comprise an amine-based compound and/or an azine-based compound. Specifically, the hole injection layer, the hole transport layer, the hole auxiliary layer, the light-emitting layer, the light-emitting auxiliary layer, or the electron-blocking layer may comprise an amine-based compound, for example, an arylamine-based compound, a styrylarylamine-based compound, etc., as a hole injection material, a hole transport material, a hole auxiliary material, a light-emitting material, a light-emitting auxiliary material, and an electron-blocking material. In addition, the electron transport layer, the electron injection layer, the electron buffer layer, and the hole-blocking layer may comprise an azine-based compound as an electron transport material, an electron injection material, an electron buffer material, and a hole-blocking material. In addition, the organic layer may further comprise at least one metal selected from the group consisting of metals of Group 1, metals of Group 2, transition metals of the 4^{th} period, transition metals of the 5^{th} period, lanthanides, and organic metals of the d-transition elements of the Periodic Table, or at least one complex compound comprising the metal thereof.

A hole transport zone comprising a hole injection layer, a hole transport layer, an electron-blocking layer, or a combination thereof is included between the anode and the light-emitting layer. The hole injection layer may be composed of multiple layers for the purpose of lowering the hole injection barrier (or hole injection voltage) from the anode to the hole transport layer or electron-blocking layer, and each layer may use two compounds simultaneously. In addition, the hole injection layer may be doped with a p-type dopant. The electron-blocking layer may be placed between the hole transport layer (or hole injection layer) and the light-emitting layer, and may block the overflow of electrons from the light-emitting layer and confine the excitons in the light-emitting layer to prevent light leakage. The hole transport layer or electron-blocking layer may use multiple layers, and multiple compounds may be used in each layer.

An electron transport zone is included between the light-emitting layer and the cathode, including an electron buffer layer, a hole-blocking layer, an electron transport layer, an electron injection layer, or a combination thereof. The electron buffer layer may be multi-layers in order to control the injection of the electron and improve the interfacial properties between the light-emitting layer and the electron injection layer, wherein each of the multi-layers may use two compounds simultaneously. The hole-blocking layer is located between the electron transport layer (or electron injection layer) and the light-emitting layer and is a layer that blocks holes from reaching the cathode, thereby improving the probability of recombination of electrons and holes in the light-emitting layer. The hole-blocking layer or electron transport layer may also use multiple layers, and multiple compounds may be used in each layer. In addition, the electron injection layer may be doped with an n-type dopant.

The light-emitting auxiliary layer may be a layer placed between an anode and a light-emitting layer, or between a cathode and a light-emitting layer. When the light-emitting auxiliary layer is placed between the anode and the light-emitting layer, the light-emitting auxiliary layer may be used to facilitate hole injection and/or hole transport or to block the overflow of electrons. When the light-emitting auxiliary layer is placed between the cathode and the light-emitting layer, the light-emitting auxiliary layer may be used to facilitate electron injection and/or electron transport or to block the overflow of holes. In addition, the hole auxiliary layer may be placed between the hole transport layer (or hole injection layer) and the light-emitting layer, and may exhibit an effect of facilitating or blocking the hole transport rate (or hole injection rate), and accordingly may adjust the charge balance. When an organic electroluminescent device includes two or more hole transport layers, the hole transport layer, which is further included, may be used as a hole auxiliary layer or an electron-blocking layer. The light-emitting auxiliary layer, the hole auxiliary layer, or the electron-blocking layer may have an effect of improving the efficiency and/or lifetime of the organic electroluminescent device.

In the organic electroluminescent device of the present disclosure, it is preferable to dispose at least one layer selected from a chalcogenide layer, a metal halide layer, and a metal oxide layer (hereinafter referred to as “surface layer”) on at least one inner surface of a pair of electrodes. Specifically, a chalcogenide (including oxide) layer of silicon and aluminum is preferably placed on an anode surface of an electroluminescent medium layer side, and a metal halide layer or a metal oxide layer is preferably placed on a cathode surface of an electroluminescent medium layer side. Driving stabilization of the organic electroluminescent device can be obtained by the surface layer. Preferred examples of the chalcogenide include SiO_{X}(1≤X≤2), AlO_{X}(1≤X≤1.5), SiON, SiAlON, etc., preferred examples of the metal halide include LiF, MgF₂, CaF₂, a rare earth metal fluoride, etc., and preferred examples of the metal oxide include Cs₂O, Li₂O, MgO, SrO, BaO, CaO, etc.

In addition, in an organic electroluminescent device of the present disclosure, a mixed region of an electron transport compound and a reductive dopant, or a mixed region of a hole transport compound and an oxidative dopant, may be placed on at least one surface of a pair of electrodes. In this case, the electron transport compound is reduced to an anion, and thus it becomes easier to inject and transport electrons from the mixed region to the light-emitting medium. Furthermore, the hole transport compound is oxidized to a cation, and thus it becomes easier to inject and transport holes from the mixed region to the light-emitting medium. Preferred oxidative dopants include various Lewis acids and acceptor compounds, and preferred reductive dopants include alkali metals, alkali metal compounds, alkaline earth metals, rare earth metals, and mixtures thereof. In addition, an organic electroluminescent device having at least two light-emitting layers and emitting white light may be manufactured by using the reductive dopant layer as a charge-generating layer.

An organic electroluminescent device according to the present disclosure may be an organic electroluminescent device having a tandem structure. In the case of the tandem organic electroluminescent device according to one embodiment, a single light-emitting unit (light-emitting part) may be formed in a structure in which two or more units are connected by a charge generation layer. The organic electroluminescent device may include a plurality of two or more light-emitting units, for example, a plurality of three or more light-emitting units, having first and second electrodes opposed to each other on a substrate and a light-emitting layer stacked between the first and second electrodes and emits light in a specific wavelength range. It may include a plurality of light-emitting units, and each of the light-emitting units may include a hole transport zone, a light-emitting layer, and an electron transport zone, and the hole transport zone may include a hole injection layer and a hole transport layer, the electron transport zone may include an electron transport layer and an electron injection layer. According to one embodiment of the present disclosure, three or more light-emitting layers may be included in the light-emitting unit. A plurality of light-emitting units may emit the same color or different colors. Additionally, one light-emitting unit may include one or more light-emitting layers, and the plurality of light-emitting layers may be light-emitting layers of the same or different colors. This may include one or more charge generation layers located between each light-emitting unit. The charge generation layer refers to the layer in which holes and electrons are generated when voltage is applied. When there are three or more light-emitting units, a charge generation layer may be located between each light-emitting unit. Here, the plurality of charge generation layers may be the same as or different from each other. By disposing the charge generating layer between light-emitting units, current efficiency is increased in each light-emitting unit, and charges can be smoothly distributed. Specifically, the charge generation layer is provided between two adjacent stacks and can serve to drive a tandem organic electroluminescent device using only a pair of anodes and cathodes without a separate internal electrode located between the stacks.

The charge generation layer may be composed of an N-type charge generation layer and a P-type charge generation layer, and the N-type charge generation layer may be doped with an alkali metal, an alkaline earth metal, or a compound of an alkali metal and an alkaline earth metal. The alkali metal may include one selected from the group consisting of Li, Na, K, Rb, Cs, Fr, Yb, and combinations thereof, and the alkaline earth metal may include one selected from the group consisting of Be, Mg, Ca, Sr, Ba, Ra, and combinations thereof. The P-type charge generation layer may be made of a metal or an organic material doped with a P-type dopant. For example, the metal may be made of one or two or more alloys selected from the group consisting of Al, Cu, Fe, Pb, Zn, Au, Pt, W, In, Mo, Ni, and Ti. Additionally, commonly used materials may be used as the P-type dopant and host materials used in the P-type doped organic material.

The manufacturing method of the organic electroluminescent device of the present disclosure is not limited, and the manufacturing method of the Device Example as described below is only an example, and the method is not limited thereto. One skilled in the art can reasonably modify the manufacturing method of the Device Examples as described below by relying on existing technology. For example, there is no particular limitation on the mixing ratio of the first compound and the second compound, and thus one skilled in the art can reasonably select this within a certain range by depending on existing technology. For example, based on the total weight of the light-emitting layer material, the total weight of the first compound and the second compound accounts for 99.5-80.0% of the total weight of the light-emitting layer, the weight ratio of the first compound and the second compound is between 1:99 and 99:1, the weight ratio of the first compound and the second compound may be between 20:80 and 99:1, or the weight ratio of the first compound and the second compound may be between 50:50 and 90:10. In the manufacture of devices, when forming a light-emitting layer by co-depositing two or more host materials and a light-emitting material, the two or more host materials and the light-emitting material may each be placed in different evaporation sources and co-deposited to form a light-emitting layer, or a pre-mixed mixture of two or more host materials may be placed on the same evaporation source and then co-deposited with a light-emitting material placed on another evaporation source to form a light-emitting layer. This premixing method can further save evaporation sources. According to one embodiment, the first compound, the second compound, and the light-emitting material of the present disclosure may each be placed in different evaporation sources and co-deposited to form a light-emitting layer, or a pre-mixed mixture of the first compound and the second compound may be placed in the same evaporation source and then co-deposited with a light-emitting material placed in another evaporation source to form a light-emitting layer.

In order to form each layer of the organic electroluminescent device of the present disclosure, dry film-forming methods such as vacuum evaporation, sputtering, plasma, ion plating methods, etc. or wet film-forming methods such as spin coating, dip coating, flow coating methods, etc. can be used. When using a wet film-forming method, a thin film may be formed by dissolving or diffusing materials forming each layer into any suitable solvent such as ethanol, chloroform, tetrahydrofuran, dioxane, etc. The solvent may be any solvent where the materials forming each layer can be dissolved or diffused, and where there are no problems in film-formation capability.

When forming a film of an organic electroluminescent material according to one embodiment, the film can be formed by the above-listed methods, and can be formed commonly by a co-deposition or mixed deposition process. The co-deposition is a method of mixing and depositing two or more materials by placing them in separate crucible sources and applying current to two cells simultaneously to evaporate the materials, and the mixed deposition is a method of mixing two or more materials in one crucible source before deposition and then applying current to one cell to evaporate the materials.

Hereinafter, for detailed understanding of the present disclosure, a method of preparing a compound according to the present disclosure will be described using the synthesis of a representative compound or intermediate compound of the present disclosure as an example.

### Example 1: Preparation of Compound HT′-47

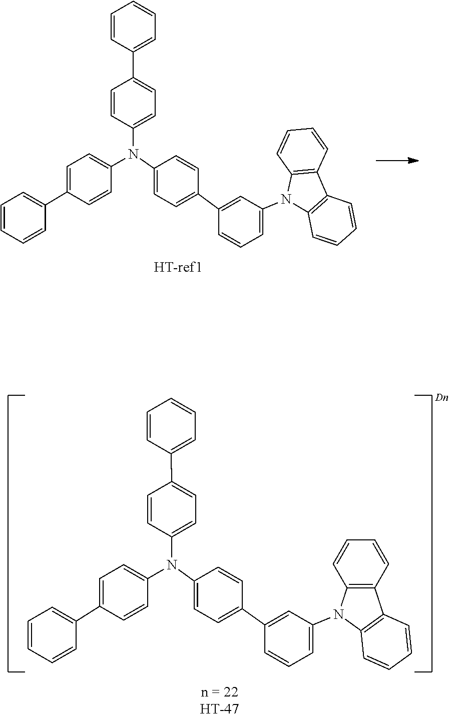

Compound HT-ref1 was synthesized using the deuteration methods disclosed in Korean Patent Publication Nos. 10-2283849, 10-1427457, etc. to obtain compound HT′-47 (17 g, yield: 65%).

| | MW | M.P. |
|---|---|---|
| HT-47 | 660 | 200° C. |

### Example 2: Preparation of Compound H1-55

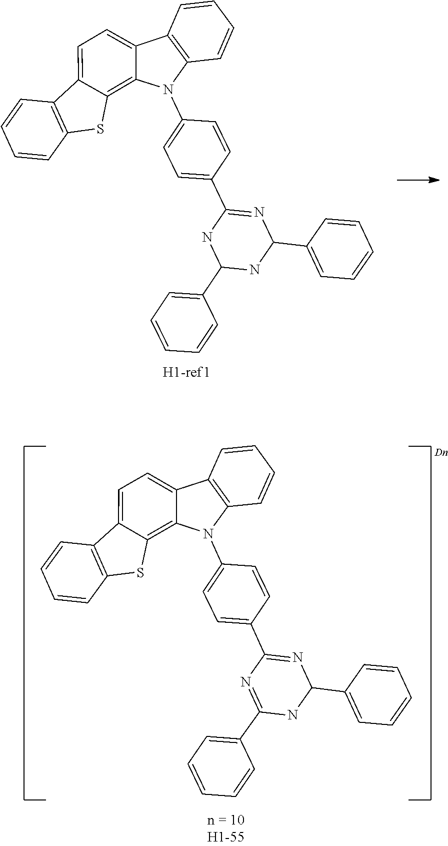

Compound H1-ref1 was synthesized using the deuteration methods disclosed in Korean Patent Publication Nos. 10-2283849, 10-1427457, etc. to obtain compound H1-55 (53 g, yield: 84%/).

| | MW | M.P. |
|---|---|---|
| H1-55 | 590 | 335° C. |

### Example 3: Preparation of Compound H2-35

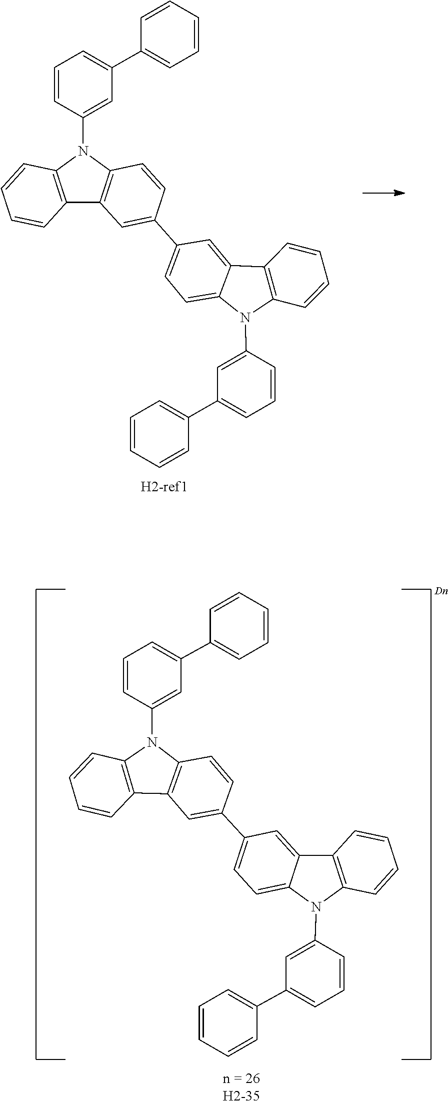

Compound H2-ref1 was synthesized using the deuteration methods disclosed in Korean Patent Publication Nos. 10-2283849, 10-1427457, etc. to obtain compound H2-35 (66, yield: 91%).

| | MW | M.P. |
|---|---|---|
| H2-35 | 662 | 200° C. |

### Example 4: Preparation of Compound ET-60

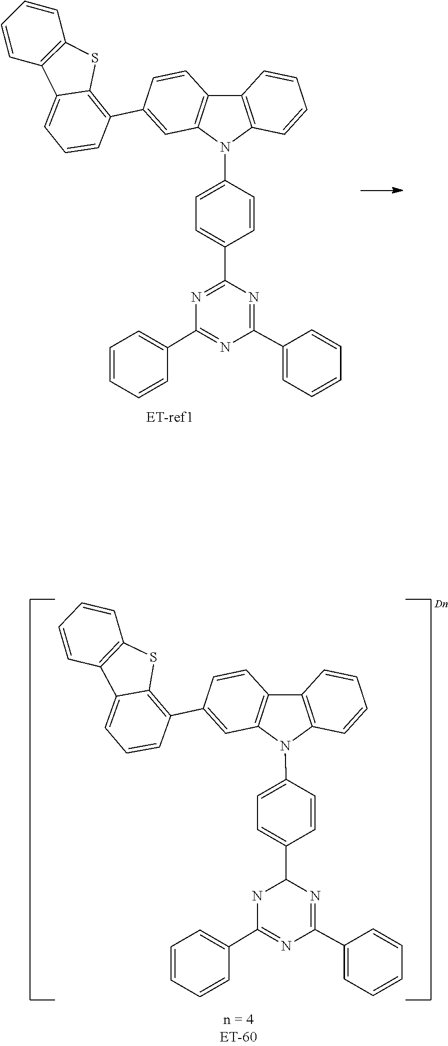

Compound ET-ref1 was synthesized using the deuteration methods disclosed in Korean Patent Publication Nos. 10-2283849, 10-1427457, etc. to obtain compound ET-60 (12 g, yield: 87%/).

| | MW | M.P. |
|---|---|---|
| ET-60 | 660 | 281° C. |

### Example 5: Preparation of Compound HT′-39

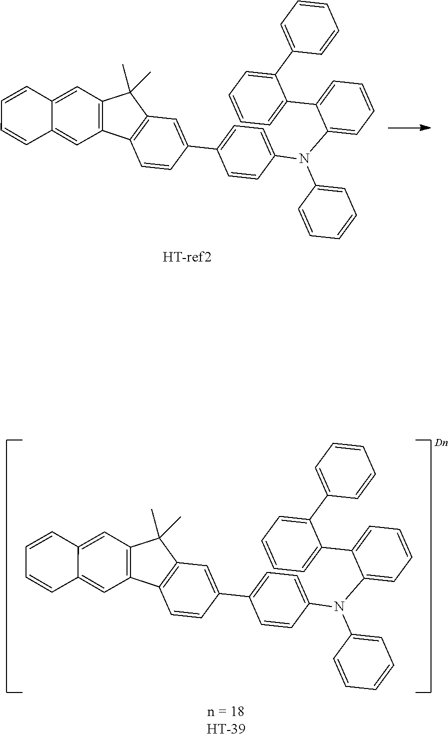

Compound HT-ref2 was synthesized using the deuteration methods disclosed in Korean Patent Publication Nos. 10-2283849, 10-1427457, etc. to obtain compound HT′-39 (7.6 g, yield: 63%).

| | MW | M.P. |
|---|---|---|
| HT-39 | 657 | 221° C. |

### Example 6: Preparation of Compound H2-61

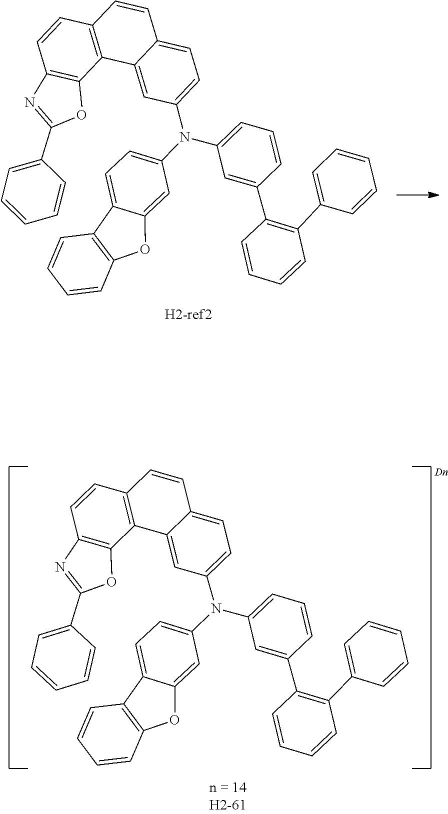

Compound H2-ref2 was synthesized using the deuteration methods disclosed in Korean Patent Publication Nos. 10-2283849, 10-1427457, etc. to obtain compound H2-61 (8.1 g, yield: 75%).

| | MW | M.P. |
|---|---|---|
| H2-61 | 718 | 244° C. |

### Example 7: Preparation of Compound H1-15

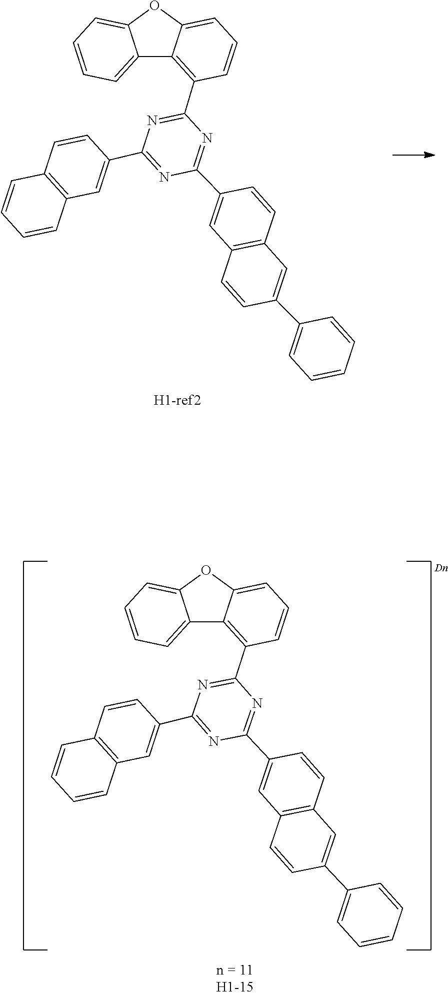

Compound H1-ref2 was synthesized using the deuteration methods disclosed in Korean Patent Publication Nos. 10-2283849, 10-1427457, etc. to obtain compound H1-15 (32 g, yield: 84%).

| | MW | M.P. |
|---|---|---|
| H1-15 | 586 | 242° C. |

### Example 8: Preparation of Compound ET-1

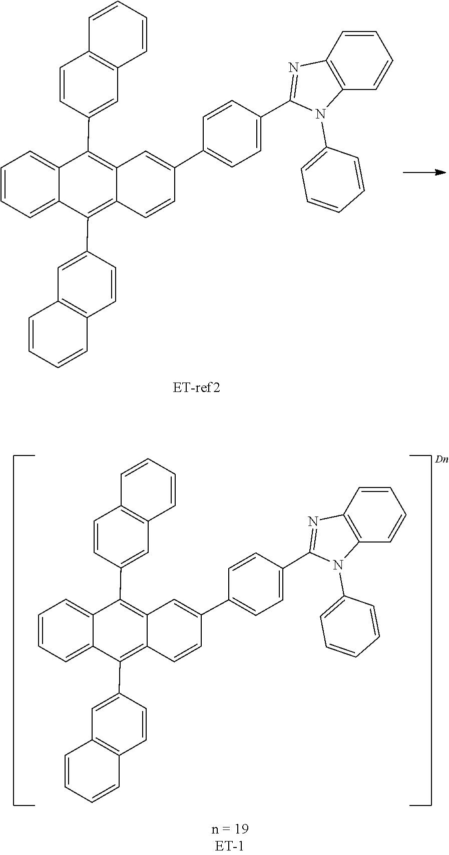

Compound ET-ref2 was synthesized using the deuteration methods disclosed in Korean Patent Publication Nos. 10-2283849, 10-1427457, etc. to obtain compound ET-1 (5 g, yield: 88%).

| | MW | M.P. |
|---|---|---|
| ET-1 | 717 | 360° C. |

### Example 9: Preparation of Compound H3-7

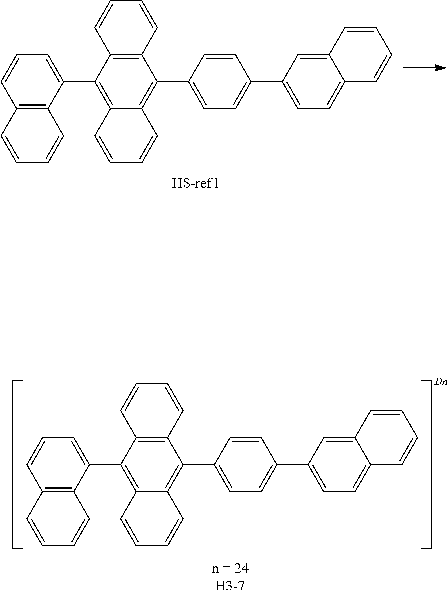

Compound H3-ref1 was synthesized using the deuteration methods disclosed in Korean Patent Publication Nos. 10-2283849, 10-1427457, etc. to obtain compound H3-7 (12 g, yield: 77%).

| | MW | M.P. |
|---|---|---|
| H3-7 | 530 | 275° C. |

### Example 10: Preparation of Compound H3-20

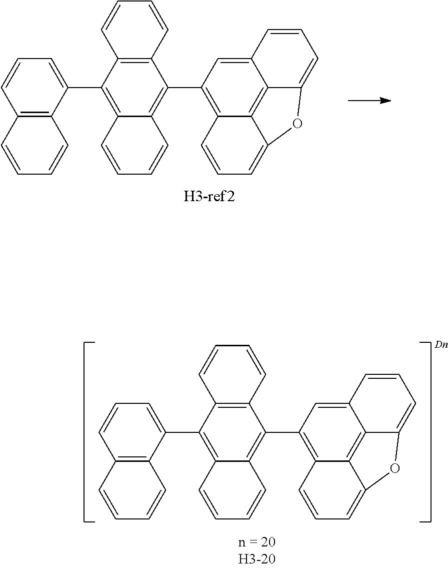

Compound H3-ref2 was synthesized using the deuteration methods disclosed in Korean Patent Publication Nos. 10-2283849, 10-1427457, etc. to obtain compound H3-20 (14 g, yield: 79%).

| | MW | M.P. |
|---|---|---|
| H3-20 | 514 | 330° C. |

### Example 11: Preparation of Compound C-52

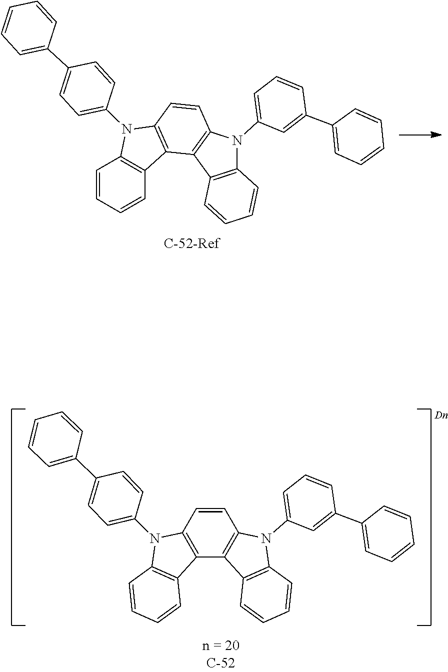

Compound C-52-ref was synthesized using the deuteration methods disclosed in Korean Patent Publication Nos. 10-2283849, 10-1427457, etc. to obtain compound C-52 (24.4 g, yield: 94%).

| | MW | M.P. |
|---|---|---|
| C-52 | 580 | 151° C. |

### Device Example 1: Producing an OLED Depositing a Compound According to the Present Disclosure

An OLED according to the present disclosure was produced. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and was then stored in isopropyl alcohol. The ITO substrate was mounted on a substrate holder of a vacuum vapor deposition apparatus. Compound HI (p-dopant) was introduced into a cell of the vacuum vapor deposition apparatus, and compound HT′-1 was introduced into another cell. The two materials were evaporated at different rates, and compound HI was deposited in a doping amount of 3 wt % based to the total amount of compound HI and compound HT′-1 to form a hole injection layer with a thickness of 10 nm. Subsequently, compound HT′-1 was deposited on the hole injection layer to form a first hole transport layer with a thickness of 80 nm. Next, the compound shown in Table 1 was introduced into another cell of the vacuum vapor deposition apparatus and was evaporated by applying an electric current to the cell, thereby depositing a second hole transport layer with a thickness of 30 nm. After forming the hole injection layer and the hole transport layers, a light-emitting layer was deposited thereon as follows: the compounds shown in Table 1 below were introduced into a cell of the vacuum vapor deposition apparatus as hosts at a ratio of 1:2, and compound GD was introduced into another cell as a dopant. The materials were evaporated at a different rate, and the dopant was deposited in a doping amount of 10 wt % based on the total amount of the hosts and dopant to form a light-emitting layer with a thickness of 40 nm on the second hole transport layer. The compounds shown in Table 1 were deposited with a thickness of 5 nm as an electron buffer layer, and then compound EI-1 and compound Liq were introduced into two other cells and evaporated at a rate of 1:1 to deposit an electron transport layer with a thickness of 30 nm on the electron buffer layer. After introducing compound Liq as an electron injection layer and depositing with a thickness of 2 nm on the electron transport layer, an A1 cathode was deposited with a thickness of 80 nm by using another vacuum vapor deposition apparatus, thereby producing an OLED. All of the materials used for producing the OLED were purified by vacuum sublimation at 10⁻⁶ Torr.

### Comparative Example 1: Producing an OLED Comprising Conventional Compounds

An OLED was produced in the same manner as in Device Example 1, except that the hole transport layer, the host material of the light-emitting layer, and the electron buffer layer were made of light hydrogen material.

Table 1 below shows the current efficiency at a luminance of 1,000 nit and time taken for luminance to reduce from 100% to 95% at a luminance of 40,000 nit (lifetime: T₉₅) for the OLEDs of Device Example 1 and Comparative Example 1 produced as described above.

TABLE 1

| | Second | | | | |
|---|---|---|---|---|---|
| | Hole | | Electron | Current | Life- |
| | Transport | | Buffer | Efficiency | time |
| | Layer | Host | Layer | [Cd/A] | T₉₅ [hr] |
| Device | HT-47 | H1-55:H2-35 | ET-60 | 104 | 89 |
| Example 1 | | | | | |
| Comparative | HT-ref1 | H1-ref1:H2-ref1 | ET-ref1 | 105 | 60 |
| Example 1 | | | | | |

Device Example 1 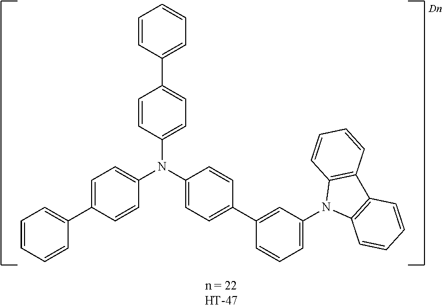 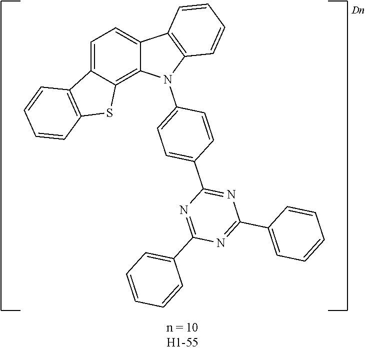 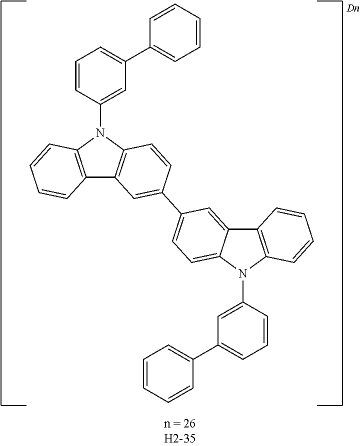 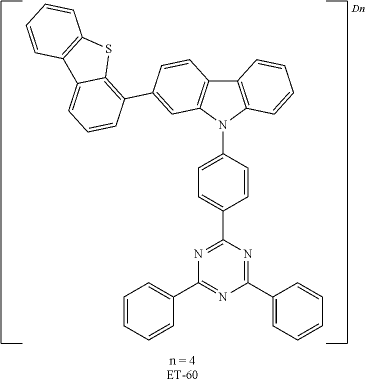
Comparative Example 1

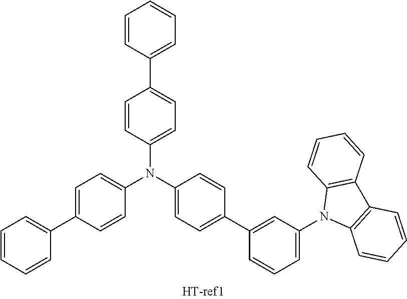 [SMILES: c1ccc(-c2ccc(N(c3ccc(-c4ccccc4)cc3)c3ccc(-c4cccc(-n5c6ccccc6c6ccccc65)c4)cc3)cc2)cc1]

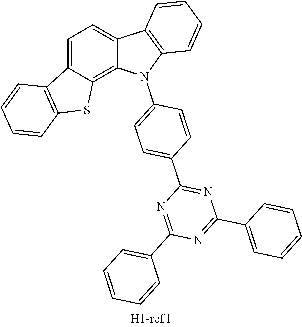 [SMILES: c1ccc(-c2nc(-c3ccccc3)nc(-c3ccc(-n4c5ccccc5c5ccc6c7ccccc7sc6c54)cc3)n2)cc1]

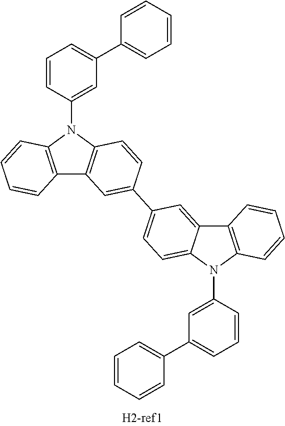 [SMILES: c1ccc(-c2cccc(-n3c4ccccc4c4cc(-c5ccc6c(c5)c5ccccc5n6-c5cccc(-c6ccccc6)c5)ccc43)c2)cc1]

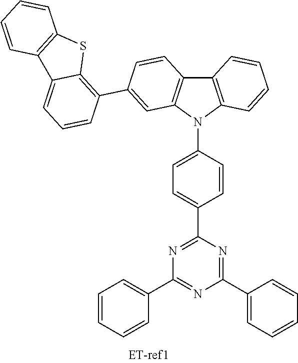 [SMILES: c1ccc(-c2nc(-c3ccccc3)nc(-c3ccc(-n4c5ccccc5c5ccc(-c6cccc7c6sc6ccccc67)cc54)cc3)n2)cc1]

From Table above, it can be confirmed that the organic electroluminescent device according to the present disclosure exhibits a longer lifetime property while maintaining current efficiency property compared to a conventional organic electroluminescent device.

### Device Example 2: Producing an OLED Depositing a Compound According to the Present Disclosure as a Host

An OLED according to the present disclosure was produced. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and was then stored in isopropyl alcohol. The ITO substrate was mounted on a substrate holder of a vacuum vapor deposition apparatus. Compound HI (p-dopant) was introduced into a cell of the vacuum vapor deposition apparatus, and compound HT′-1 was introduced into another cell. The two materials were evaporated at different rates, and compound HI was deposited in a doping amount of 3 wt % based to the total amount of compound HI and compound HT′-1 to form a hole injection layer with a thickness of 10 nm. Subsequently, compound HT′-1 was deposited on the hole injection layer to form a first hole transport layer with a thickness of 90 nm. Next, the compound shown in Table 2 was introduced into another cell of the vacuum vapor deposition apparatus as a second hole transport layer and was evaporated by applying an electric current to the cell, thereby depositing with a thickness of 60 nm on the first hole transport layer. After forming the hole injection layer and the hole transport layers, a light-emitting layer was deposited thereon as follows: the compounds shown in Table 2 below were introduced into a cell of the vacuum vapor deposition apparatus as hosts at a ratio of 1:1, and compound RD was introduced into another cell as a dopant. The materials were evaporated at a different rate, and the dopant was deposited in a doping amount of 3 wt % based on the total amount of the hosts and dopant to form a light-emitting layer with a thickness of 40 nm on the second hole transport layer. The compound shown in Table 2 was deposited with a thickness of 5 nm as an electron buffer layer, and then compound EI-1 and compound Liq were introduced into two other cells and evaporated at a rate of 1:1 to deposit an electron transport layer with a thickness of 30 nm on the light-emitting layer. After introducing compound Liq as an electron injection layer with a thickness of 2 nm on the electron transport layer, an A1 cathode was deposited with a thickness of 80 nm by using another vacuum vapor deposition apparatus, thereby producing an OLED. All of the materials used for producing the OLED were purified by vacuum sublimation at 10⁻⁶ Torr.

### Comparative Example 2: Producing an OLED Comprising Conventional Compounds

An OLED was produced in the same manner as in Device Example 2, except that the hole transport layer, the host material of the light-emitting layer, and the electron buffer layer were made of light hydrogen material.

Table 2 below shows the current efficiency at a luminance of 1,000 nit and time taken for luminance to reduce from 100% to 97% at a luminance of 10,000 nit (lifetime: T₉₇) for the OLEDs of Device Example 2 and Comparative Example 2 produced as described above.

TABLE 2

| | Second | | | | |
|---|---|---|---|---|---|
| | Hole | | Electron | Current | Life- |
| | Transport | | Buffer | Efficiency | time |
| | Layer | Host | Layer | [Cd/A] | T₉₇ [hr] |
| Device | HT-39 | H2-61:H1-15 | ET-60 | 32.4 | 215 |
| Example 2 | | | | | |
| Comparative | HT-ref2 | H2-ref2:H1-ref2 | ET-ref1 | 31.3 | 64 |
| Example 2 | | | | | |

Device Example 2 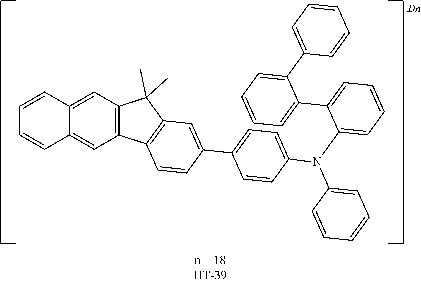 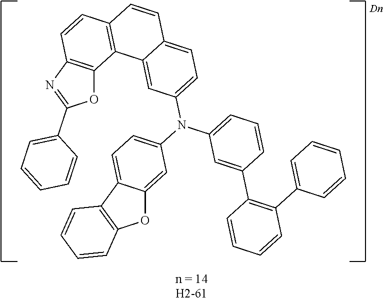 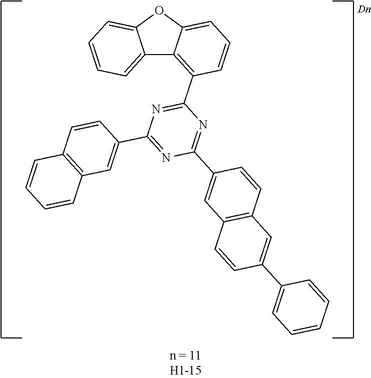 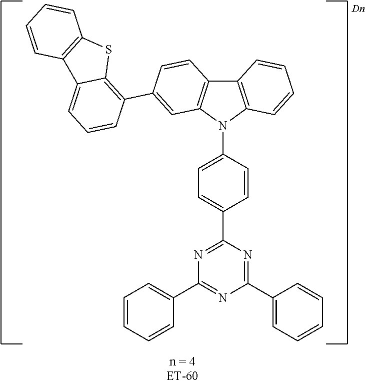
Comparative Example 2

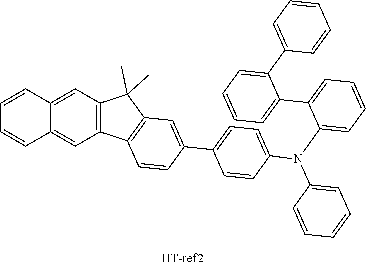 [SMILES: CC1(C)c2cc(-c3ccc(N(c4ccccc4)c4ccccc4-c4ccccc4-c4ccccc4)cc3)ccc2-c2cc3ccccc3cc21]

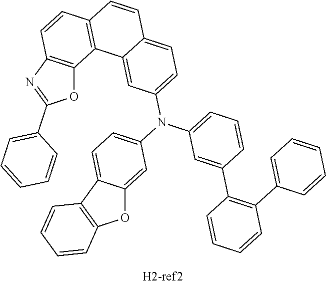 [SMILES: c1ccc(-c2nc3ccc4ccc5ccc(N(c6cccc(-c7ccccc7-c7ccccc7)c6)c6ccc7c(c6)oc6ccccc67)cc5c4c3o2)cc1]

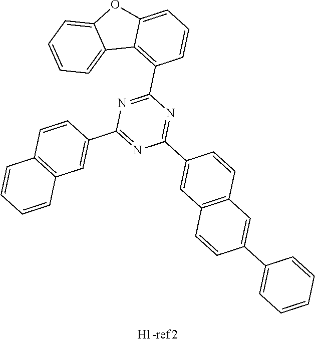 [SMILES: c1ccc(-c2ccc3cc(-c4nc(-c5ccc6ccccc6c5)nc(-c5cccc6oc7ccccc7c56)n4)ccc3c2)cc1]

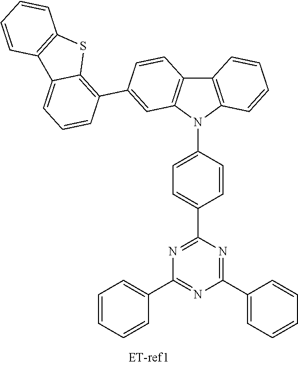 [SMILES: c1ccc(-c2nc(-c3ccccc3)nc(-c3ccc(-n4c5ccccc5c5ccc(-c6cccc7c6sc6ccccc67)cc54)cc3)n2)cc1]

From Table 2 above, it can be confirmed that the organic electroluminescent device according to the present disclosure exhibits higher current efficiency and much higher lifetime compared to a conventional organic electroluminescent device.

### Device Example 3: Producing an OLED Depositing a Compound According to the Present Disclosure

An OLED was produced in the same manner as in Device Example 2, except that the compound shown in Table 3 and compound Liq were introduced into two other cells and evaporated at a rate of 1:1 to deposit an electron transport layer with a thickness of 35 nm on the light-emitting layer without an electron buffer layer.

### Comparative Example 3: Producing an OLED Comprising Conventional Compounds

An OLED was produced in the same manner as in Device Example 3, except that the hole transport layer, the host material of the light-emitting layer, and the electron transport layer were made of light hydrogen material.

Table 3 below shows the current efficiency at a luminance of 1,000 nit and time taken for luminance to reduce from 100% to 97% at a luminance of 10,000 nit (lifetime: T₉₇) for the OLEDs of Device Example 3 and Comparative Example 3 produced as described above.

TABLE 3

| | Second | | | Current | |
|---|---|---|---|---|---|
| | Hole | | Electron | Effi- | Life- |
| | Transport | | Transport | ciency | time |
| | Layer | Host | Layer | [Cd/A] | T₉₇ [hr] |
| Device | HT-39 | H2-61:H1-15 | ET-1 | 32.1 | 177 |
| Example 3 | | | | | |
| Comparative | HT-ref2 | H2-ref2:H1-ref2 | ET-ref2 | 32.4 | 78 |
| Example 3 | | | | | |

Device Example 3 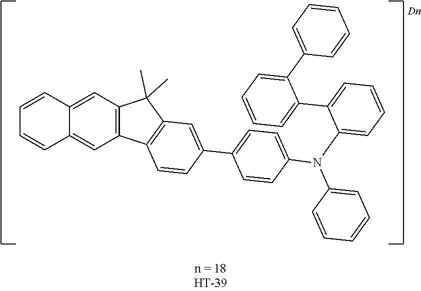 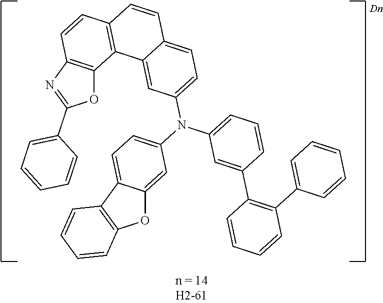 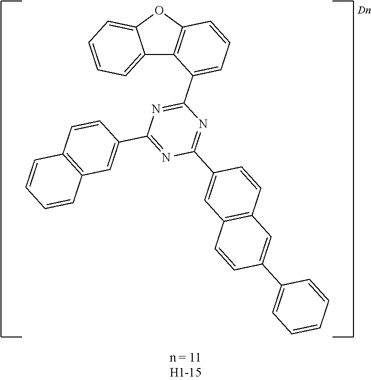 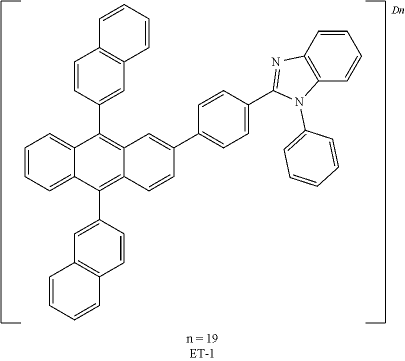
Comparative Example 3

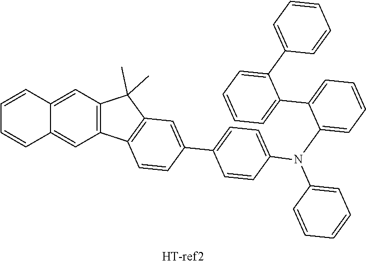 [SMILES: CC1(C)c2cc(-c3ccc(N(c4ccccc4)c4ccccc4-c4ccccc4-c4ccccc4)cc3)ccc2-c2cc3ccccc3cc21]

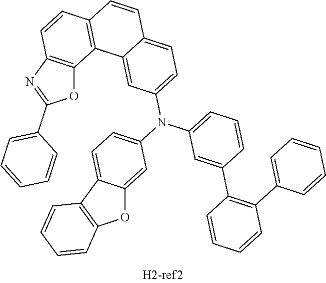 [SMILES: c1ccc(-c2nc3ccc4ccc5ccc(N(c6cccc(-c7ccccc7-c7ccccc7)c6)c6ccc7c(c6)oc6ccccc67)cc5c4c3o2)cc1]

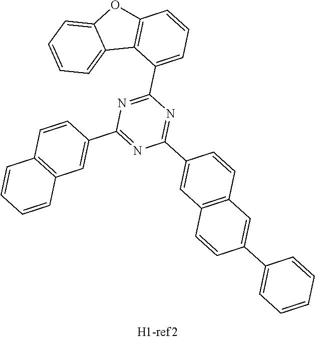 [SMILES: c1ccc(-c2ccc3cc(-c4nc(-c5ccc6ccccc6c5)nc(-c5cccc6oc7ccccc7c56)n4)ccc3c2)cc1]

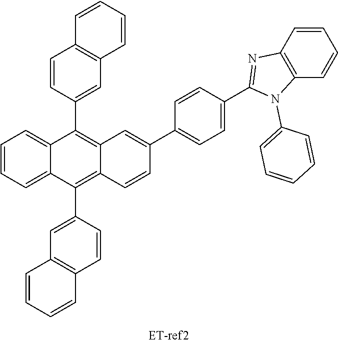 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

From Table 3 above, it can be confirmed that the organic electroluminescent device according to the present disclosure exhibits higher lifetime while maintaining current efficiency compared to a conventional organic electroluminescent device.

### Device Examples 4 and 5: Producing OLEDs Depositing a Compound According to the Present Disclosure

OLEDs according to the present disclosure were produced. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and was then stored in isopropyl alcohol. The ITO substrate was mounted on a substrate holder of a vacuum vapor deposition apparatus. Compound HI (p-dopant) was introduced into a cell of the vacuum vapor deposition apparatus, and compound HT′-1 was introduced into another cell. The two materials were evaporated at different rates, and compound HI was deposited in a doping amount of 3 wt % based to the total amount of compound HI and compound HT′-1 to form a hole injection layer with a thickness of 10 nm. Subsequently, compound HT′-1 was deposited on the hole injection layer to form a first hole transport layer with a thickness of 80 nm. Next, the compound shown in Table 4 was introduced into another cell of the vacuum vapor deposition apparatus as a second hole transport layer and was evaporated by applying an electric current to the cell, thereby depositing with a thickness of 5 nm on the first hole transport layer. After forming the hole injection layer and the hole transport layers, a light-emitting layer was deposited thereon as follows: After introducing the compound shown in Table 4 as a host in a cell in a vacuum vapor deposition apparatus, the two materials were evaporated at different rates, and the dopant was deposited in a doping amount of 2 wt % based on the total amount of the hosts and dopant to form a light-emitting layer with a thickness of 20 nm on the second hole transport layer. Then the compound shown in Table 4 and compound Liq were introduced to two other cells and evaporated at a rate of 1:1 to deposit an electron transport layer with a thickness of 35 nm on the light-emitting layer. After introducing compound Liq as an electron injection layer and depositing with a thickness of 2 nm on the electron transport layer, an A1 cathode was deposited with a thickness of 80 nm by using another vacuum vapor deposition apparatus, thereby producing an OLED. All the materials used for producing the OLED were purified by vacuum sublimation at 10⁻⁶ Torr.

### Comparative Examples 4 and 5: Producing OLEDs Comprising Conventional Compounds

OLEDs were produced in the same manner as in Device Example 4, except that the hole transport layer, the host material of the light-emitting layer, and the electron buffer layer were made of light hydrogen material.

Table 4 below shows the current efficiency at a luminance of 1,000 nit CIE color coordinates and time taken for luminance to reduce from 100% to 97% at a luminance of 10,000 nit according to CIE color coordinates (lifetime: T₉₇) for the OLEDs of Device Examples 4 and 5 and Comparative Examples 4 and 5 produced as described above.

TABLE 4

| | Second Hole | | | Current | | |
|---|---|---|---|---|---|---|
| | Transport | | Electron Transport | Efficiency | CIE | Lifetime |
| | Layer | Host | layer | [Cd/A] | (X, Y) | T₉₇ [hr] |
| Device | HT-47 | H3-7 | ET-1 | 6.8 | 0.130, 0.093 | 164 |
| Example 4 | | | | | | |
| Comparative | HT-ref1 | H3-ref1 | ET-ref2 | 6.5 | 0.131, 0.091 | 79 |
| Example 4 | | | | | | |
| Device | HT-47 | H3-20 | ET-1 | 7.1 | 0.130, 0.088 | 117 |
| Example 5 | | | | | | |
| Comparative | HT-ref1 | H3-ref2 | ET-ref2 | 6.9 | 0.130, 0.089 | 89 |
| Example 5 | | | | | | |

Device Example 4 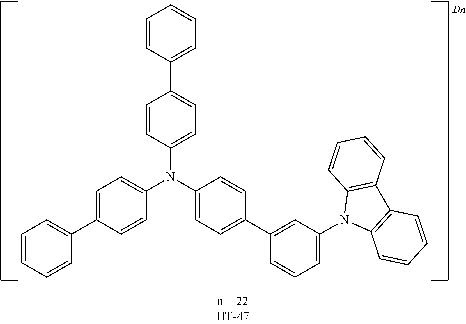 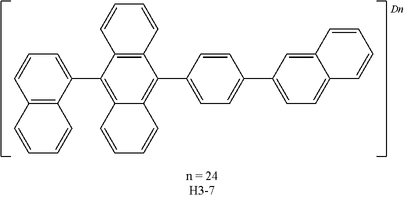 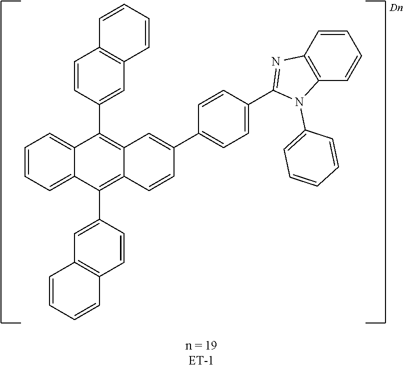
Comparative Example 4 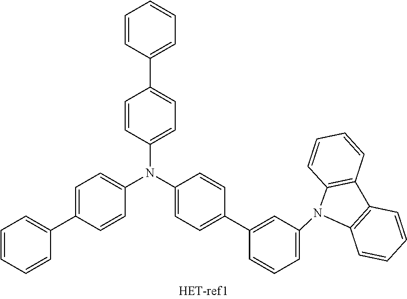 [SMILES: c1ccc(-c2ccc(N(c3ccc(-c4ccccc4)cc3)c3ccc(-c4cccc(-n5c6ccccc6c6ccccc65)c4)cc3)cc2)cc1] 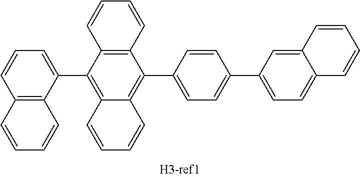 [SMILES: c1ccc2cc(-c3ccc(-c4c5ccccc5c(-c5cccc6ccccc56)c5ccccc45)cc3)ccc2c1] 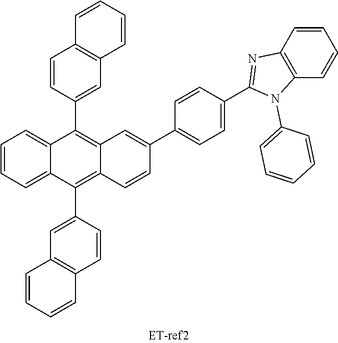 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]
Device Example 5 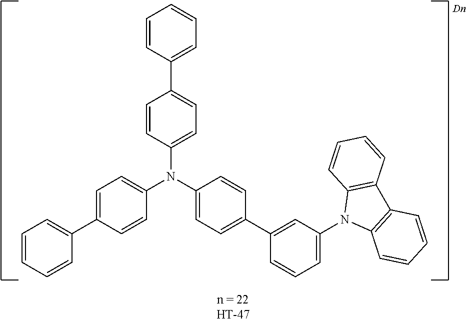 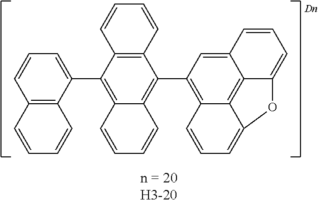 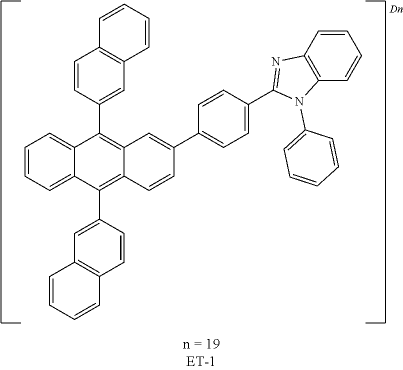
Comparative Example 5

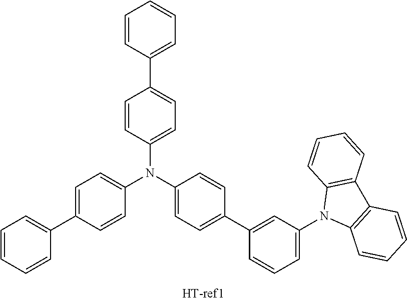 [SMILES: c1ccc(-c2ccc(N(c3ccc(-c4ccccc4)cc3)c3ccc(-c4cccc(-n5c6ccccc6c6ccccc65)c4)cc3)cc2)cc1]

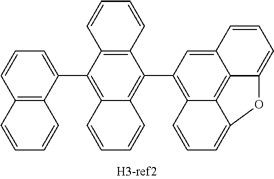 [SMILES: c1ccc2c(-c3c4ccccc4c(-c4cc5cccc6oc7cccc4c7c56)c4ccccc34)cccc2c1]

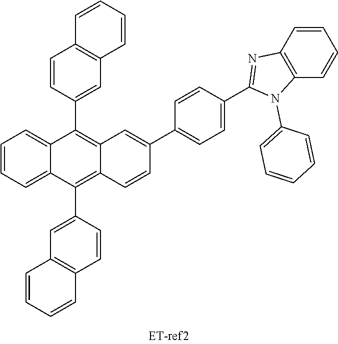 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

From Table 4 above, it can be confirmed that the organic electroluminescent device according to the present disclosure exhibits higher current efficiency and much higher lifetime compared to a conventional organic electroluminescent device.

### Device Example 6: Producing an OLED Depositing a Compound According to the Present Disclosure

An OLED according to the present disclosure was produced. First, a transparent electrode indium tin oxide (ITO) thin film (10 Ω/sq) on a glass substrate for an OLED (GEOMATEC CO., LTD., Japan) was subjected to an ultrasonic washing with acetone and isopropyl alcohol, sequentially, and was then stored in isopropyl alcohol. The ITO substrate was mounted on a substrate holder of a vacuum vapor deposition apparatus. Compound HI (p-dopant) was introduced into a cell of the vacuum vapor deposition apparatus, and compound HT′-1 was introduced into another cell. The two materials were evaporated at different rates, and compound HI was deposited in a doping amount of 3 wt % based to the total amount of compound HI and compound HT′-1 to form a hole injection layer with a thickness of 10 nm. Subsequently, compound HT′-1 was deposited on the hole injection layer to form a first hole transport layer with a thickness of 80 nm. Next, the compound shown in Table 5 was introduced into another cell of the vacuum vapor deposition apparatus as a second hole transport layer and was evaporated by applying an electric current to the cell, thereby depositing with a thickness of 30 nm. After forming the hole injection layer and the hole transport layers, a light-emitting layer was deposited thereon as follows: the compounds shown in Table 5 below were introduced into a cell of the vacuum vapor deposition apparatus as hosts at a ratio of 2:1, and compound GD was introduced into another cell as a dopant. The materials were evaporated at a different rate, and the dopant was deposited in a doping amount of 10 wt % based on the total amount of the hosts and dopant to form a light-emitting layer with a thickness of 40 nm on the second hole transport layer. The compound shown in Table 5 was deposited with a thickness of 5 nm as an electron buffer layer, and then compound EI-1 and compound Liq were introduced into two other cells and evaporated at a rate of 1:1 to deposit an electron transport layer with a thickness of 35 nm on the light-emitting layer. After introducing compound Liq as an electron injection layer and depositing with a thickness of 2 nm on the electron transport layer, an Al cathode was deposited with a thickness of 80 nm by using another vacuum vapor deposition apparatus, thereby producing an OLED. All the materials used for producing the OLED were purified by vacuum sublimation at 10 Torr.

### Comparative Example 6: Producing an OLED Comprising Conventional Compound

An OLED was produced in the same manner as in Device Example 6, except that the hole transport layer, the host material of the light-emitting layer, and the electron buffer layer were made of light hydrogen material.

Table 5 below shows the current efficiency at a luminance of 1,000 nit and time taken for luminance to reduce from 100% to 95% at a luminance of 1,000 nit (lifetime: T₉₅) for the OLEDs of Device Example 6 and Comparative Example 6 produced as described above.

TABLE 5

| | Second | | | Current | |
|---|---|---|---|---|---|
| | Hole | | Electron | Effic- | Life- |
| | Transport | Host | Buffer | iency | time |
| | Layer | (2:1) | Layer | [Cd/A] | T₉₅ [hr] |
| Device | HT-47 | C-52:H2-35 | ET-1 | 102.9 | 94.6 |
| Example 6 | | | | | |
| Comparative | HT-ref1 | C-52-ref:H2-ref1 | ET-ref2 | 102.3 | 60.2 |
| Example 6 | | | | | |

Device Example 6 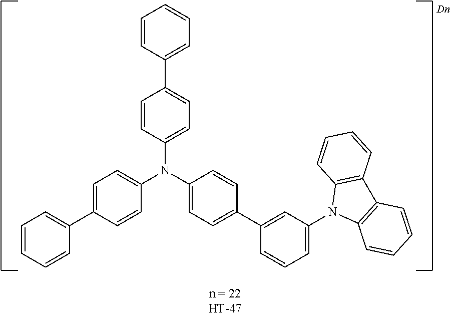 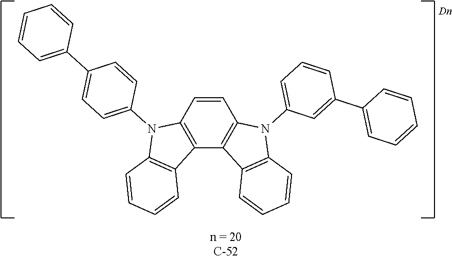 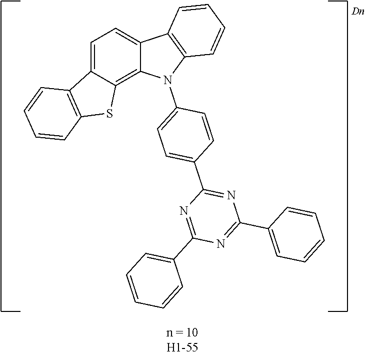 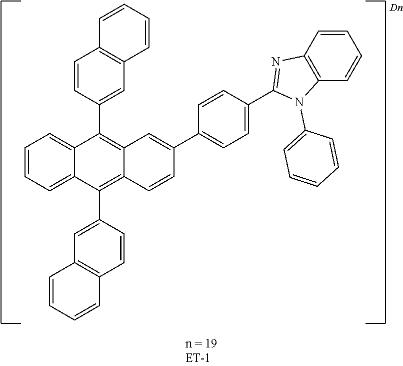
Comparative Example 6

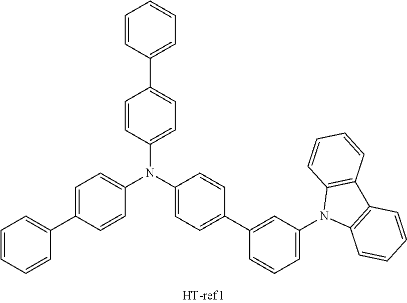 [SMILES: c1ccc(-c2ccc(N(c3ccc(-c4ccccc4)cc3)c3ccc(-c4cccc(-n5c6ccccc6c6ccccc65)c4)cc3)cc2)cc1]

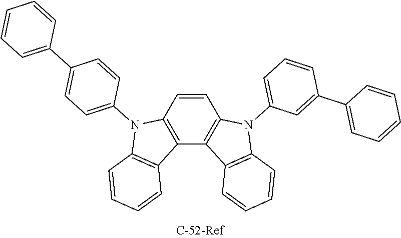 [SMILES: c1ccc(-c2ccc(-n3c4ccccc4c4c5c6ccccc6n(-c6cccc(-c7ccccc7)c6)c5ccc43)cc2)cc1]

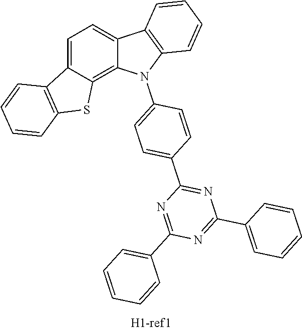 [SMILES: c1ccc(-c2nc(-c3ccccc3)nc(-c3ccc(-n4c5ccccc5c5ccc6c7ccccc7sc6c54)cc3)n2)cc1]

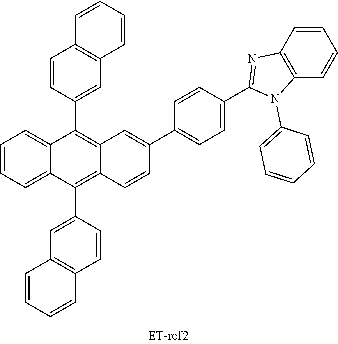 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

From Table 5 above, it can be confirmed that the organic electroluminescent device according to the present disclosure exhibits higher lifetime while maintaining current efficiency compared to a conventional organic electroluminescent device.

The compounds used in the above Device Examples and Comparative Examples are shown in Table 6 below.

TABLE 6
Compounds used in Device Examples and Comparative Examples

| | |
|---|---|
| Hole Injection Layer/ Hole Transport Layer | 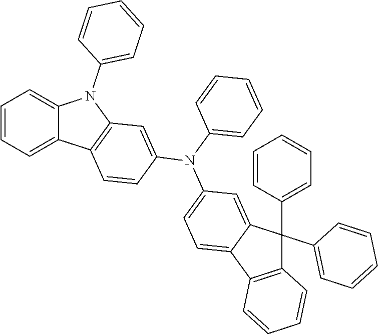 [SMILES: c1ccc(N(c2ccc3c(c2)C(c2ccccc2)(c2ccccc2)c2ccccc2-3)c2ccc3c4ccccc4n(-c4ccccc4)c3c2)cc1] |
| | HT′-1 |
| | 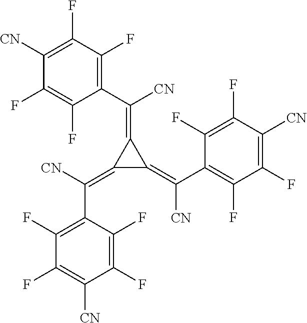 |
| | HI (p-dopant) |
| Light- Emitting Layer | 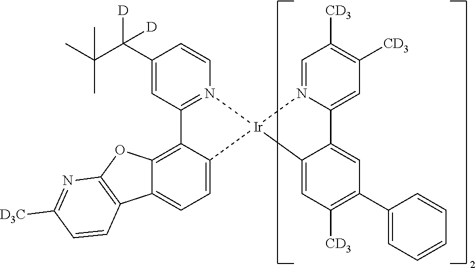 |
| | GD |
| | 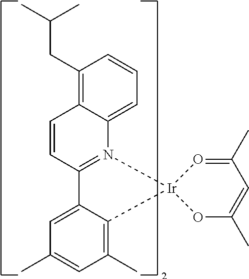 |
| | RD |
| | 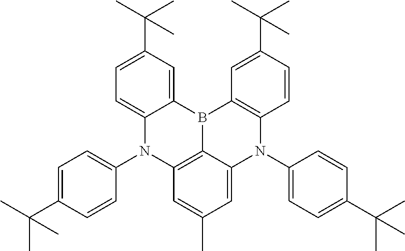 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1] |
| | BD |
| Electron Buffer Layer/ Electron Injection Layer/ Electron Transport Layer | 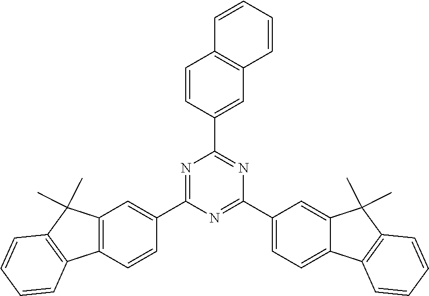 [SMILES: CC1(C)c2ccccc2-c2ccc(-c3nc(-c4ccc5c(c4)C(C)(C)c4ccccc4-5)nc(-c4ccc5ccccc5c4)n3)cc21] |
| | EI-1 |
| | 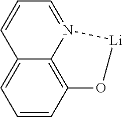 |
| | Liq |

1. An organic electroluminescent device comprising an anode, a hole transport zone, a light-emitting layer, an electron transport zone, and a cathode, wherein the hole transport zone, the light-emitting layer, and the electron transport zone each comprise a deuterated compound(s), and structures of each of the compounds are the same as or different from each other.

2. The organic electroluminescent device according to claim 1, wherein the hole transport zone is configured by sequentially stacking a hole injection layer, a hole transport layer composed of one or more layers, and a hole auxiliary layer or an electron-blocking layer composed of one or more layers on the anode, and wherein at least one of the layers comprises a deuterated compound(s).

3. The organic electroluminescent device according to claim 1, wherein the electron transport zone is configured by sequentially stacking an electron buffer layer or a hole-blocking layer composed of one or more layers, an electron transport layer composed of one or more layers, and an electron injection layer on the light-emitting layer, and at least one of the layers comprises a deuterated compound(s).

4. The organic electroluminescent device according to claim 1, wherein the light-emitting layer is composed of one or more layers, and at least one layer in the light-emitting layers comprises one or more deuterated compounds as a host.

5. The organic electroluminescent device according to claim 1, wherein the light-emitting layer comprises a phosphorescent or fluorescent luminescent compound, and the compound comprises iridium (Ir), platinum (Pt), or boron (B) atoms.

6. The organic electroluminescent device according to claim 2, wherein at least one layer of the hole transport zone comprises a compound represented by the following formula 1: 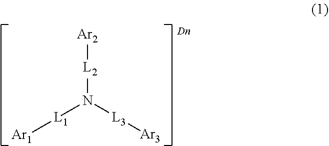
wherein in formula 1,
Ar₁ to Ar₃ each independently represent hydrogen, deuterium, a halogen, a cyano, a substituted or unsubstituted (C1-C30)alkyl, a substituted or unsubstituted (C3-C30)cycloalkyl, a substituted or unsubstituted silyl, a substituted or unsubstituted (C6-C30)aryl, a substituted or unsubstituted (3- to 30-membered)heteroaryl, a substituted or unsubstituted mono- or di-(C6-C30)arylamino, a mono- or di-(C1-C30)alkylamino, a mono- or di-(C2-C30)alkenylamino, a (C1-C30)alkyl(C6-C30)arylamino, a mono- or di-(3- to 30-membered)heteroarylamino, or a (C6-C30)aryl(3- to 30-membered)heteroarylamino, with a proviso that each of Ar₁ to each of Ar₃ comprise at least one of a substituted or unsubstituted (C6-C30)aryl(s) or a substituted or unsubstituted (3- to 30-membered)heteroaryl(s);
L₁ to L₃ each independently represent a single bond, a substituted or unsubstituted (C6-C30)arylene, or a substituted or unsubstituted (3- to 30-membered)heteroarylene; and
Dₙ represents that n number of hydrogens are replaced with deuterium, and n represents an integer of 1 or more, and has an upper limit of the number of hydrogen atoms in the non-deuterated compound.

7. The organic electroluminescent device according to claim 6, wherein at least one of Ar₁ to Ar₃ comprises a substituted or unsubstituted phenanthrenyl, a substituted or unsubstituted carbazolyl, a substituted or unsubstituted fluorenyl, a substituted or unsubstituted benzofluorenyl, a substituted or unsubstituted triphenylenyl, a substituted or unsubstituted dibenzofuranyl, or a substituted or unsubstituted dibenzothiophenyl.

8. The organic electroluminescent device according to claim 3, wherein at least one layer of the electron transport zone comprises a compound represented by the following formula 2 or formula 3: 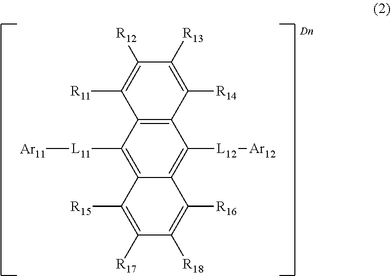
wherein in formula 2,
L₁₁ and L₁₂ each independently represent a single bond, a substituted or unsubstituted (C6-C30)arylene, or a substituted or unsubstituted (3- to 30-membered)heteroarylene;
Ar₁₁ and Ar₁₂ each independently represent a substituted or unsubstituted (C6-C30)aryl or a substituted or unsubstituted (3- to 30-membered)heteroaryl;
R₁₁ to R₁₈ each independently represent hydrogen, deuterium, a halogen, a cyano, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted mono- or di-(C1-C30)alkylamino, a substituted or unsubstituted mono- or di-(C2-C30)alkenylamino, a substituted or unsubstituted mono- or di-(C6-C30)arylamino, a substituted or unsubstituted mono- or di-(3- to 30-membered)heteroarylamino, a substituted or unsubstituted (C1-C30)alkyl(C2-C30)alkenylamino, a substituted or unsubstituted (C1-C30)alkyl(C6-C30)arylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino;
at least one of R₁₁ and R₁₄ to R₁₆ represents deuterium; and
Dₙ represents that n number of hydrogens are replaced with deuterium, and n represents an integer of 1 or more, and has an upper limit of the number of hydrogen atoms in the non-deuterated compound; 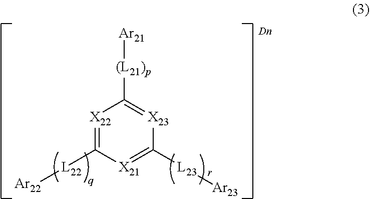
and wherein in formula 3,
X₂₁ to X₂₃ each independently represent CR′ or N, with a proviso that at least two of X₂₁ to X₂₃ represent N;
R′ represents hydrogen or deuterium;
L₂₁ to L₂₃ each independently represent a single bond, a substituted or unsubstituted (C6-C30)arylene, or a substituted or unsubstituted (3- to 30-membered)heteroarylene;
Ar₂₁ to Ar₂₃ each independently represent a substituted or unsubstituted (C6-C30)aryl or a substituted or unsubstituted (3- to 30-membered)heteroaryl, with a proviso that at least one of Ar₂₁ to Ar₂₃ comprises deuterium;
p, q, and reach independently represent an integer of 1 to 3, in which if p, q, and r represent an integer of 2 or more, each of L₂₁ to each of L₂₃ may be the same or different; and
Dₙ represents that n number of hydrogens are replaced with deuterium, and n represents an integer of 1 or more, and has an upper limit of the number of hydrogen atoms in the non-deuterated compound.

9. The organic electroluminescent device according to claim 8, wherein at least one of R₁₁ to R₁₈, Ar₁₁, and Ar₁₂ in formula 2 is represented by the following formula 2-1 or formula 2-2: 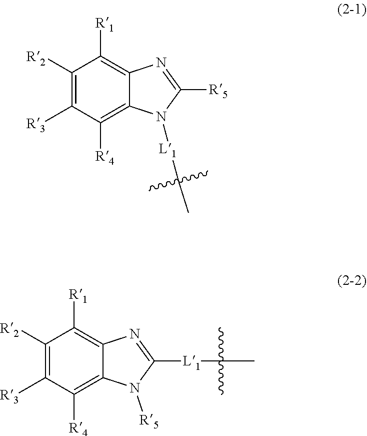
wherein in formulas 2-1 and 2-2,
L′₁ represents a single bond, a substituted or unsubstituted (C6-C30)arylene, or a substituted or unsubstituted (3- to 30-membered)heteroarylene; and
R′₁ to R'₅ each independently represent hydrogen, deuterium, a substituted or unsubstituted (C1-C30)alkyl, a substituted or unsubstituted (C6-C30)aryl, or a substituted or unsubstituted (3- to 30-membered)heteroaryl.

10. The organic electroluminescent device according to claim 8, wherein at least one of Ar₂₁ to Ar₂₃ comprises a substituted or unsubstituted phenanthrenyl, a substituted or unsubstituted carbazolyl, a substituted or unsubstituted fluorenyl, a substituted or unsubstituted benzofluorenyl, a substituted or unsubstituted triphenylenyl, a substituted or unsubstituted dibenzofuranyl, or a substituted or unsubstituted dibenzothiophenyl, with a proviso that at least one of Ar₂₁ to Ar₂₃ comprises deuterium.

11. The organic electroluminescent device according to claim 4, wherein at least one layer in the light-emitting layer comprises a compound represented by the following formula 4 or formula 5: 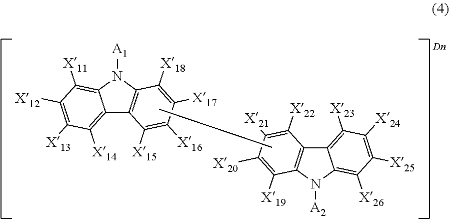
wherein in formula 4,
A₁ and A₂ each independently represent a substituted or unsubstituted (C6-C30)aryl, a substituted or unsubstituted dibenzofuranyl, a substituted or unsubstituted dibenzothiophenyl, or a substituted or unsubstituted carbazolyl;
any one of X′₁₅ to X′₁₈ and any one of X′₁₉ to X′₂₂ are linked to each other to form a single bond;
X′₁₁ to X′₁₄, X′₂₃ to X′₂₆, and X′₁₅ to X′₂₂ which do not form a single bond each independently represent hydrogen, deuterium, a substituted or unsubstituted (C6-C30)aryl, or a substituted or unsubstituted (3- to 30-membered)heteroaryl, or may be linked to an adjacent substituent(s) to form a ring(s);
at least one of X′₁₁, X′₁₈, X′₁₉, or X′₂₆ represents deuterium; and
Dₙ represents that n number of hydrogens are replaced with deuterium, and n represents an integer of 1 or more, and has an upper limit of the number of hydrogen atoms in the non-deuterated compound; 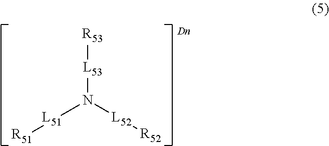
and wherein in formula 5,
at least one of R₅₁ to R₅₃ comprises the following formula 5-1 or formula 5-2: 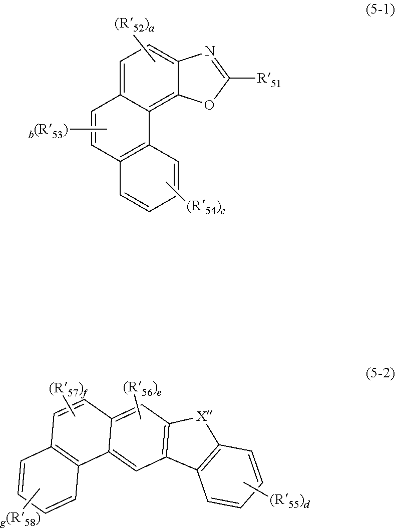
or L₅₁ and L₅₂ may be single bonds, and R₅₁ and R₅₂ may be linked to each other to be represented by any one of the following formulas 5-3 to 5-5: 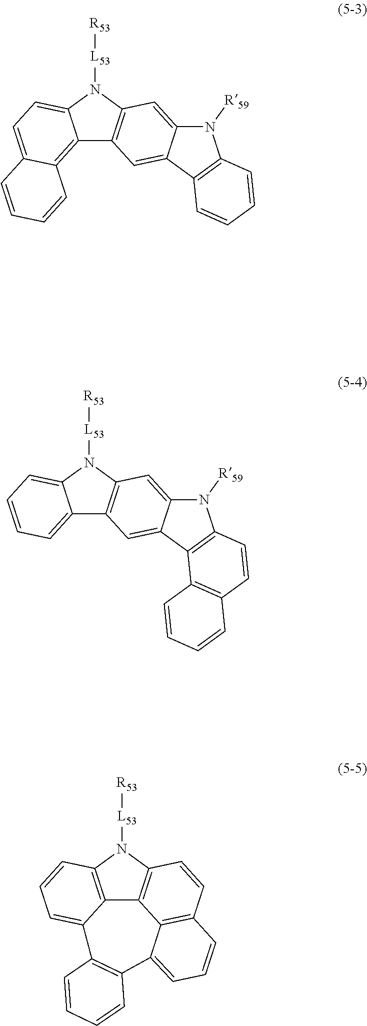
R₅₁ to R₅₃ and R′₅₁ to R′₅₉ each independently represent hydrogen, deuterium, a substituted or unsubstituted (C1-C30)alkyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), a substituted or unsubstituted mono- or di-(C1-C30)alkylamino, a substituted or unsubstituted mono- or di-(C2-C30)alkenylamino, a substituted or unsubstituted (C1-C30)alkyl(C2-C30)alkenylamino, a substituted or unsubstituted mono- or di-(C6-C30)arylamino, a substituted or unsubstituted (C1-C30)alkyl(C6-C30)arylamino, a substituted or unsubstituted mono- or di-(3- to 30-membered)heteroarylamino, a substituted or unsubstituted (C1-C30)alkyl(3- to 30-membered)heteroarylamino, a substituted or unsubstituted (C2-C30)alkenyl(C6-C30)arylamino, a substituted or unsubstituted (C2-C30)alkenyl(3- to 30-membered)heteroarylamino, or a substituted or unsubstituted (C6-C30)aryl(3- to 30-membered)heteroarylamino, or may be linked to adjacent substituent(s) to form a ring(s);
L₅₁ to L₅₃ each independently represent a single bond, a substituted or unsubstituted (C6-C30)arylene, or a substituted or unsubstituted (3- to 30-membered)heteroarylene;
X″ represents O or S;
a, b, e, and f each independently represent an integer of 1 or 2, c, d, and g each independently represent an integer of 1 to 4, in which if a to g represent an integer of 2 or more, each of R′₅₁ to each of R′₅₉ may be the same or different; and
Dₙ represents that n number of hydrogens are replaced with deuterium, and n represents an integer of 1 or more, and has an upper limit of the number of hydrogen atoms in the non-deuterated compound.

12. The organic electroluminescent device according to claim 4, in which if the at least one layer in the light-emitting layer comprises two or more compounds, the two or more compounds comprise a compound represented by the following formula 6 or formula 7: 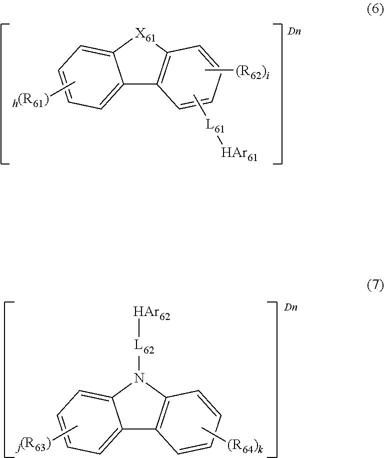
wherein in formula 6 and formula 7,
X₆₁ represents O or S;
HAr₆₁ and HAr₆₂ each independently represent a substituted or unsubstituted (3- to 30-membered)heteroaryl containing one or more nitrogen atoms;
L₆₁ and L₆₂ each independently represent a single bond, a substituted or unsubstituted (C6-C30)arylene, or a substituted or unsubstituted (3- to 30-membered)heteroarylene;
R₆₁ to R₆₄ each independently represent hydrogen, deuterium, a substituted or unsubstituted (C6-C30)aryl, or a substituted or unsubstituted (3- to 30-membered)heteroaryl; or may be linked to an adjacent substituent(s) to form a ring(s);
h to k each independently represent an integer of 1 to 4, in which if h to k represent an integer of 2 or more, each of R₆₁ to each of R₆₄ may be the same or different; and
Dₙ represents that n number of hydrogens are replaced with deuterium, and n represents an integer of 1 or more, and has an upper limit of the number of hydrogen atoms in the non-deuterated compound.

13. The organic electroluminescent device according to claim 4, wherein at least one layer in the light-emitting layer comprises a compound represented by the following formula 8: 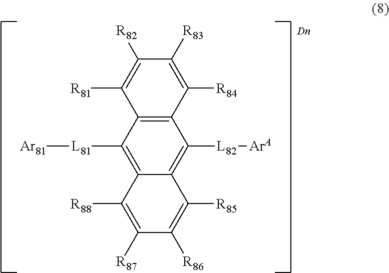
wherein in formula 8,
Ar₈₁ represents a substituted or unsubstituted (C6-C30)aryl, or a substituted or unsubstituted (3- to 30-membered)heteroaryl;
R₈₁ to R₈₈ each independently represent hydrogen, deuterium, a halogen, a cyano, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C3-C30)cycloalkenyl, a substituted or unsubstituted (3- to 7-membered) heterocycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, or a substituted or unsubstituted fused ring group of a (C3-C30) aliphatic ring(s) and a (C6-C30) aromatic ring(s);
Ar^{A} represents a substituted or unsubstituted (C6-C30)aryl, or a substituted or unsubstituted (3- to 30-membered)heteroaryl, or is represented by the following formula A-1; and
Dₙ represents that n number of hydrogens are replaced with deuterium, and n represents an integer of 1 or more, and has an upper limit of the number of hydrogen atoms in the non-deuterated compound; 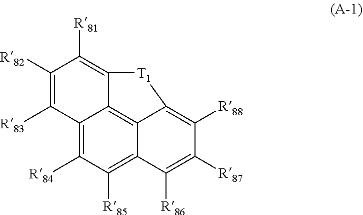
T₁ represents O, S, or CR_{f}Rₘ;
R′₈₁ to R′₈₈ each independently are a site linked to L₈₂, or represent hydrogen, deuterium, a halogen, a cyano, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C3-C30)cycloalkenyl, a substituted or unsubstituted (3- to 7-membered) heterocycloalkyl, a substituted or unsubstituted (C1-C30)alkoxy, a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, a substituted or unsubstituted tri(C6-C30)arylsilyl, a substituted or unsubstituted fused ring group of a (C3-C30) aliphatic ring(s) and a (C6-C30) aromatic ring(s), or -L₈₃-N(Ar₈₃) (Ar₈₄);
Rₗ and Rₘ each independently represent a substituted or unsubstituted (C1-C30)alkyl, or a substituted or unsubstituted (C6-C30)aryl, or may be linked to each other to form a ring(s);
L₈₁ to L₈₃ each independently represent a single bond, a substituted or unsubstituted (C6-C30)arylene, or a substituted or unsubstituted (3- to 30-membered)heteroarylene; and
Ar₈₃ and Ar₈₄ each independently represent hydrogen, deuterium, a halogen, a cyano, a substituted or unsubstituted (C1-C30)alkyl, a substituted or unsubstituted (C2-C30)alkenyl, a substituted or unsubstituted (C6-C30)aryl, a substituted or unsubstituted (3- to 30-membered)heteroaryl, a substituted or unsubstituted (C3-C30)cycloalkyl, a substituted or unsubstituted (C3-C30)cycloalkenyl, a substituted or unsubstituted (3- to 7-membered) heterocycloalkyl, a substituted or unsubstituted (C1-C30)alkoxy, a substituted or unsubstituted fused ring group of a (C3-C30) aliphatic ring(s) and a (C6-C30) aromatic ring(s), a substituted or unsubstituted tri(C1-C30)alkylsilyl, a substituted or unsubstituted di(C1-C30)alkyl(C6-C30)arylsilyl, a substituted or unsubstituted (C1-C30)alkyldi(C6-C30)arylsilyl, or a substituted or unsubstituted tri(C6-C30)arylsilyl.

14. The organic electroluminescent device according to claim 6, wherein the compound represented by formula 1 is at least one selected from the following compounds:

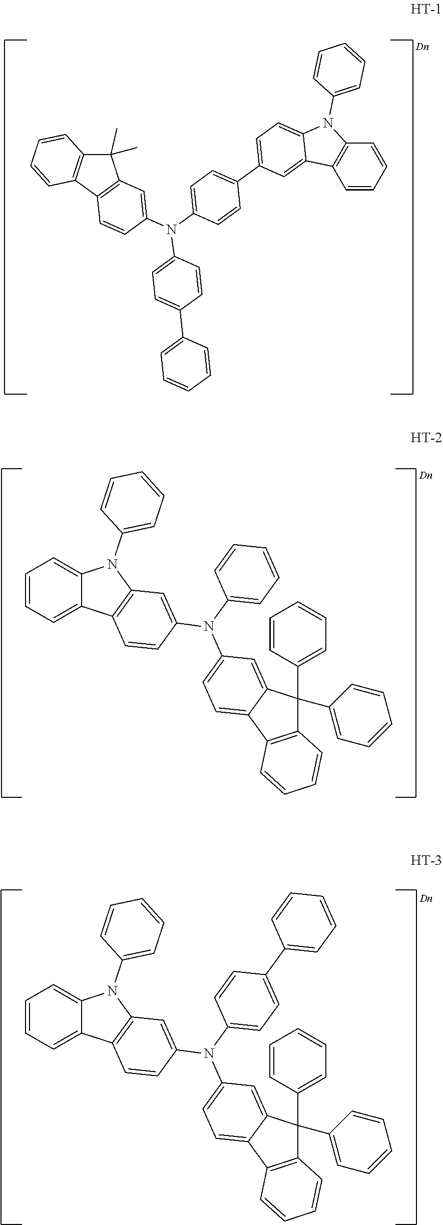

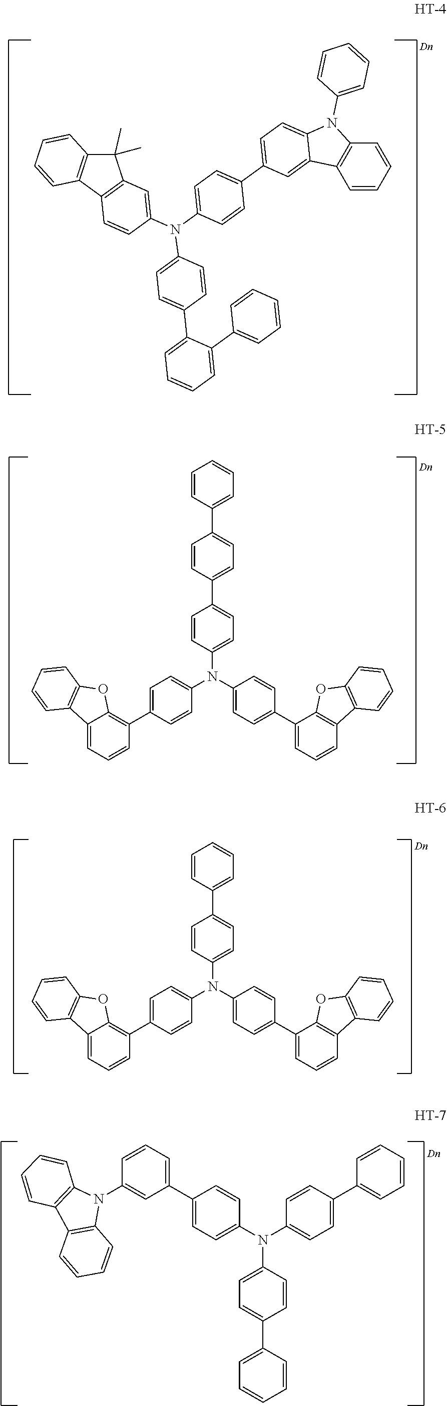

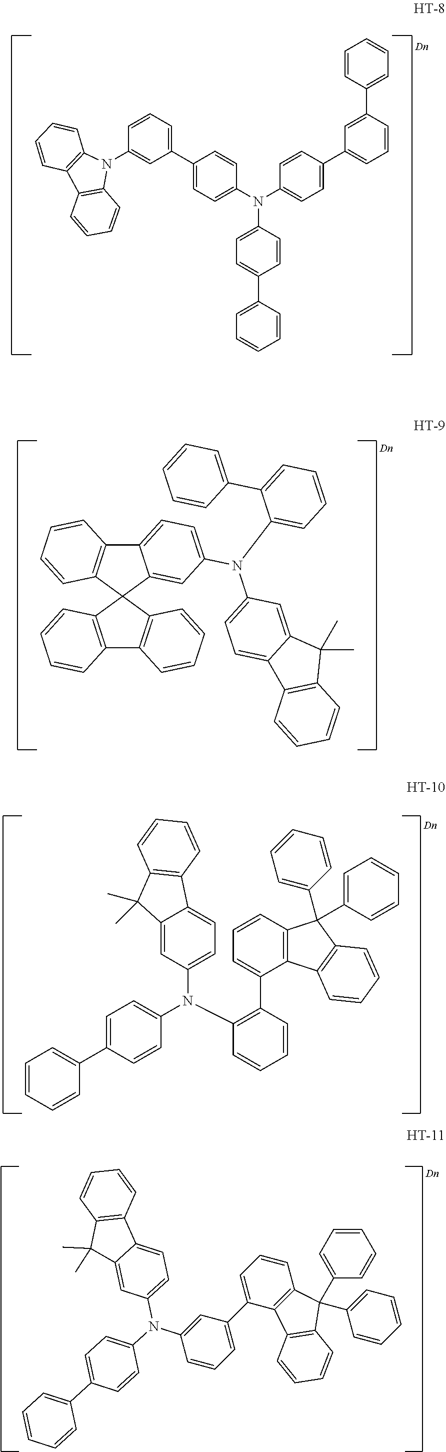

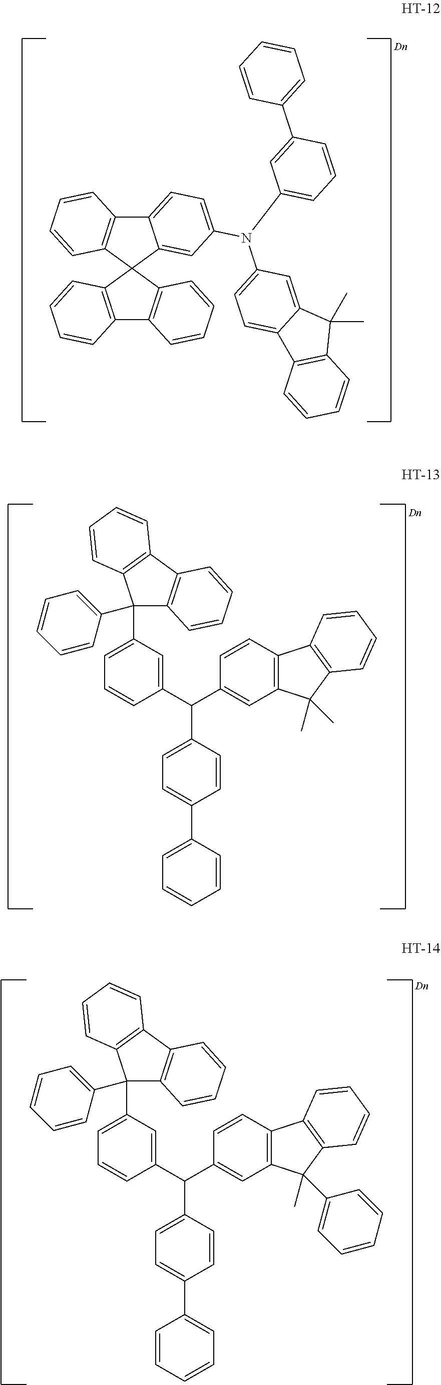

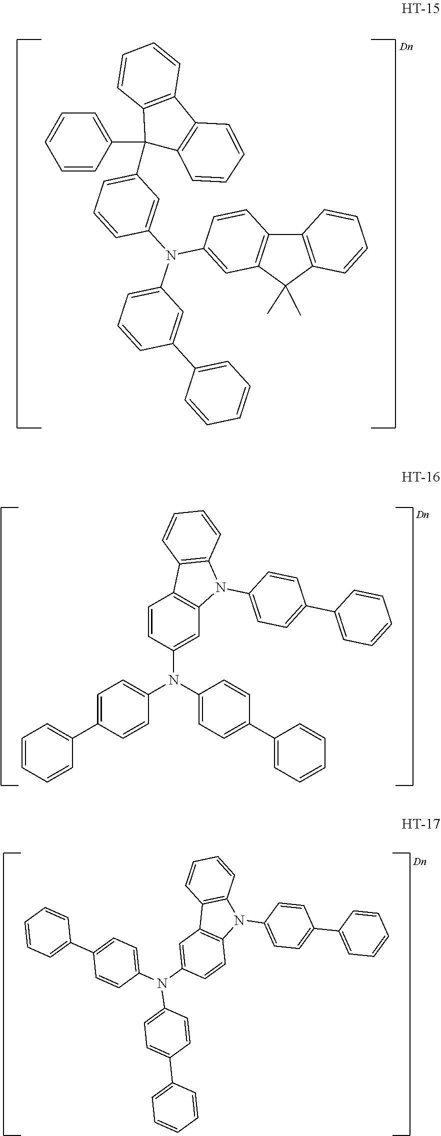

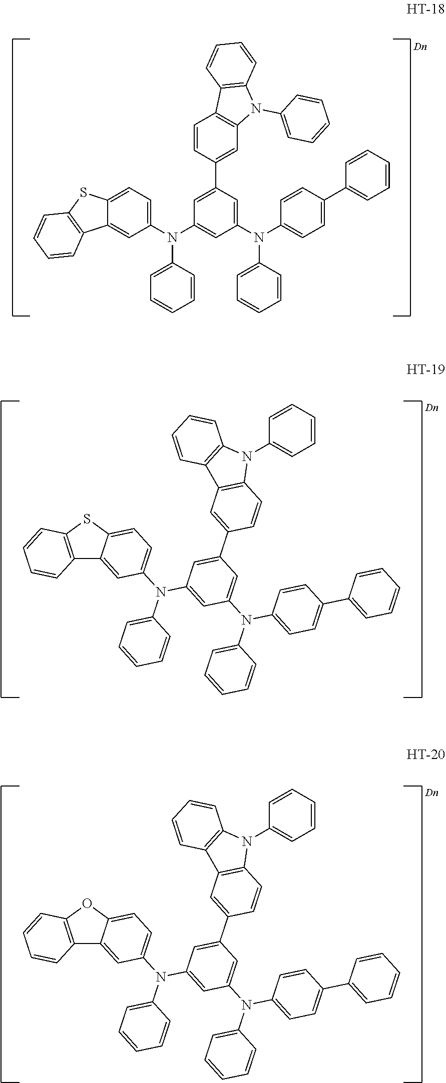

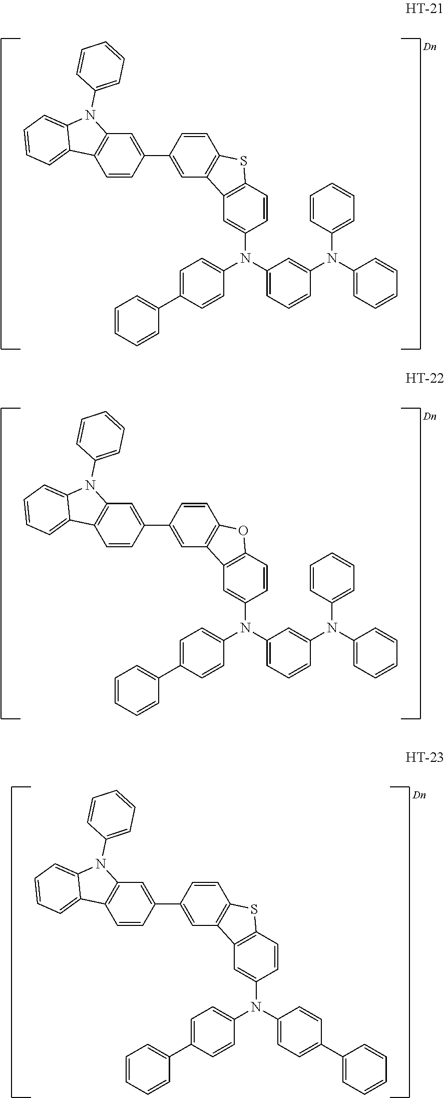

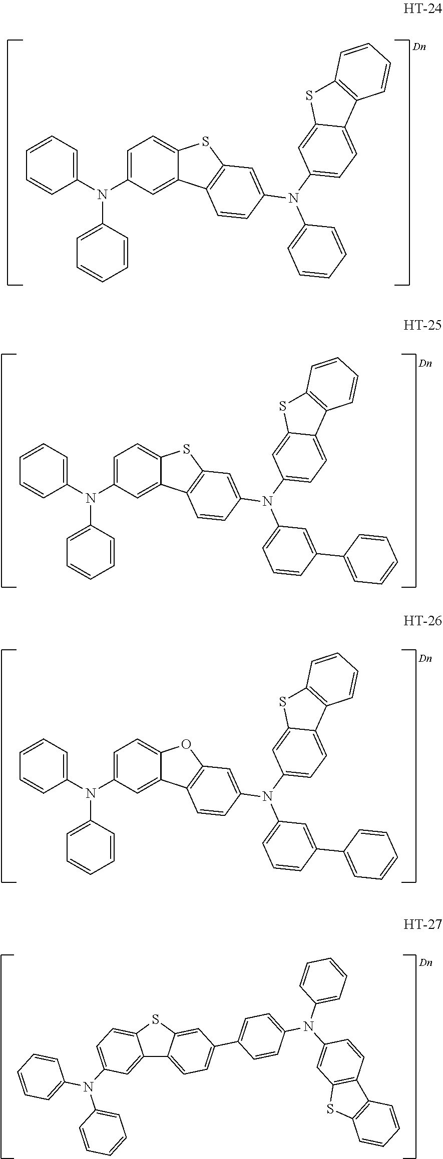

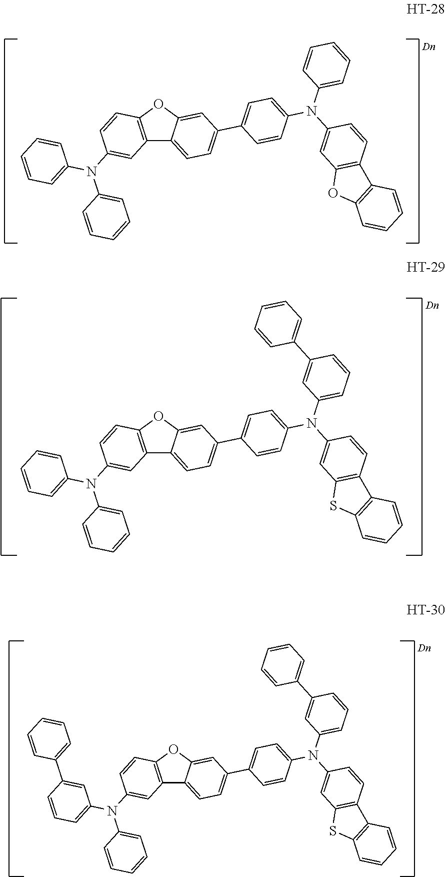

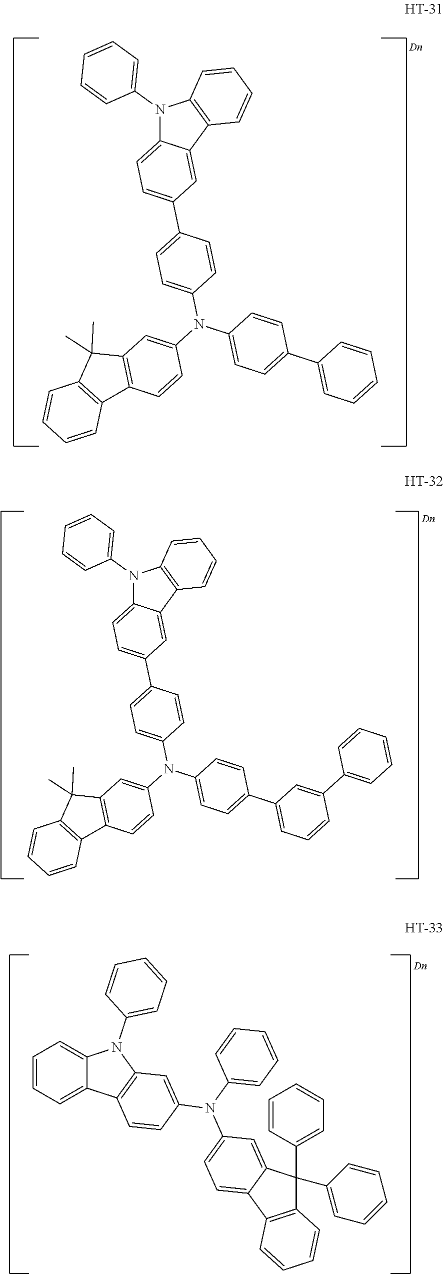

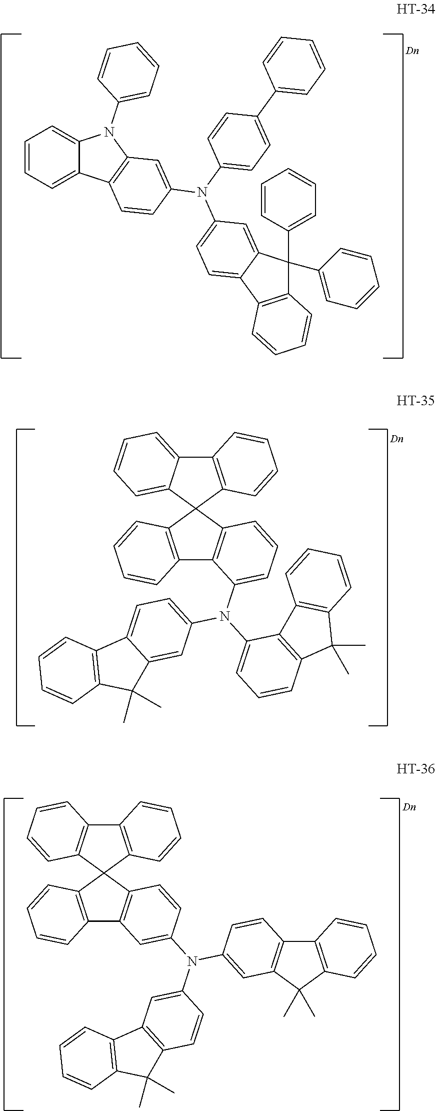

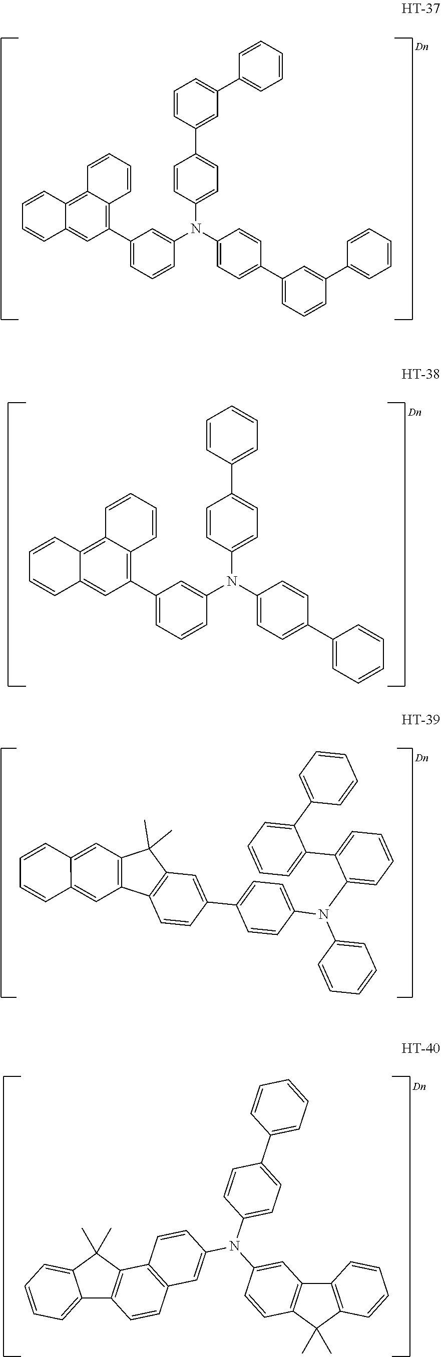

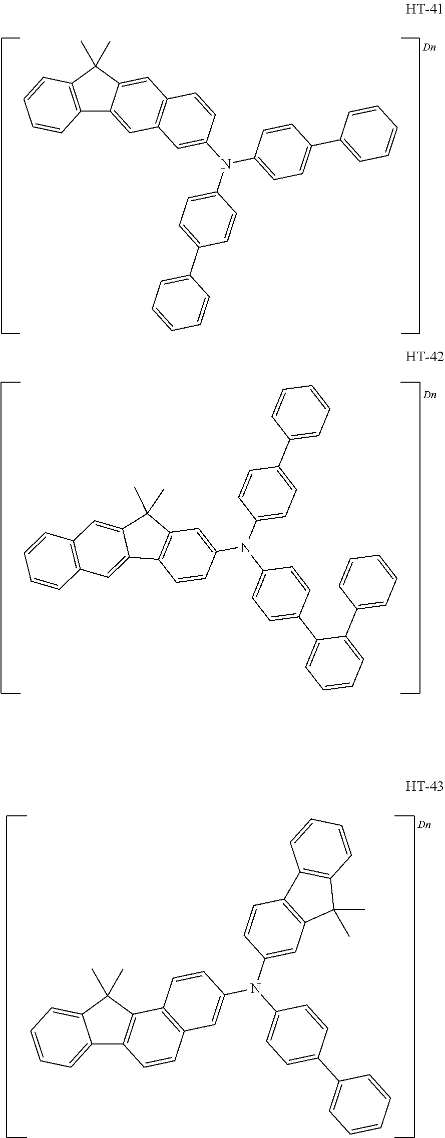

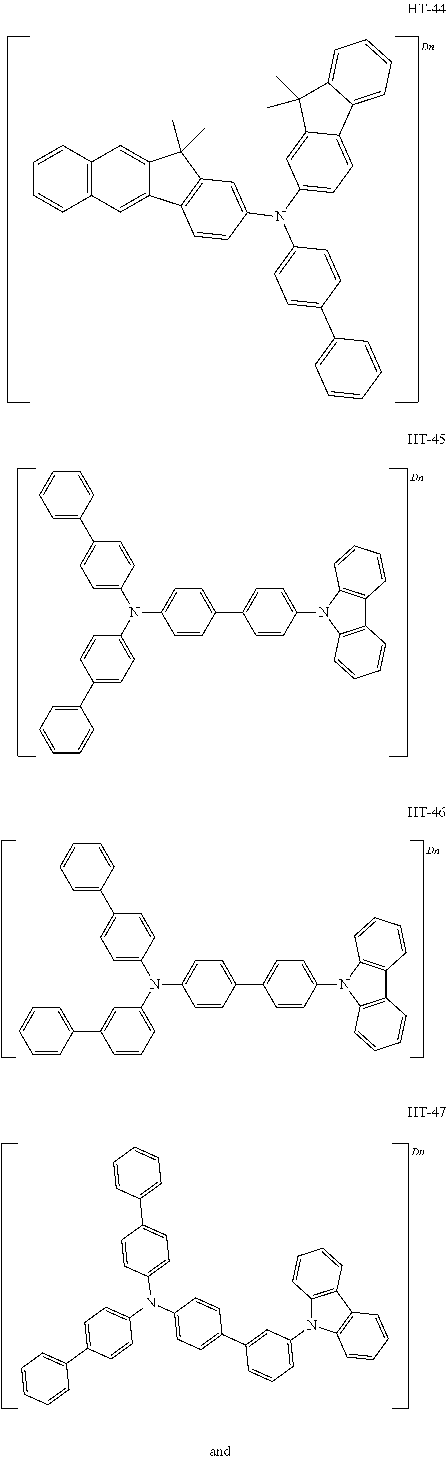

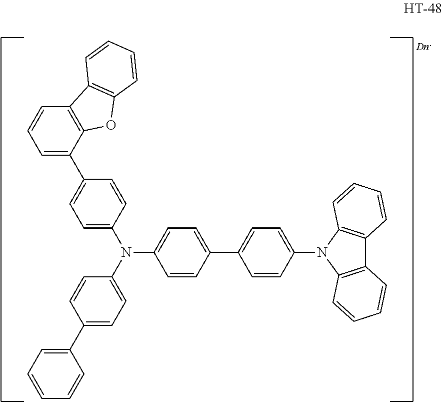

15. The organic electroluminescent device according to claim 8, wherein the compound represented by formula 2 or formula 3 is at least one selected from the following compounds:

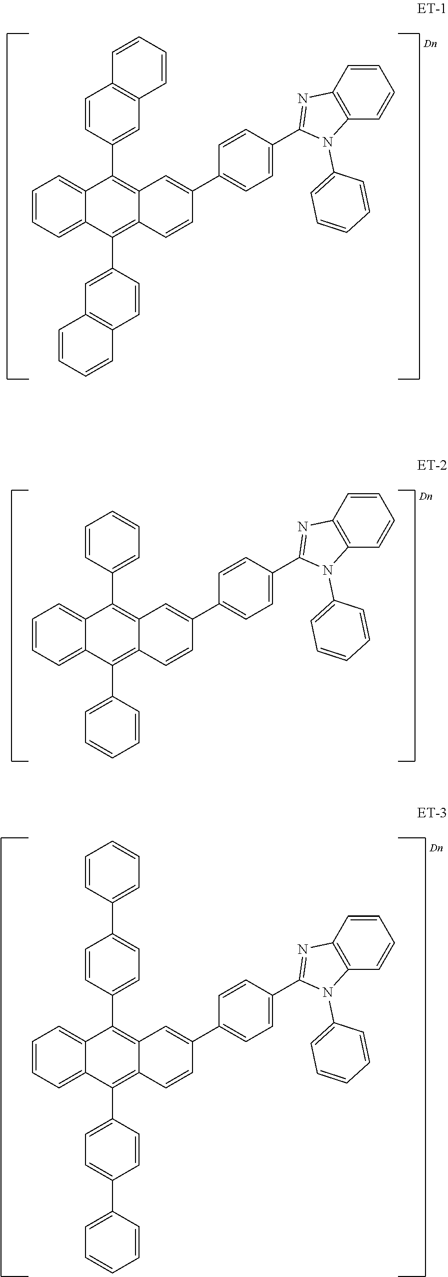

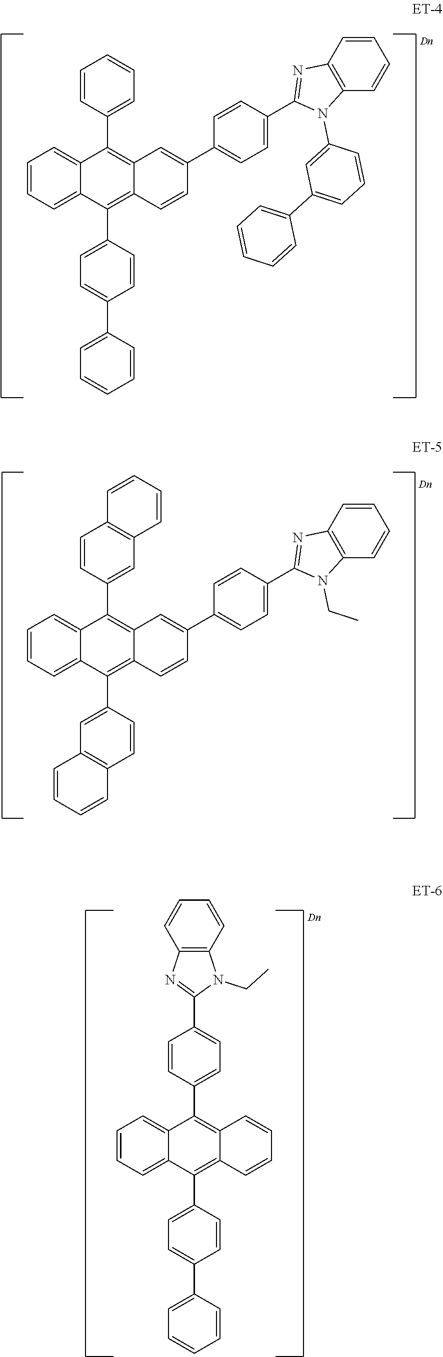

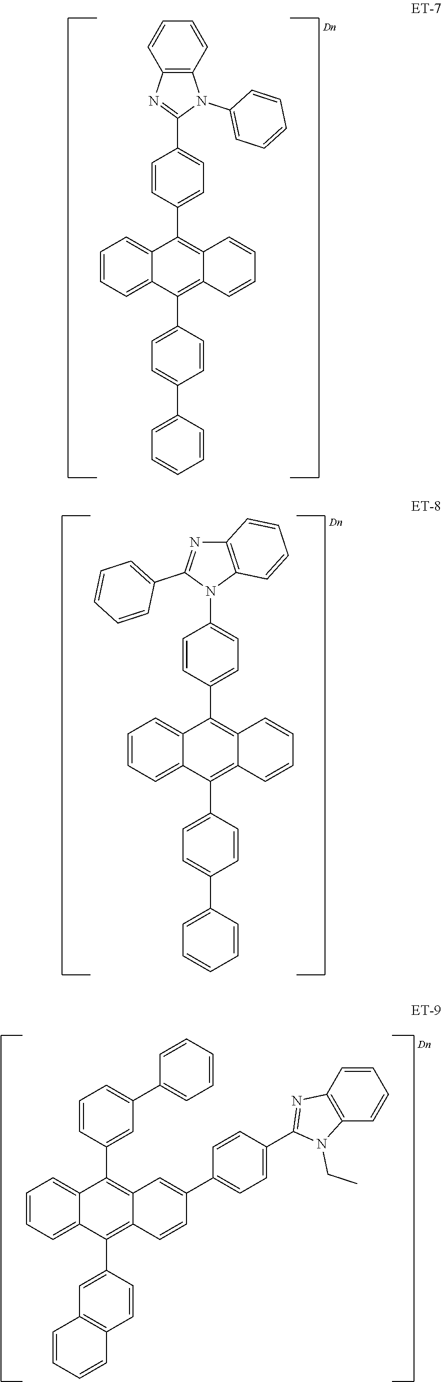

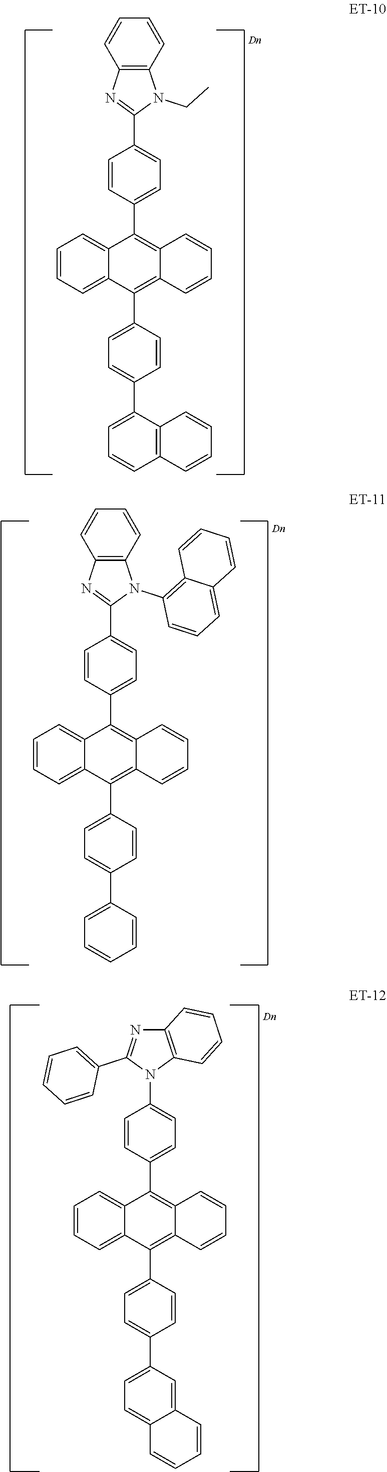

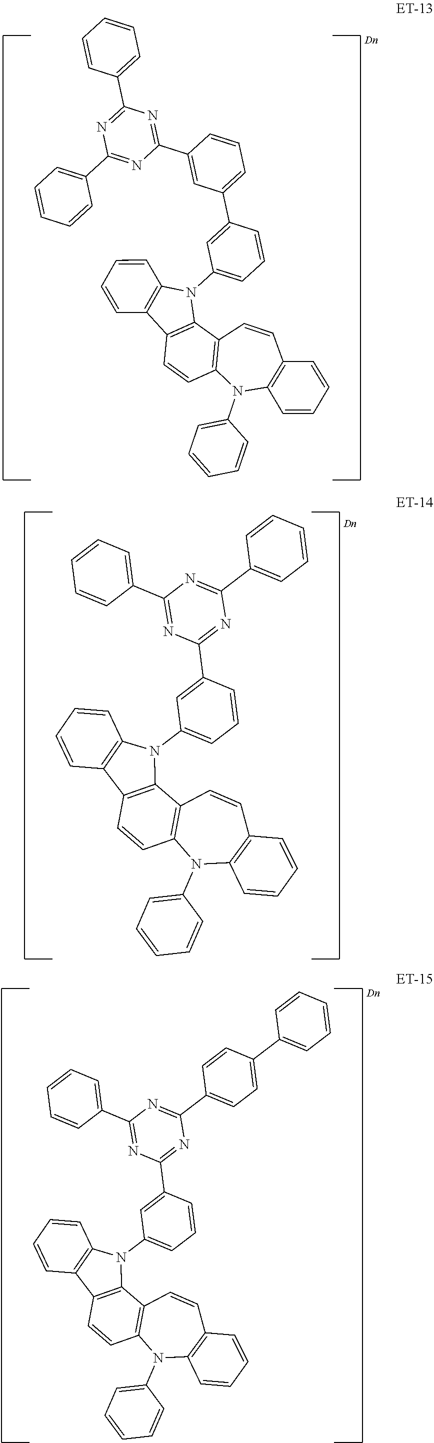

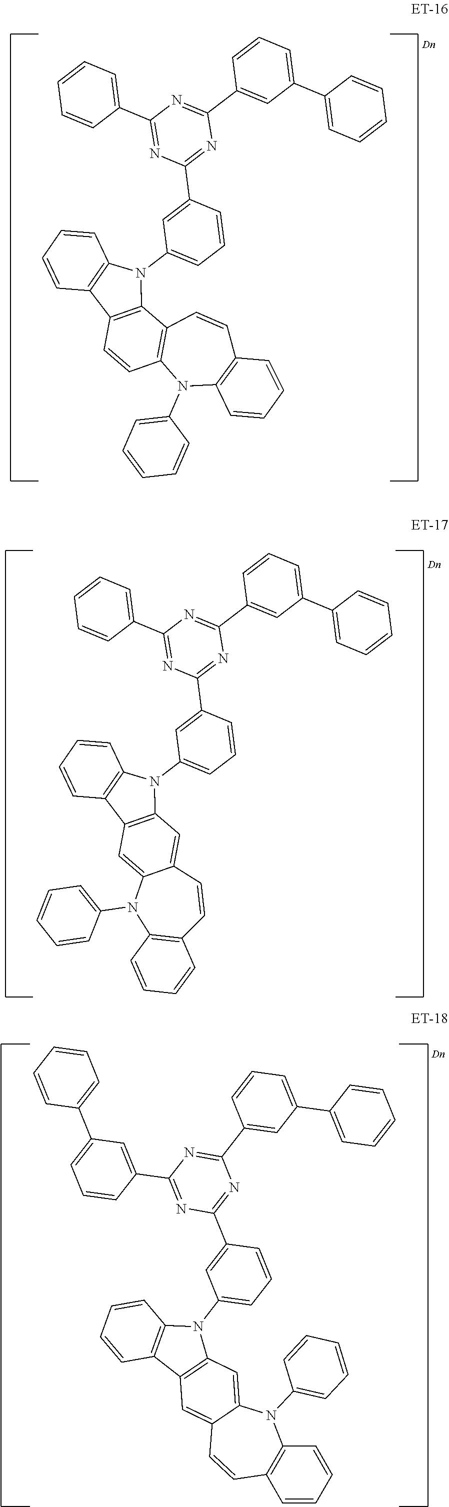

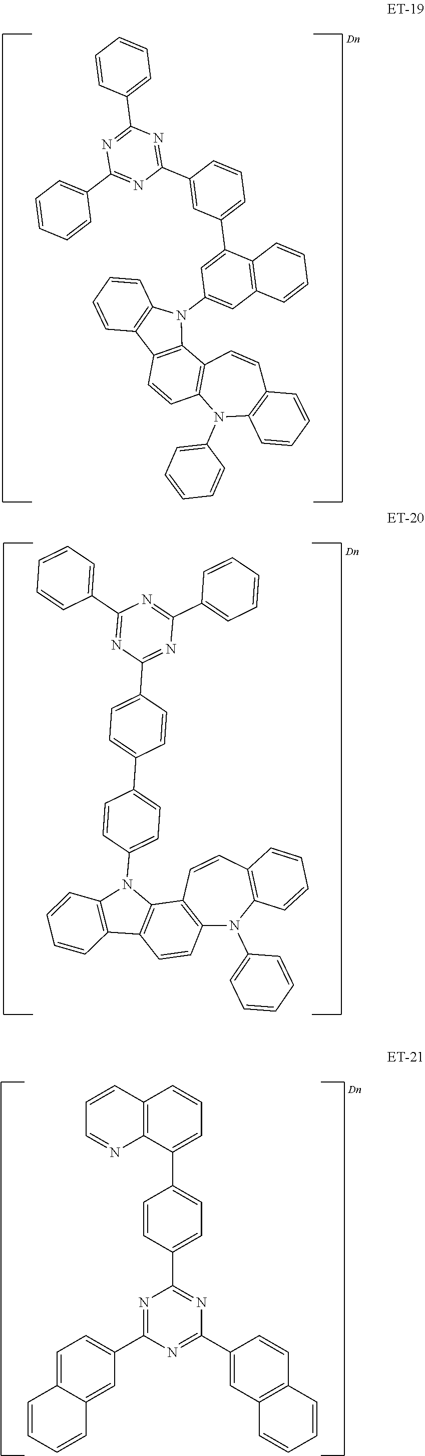

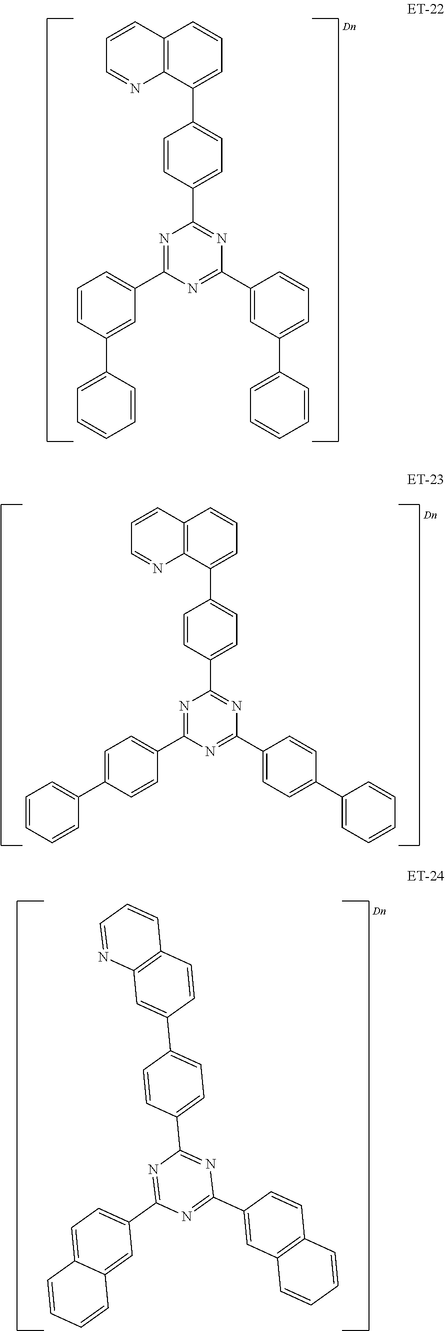

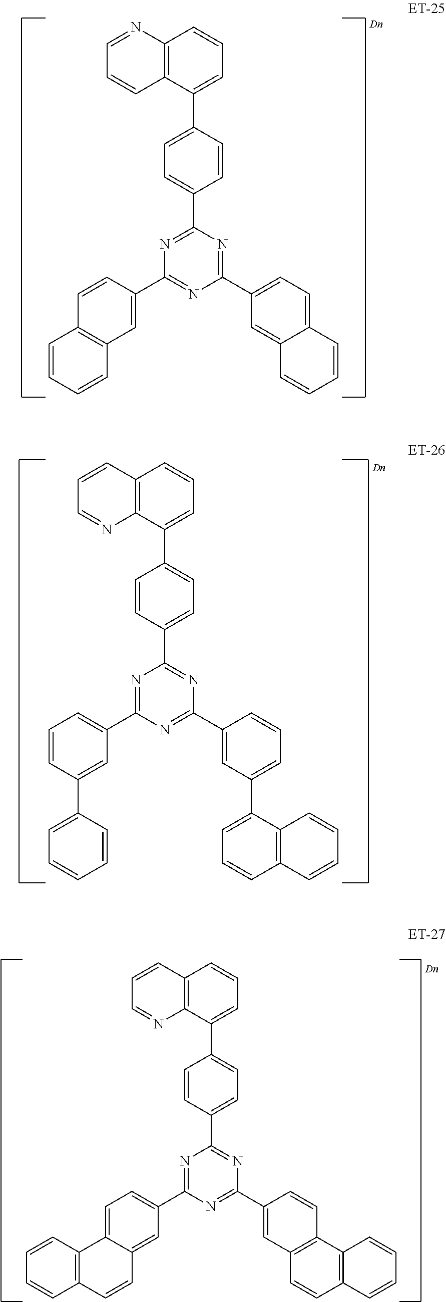

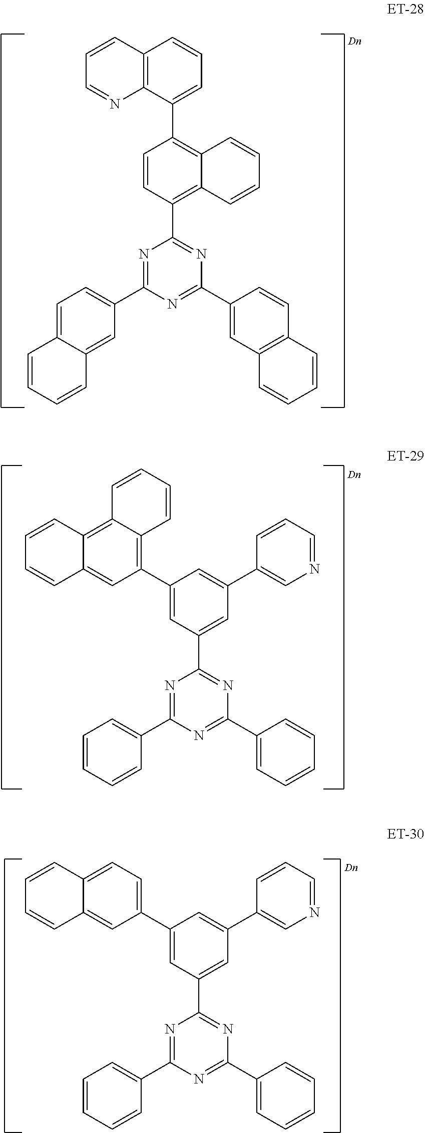

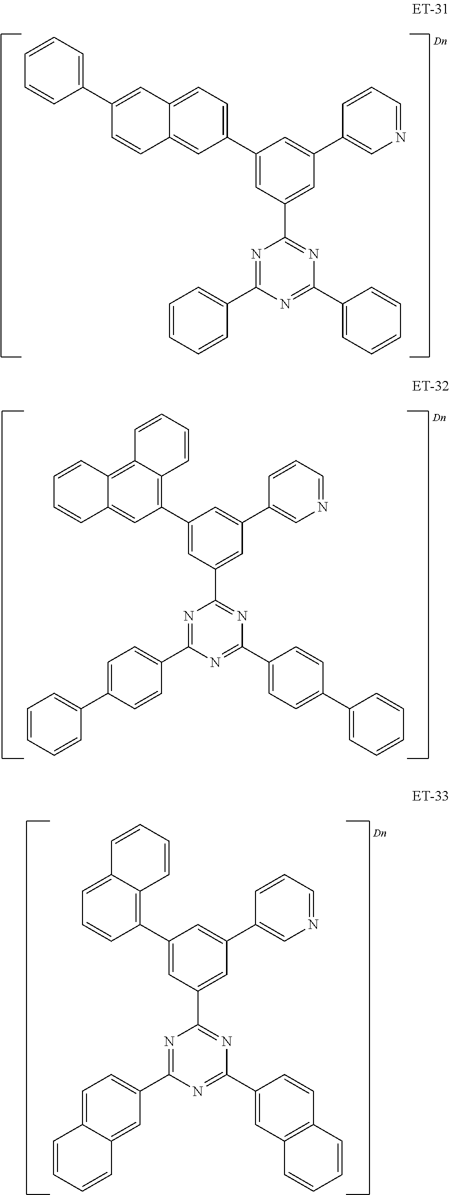

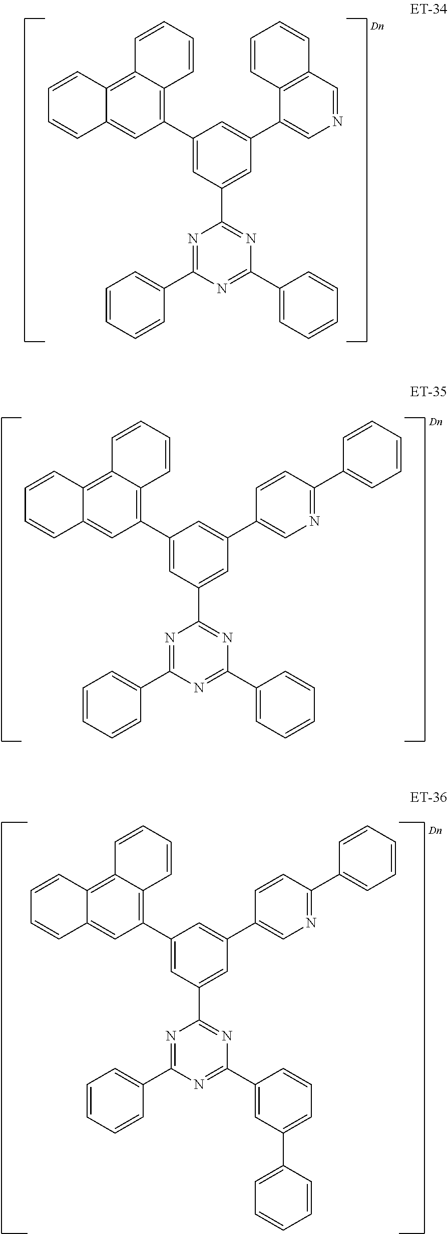

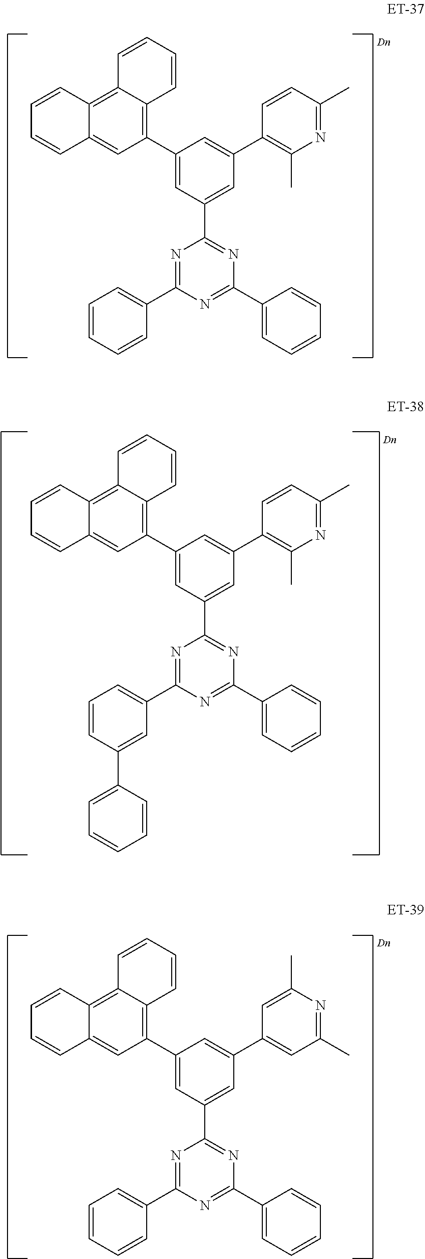

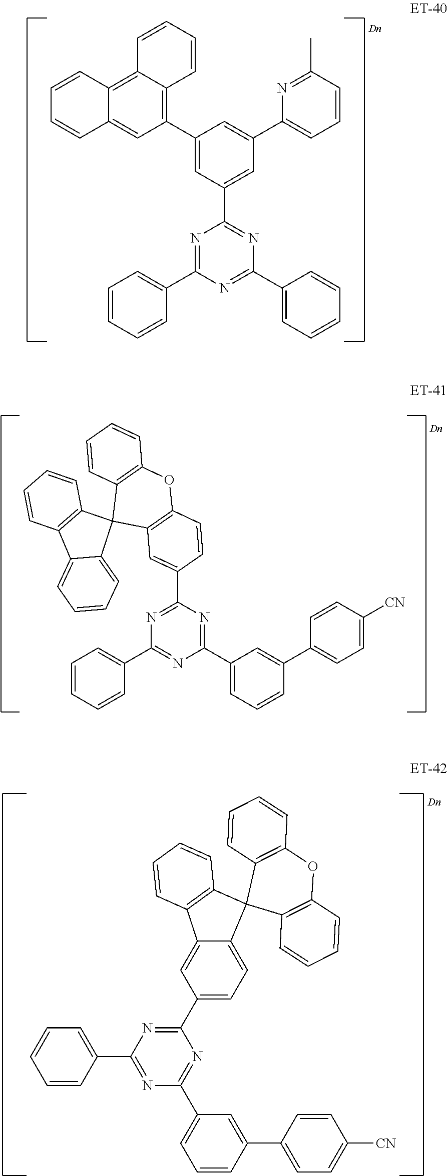

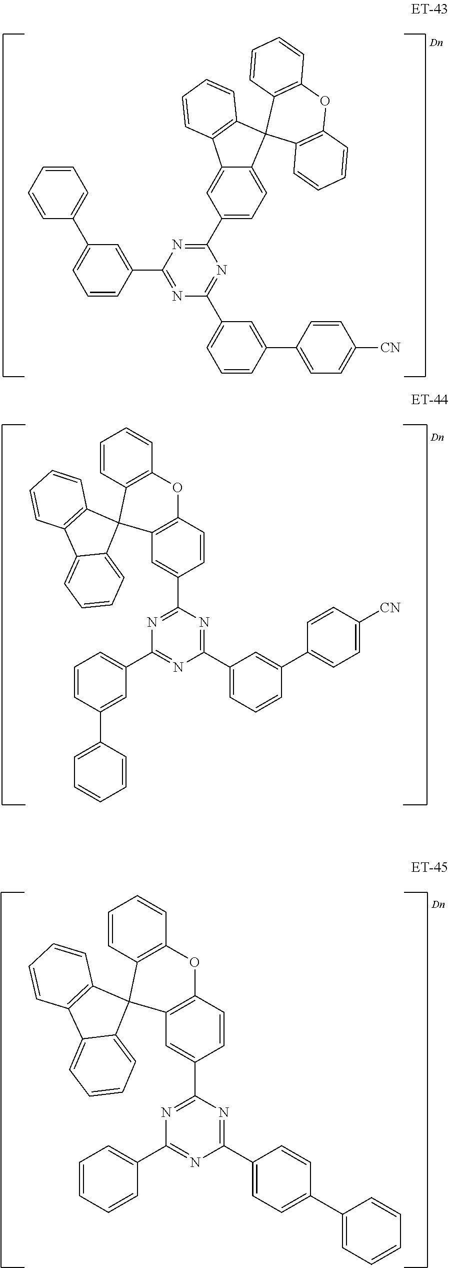

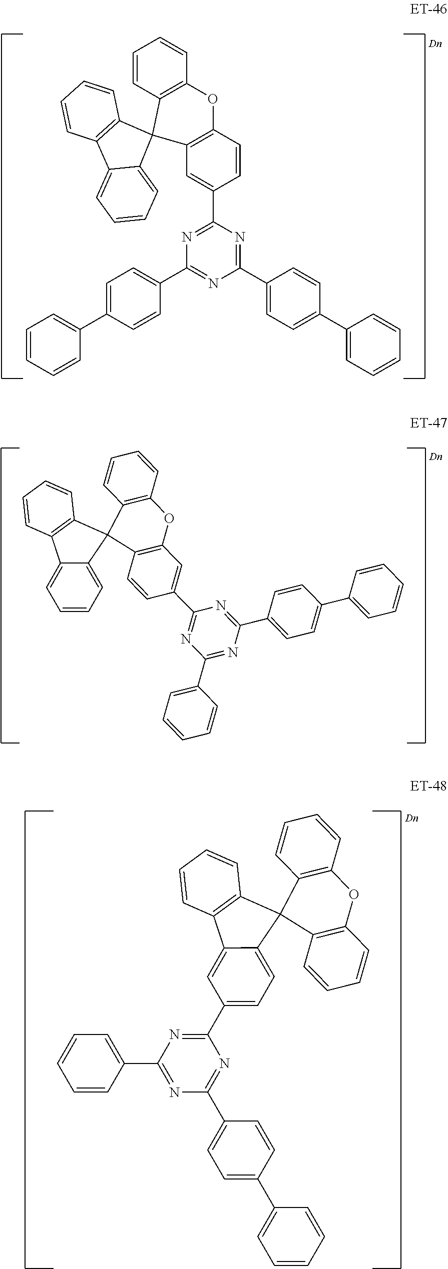

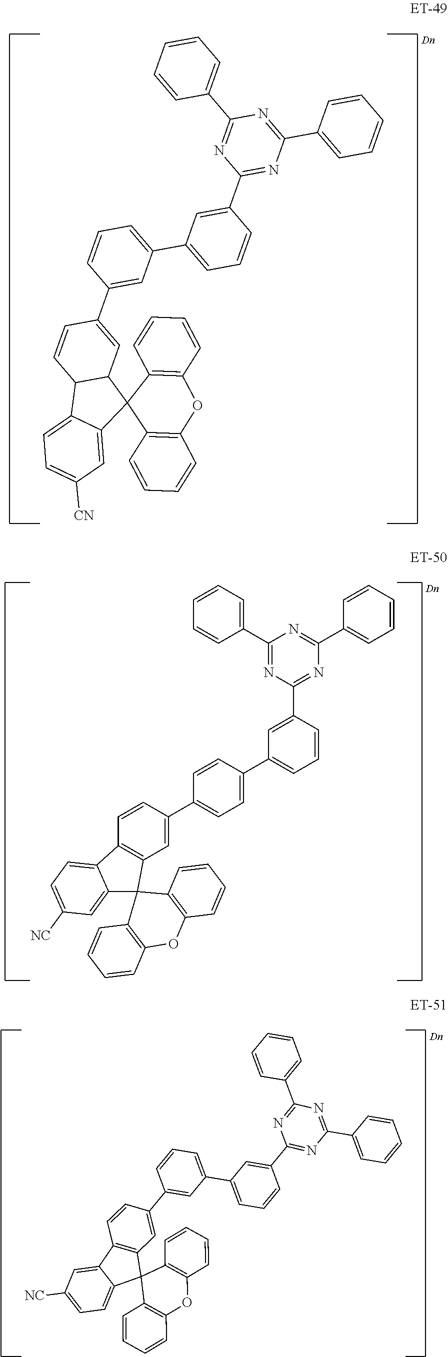

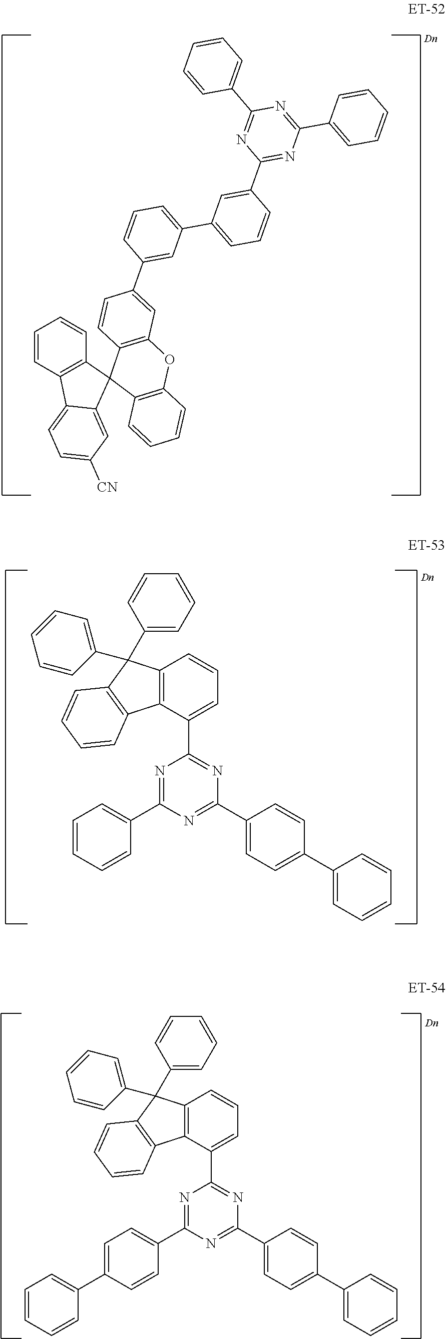

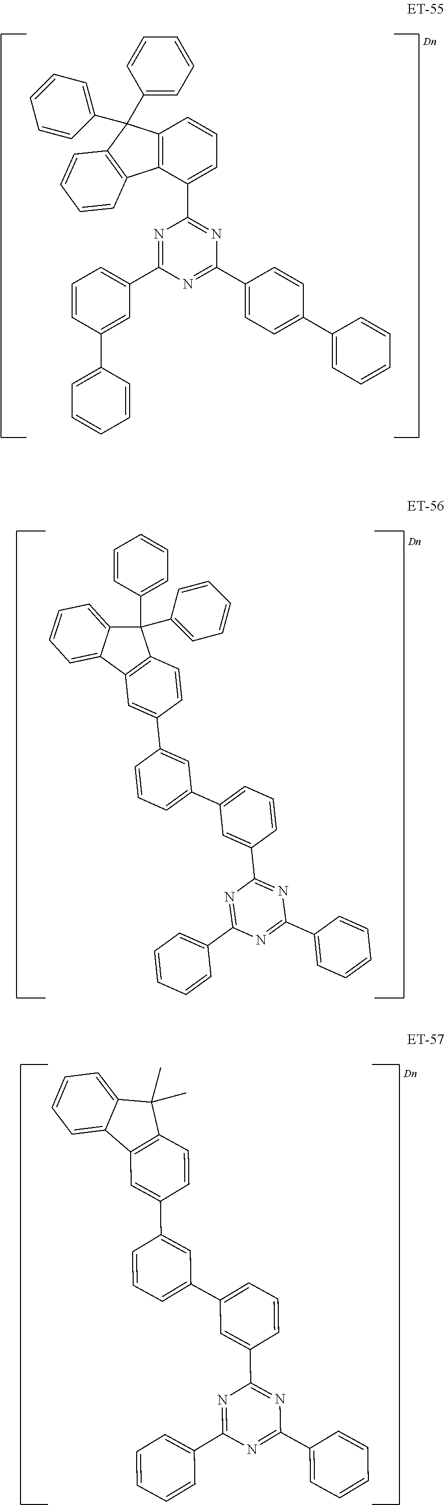

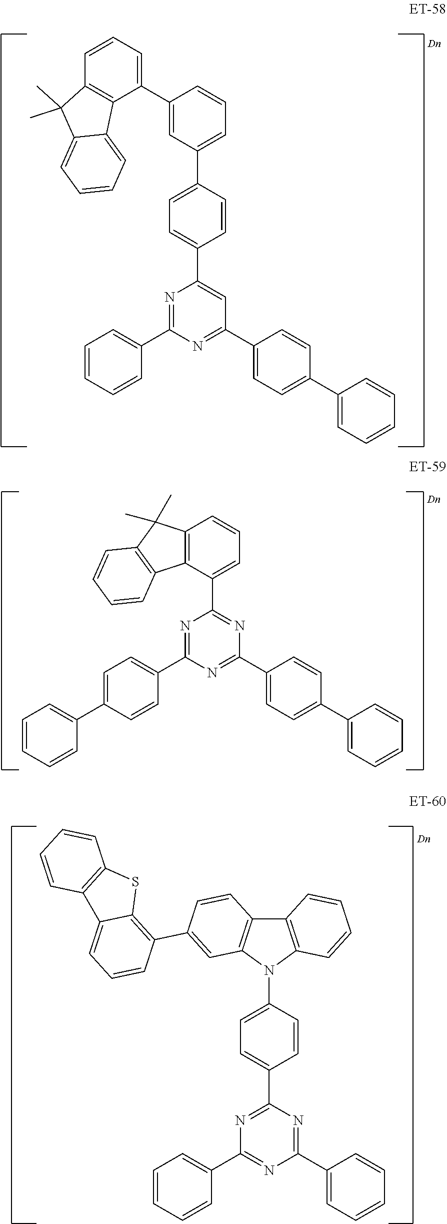

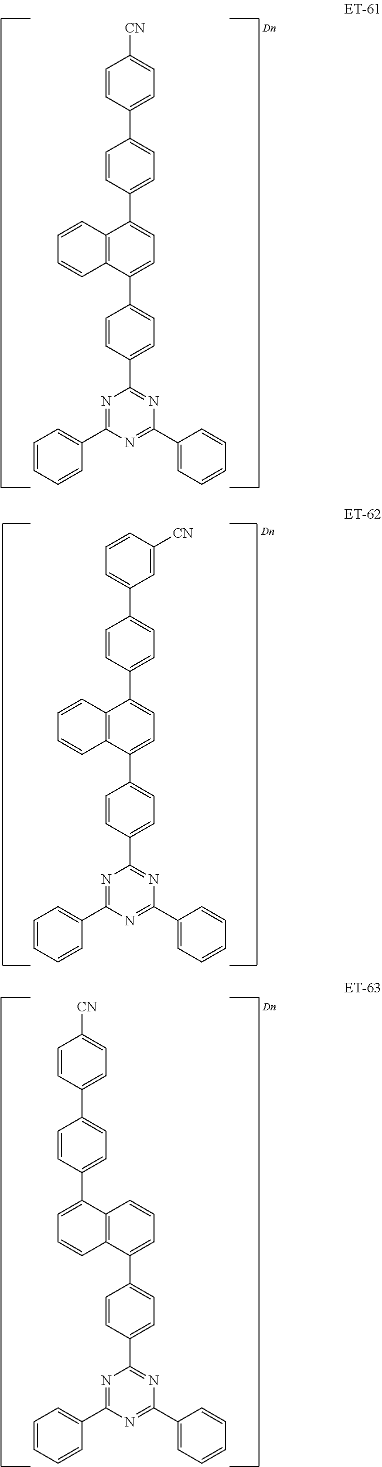

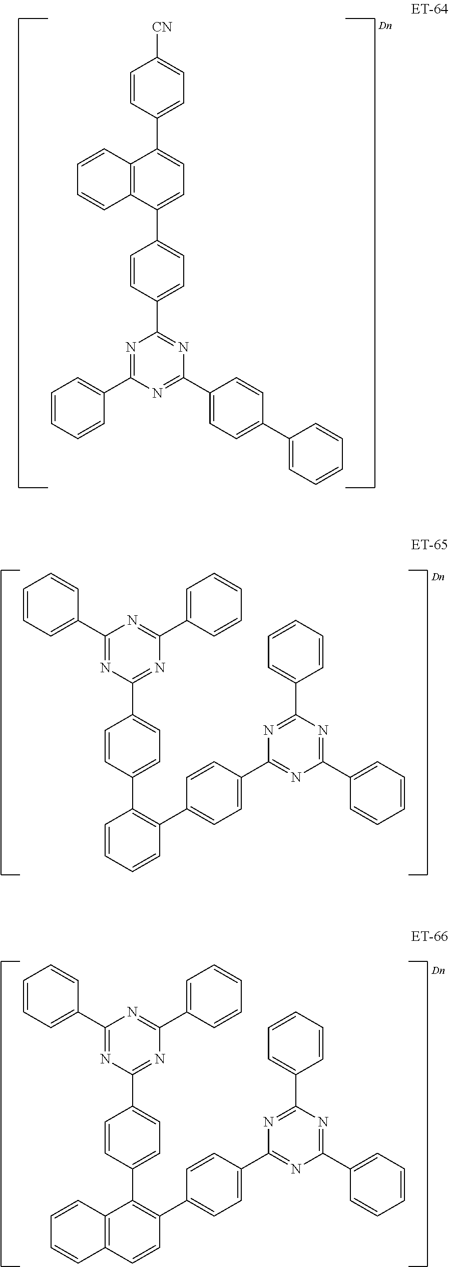

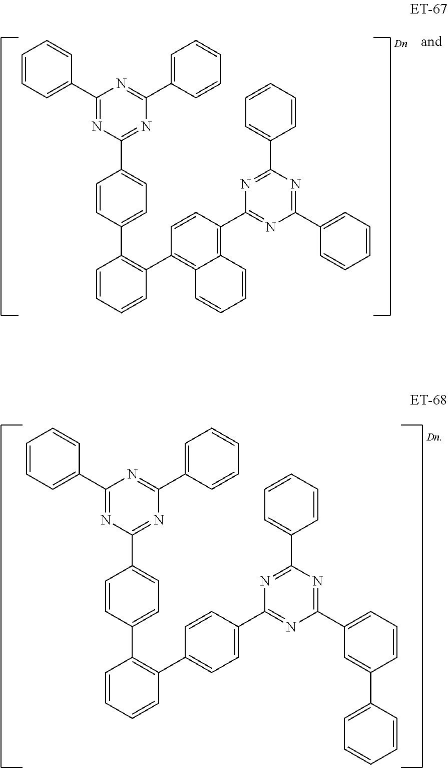

16. The organic electroluminescent device according to claim 11, wherein the compound represented by formula 4 or formula 5 is at least one selected from the following compounds:

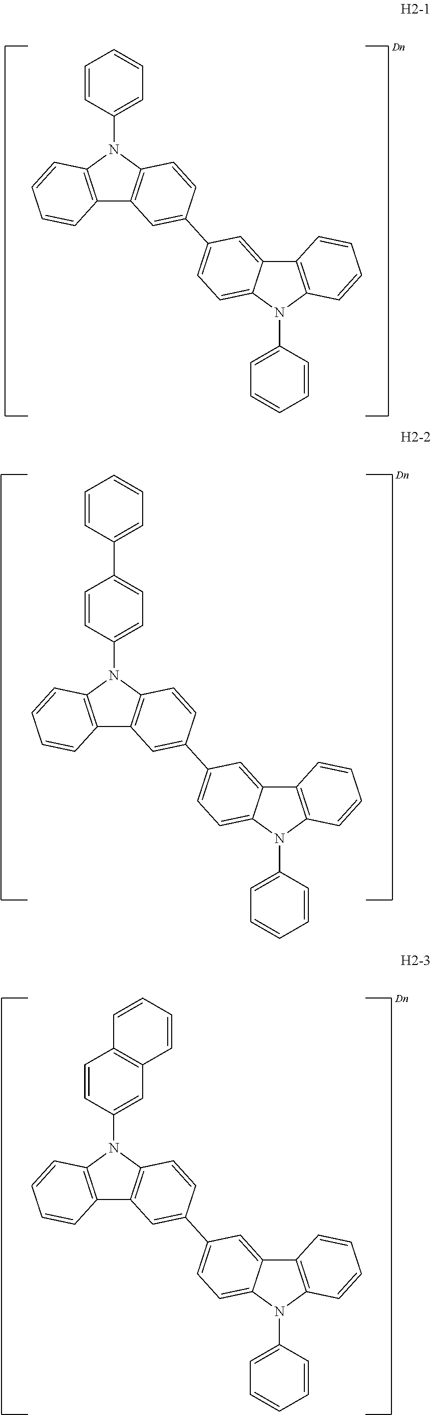

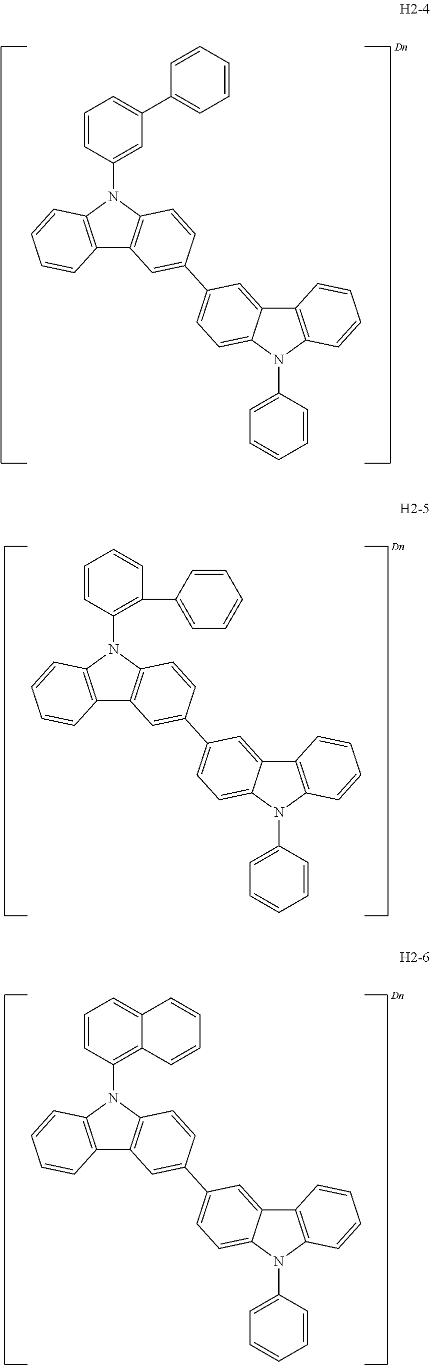

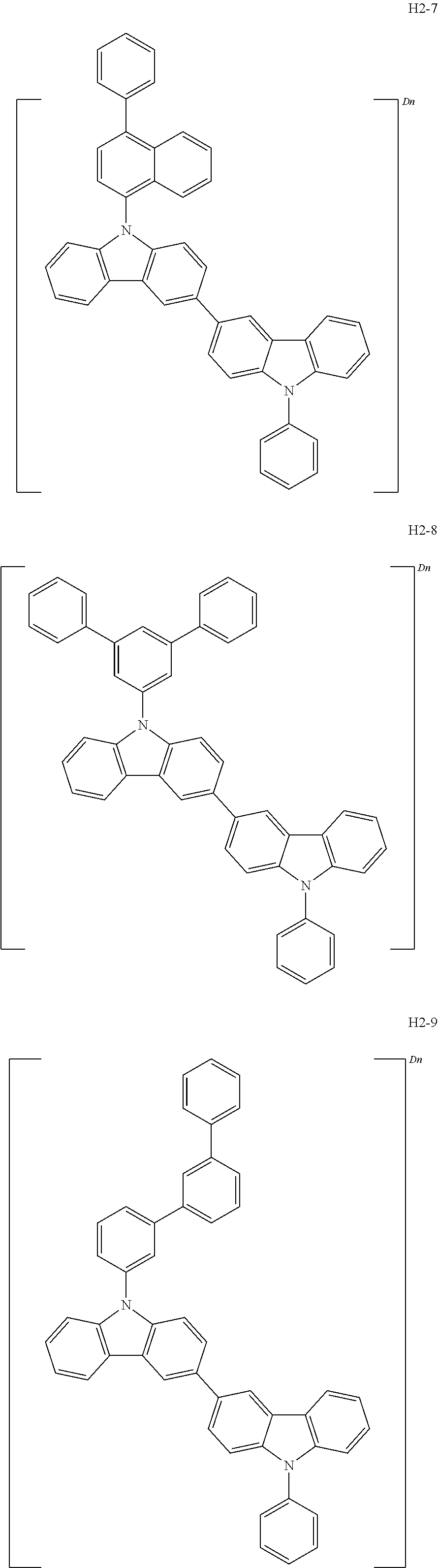

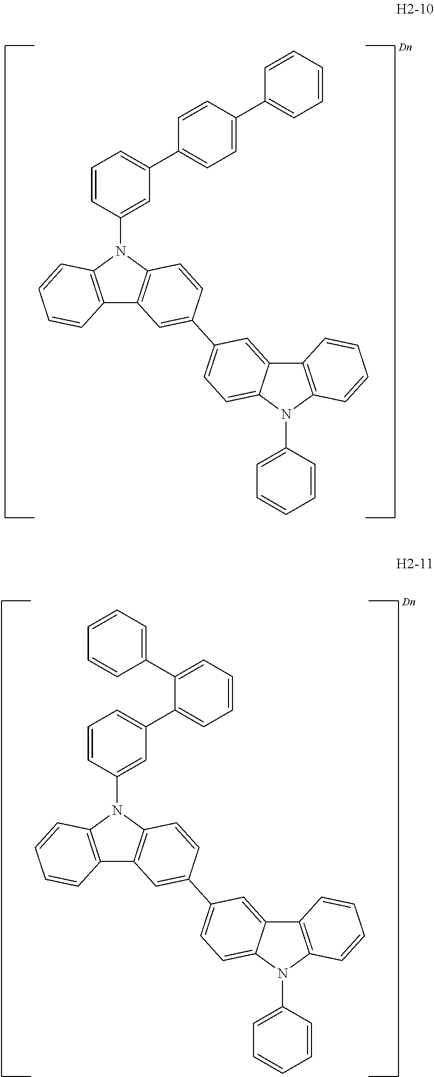

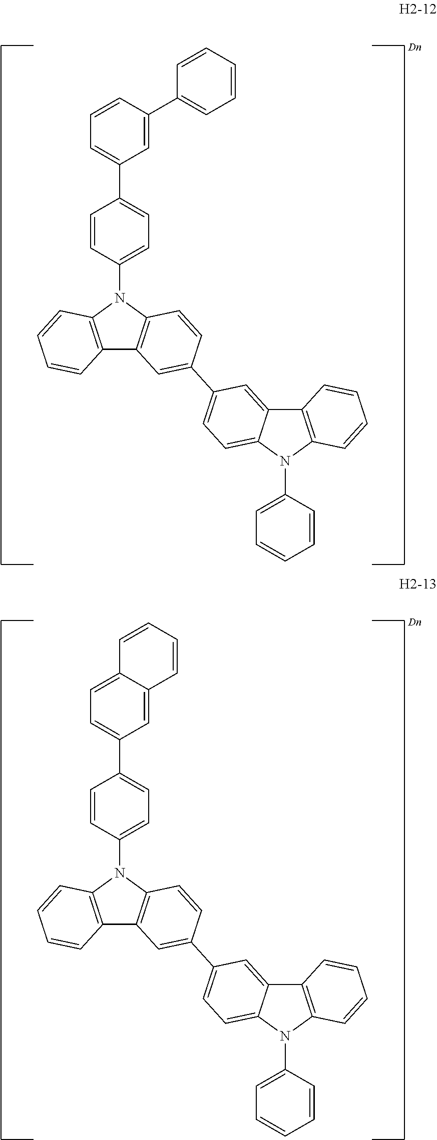

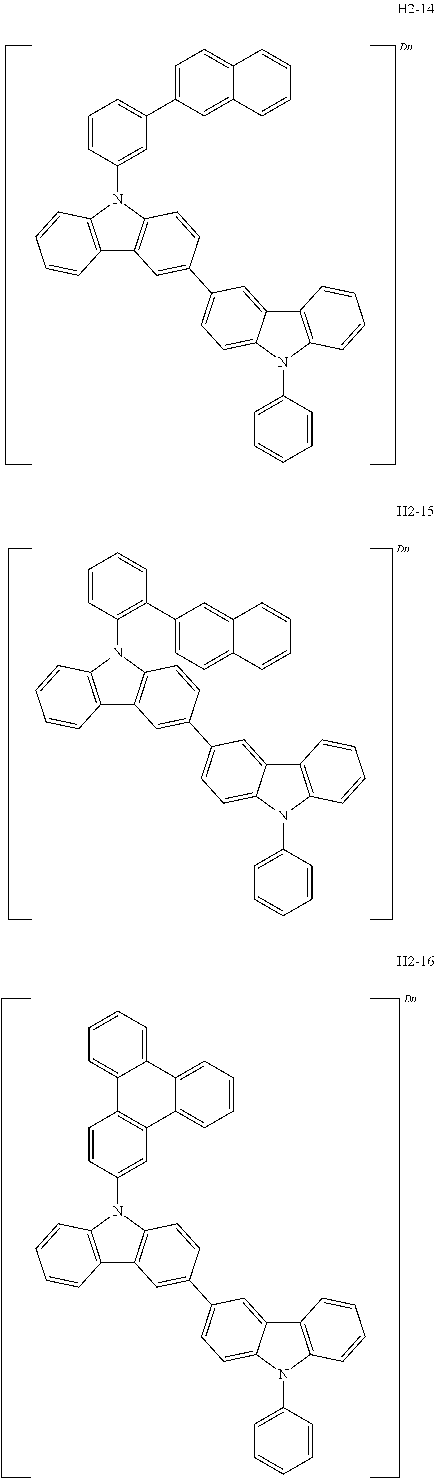

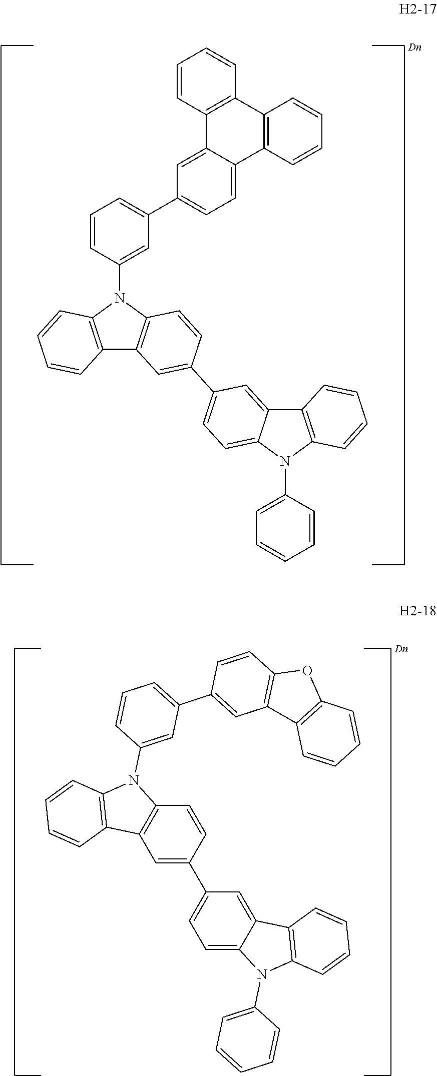

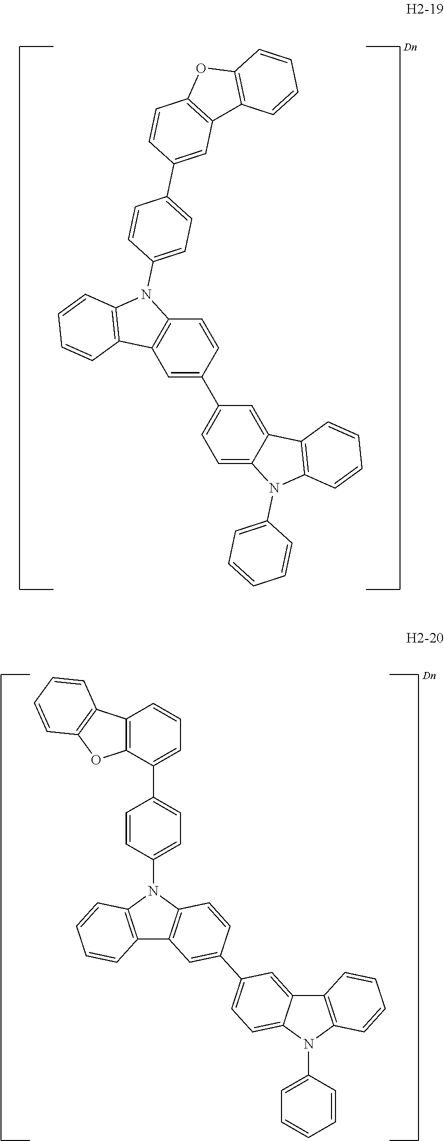

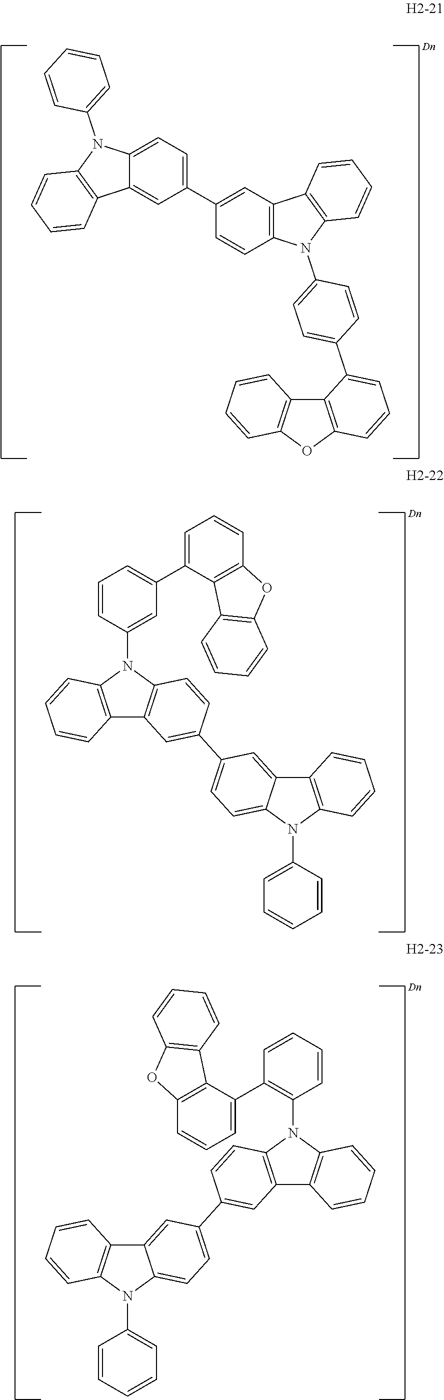

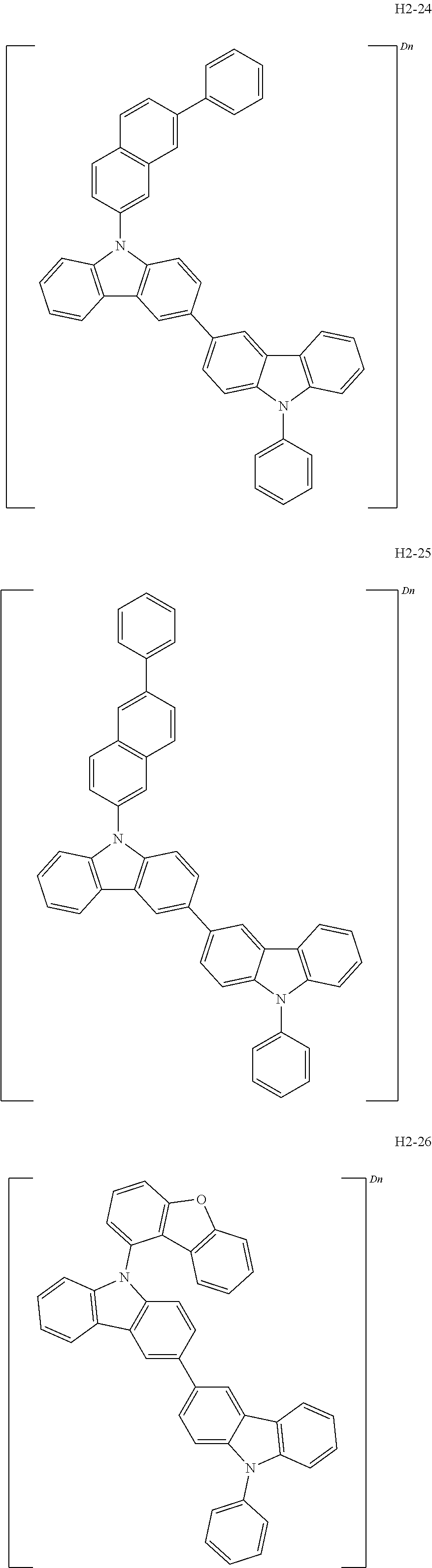

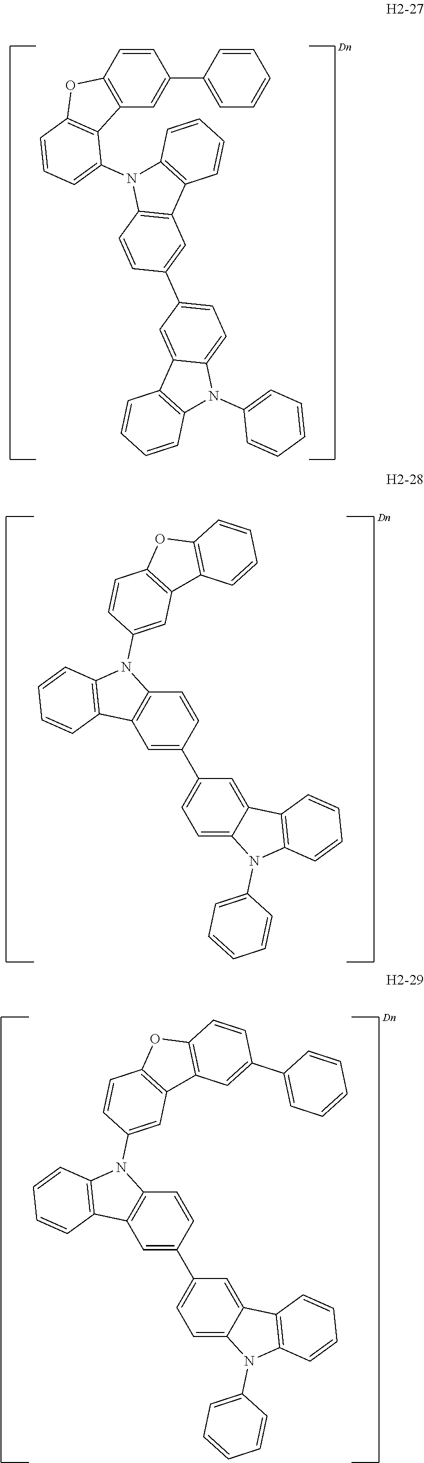

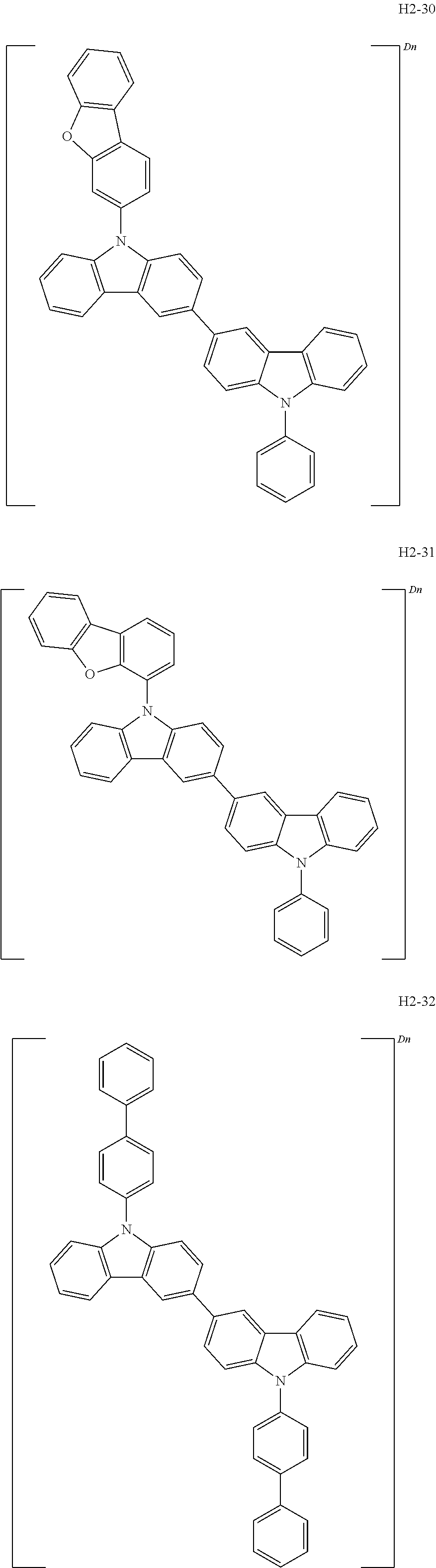

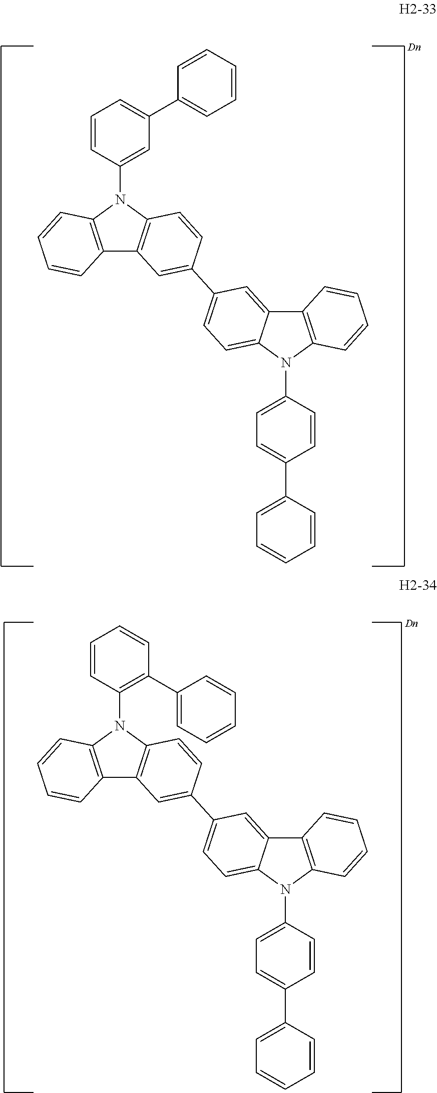

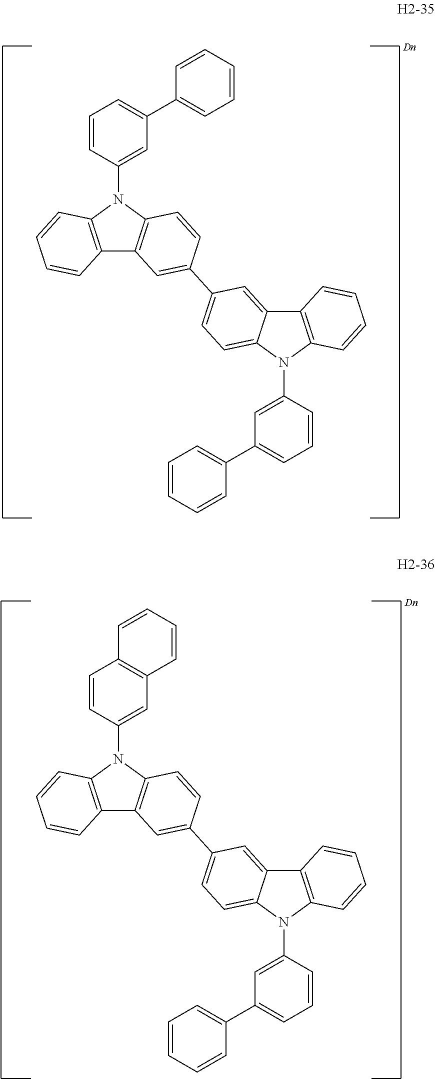

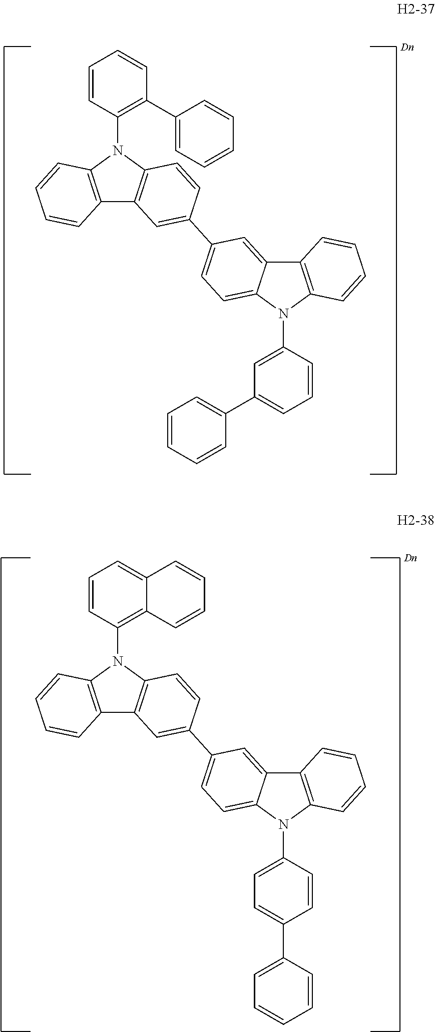

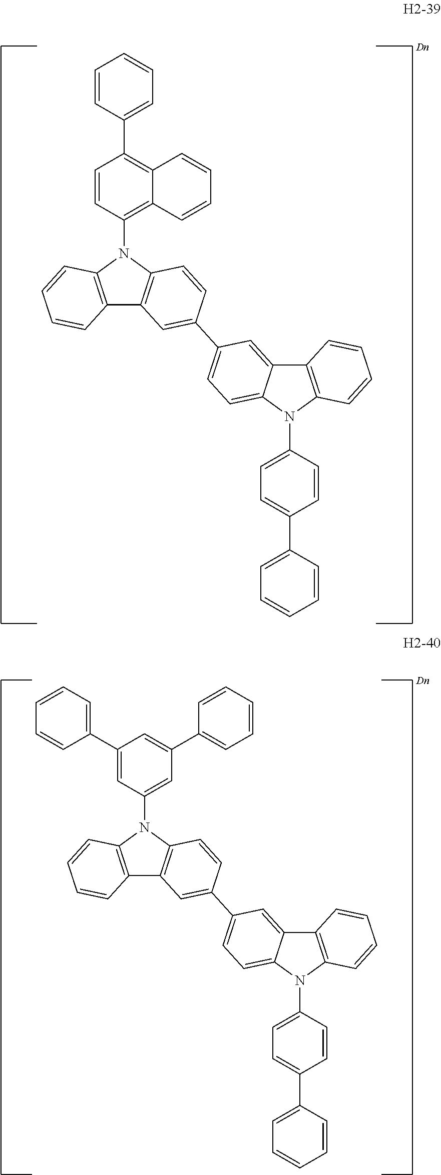

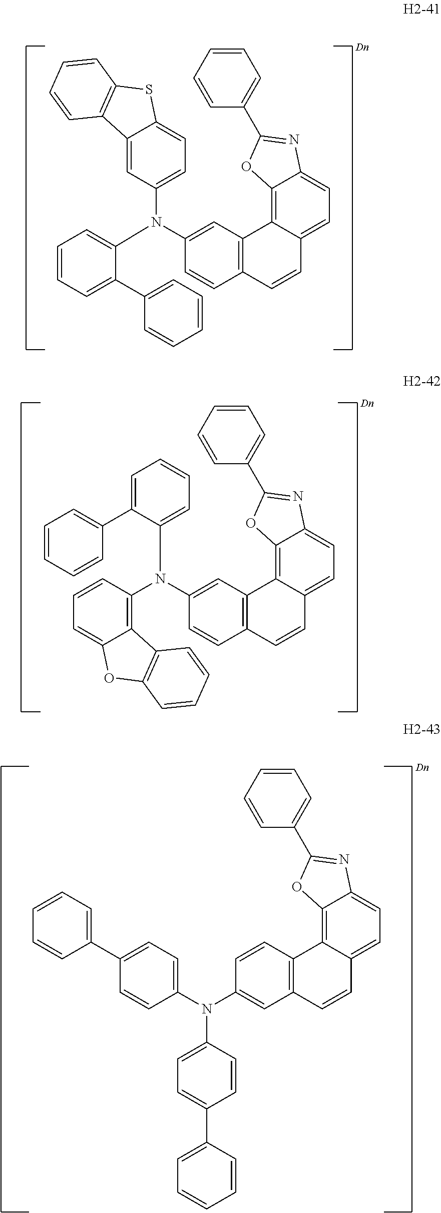

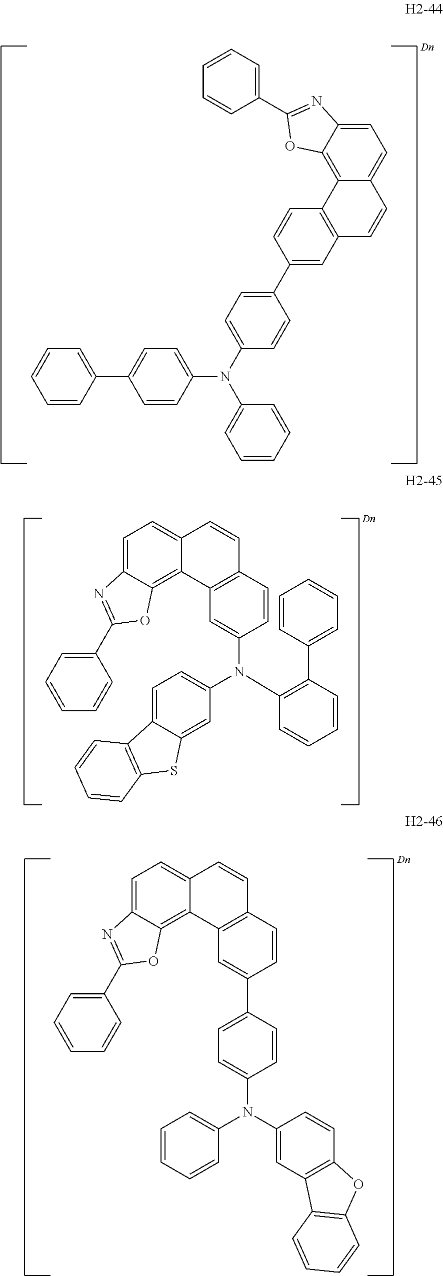

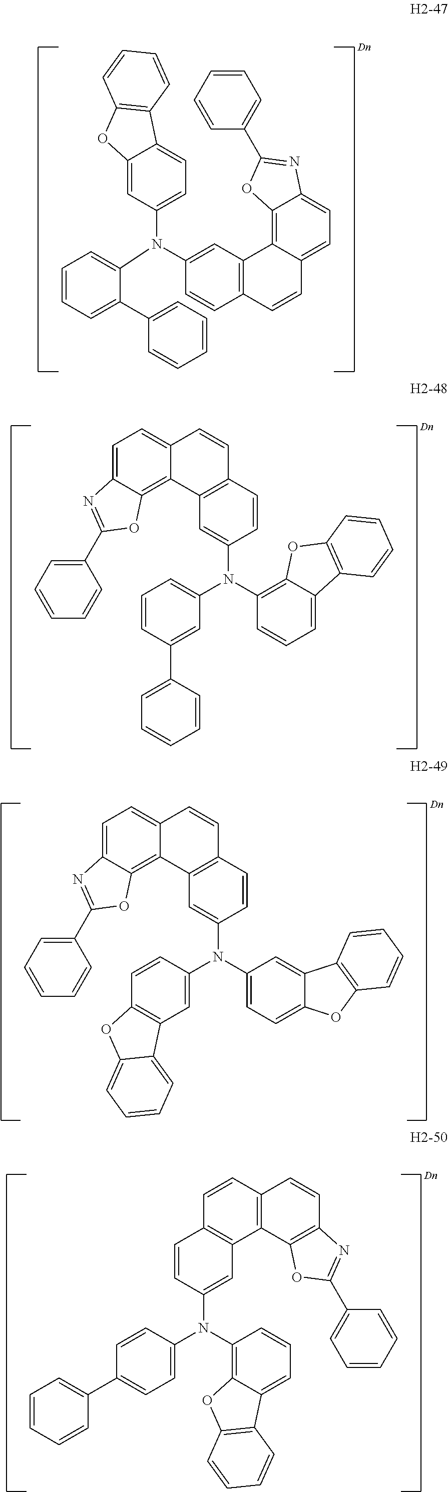

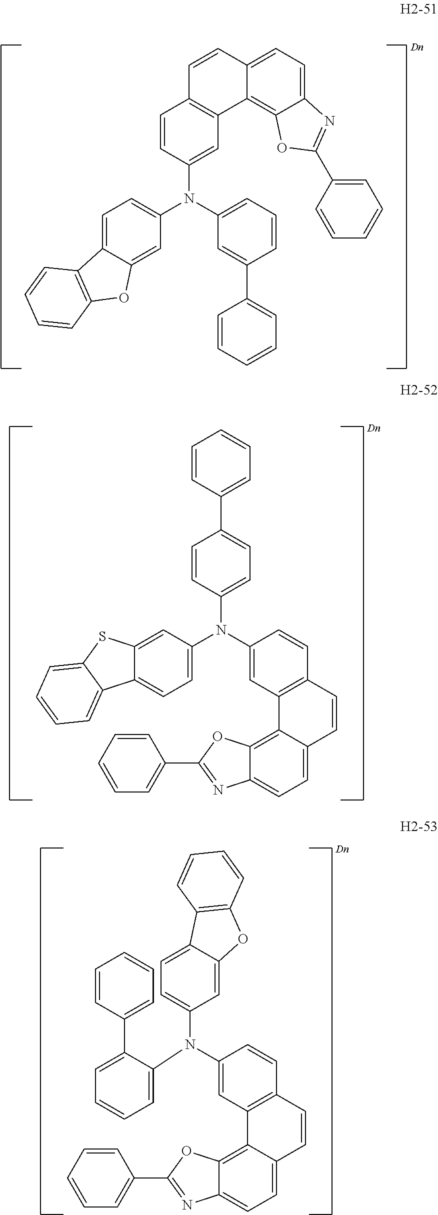

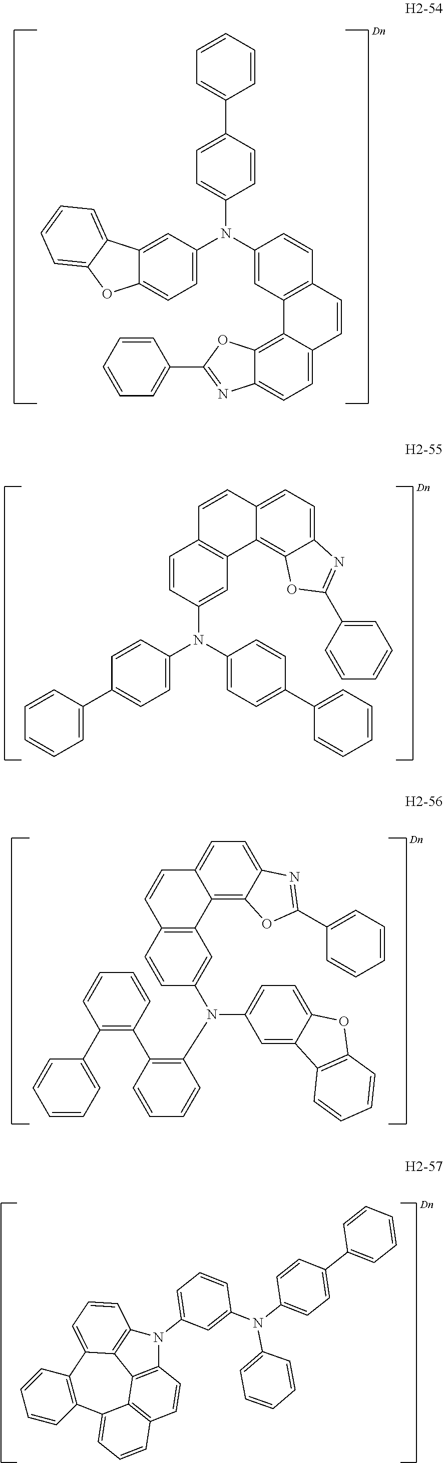

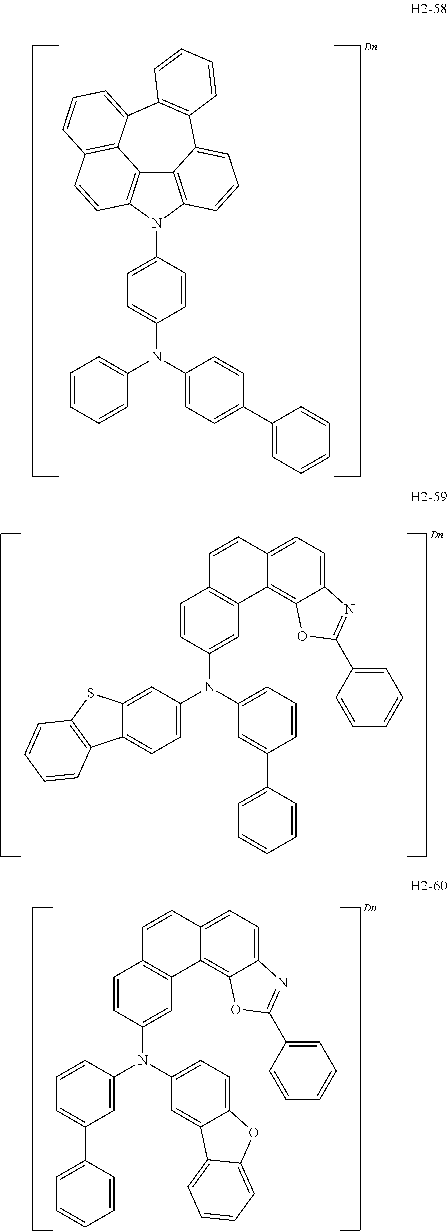

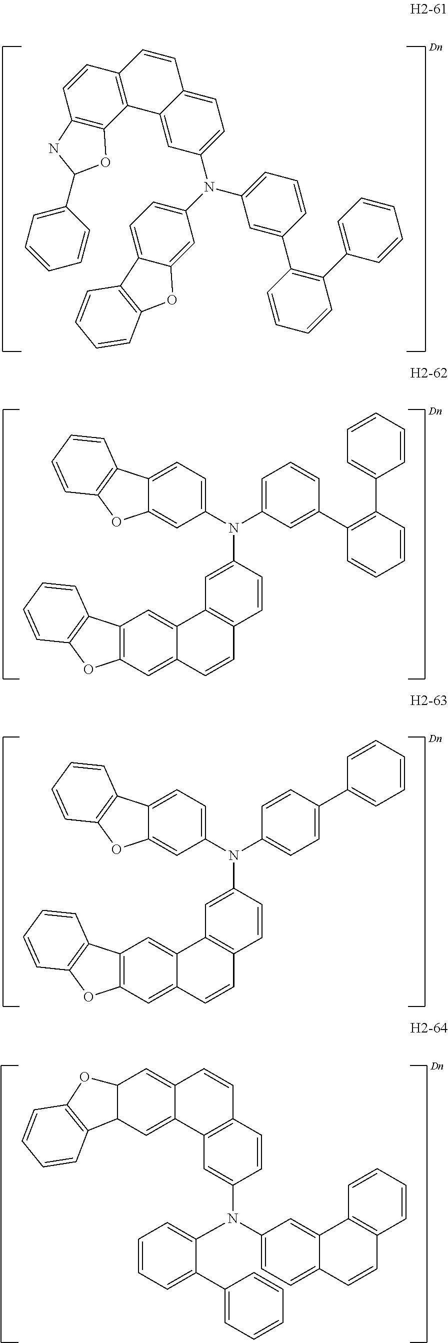

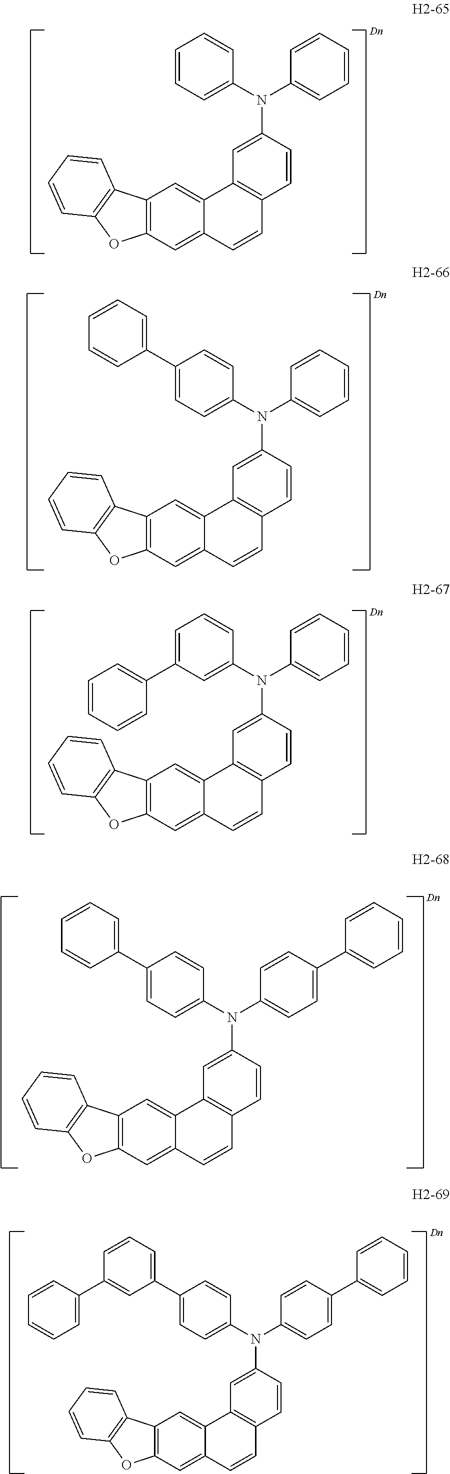

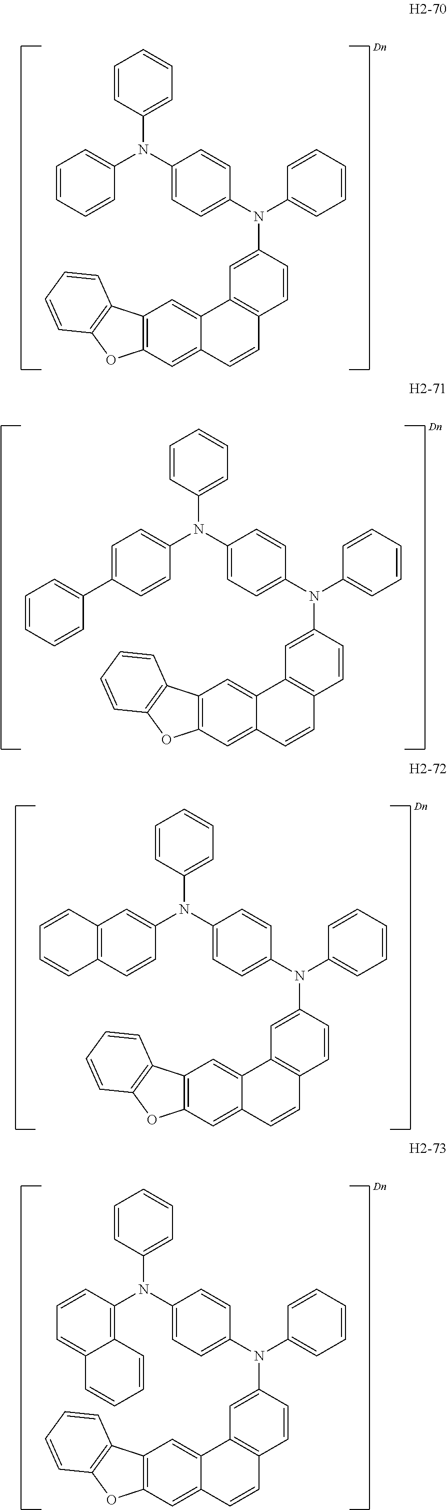

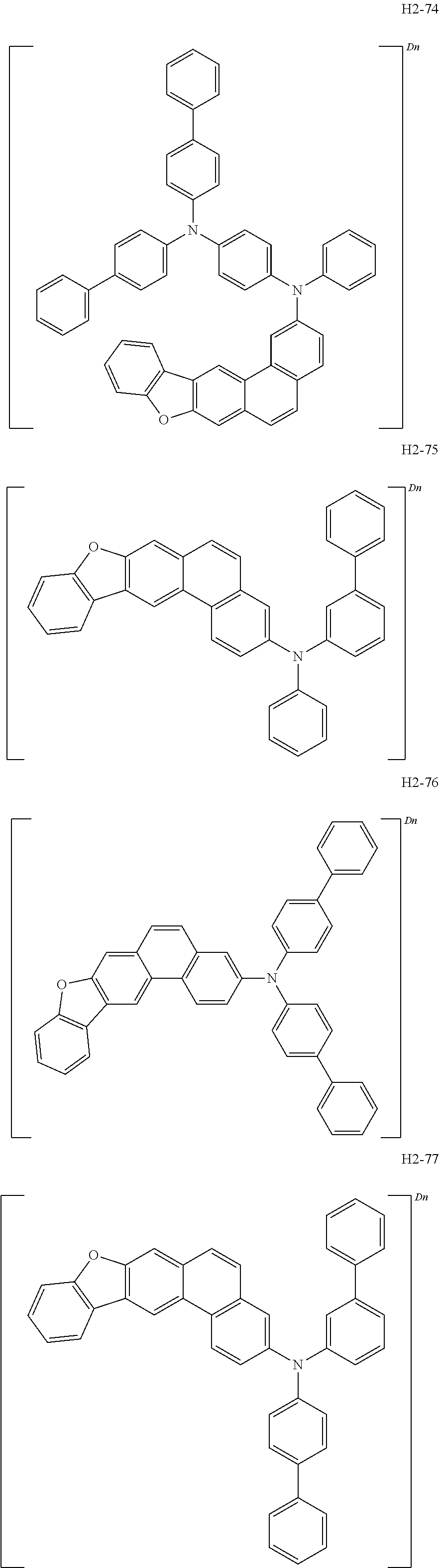

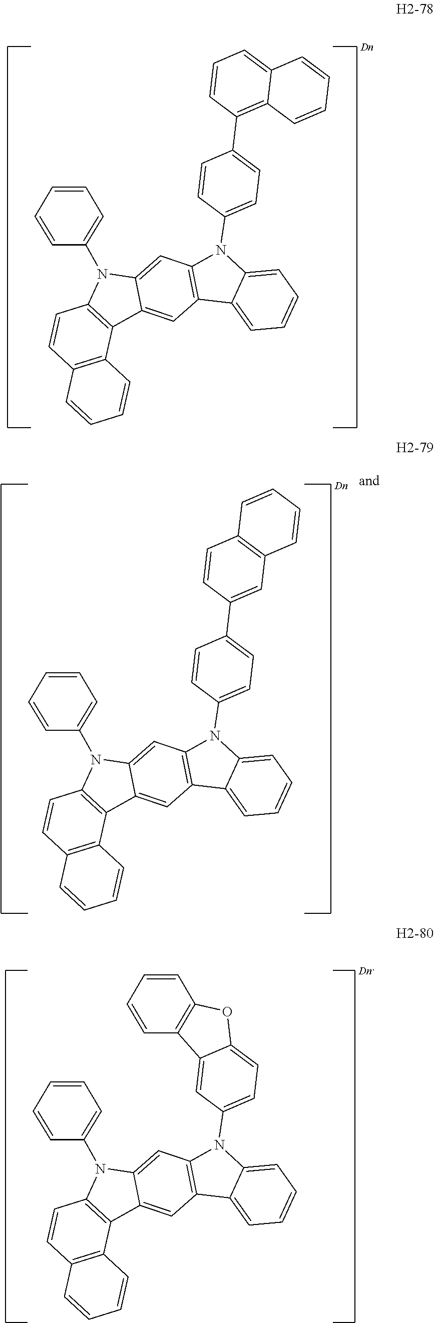

17. The organic electroluminescent device according to claim 12, wherein the compound represented by formula 6 or formula 7 is at least one selected from the following compounds:

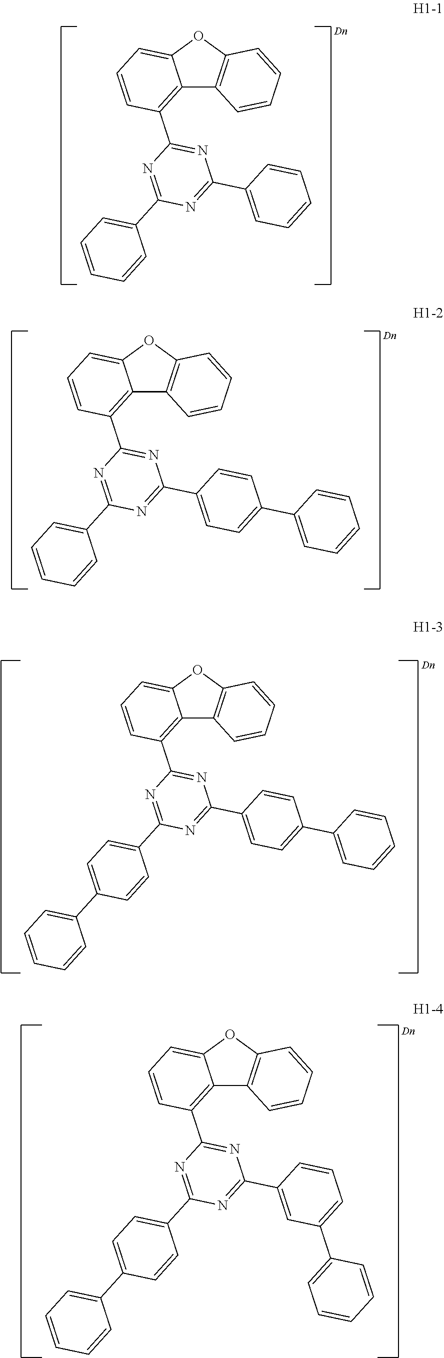

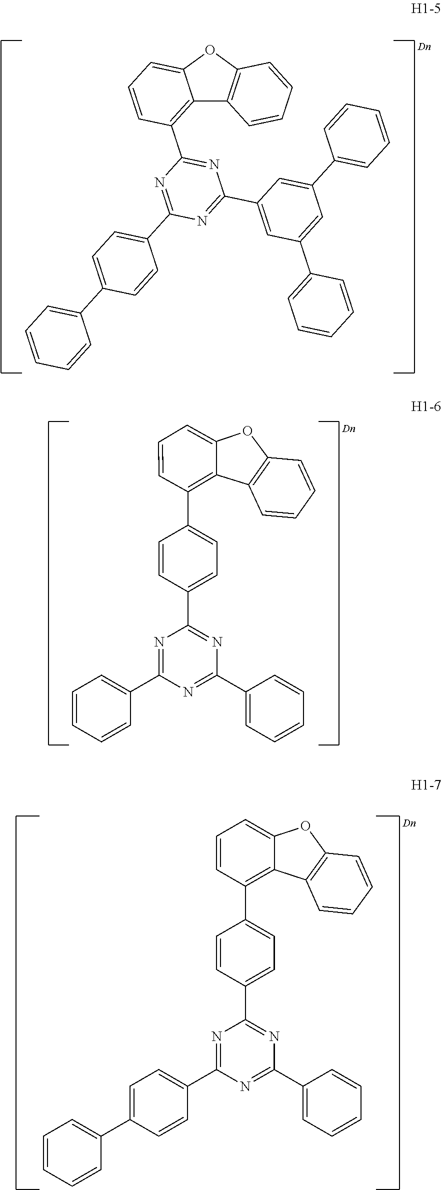

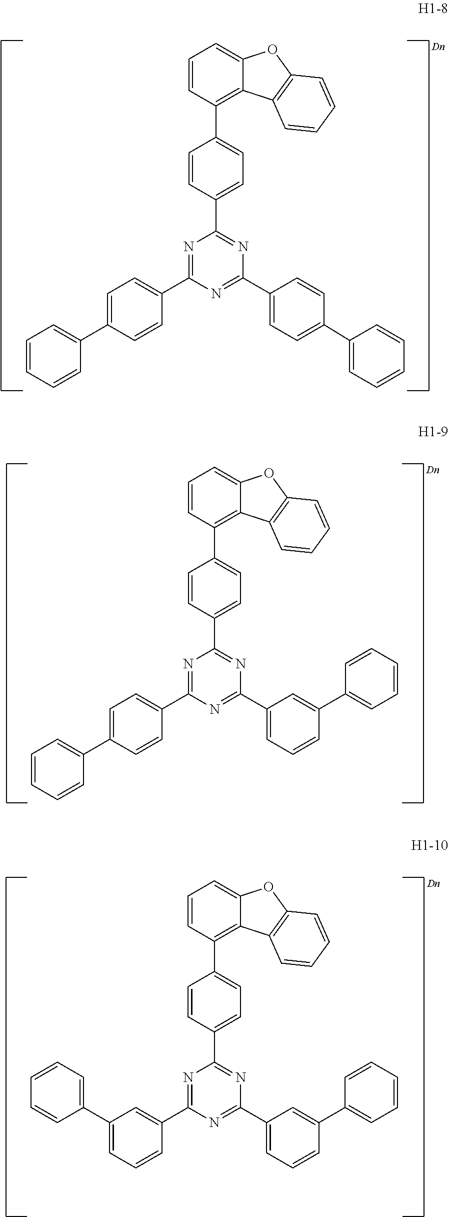

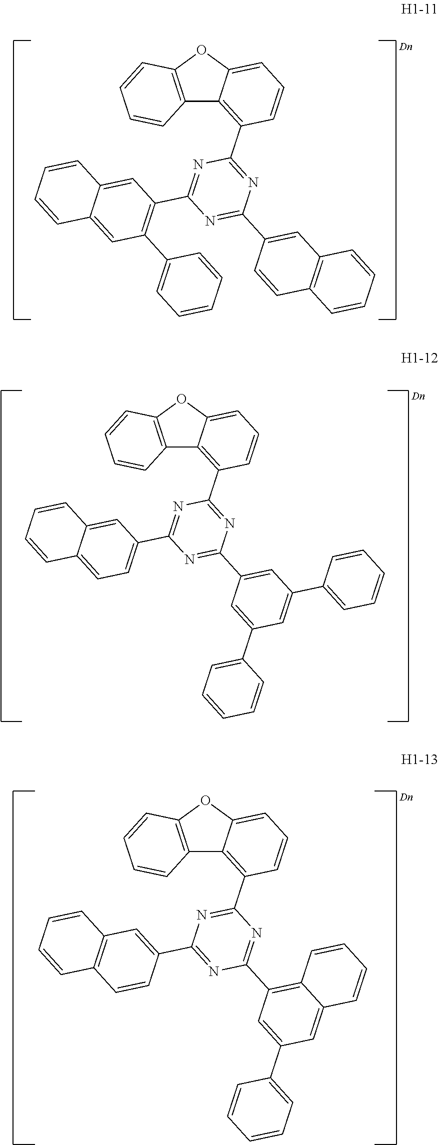

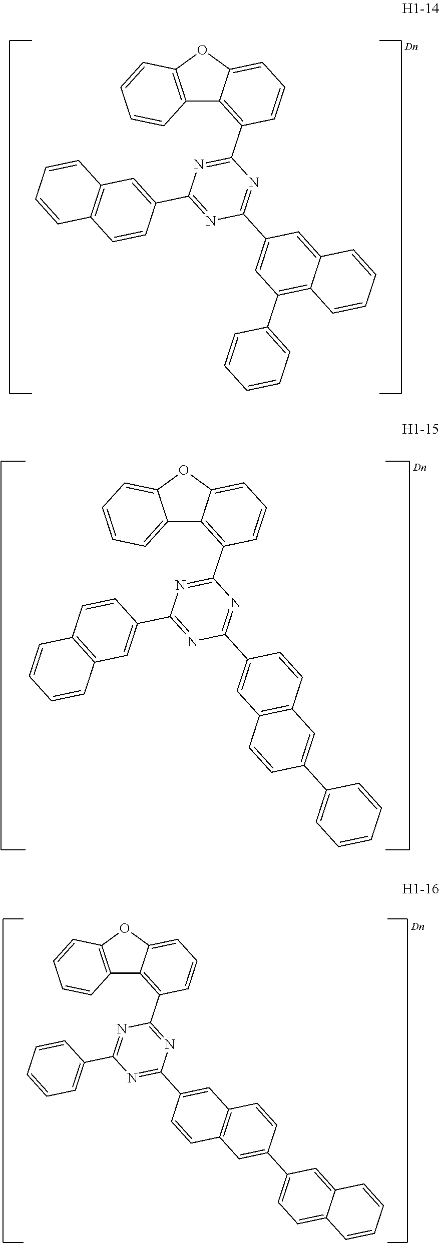

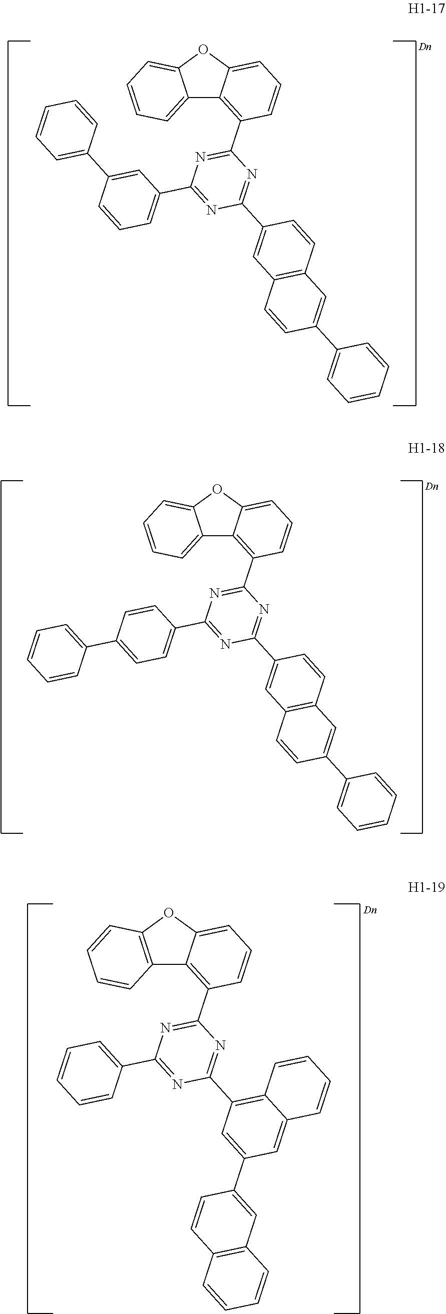

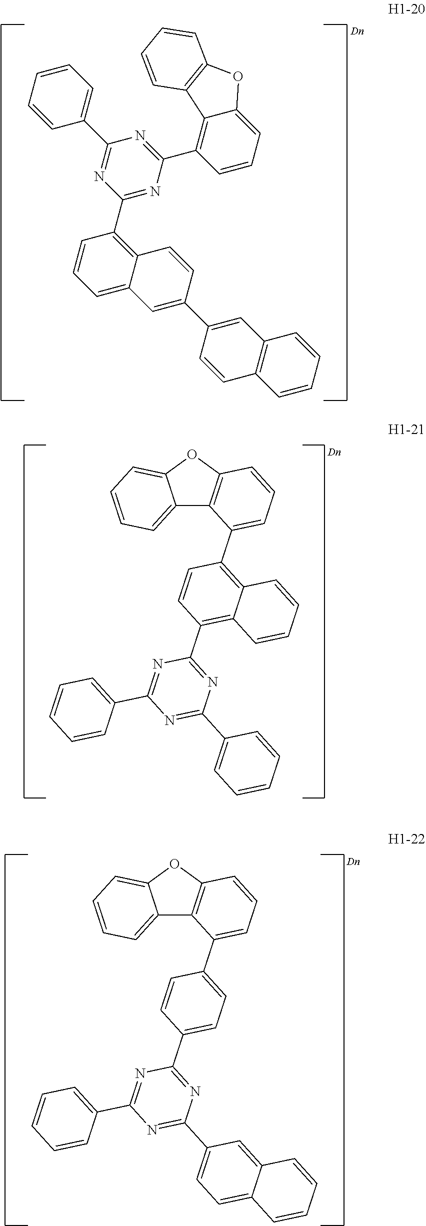

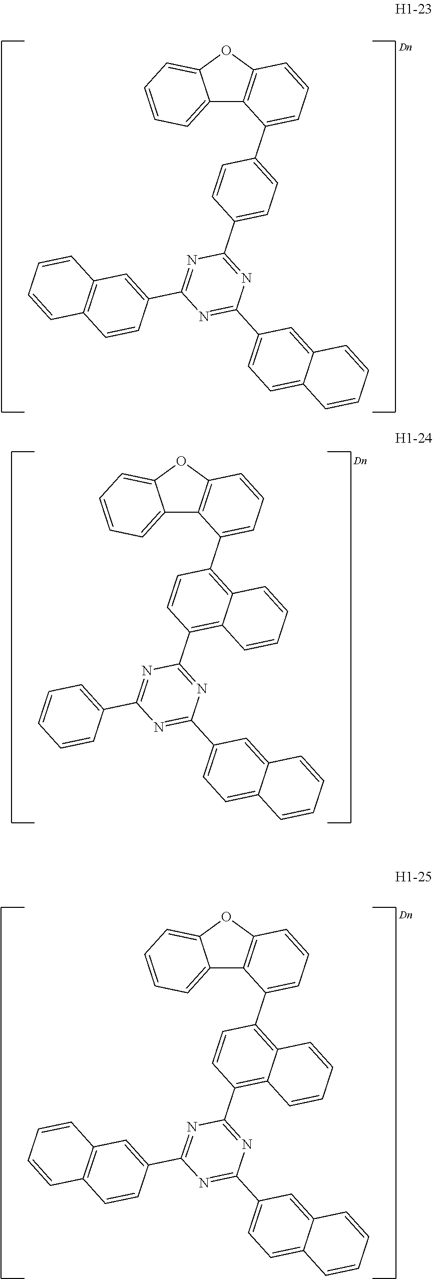

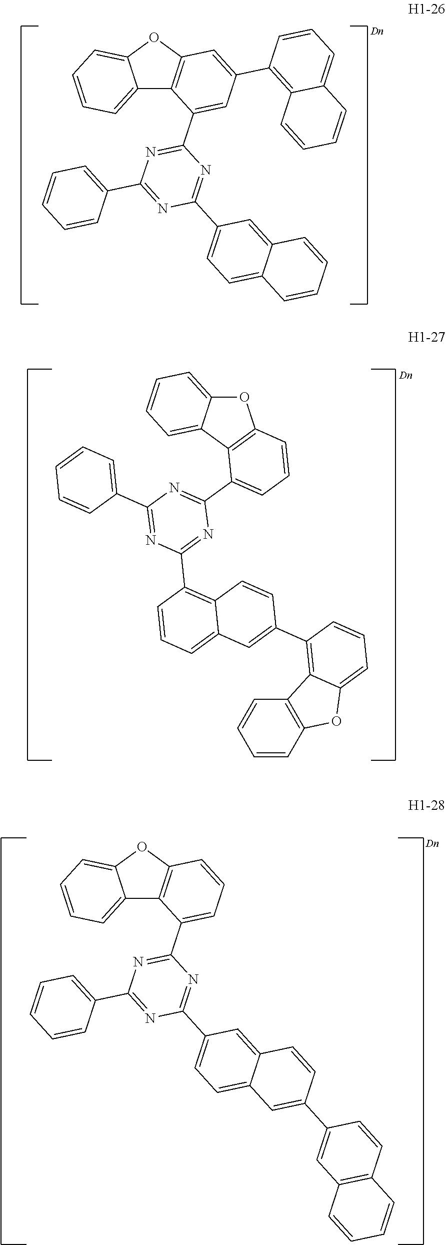

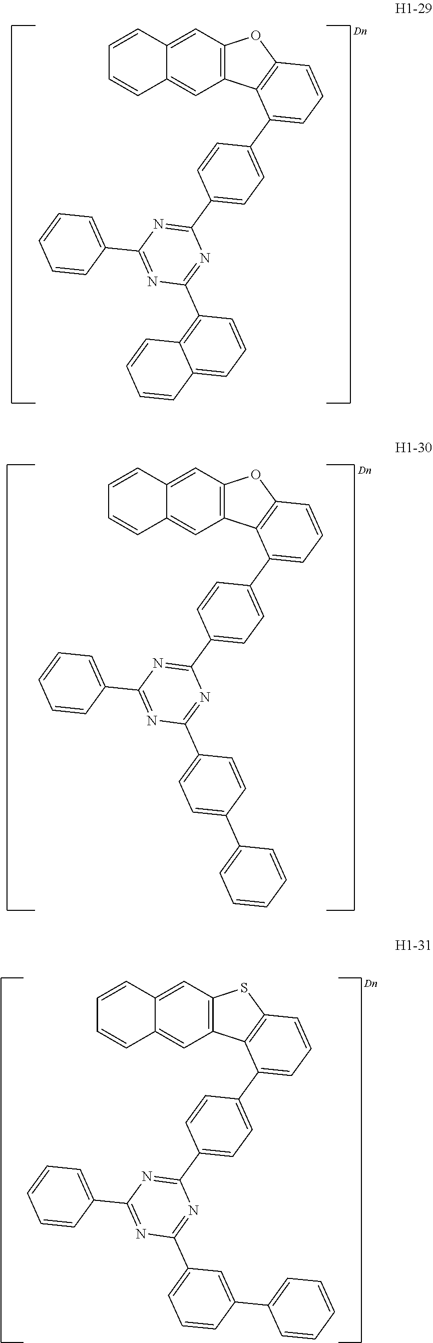

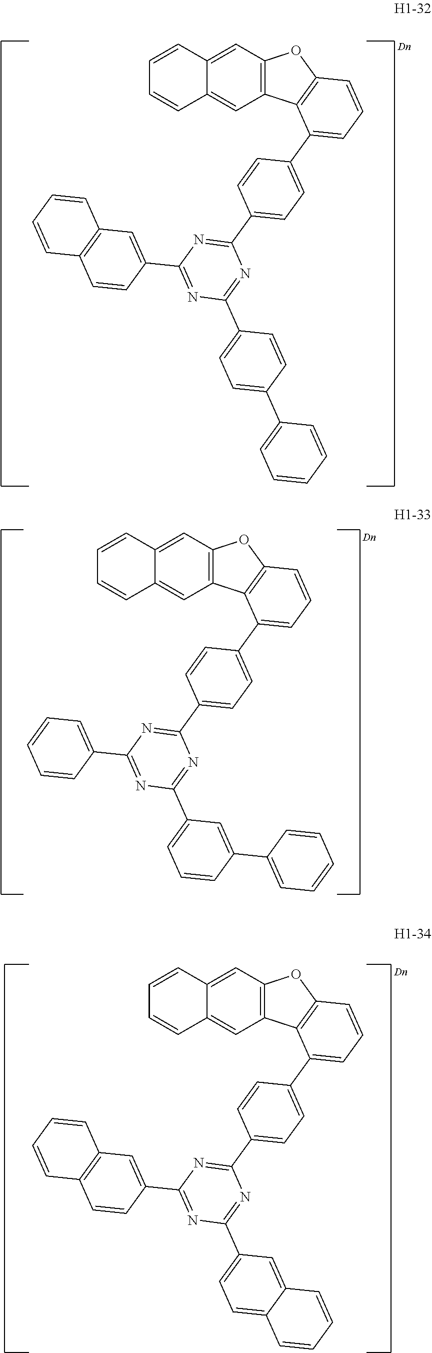

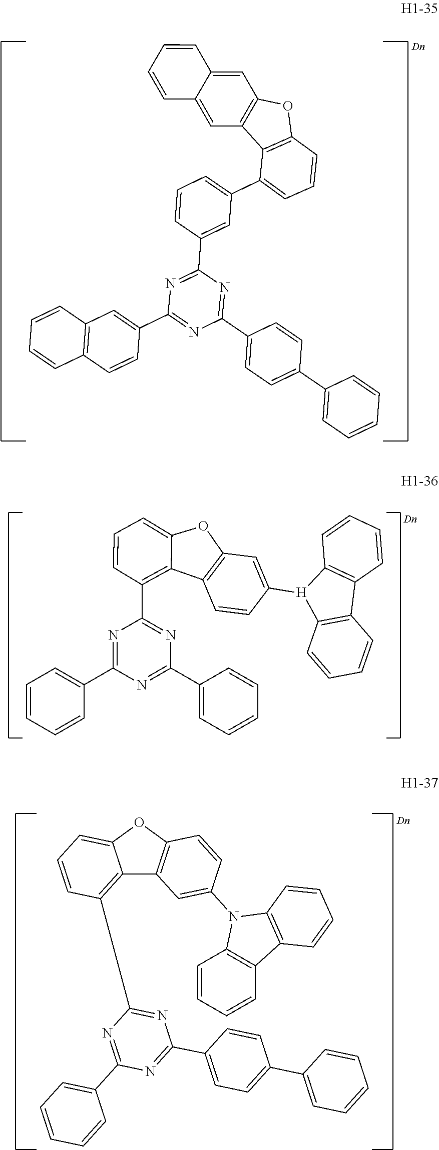

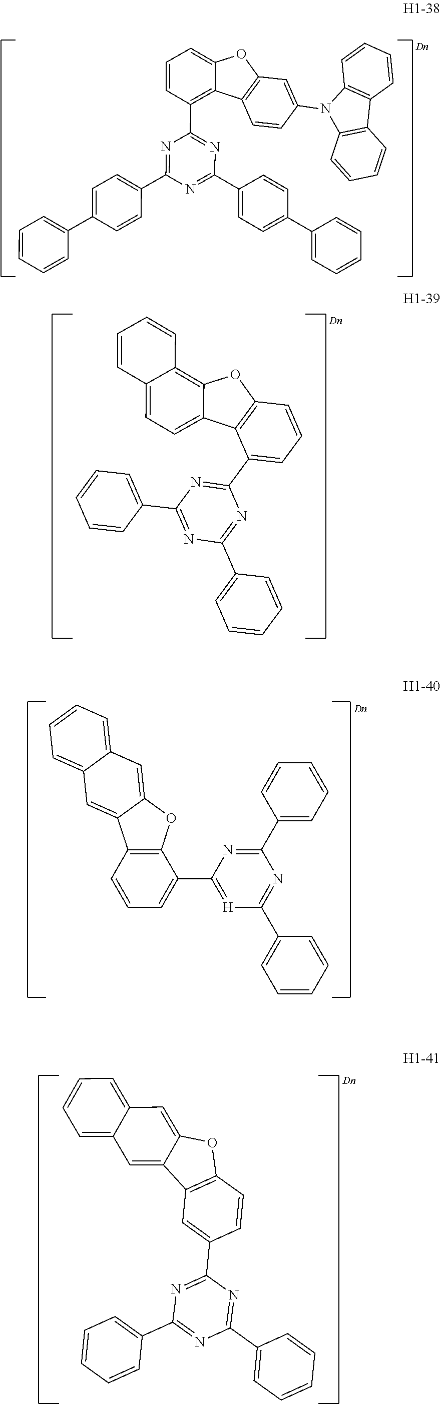

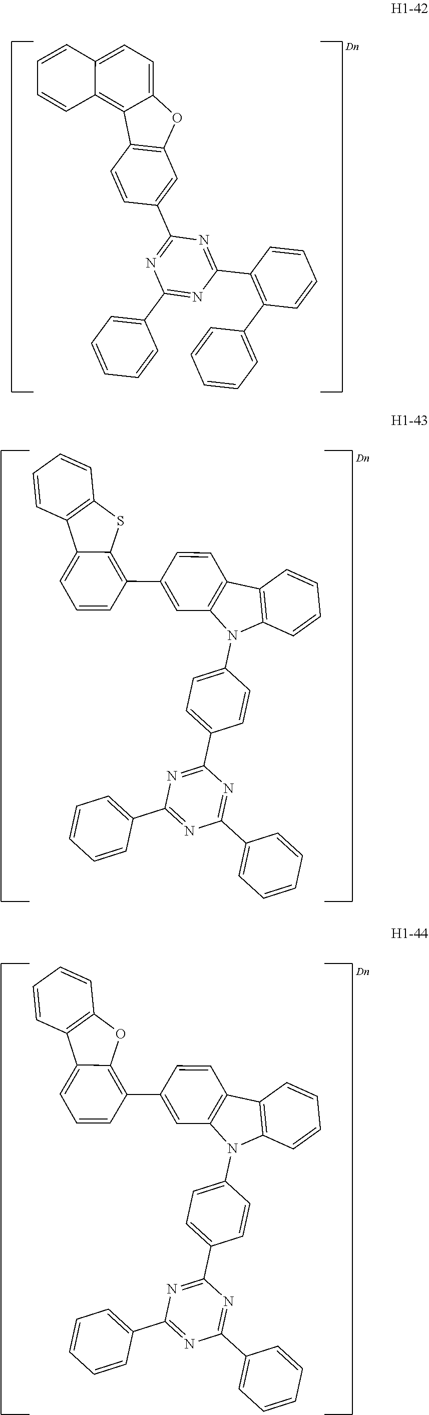

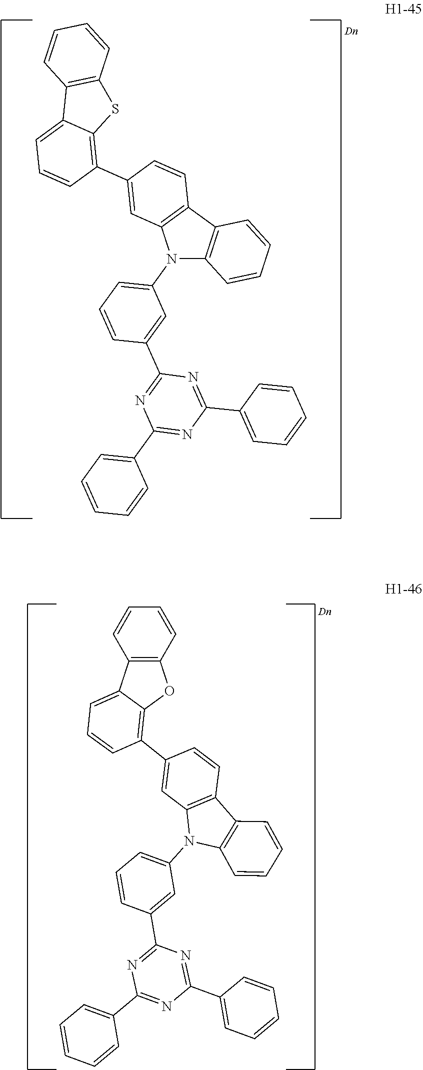

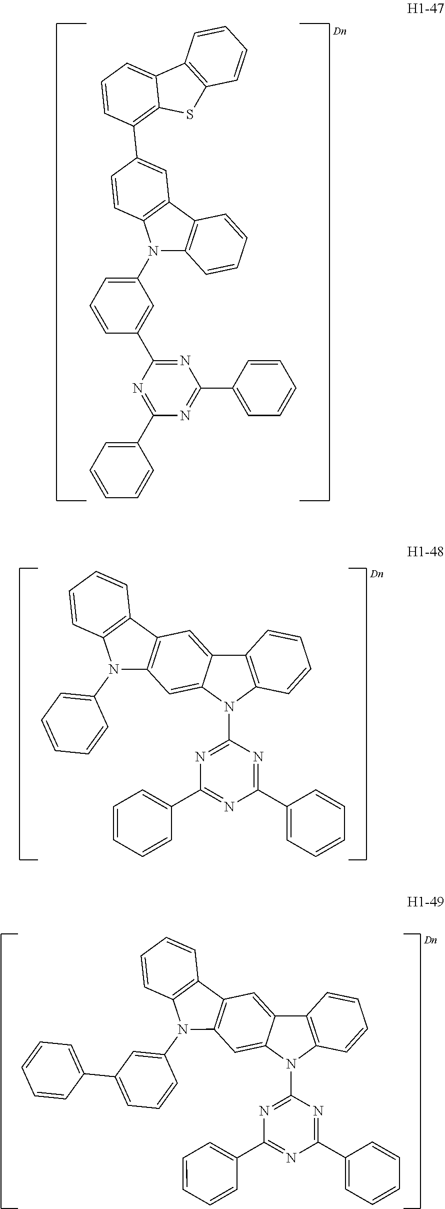

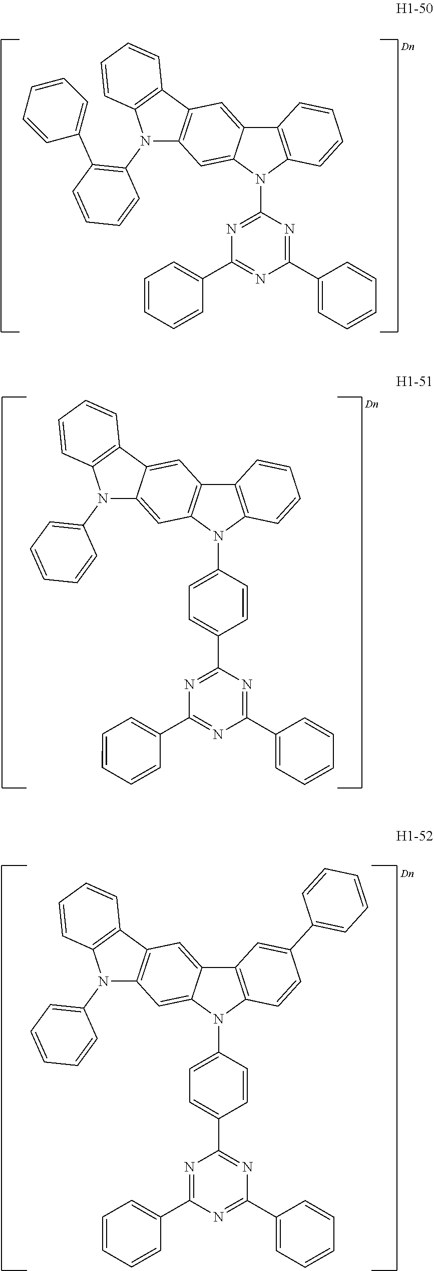

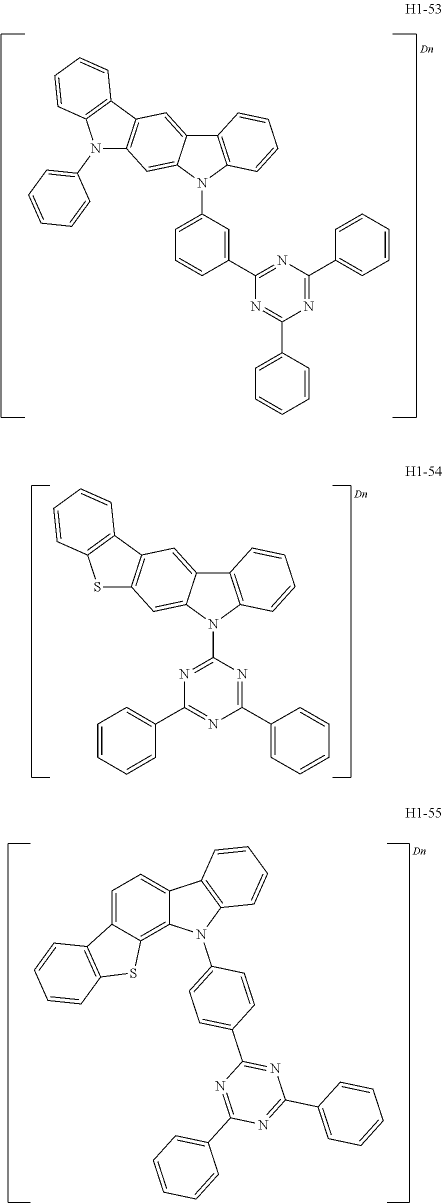

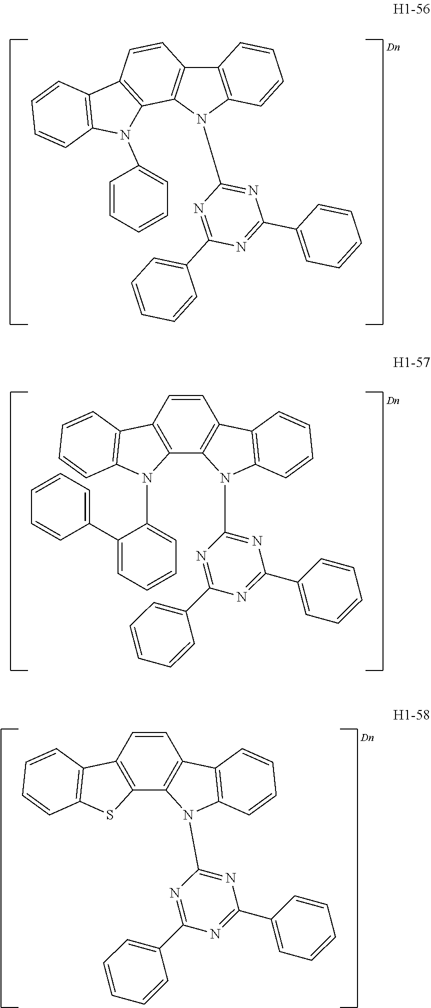

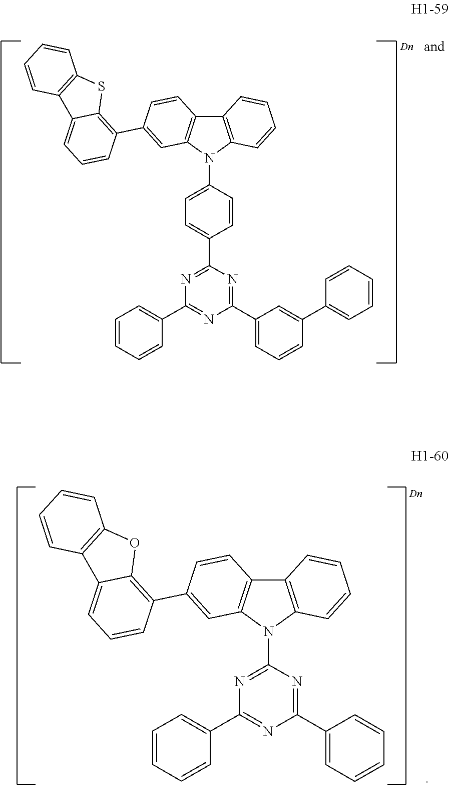

18. The organic electroluminescent device according to claim 13, wherein the compound represented by formula 8 is at least one selected from the following compounds:

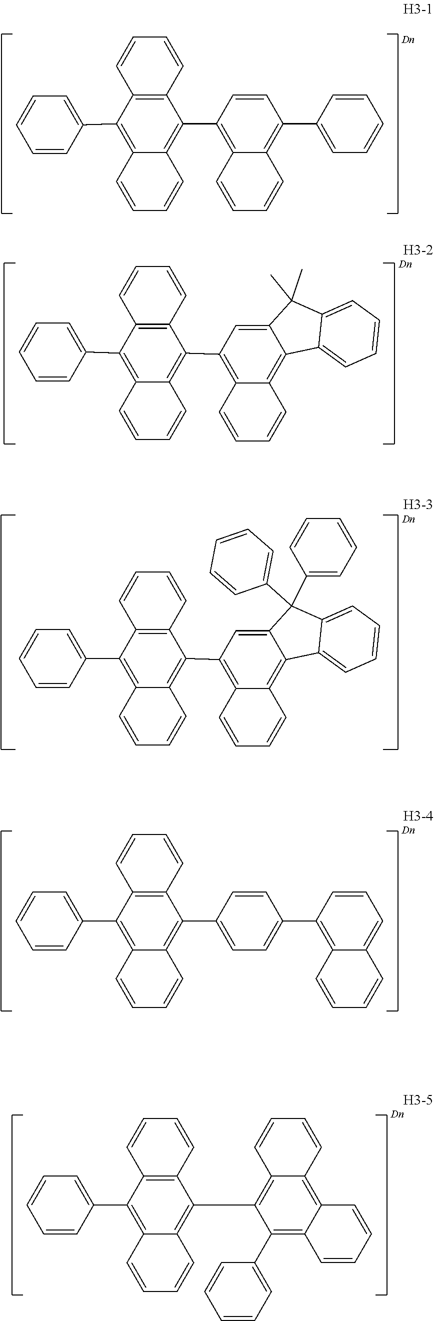

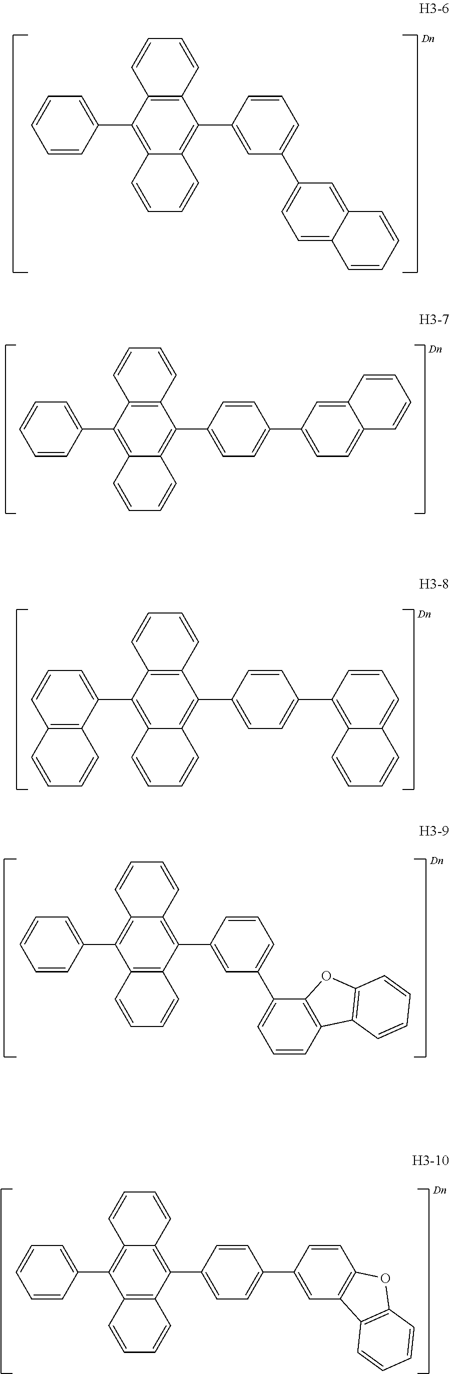

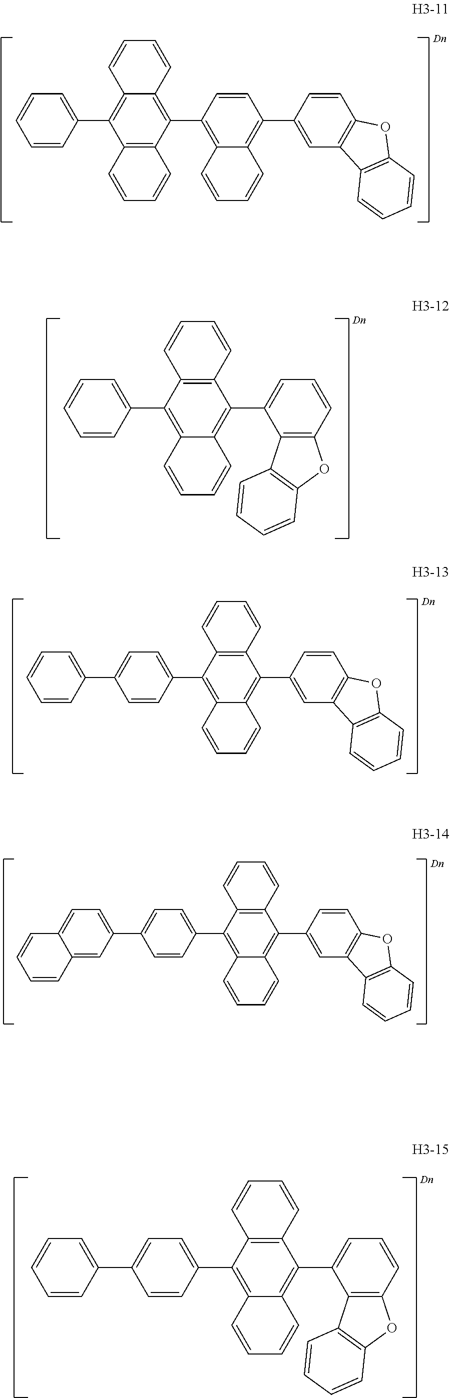

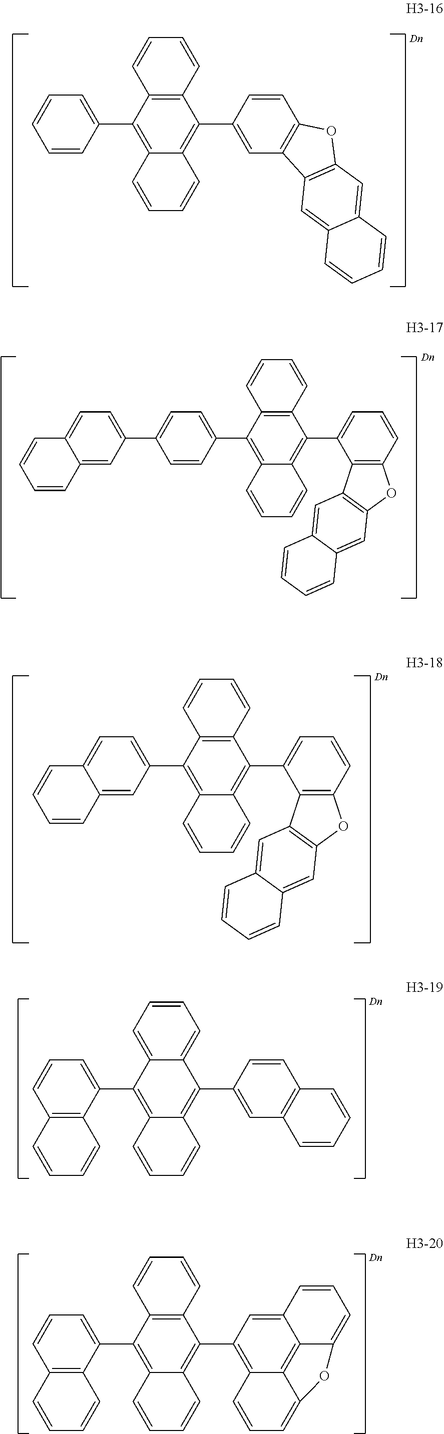

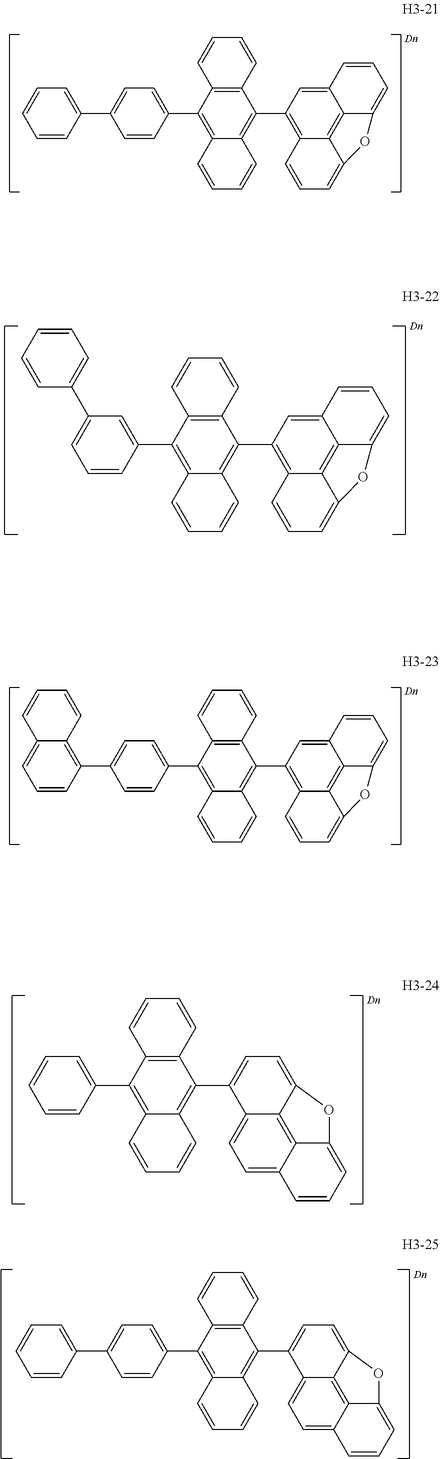

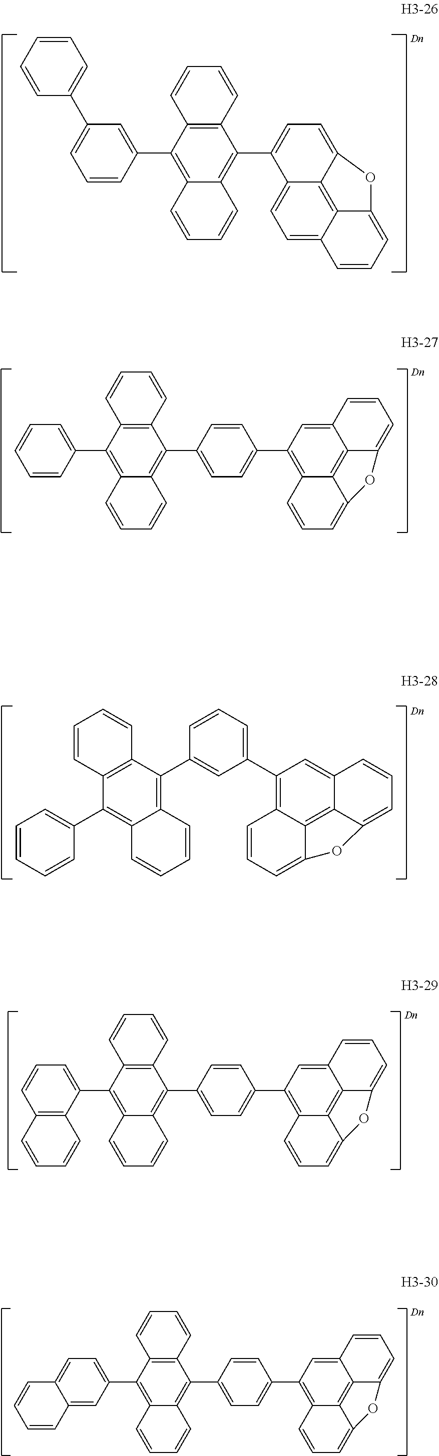

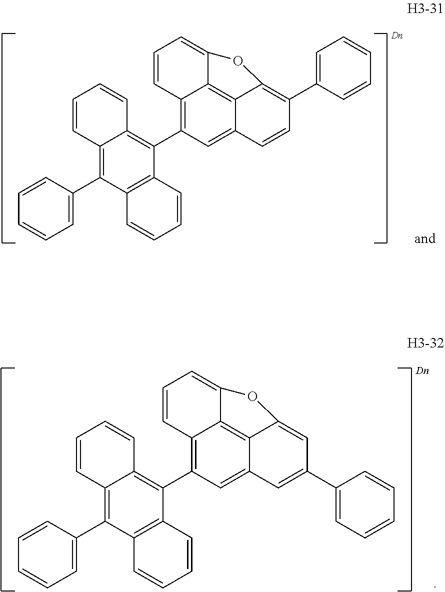

19. The organic electroluminescent device according to claim 4, wherein at least one layer in the light-emitting layer comprises a compound represented by the following formula 9: 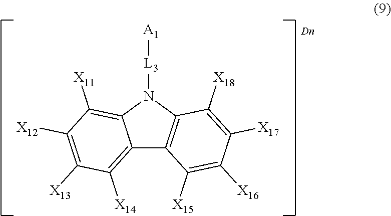
wherein in formula 9,
any adjacent pair of X₁₅ to X₁₈ is linked to the following formula 9-A to form a ring(s), and X₁₅ to X₁₈, which do not form a ring, X₁₁ to X₁₄, and X₃₁ to X₃₄ each independently represent hydrogen, deuterium, a substituted or unsubstituted (C6-C30)aryl, or a substituted or unsubstituted (3- to 30-membered)heteroaryl; 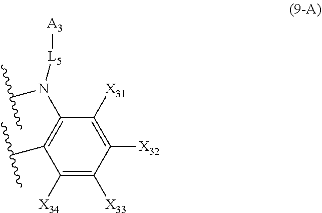
wherein in formulas 9 and 9-A,
A₁ and A₃ each independently represent a substituted or unsubstituted (C6-C30)aryl, a substituted or unsubstituted dibenzofuranyl, a substituted or unsubstituted dibenzothiophenyl, or a substituted or unsubstituted carbazolyl;
L₃ and L₅ each independently represent a single bond, or a substituted or unsubstituted (C6-C30)arylene; and
Dₙ represents that n number of hydrogens are replaced with deuterium, and n represents an integer of 1 or more, and has an upper limit of the number of hydrogen atoms in the non-deuterated compound.

20. The organic electroluminescent device according to claim 19, wherein X₁₁ or X₃₁ represents deuterium.

21. The organic electroluminescent device according to claim 19, wherein the compound represented by formula 9 is represented by any one of the following formulas 9-1 to 9-6: 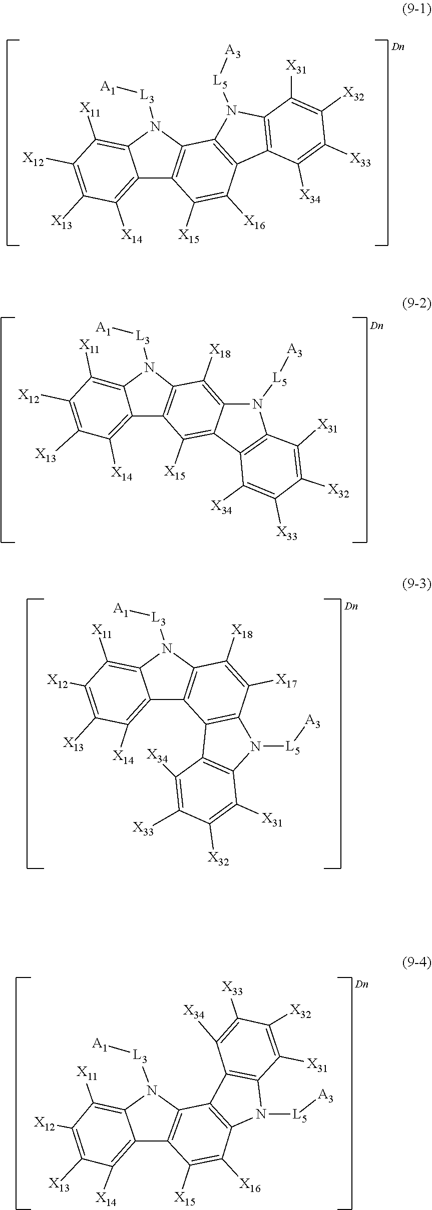 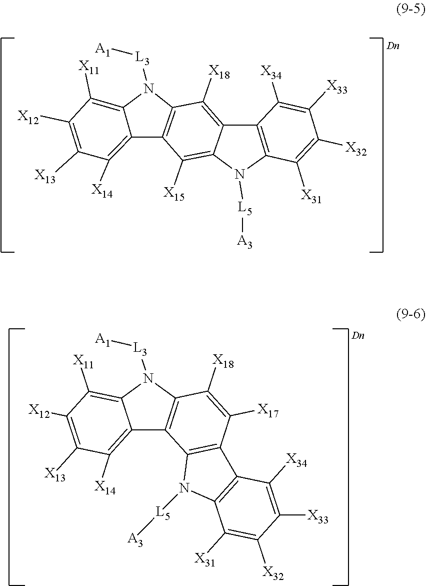
wherein in formulas 9-1 to 9-6, A₁, A₃, L₃, L₅, X₁₁ to X₁₈, X₃₁ to X₃₄, and Dₙ are as defined in claim 19.

22. The organic electroluminescent device according to claim 19, wherein the compound represented by formula 9 is at least one selected from the following compounds: 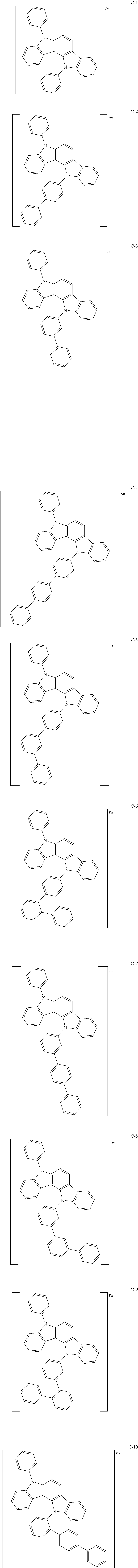 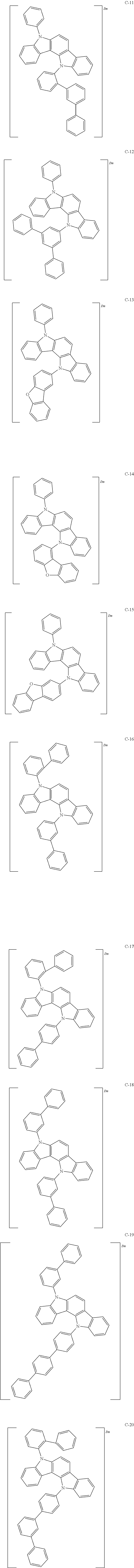 [chemical structure] [chemical structure] 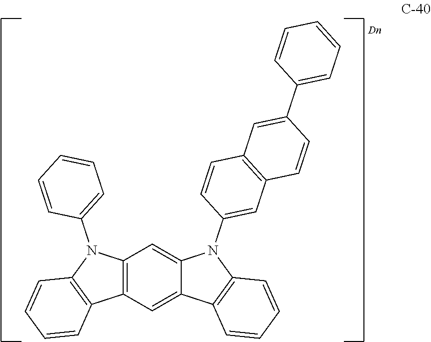 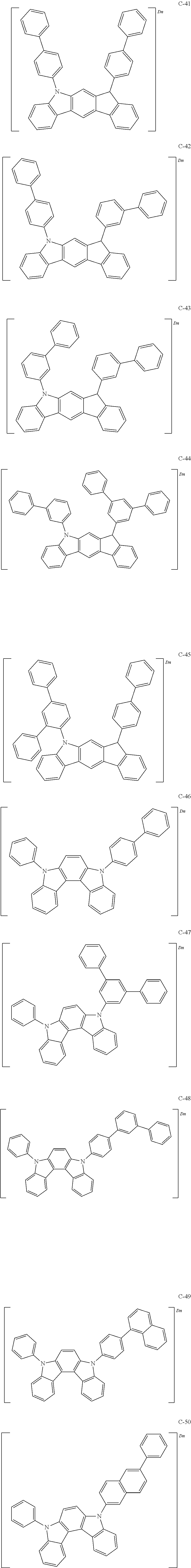 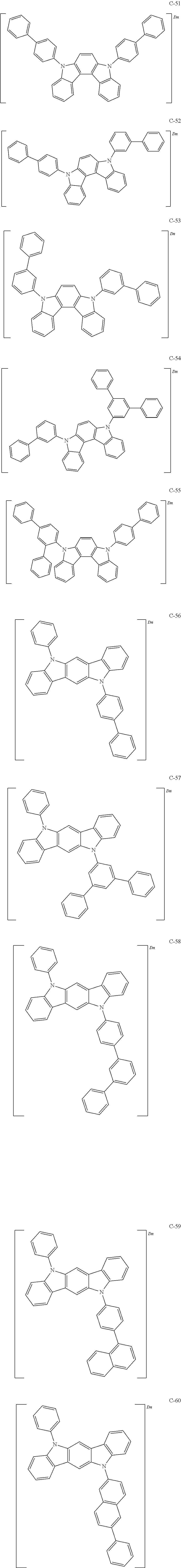 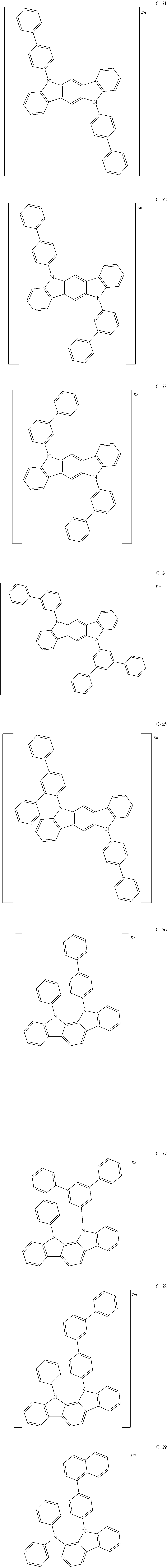 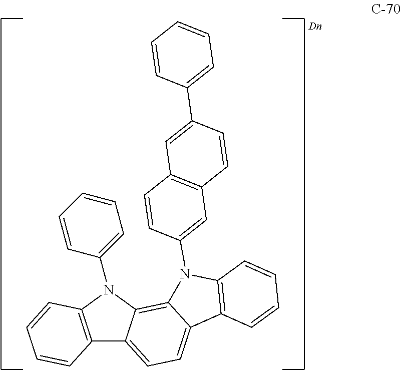 [chemical structure]
